(19) United States
(12) Patent Application Publication
(10) Pub. No.: US 2024/0051980 A1
(43) Pub. Date: Feb. 15, 2024

(54) ORGANOMETALLIC COMPOUND AND APPLICATION THEREOF

(71) Applicant: GUANGDONG AGLAIA OPTOELECTRONIC MATERIALS CO., LTD, Foshan, Guangdong (CN)

(72) Inventors: Liangliang YAN, Foshan (CN); Lei DAI, Foshan (CN); Lifei CAI, Foshan (CN)

(73) Assignee: GUANGDONG AGLAIA OPTOELECTRONIC MATERIALS CO., LTD, Foshan, Guangdong (CN)

(21) Appl. No.: 18/030,964

(22) PCT Filed: Aug. 15, 2021
(86) PCT No.: PCT/CN2021/112646

§ 371 Date: Apr. 7, 2023

(30) Foreign Application Priority Data
Oct. 28, 2020 (CN) 202011167564.6

(51) Int. Cl. C07F 15/00; H10K 85/30; H10K 50/12

(52) U.S. Cl. CPC C07F 15/0033; H10K 85/342; H10K 50/12

(57) ABSTRACT

The present disclosure relates to an organometallic compound and application thereof. The organometallic compound has a structure as shown in a formula (1). The compound provided by the present disclosure has the advantages of high optical and electrochemical stability, small half-peak width of emission spectrum, high color saturation, high luminous efficiency and long device service life, and can be used in organic electroluminescent devices. In particular, the compound has the potential for application in the AMOLED industry as a green light-emitting dopant.

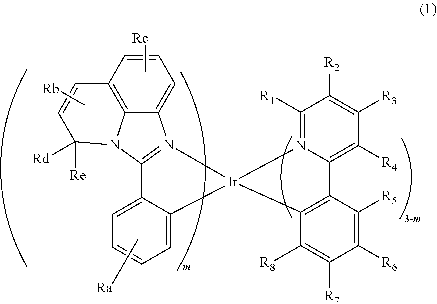

### TECHNICAL FIELD

The present disclosure relates to the technical field of organic electroluminescence, in particular to an organic light-emitting material applicable to organic electroluminescent devices, and specially in particular to an organometallic compound and application thereof to an organic electroluminescent device.

### BACKGROUND

At present, as a new-generation display technology, an organic electroluminescent device (OLED) has attracted more and more attention in display and lighting technologies, thus having a wide application prospect. However, compared with market application requirements, properties, such as luminous efficiency, driving voltage, and service life of the OLED still need to be strengthened and improved.

In generally, the OLED includes various organic functional material films with different functions sandwiched between metal electrodes as basic structures, which are similar to a sandwich structure. Under the driving of a current, holes and electrons are injected from a cathode and an anode, respectively. After moving a certain distance, the holes and the electrons are compounded in a light-emitting layer, and then released in the form of light or heat to achieve luminescence of the OLED.

However, organic functional materials are core components of the OLED, and the thermal stability, photochemical stability, electrochemical stability, quantum yield, film forming stability, crystallinity, and color saturation of the materials are main factors affecting properties of the device.

Generally, the organic functional materials include fluorescent materials and phosphorescent materials. The fluorescent materials are usually organic small-molecule materials, which can only utilize 25% of a singlet state for luminescence, so that the luminous efficiency is relatively low. Meanwhile, due to an earth-spin orbit coupling effect caused by a heavy atom effect, the phosphorescent materials can utilize 25% of a singlet state and can also utilize 75% of the energy of triplet excitons, so that the luminous efficiency can be improved. However, compared with the fluorescent materials, the phosphorescent materials are started later, and the thermal stability, service life, and color saturation of the materials need to be improved. Thus, the phosphorescent materials are a challenging topic. Various organometallic compounds have been developed to serve as the phosphorescent materials. For example, according to a patent for invention (CN1726606), an aryl-benzimidazole iridium compound is disclosed. However, the luminous efficiency of such compound is far from enough to meet market demands. According to a non-patent document published by Wen et al. (Chem. Mater. 2004, 16, 2480-2488) in 2004, a benzimidazole-aromatic ring metallic iridium complex is disclosed. Although the complex has certain luminous efficiency, market application demands are difficult to meet due to too large half-peak width of the material and too short device service life, especially too short T95 service life, and the material needs to be further improved. According to a patent document for invention (CN102272261), an iridium compound connected with aryl-substituted benzimidazole having steric hindrance on N is disclosed. However, the color saturation, half-peak width of emission spectrum and device properties, especially luminous efficiency and device service life, of the compound need to be improved. According to a patent document for invention (CN103396455), an iridium compound connected with alkyl-substituted benzimidazole on N is disclosed. Similarly, the compound also has problems such as poor color saturation, too large half-peak width of emission spectrum, insufficient device efficiency and short device service life, and needs to be improved. According to a patent document for invention (CN103254238), an iridium compound connected with aryl-substituted benzimidazoline-dibenzoheterocycle having steric hindrance on N is disclosed. However, the compound also has related problems of too large half-peak width of emission spectrum, insufficient device efficiency and short device service life, and needs to be improved. According to a patent document for invention (CN102898477), an iridium compound as shown as

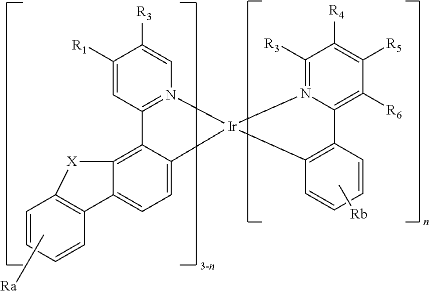

is disclosed. However, the compound also has related problems of too large half-peak width of emission spectrum, insufficient device efficiency and short device service life, and needs to be improved.

### SUMMARY

In order to overcome the above defects, the present disclosure provides an organic electroluminescent device with high properties and an organometallic compound material capable of realizing the organic electroluminescent device.

An organometallic compound of the present disclosure has the following structure as shown in a formula (1). An iridium complex provided by the present disclosure has the advantages of great optical and electrical stability, small half-peak width of emission spectrum, high luminous efficiency, long service life and high color saturation, and can be used in organic light-emitting devices. In particular, the compound has the potential for application in the AMOLED industry as a green light-emitting phosphorescent material.

An organometallic compound has a structure formula as shown in the following formula (1):

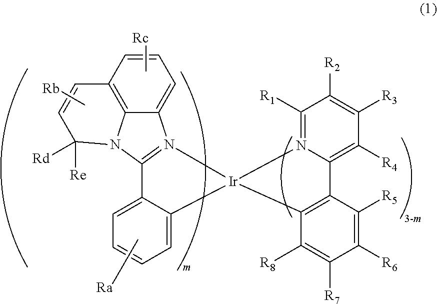

where

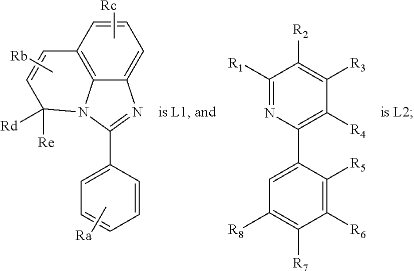

m is 1, 2, or 3, and when m is 1, the two L2 are the same or different;
the number of Ra, Rb and Rc is from 1 to a maximum substitution number;
Ra, Rb, Rc, Rd and Re are independently selected from hydrogen, deuterium, halogen, substituted or unsubstituted C₁-C₁₀ alkyl, substituted or unsubstituted C₃-C₂₀cycloalkyl, substituted or unsubstituted C₆-C₁₈ aryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
R₁-R₈ are independently selected from hydrogen, deuterium, halogen, hydroxyl, sulfhydryl, substituted or unsubstituted C₁-C₁₀ alkyl, substituted or unsubstituted C₁-C₁₀heteroalkyl, substituted or unsubstituted C₃-C₂₀cycloalkyl, substituted or unsubstituted C₂-C₁₀ alkenyl, substituted or unsubstituted C₂-C₁₀alkynyl, substituted or unsubstituted C₆-C₁₈ aryl, substituted or unsubstituted C₂-C₁₇heteroaryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl, or two adjacent groups of R₁-R₈ may be connected with each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, C₃-C₆cycloalkyl, amino substituted with C₁-C₆ alkyl, nitrile, isonitrile, or phosphino, and the substitution ranges from a single substitution number to a maximum substitution number.

When the m is 1 or 2, the two L1 or the two L2 are the same.

As a preferred organometallic compound, the Ra, the Rd and the Re are hydrogen.

As a preferred organometallic compound, at least one of the R₁-R₄ is not hydrogen.

As a preferred organometallic compound, at least one of the R₅-R₈ is not hydrogen.

As a preferred organometallic compound, at least one of the R₁-R₄ is not hydrogen, and at least one of the R₅-R₈ is not hydrogen.

As a preferred organometallic compound, one of the R₁-R₄ is deuterium, C₁-C₅ alkyl substituted or unsubstituted with deuterium, or C₃-C₅cycloalkyl substituted or unsubstituted with deuterium, one of the R₅-R₈ is deuterium, C₁-C₅ alkyl substituted or unsubstituted with deuterium, or C₃-C₅cycloalkyl substituted or unsubstituted with deuterium, and the other groups are hydrogen.

As a preferred organometallic compound, the R₅ and the R₆, the R₆ and the R₇, or the R₇ and the R₈ are connected with each other to form a parallel ring structure as shown in a formula (2):

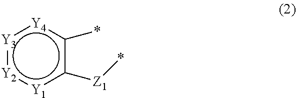

where * indicates a connecting position;
Y₁-Y₄ are independently CR₀ or N;
Z₁ is selected from O or S;
R₀ is independently hydrogen, deuterium, F, cyano, substituted or unsubstituted C₁-C₁₀ alkyl, substituted or unsubstituted C₃-C₂₀cycloalkyl, substituted or unsubstituted C₂-C₃₀ alkenyl, substituted or unsubstituted C₂-C₃₀alkynyl, substituted or unsubstituted C₆-C₃₀ aryl, substituted or unsubstituted C₁-C₃₀heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄alkoxyl, C₃-C₆cycloalkyl, amino substituted with C₁-C₄ alkyl, nitrile, isonitrile, or phosphino.

As a preferred organometallic compound, the R₄ and the R₅ are connected with each other to form an aliphatic ring structure as shown in a formula (3):

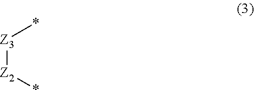

where * indicates a connecting position;
Z₂ and Z₃ are independently selected from O, S, N(R₀) and C(R₀)₂, and at least one of the Z₂ and Z₃ is C(R₀)₂;
R₀ is independently hydrogen, deuterium, F, cyano, substituted or unsubstituted C₁-C₁₀ alkyl, substituted or unsubstituted C₃-C₂₀cycloalkyl, substituted or unsubstituted C₂-C₃₀ alkenyl, substituted or unsubstituted C₂-C₃₀alkynyl, substituted or unsubstituted C₆-C₃₀ aryl, substituted or unsubstituted C₁-C₃₀heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄alkoxyl, C₃-C₆cycloalkyl, amino substituted with C₁-C₄ alkyl, nitrile, isonitrile, or phosphino.

As a preferred organometallic compound, at least one of the Rb and the Rc is not hydrogen.

As a preferred organometallic compound, at least one of the Rb and the Rc is substituted or unsubstituted C₁-C₆ alkyl, or substituted or unsubstituted C₃-C₆cycloalkyl.

As a preferred organometallic compound, at least one of the Rb and the Rc is substituted or unsubstituted C₁-C₆ alkyl, or substituted or unsubstituted C₃-C₆cycloalkyl, and the other group is hydrogen.

As a preferred organometallic compound, the L1 preferably has one of the following structural formulas, or is partially or completely deuterated or fluorinated correspondingly,

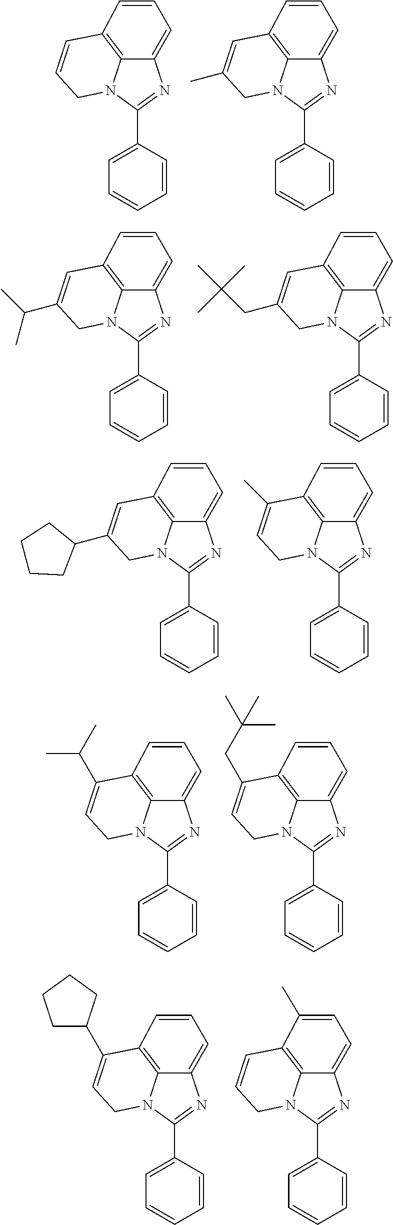

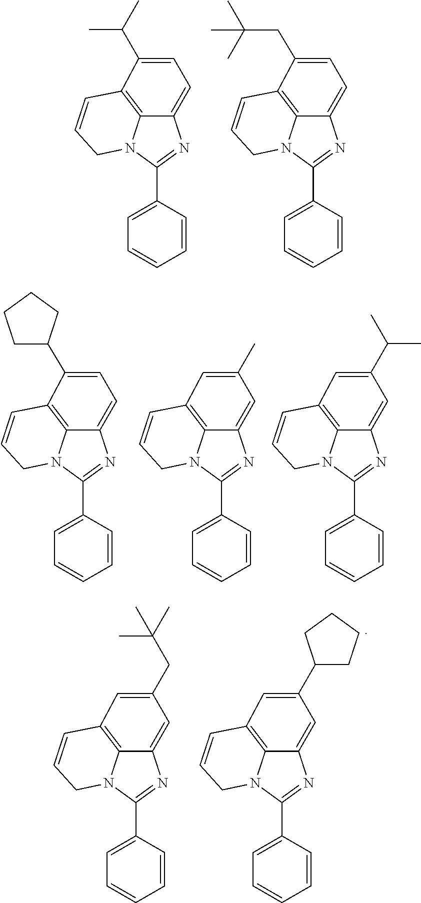

As a preferred organometallic compound, the L2 preferably has one of the following structural formulas, or is partially or completely deuterated or fluorinated correspondingly,

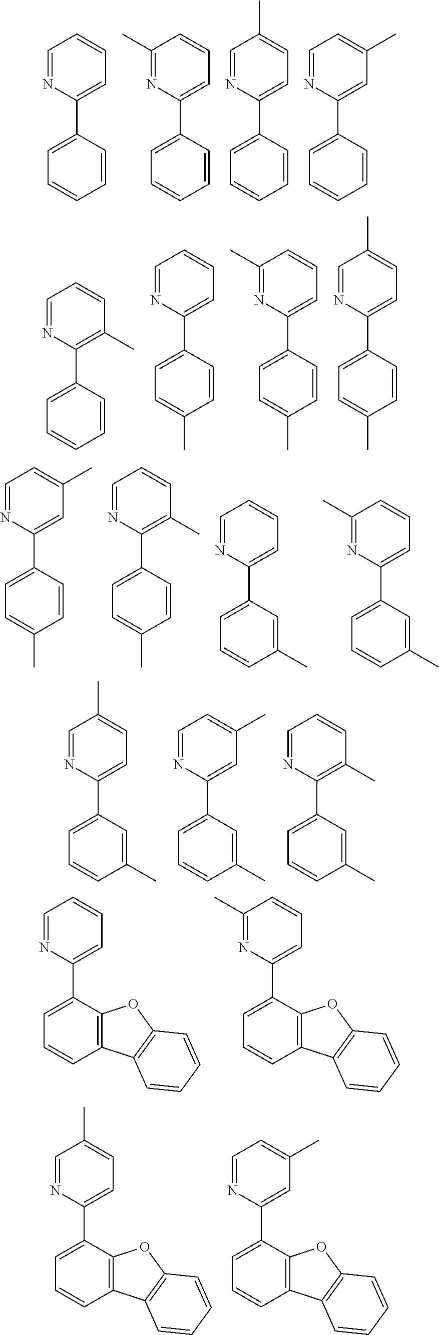

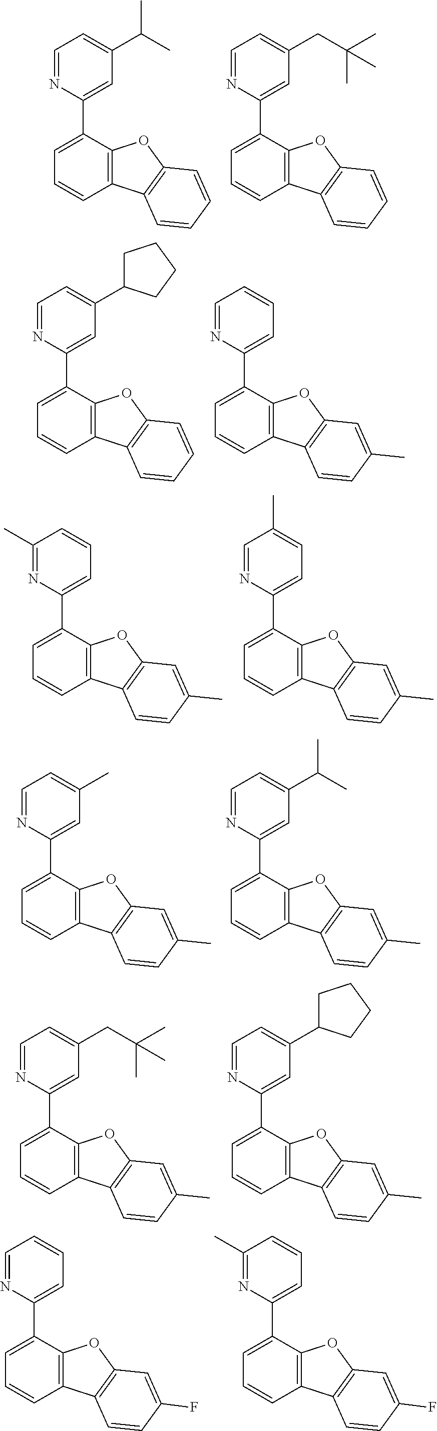

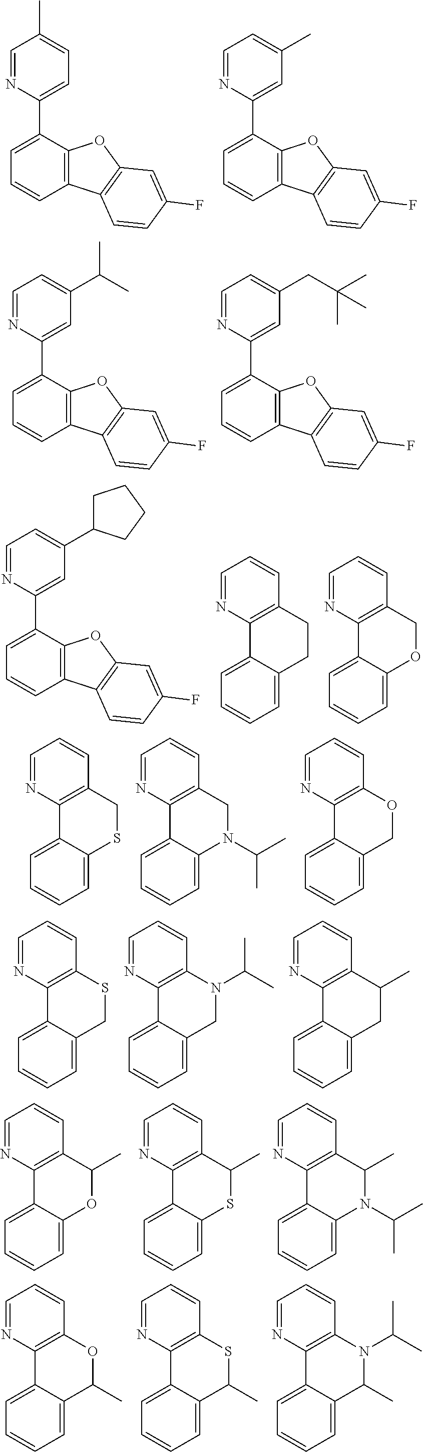

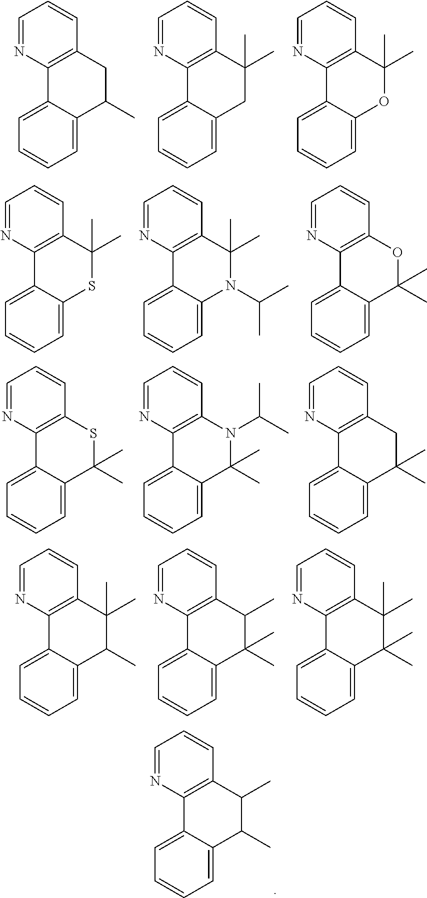

As a preferred organometallic compound, the compound as shown in the formula (1) preferably has one of the following structural formulas, or corresponding partial or complete deuterides thereof, or corresponding partial or complete fluorides thereof.

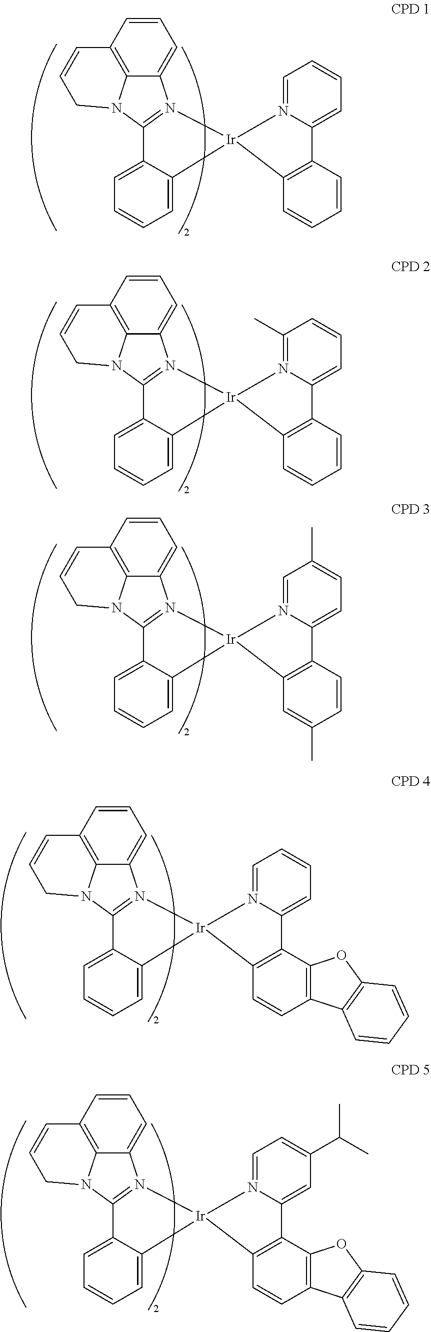

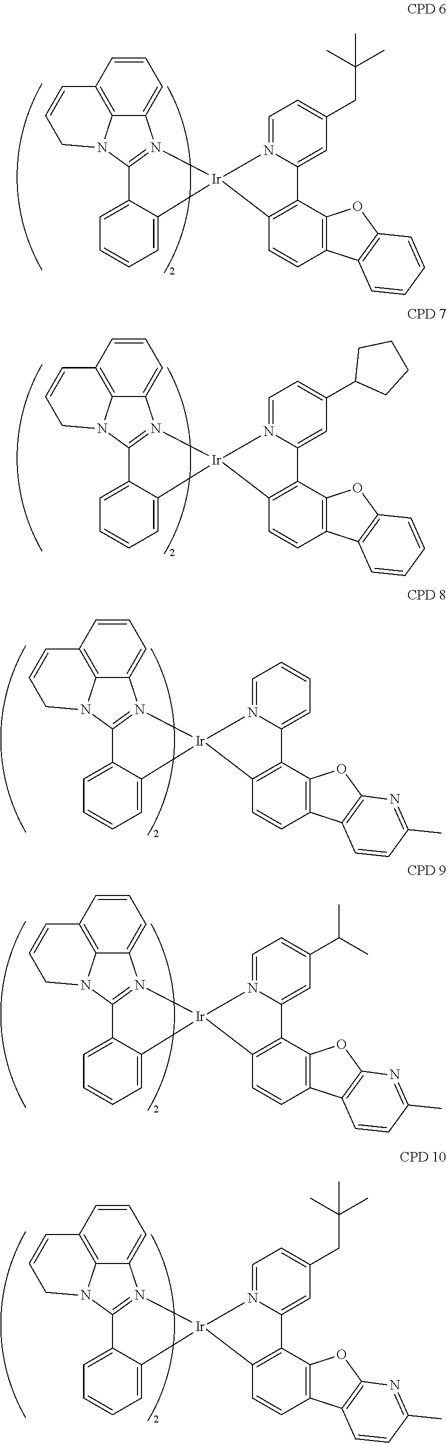

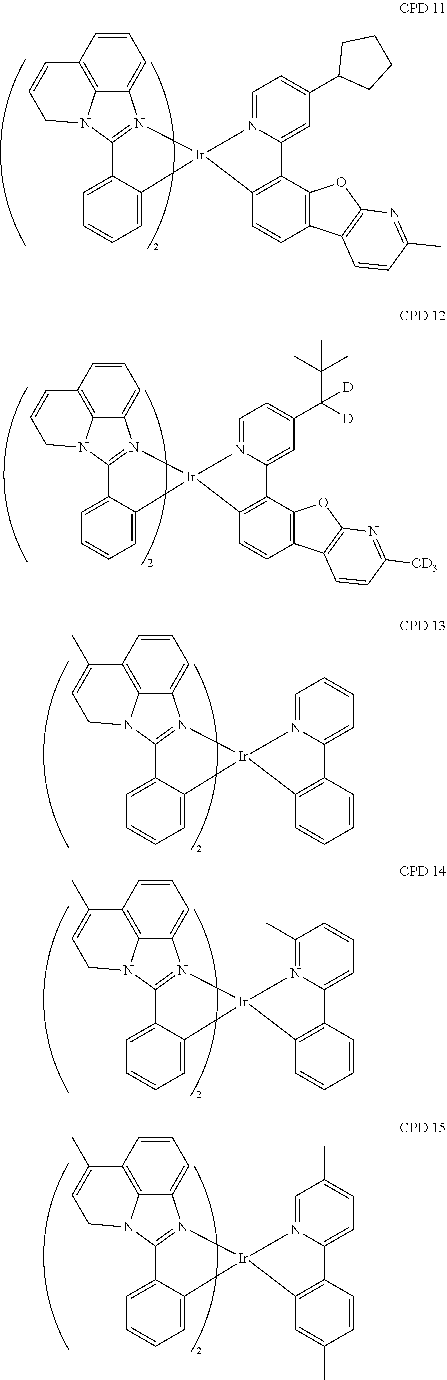

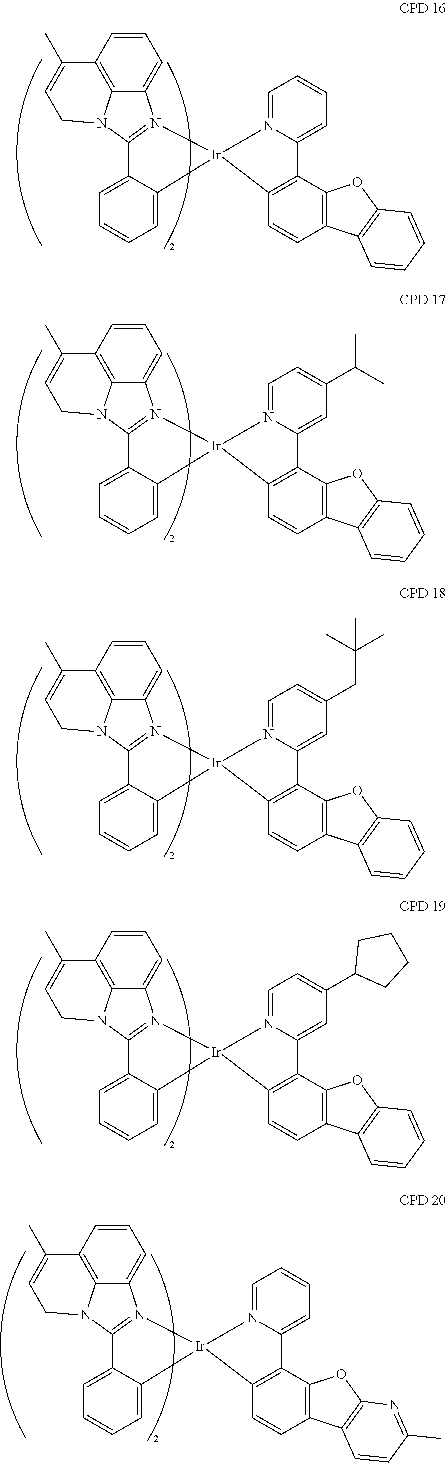

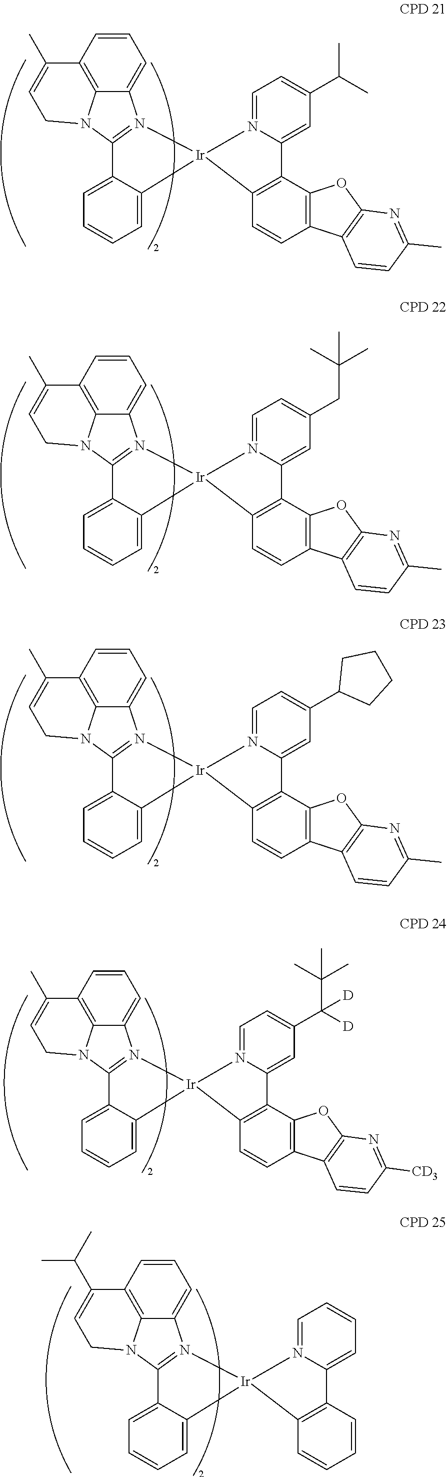

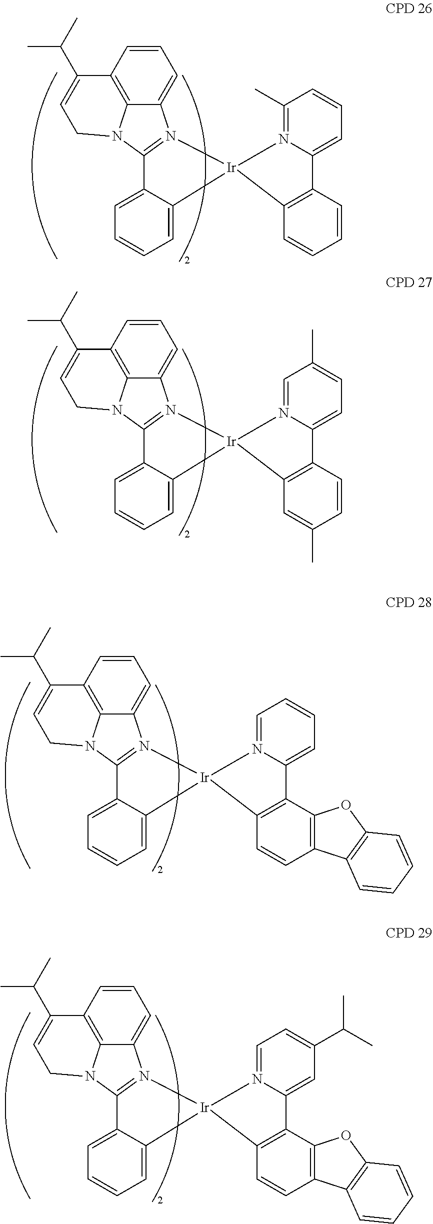

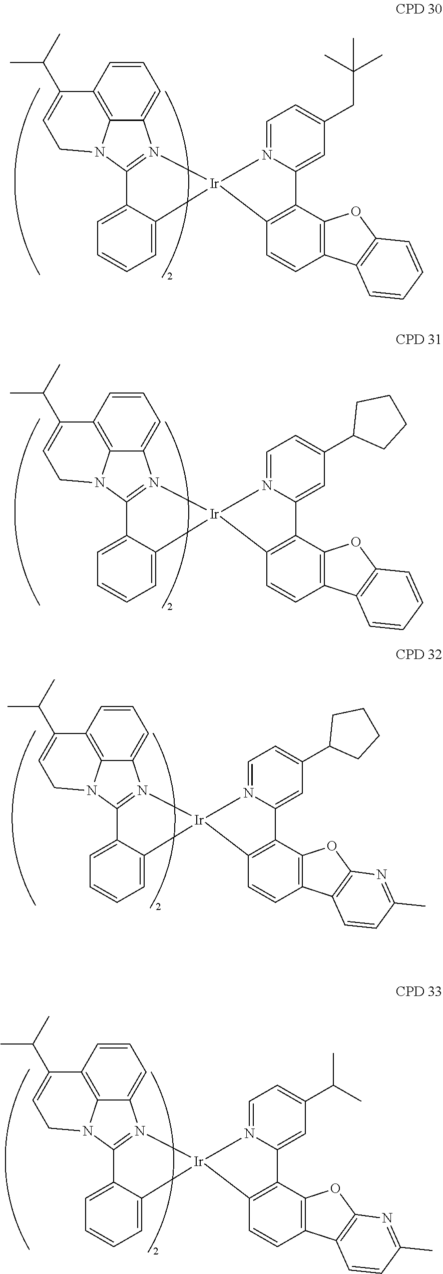

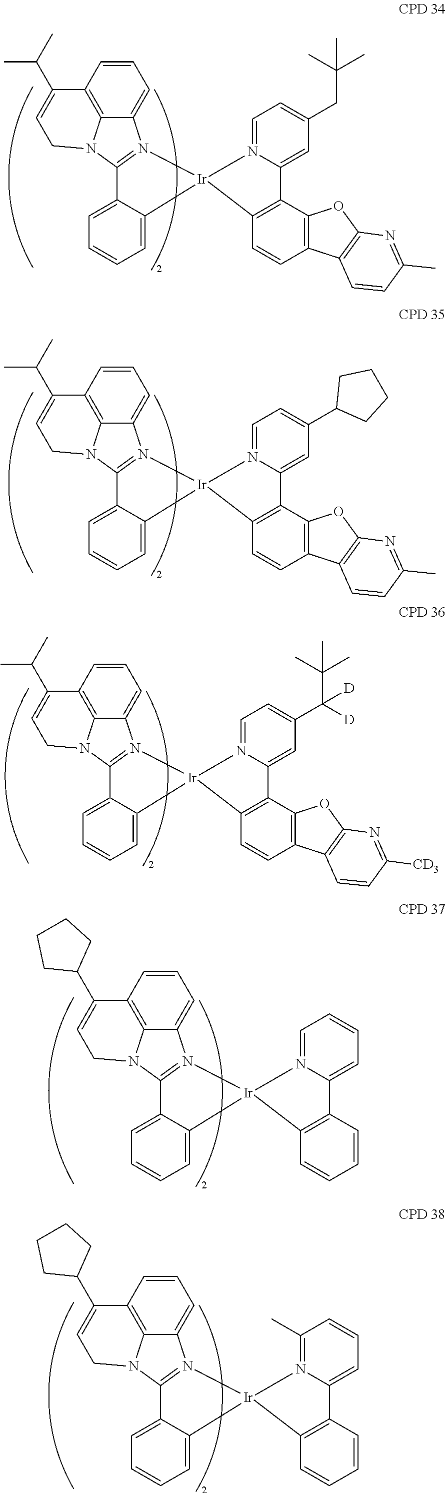

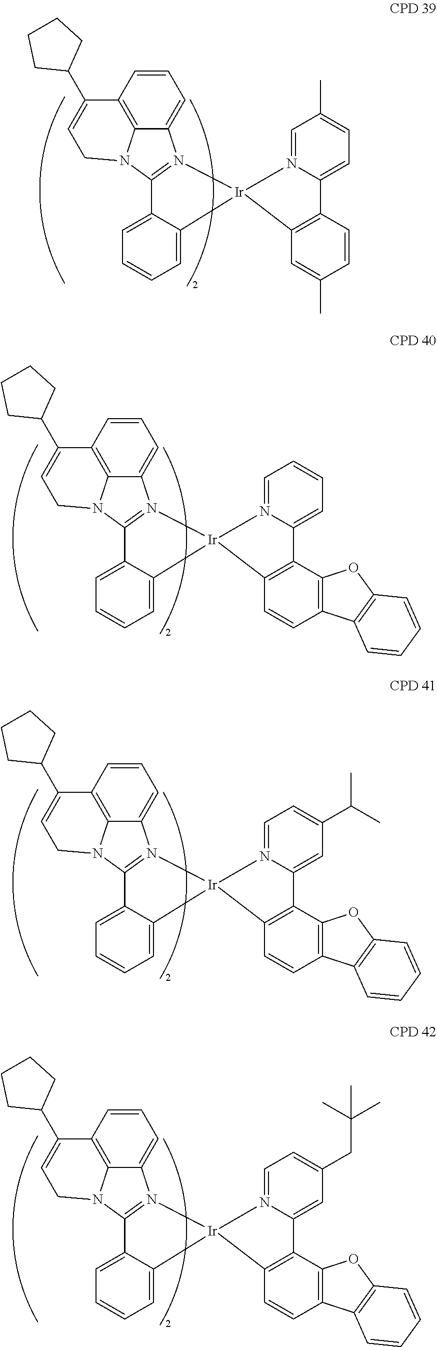

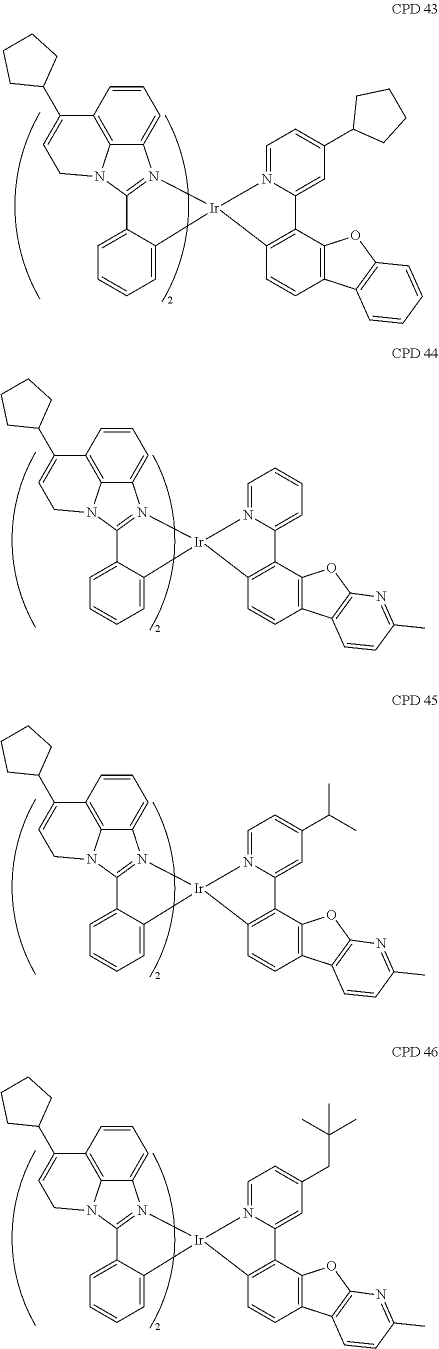

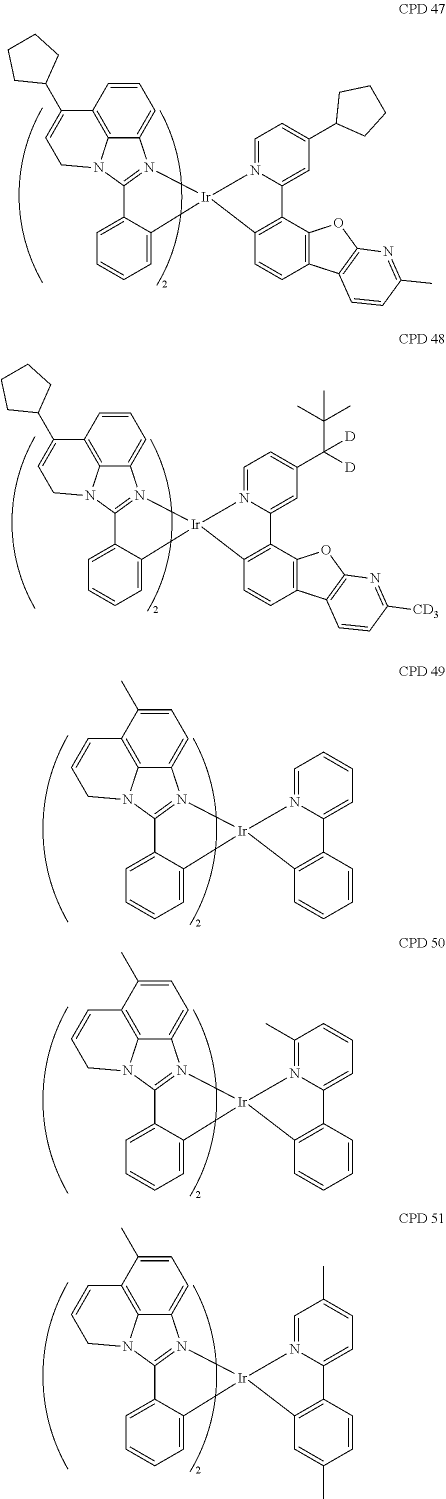

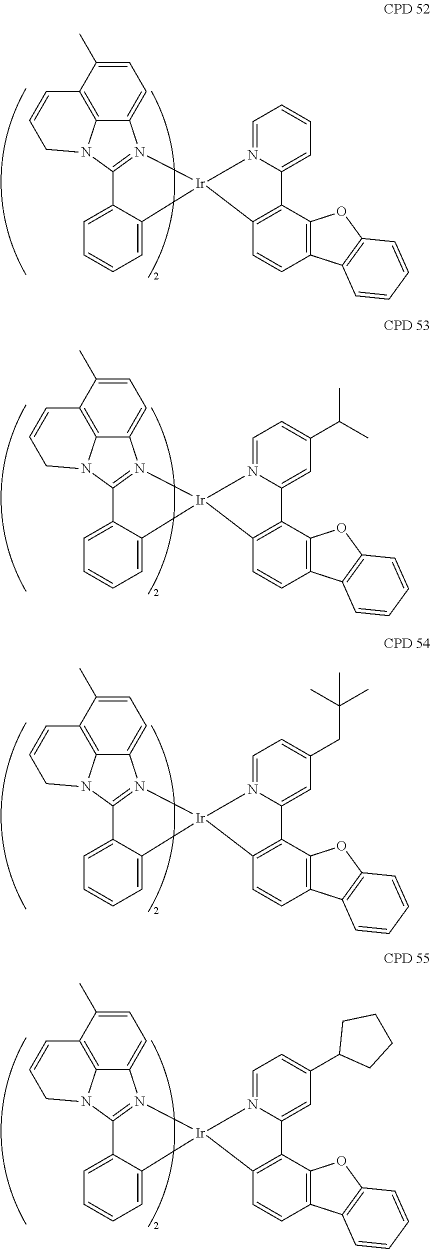

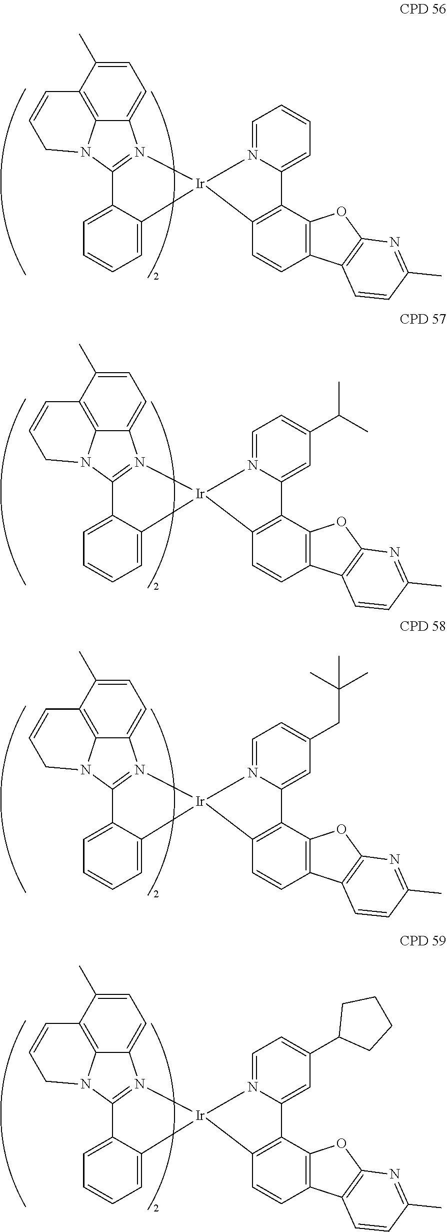

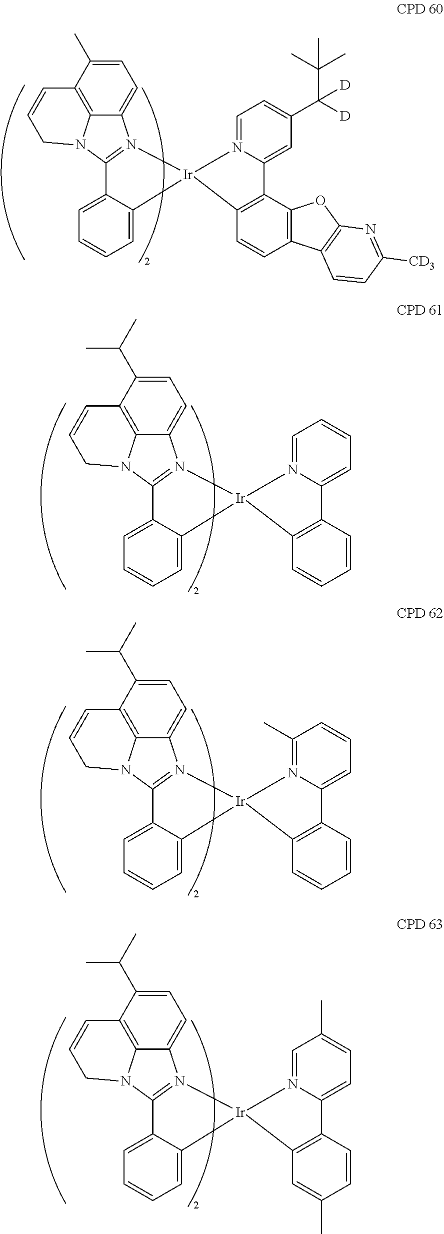

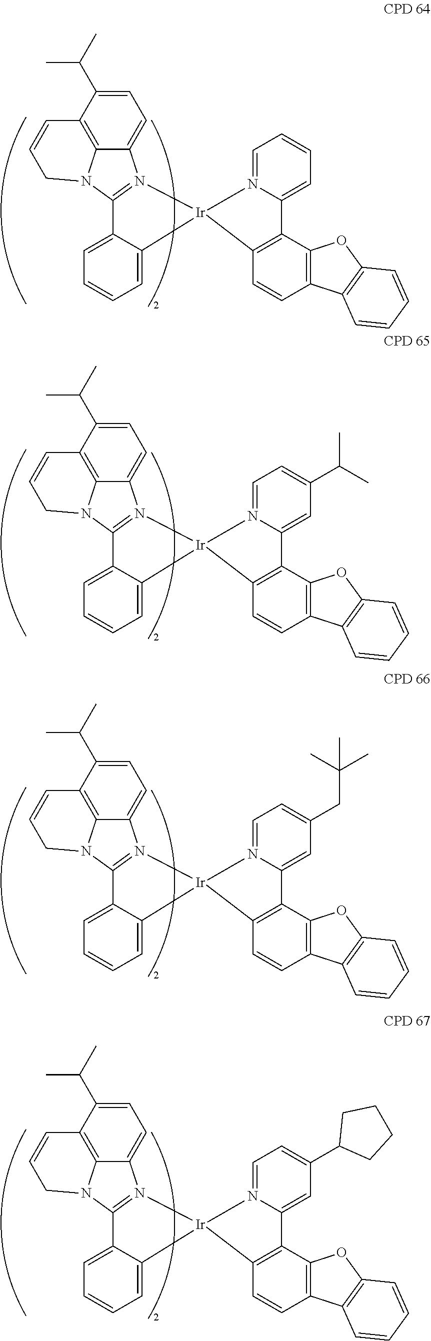

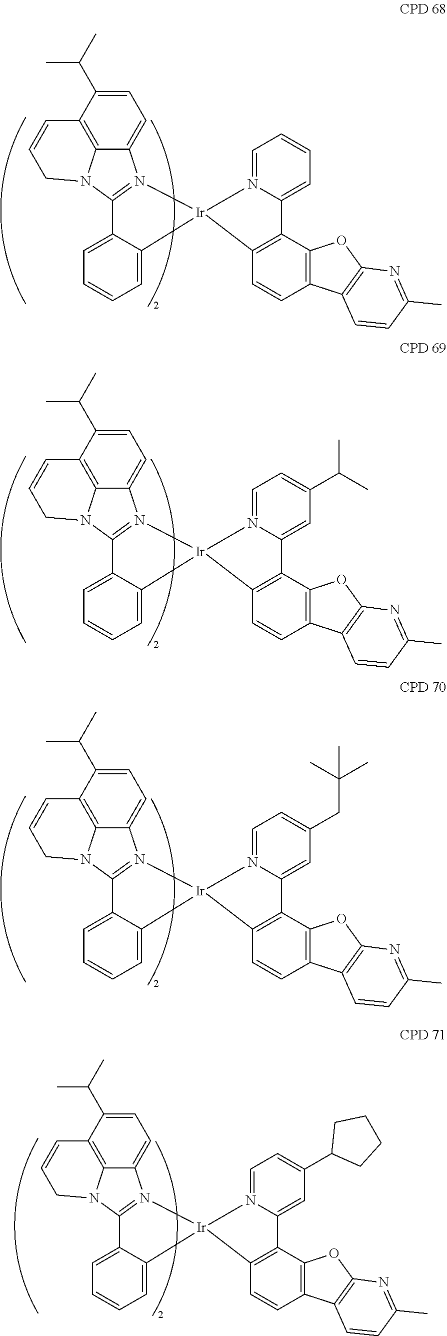

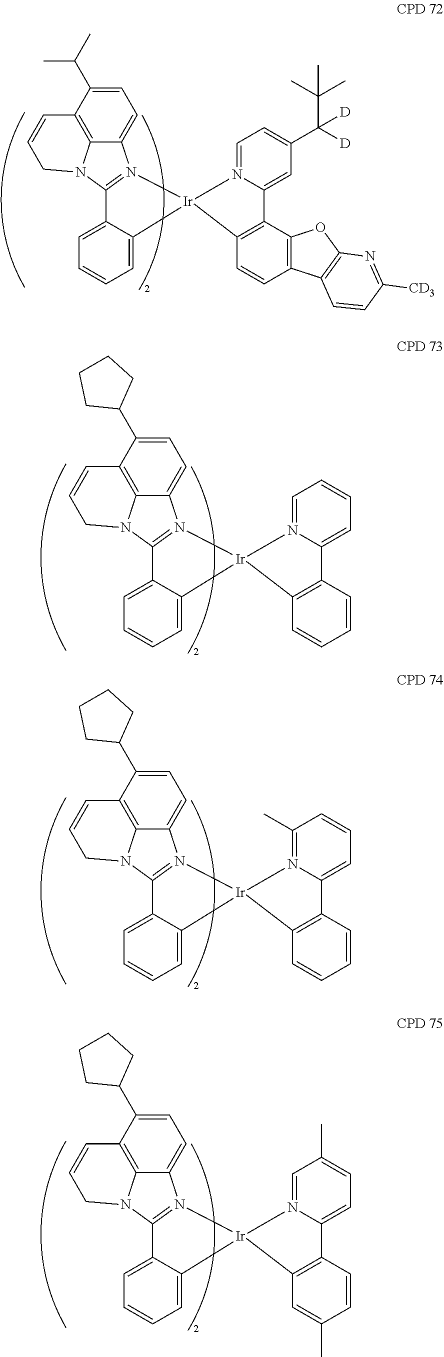

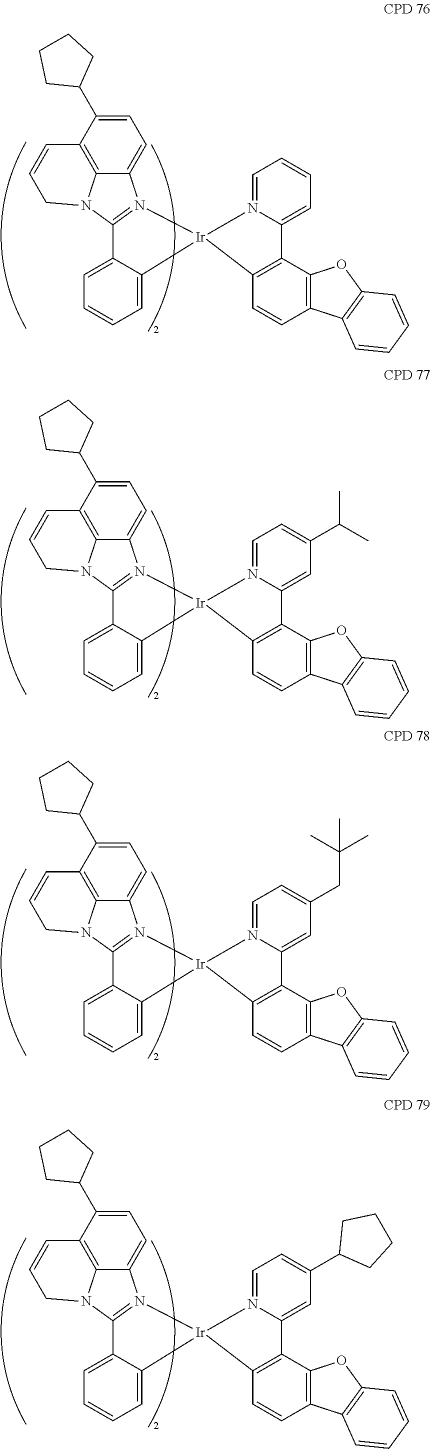

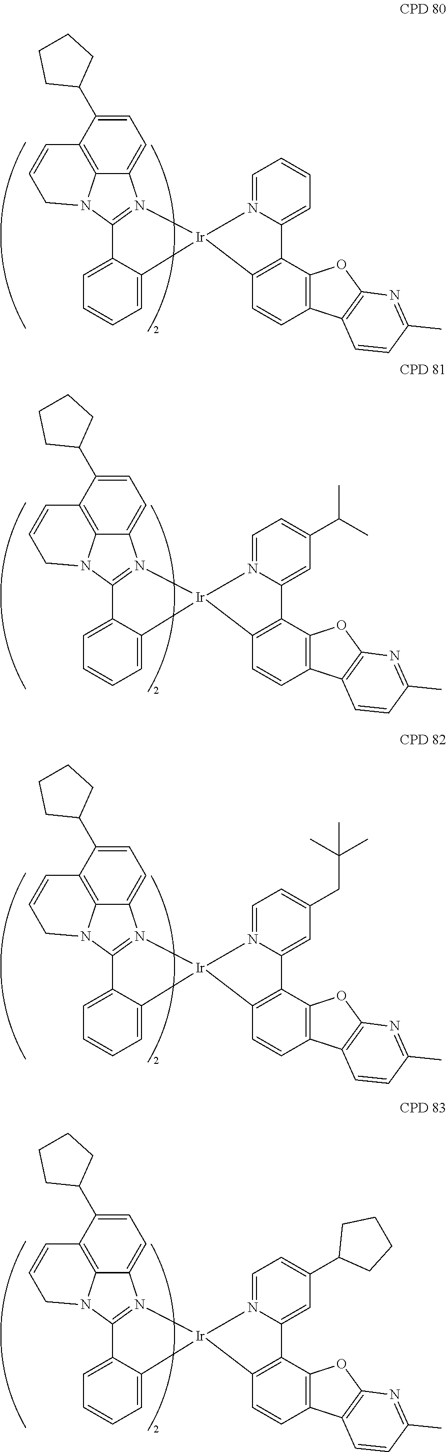

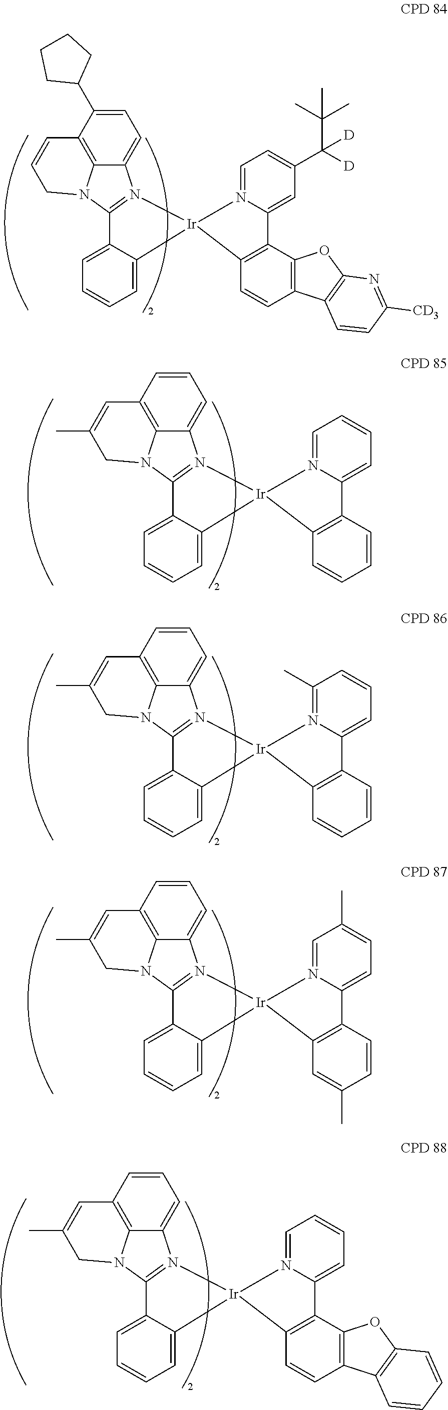

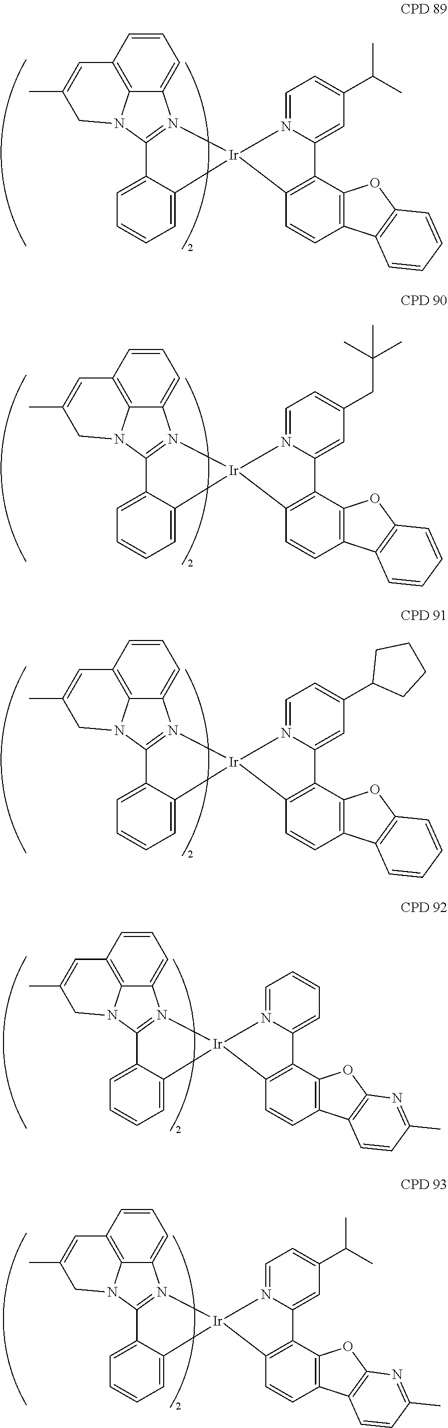

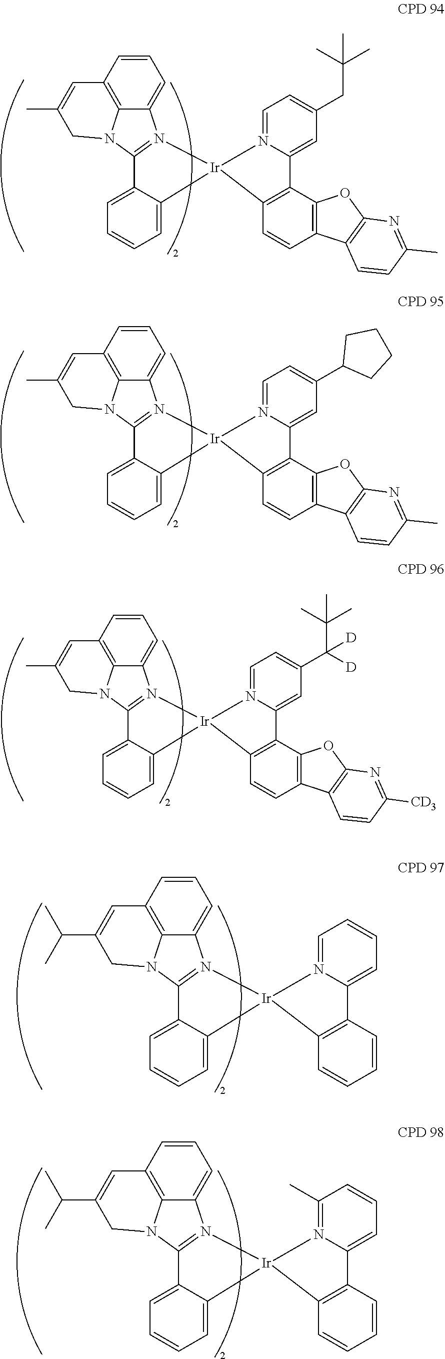

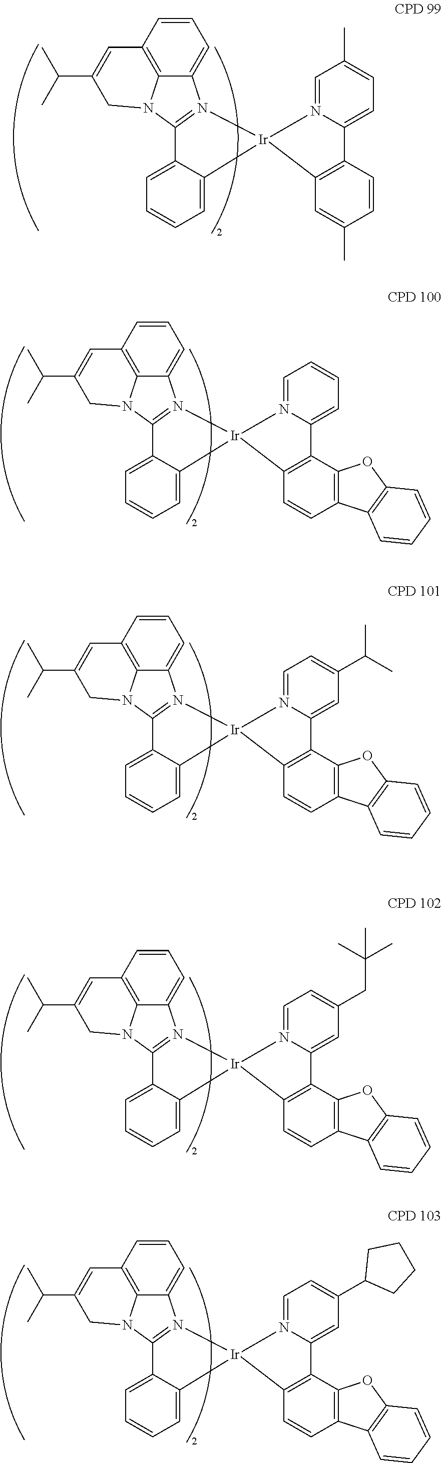

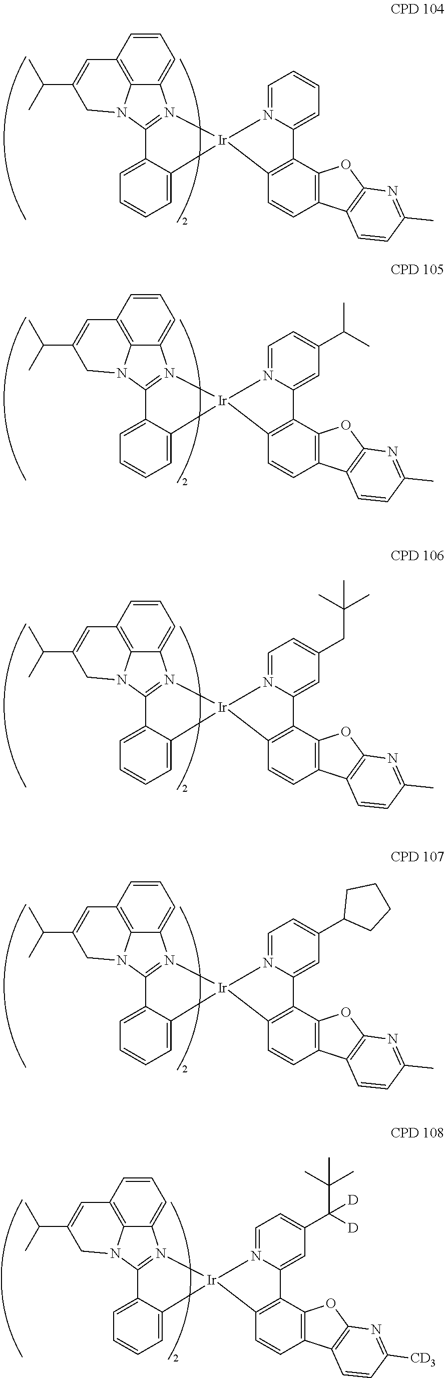

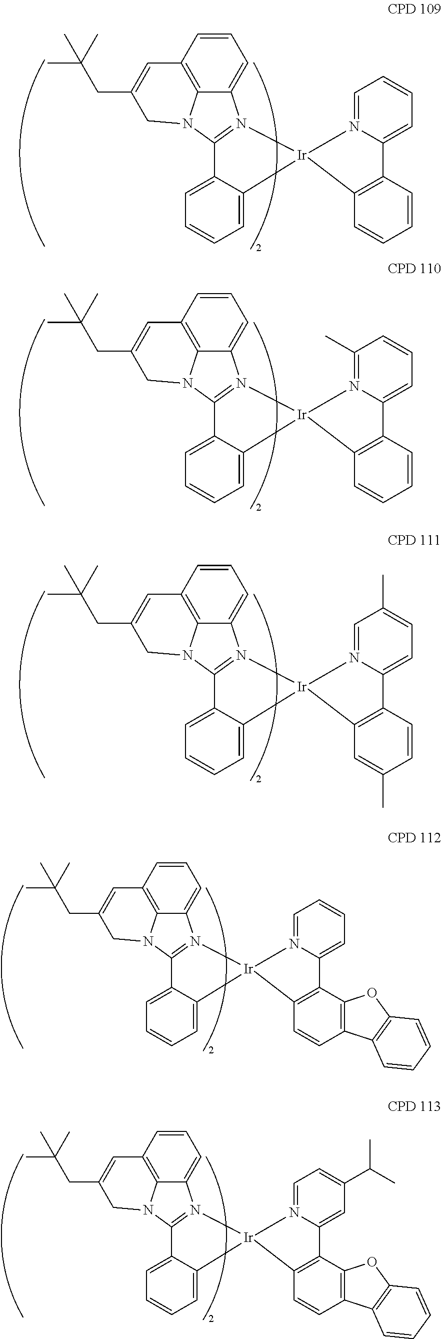

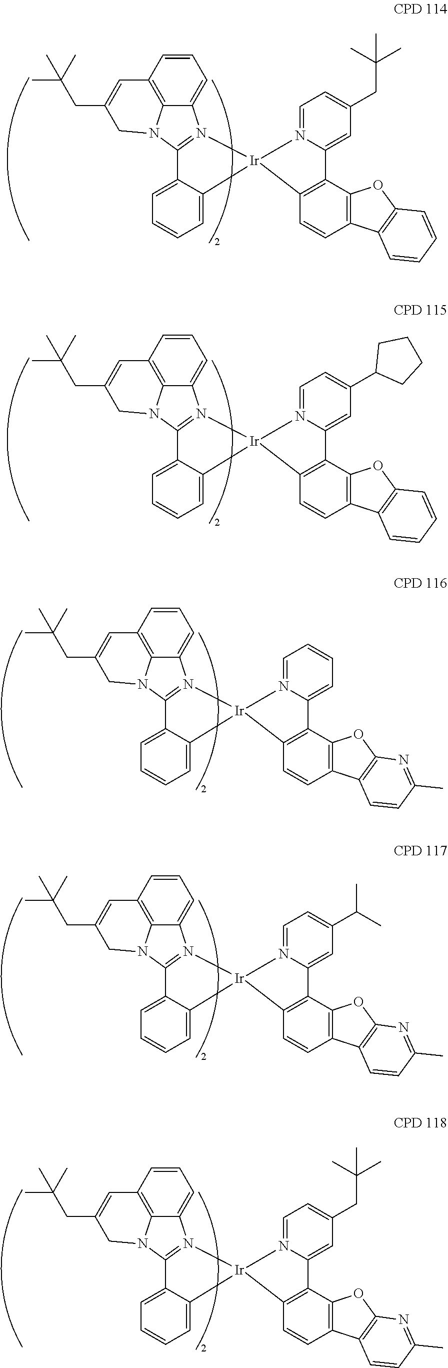

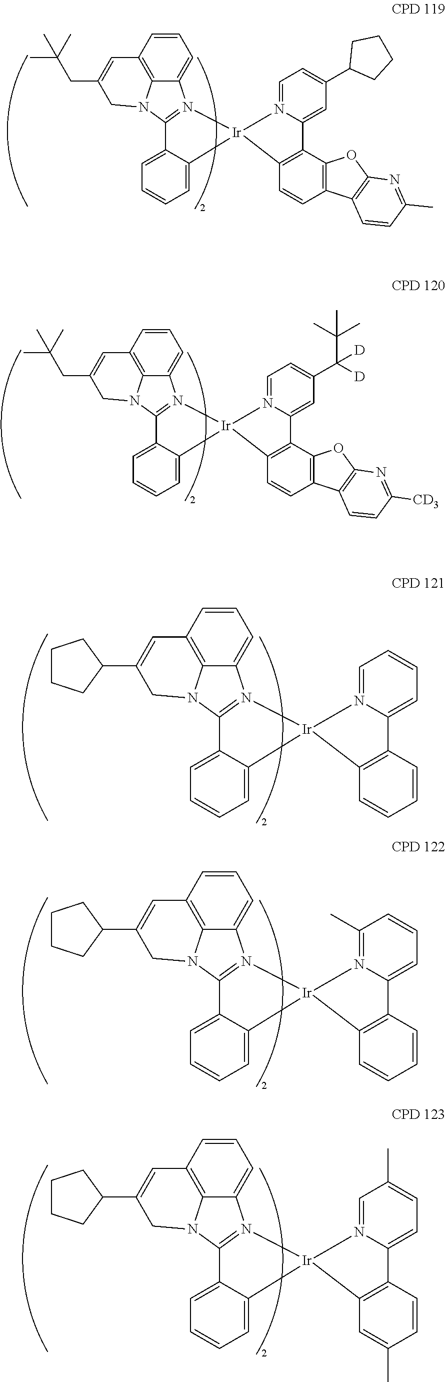

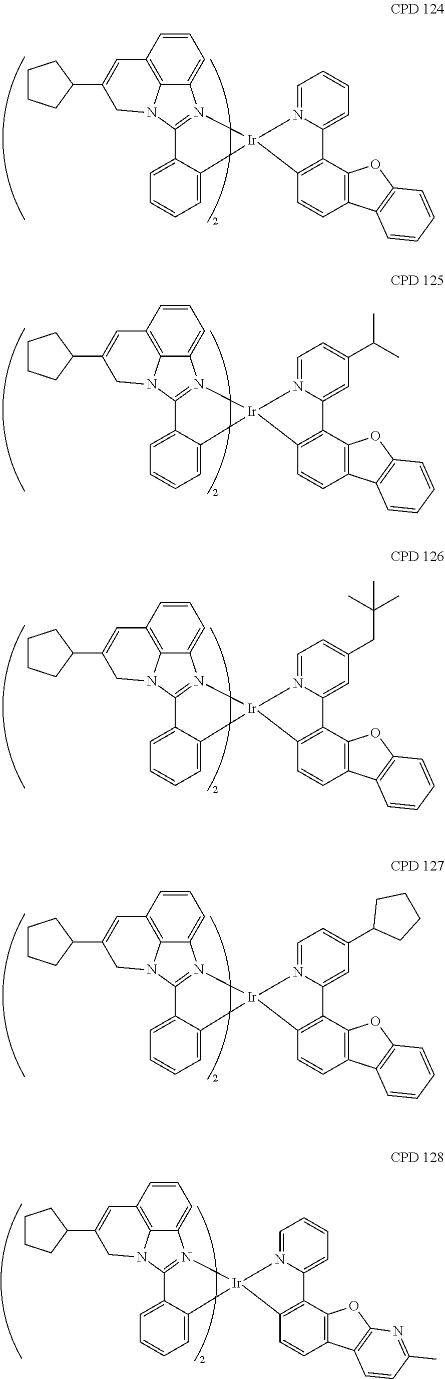

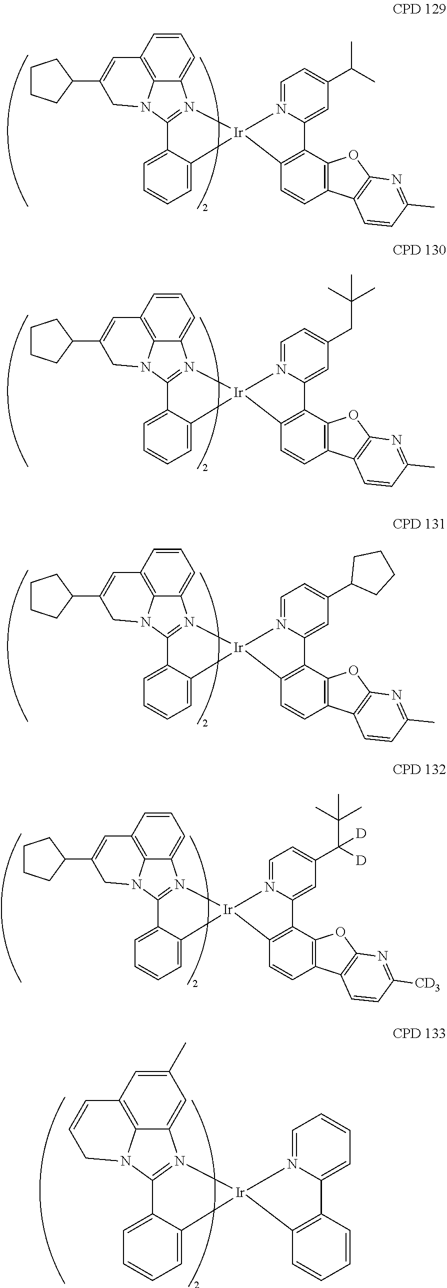

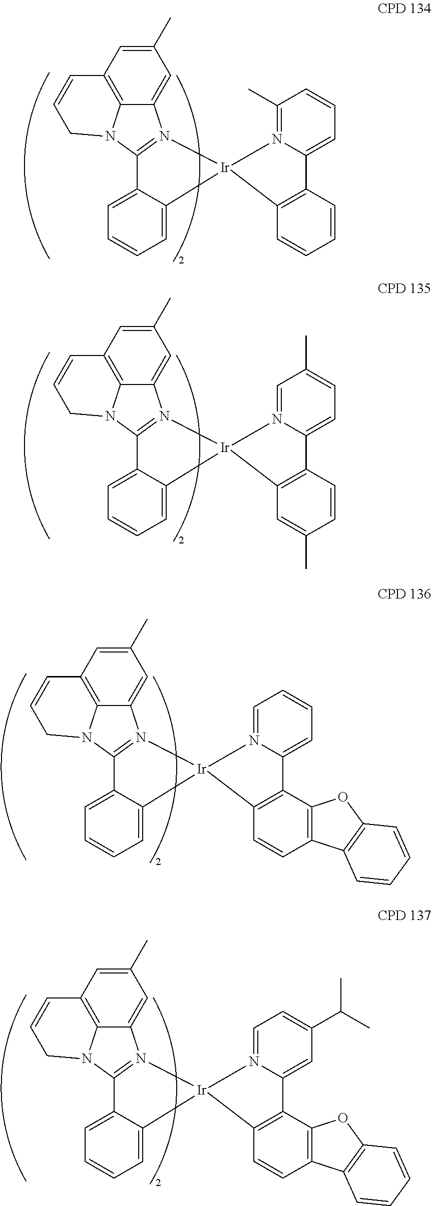

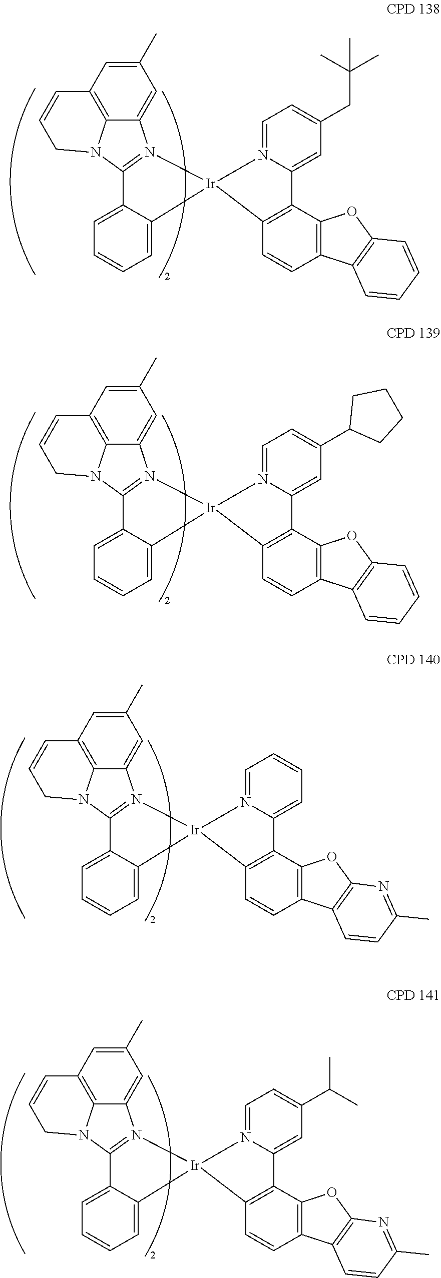

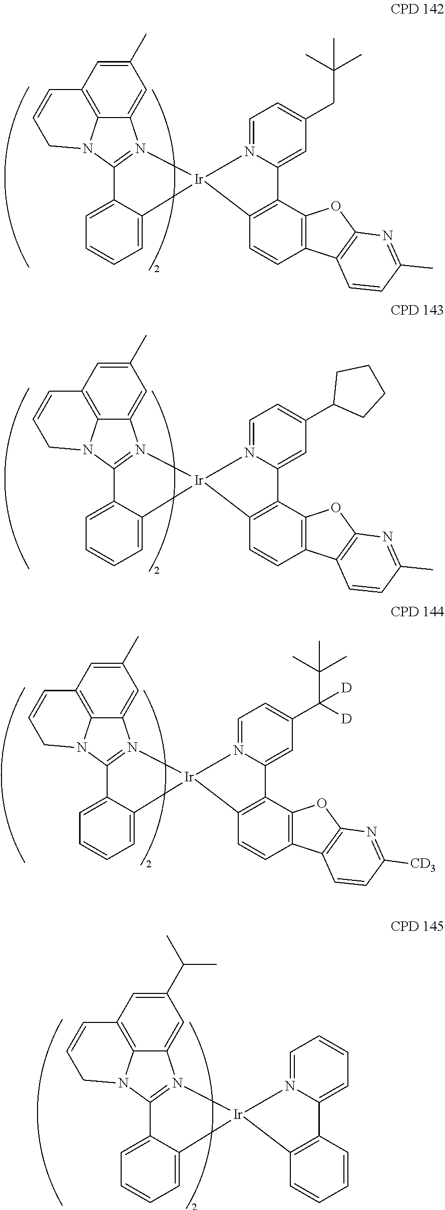

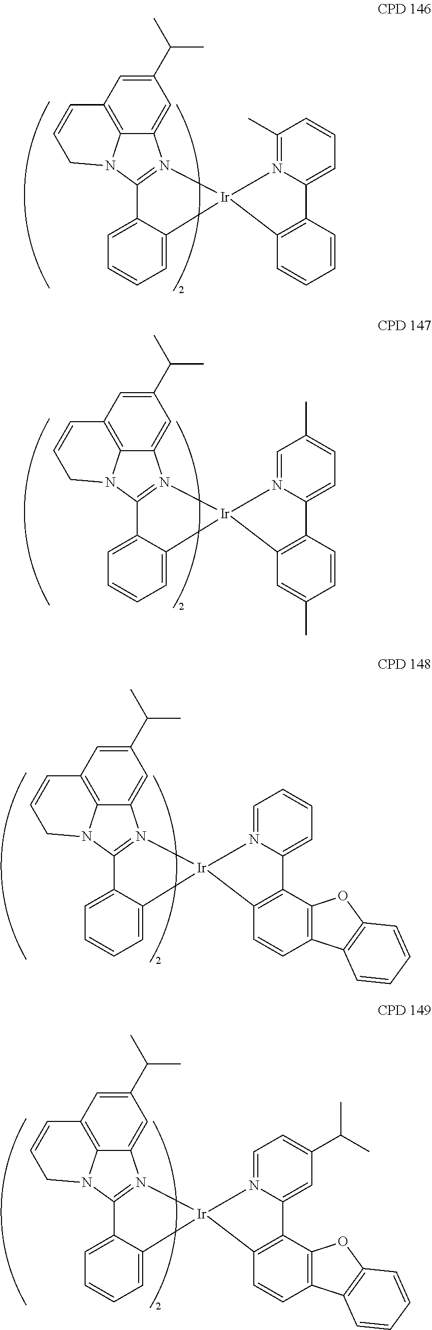

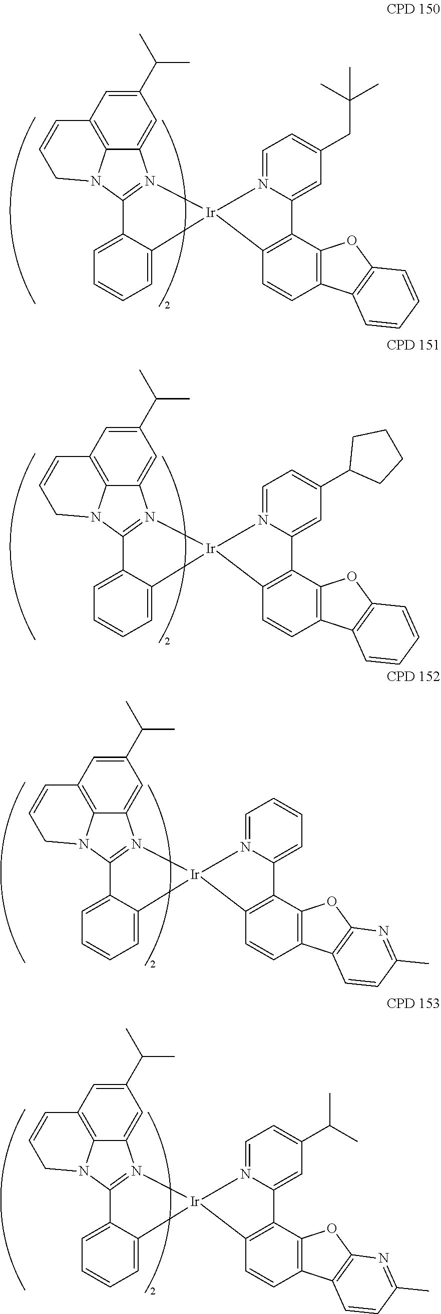

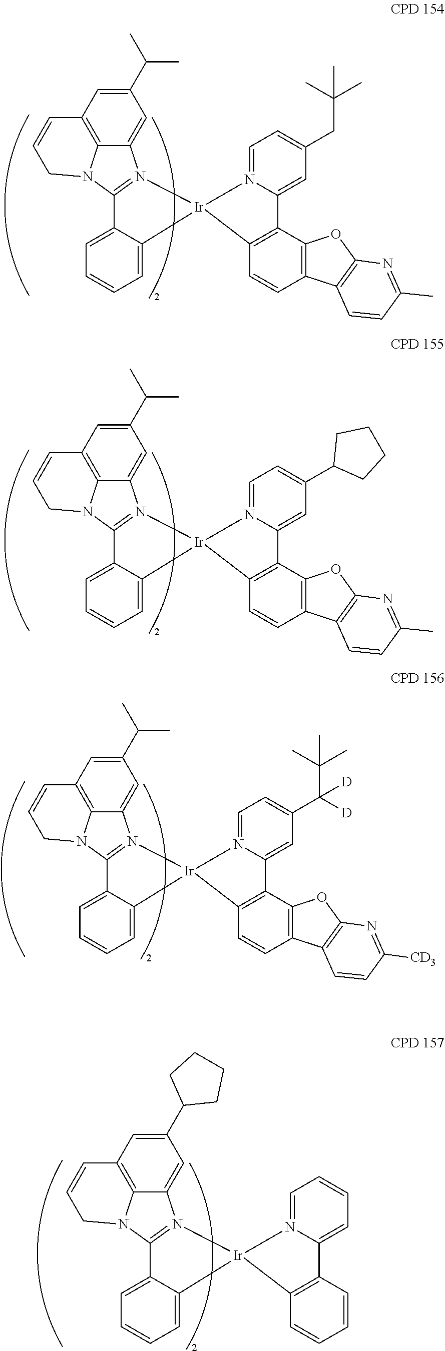

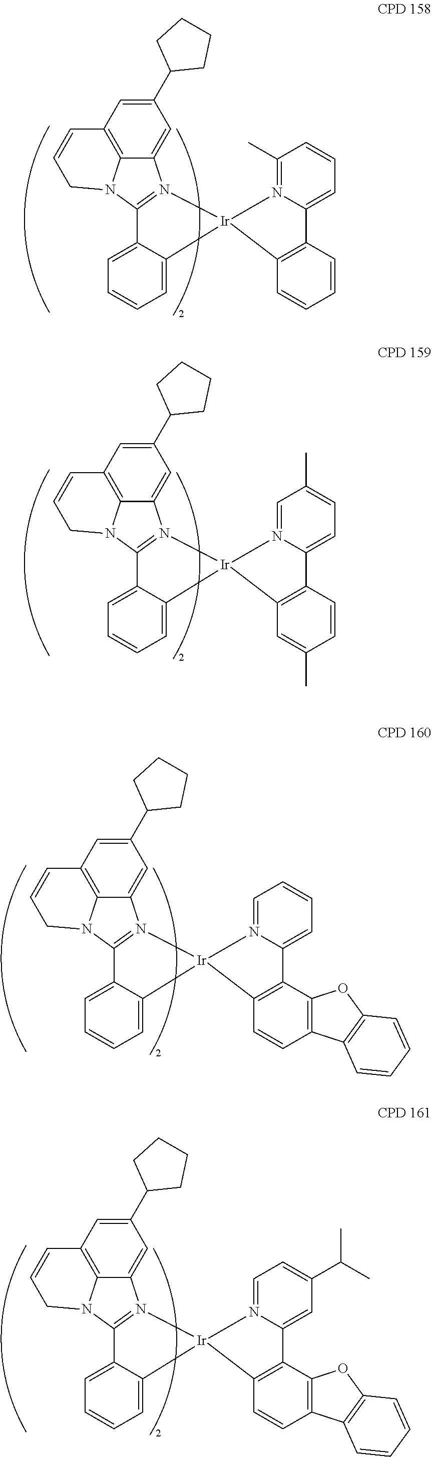

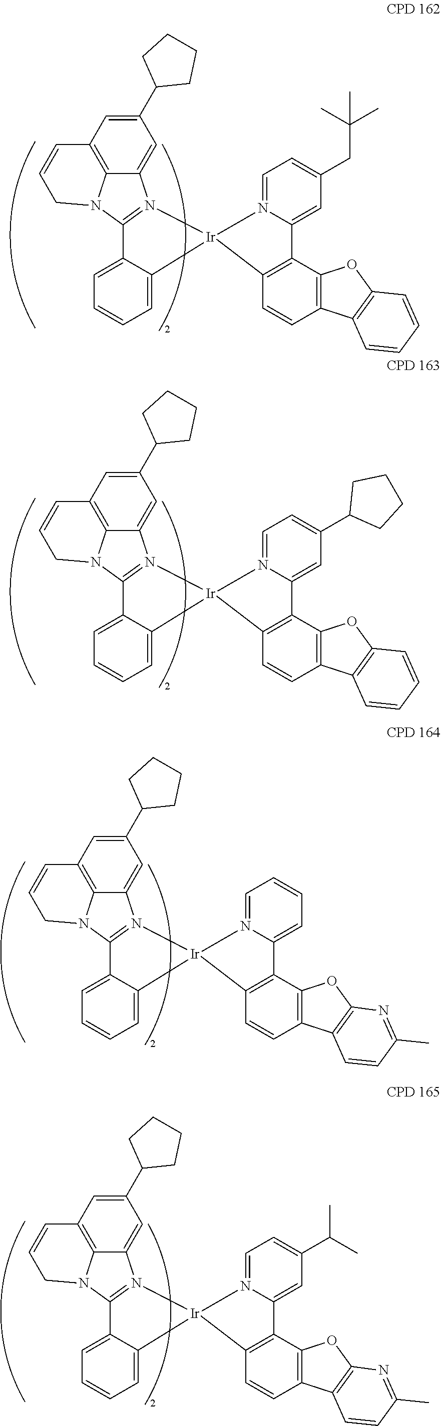

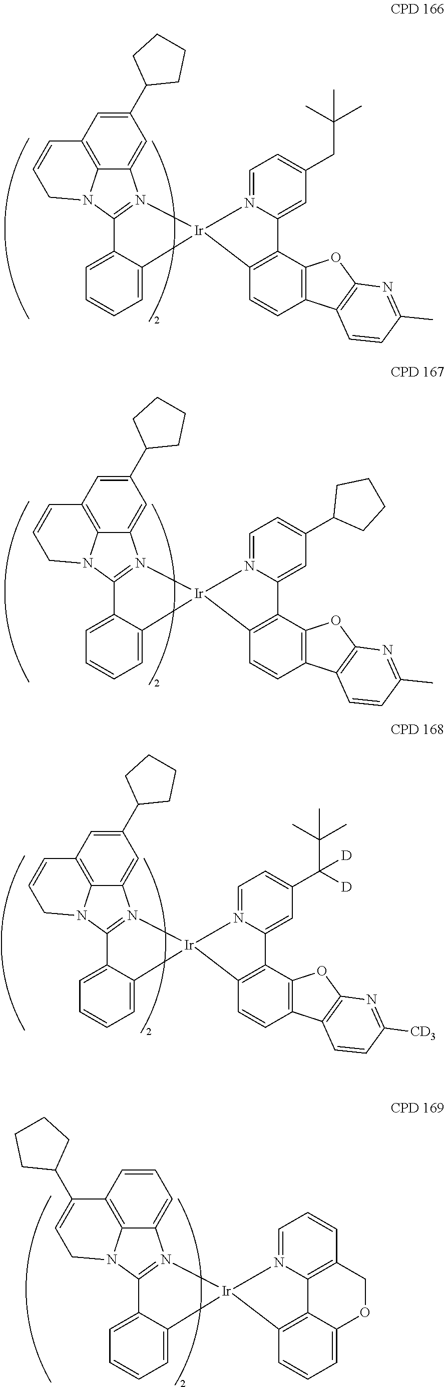

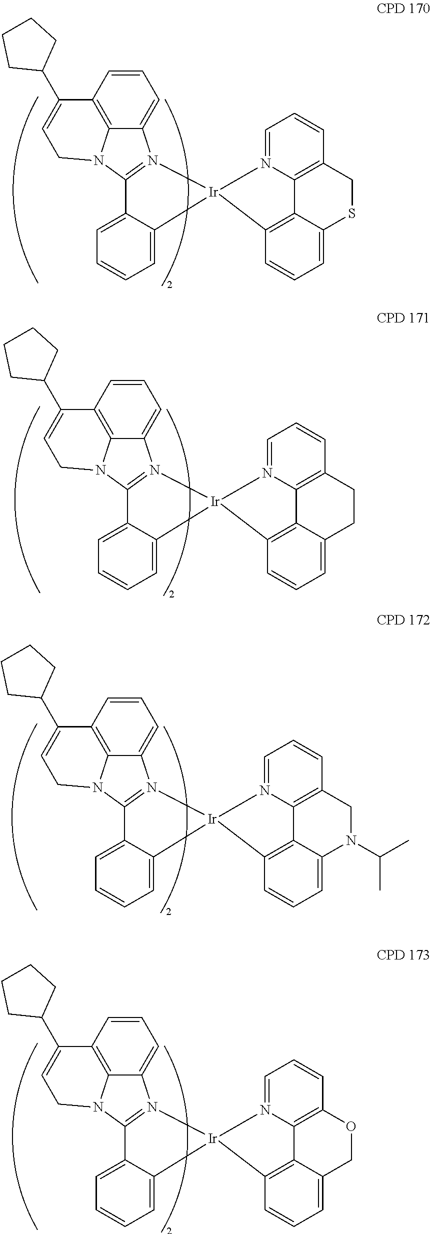

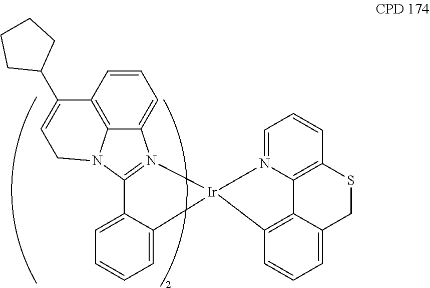

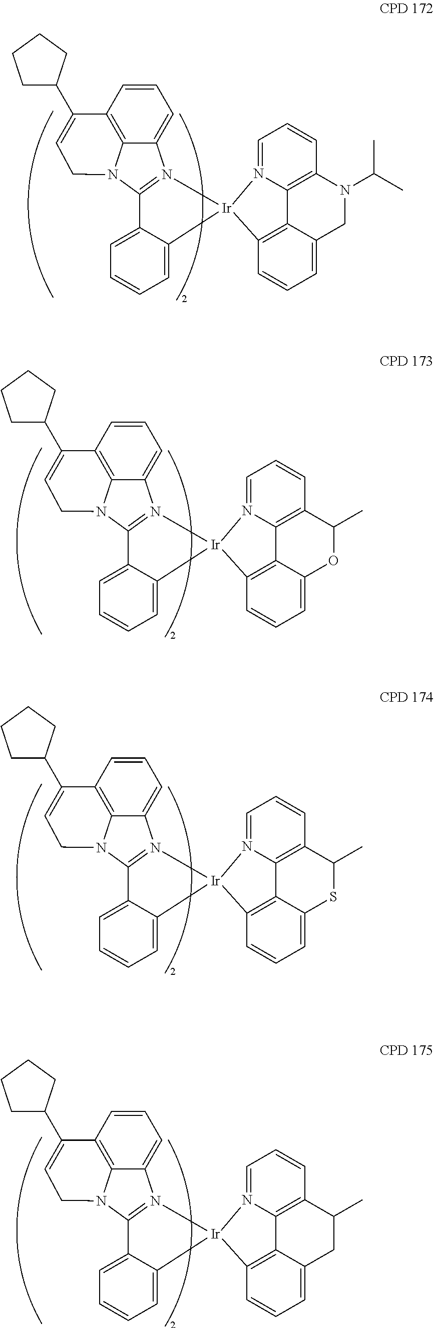

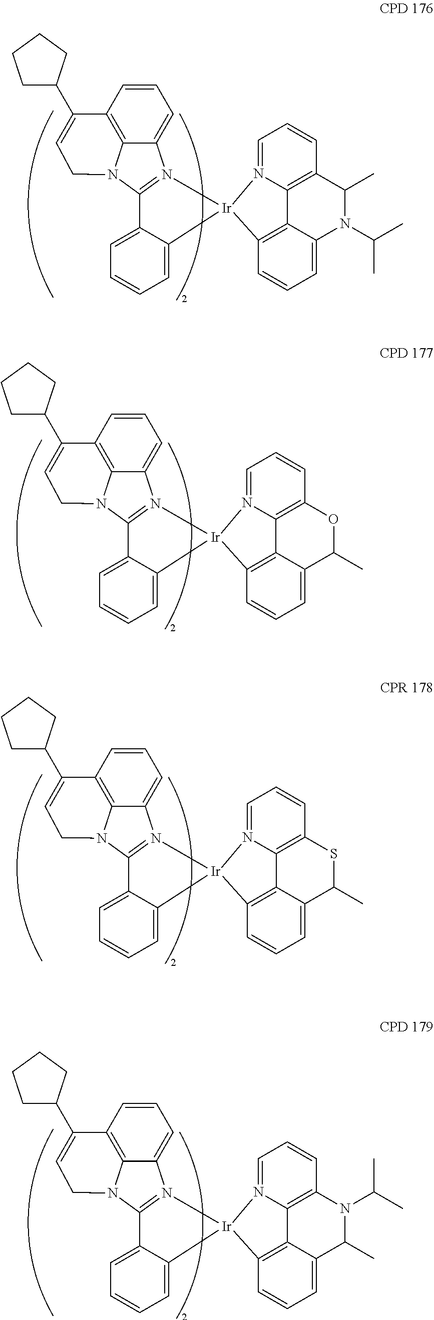

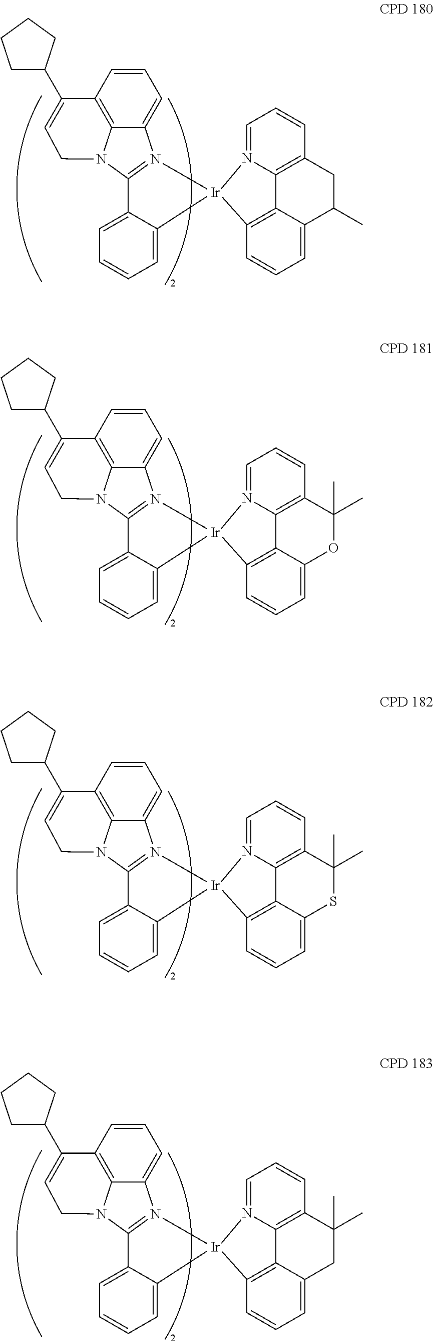

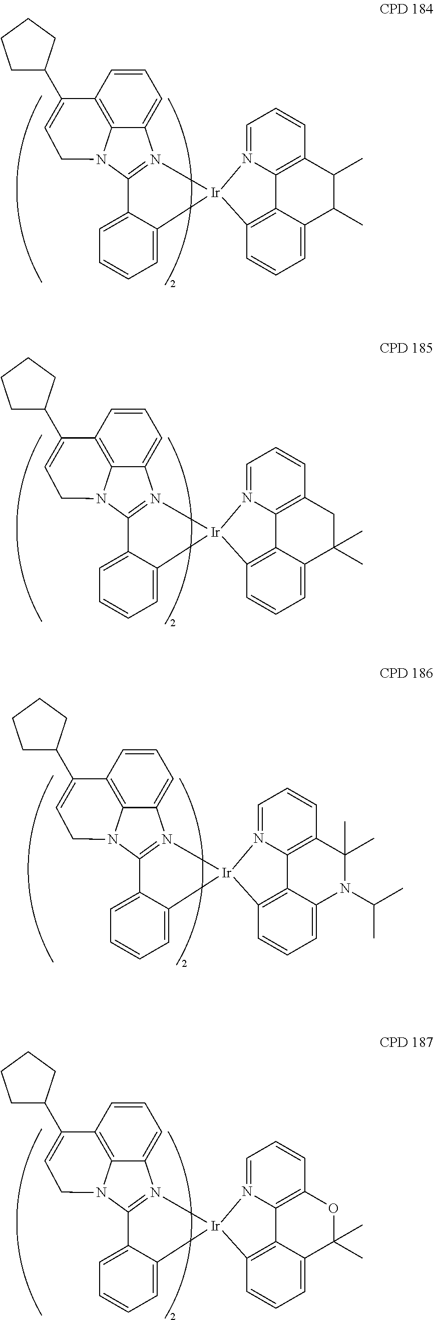

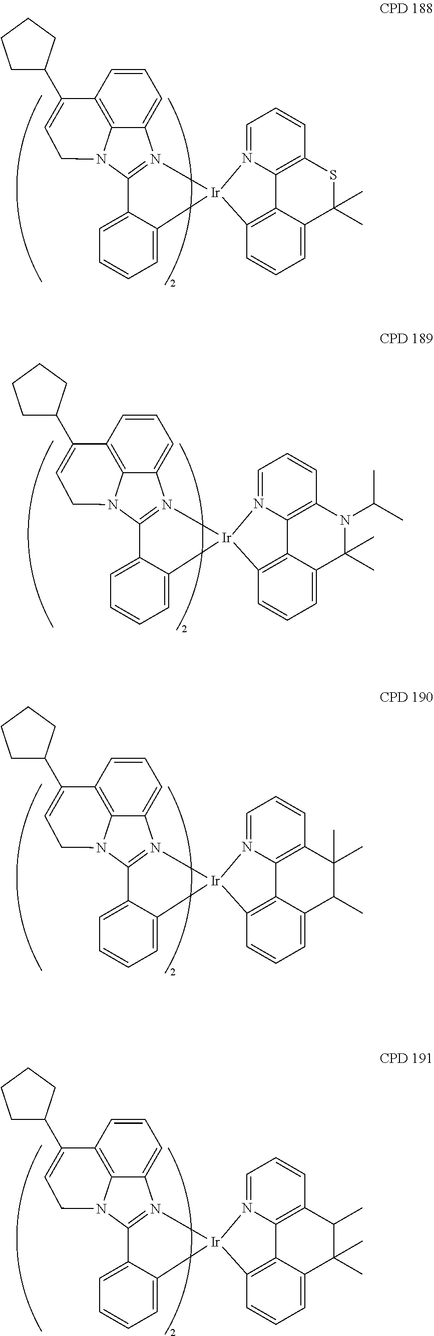

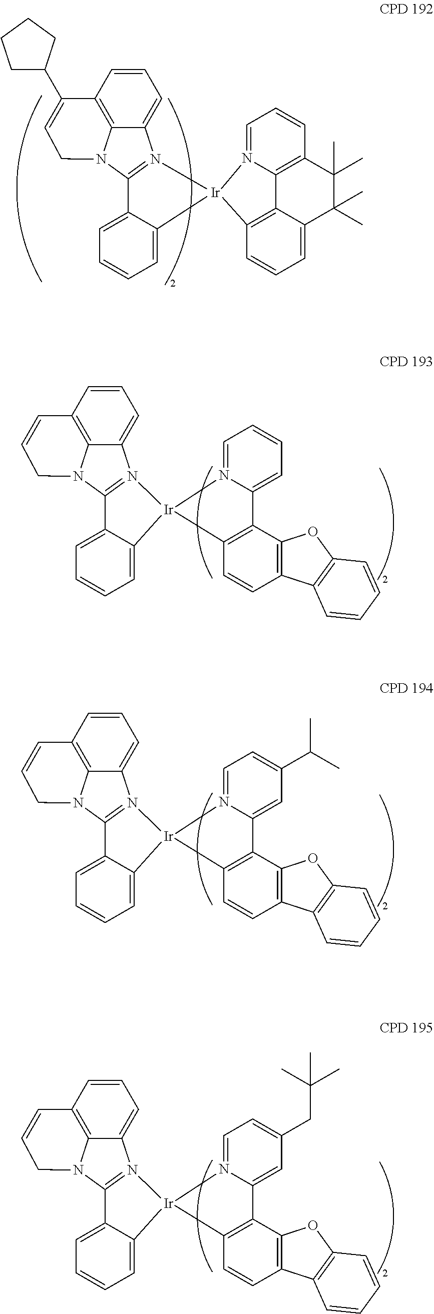

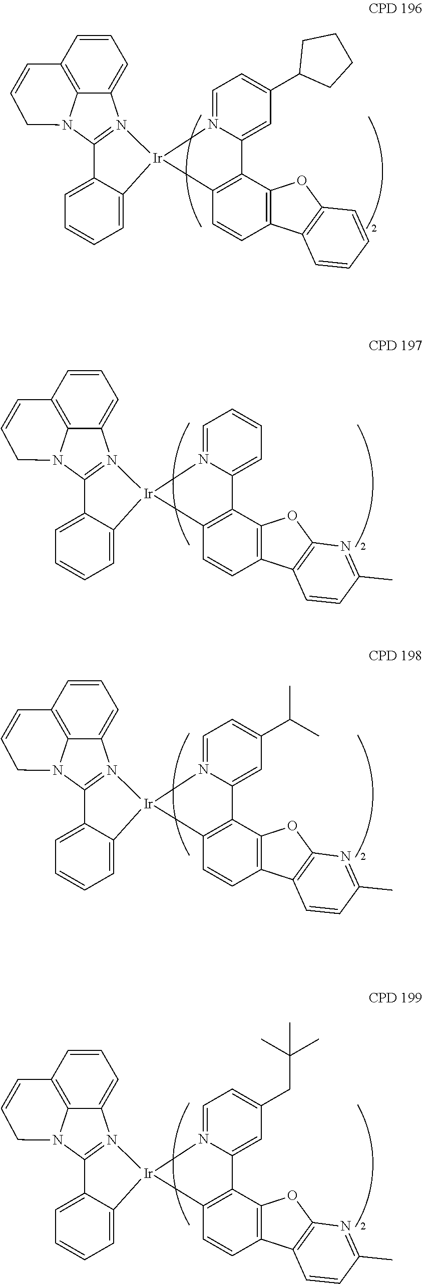

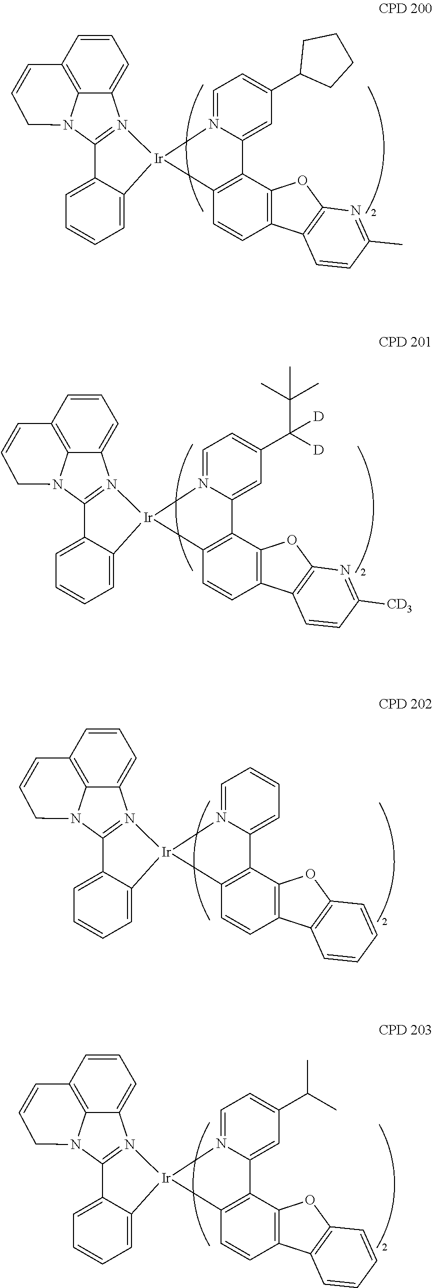

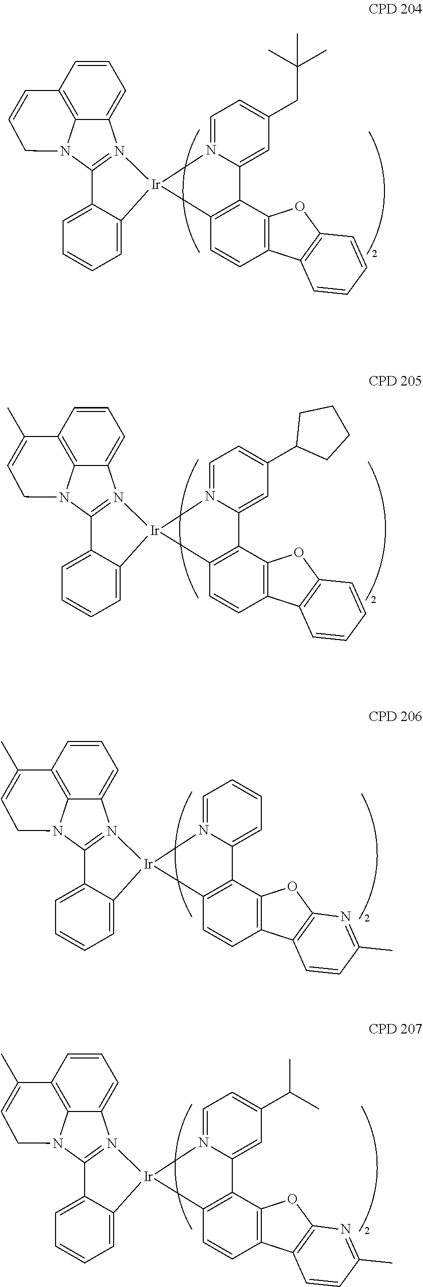

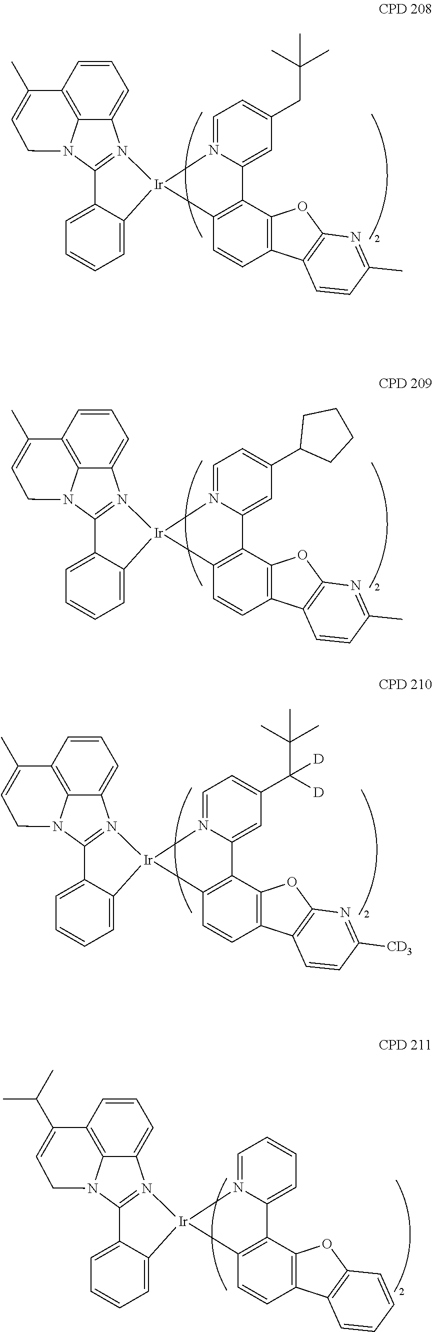

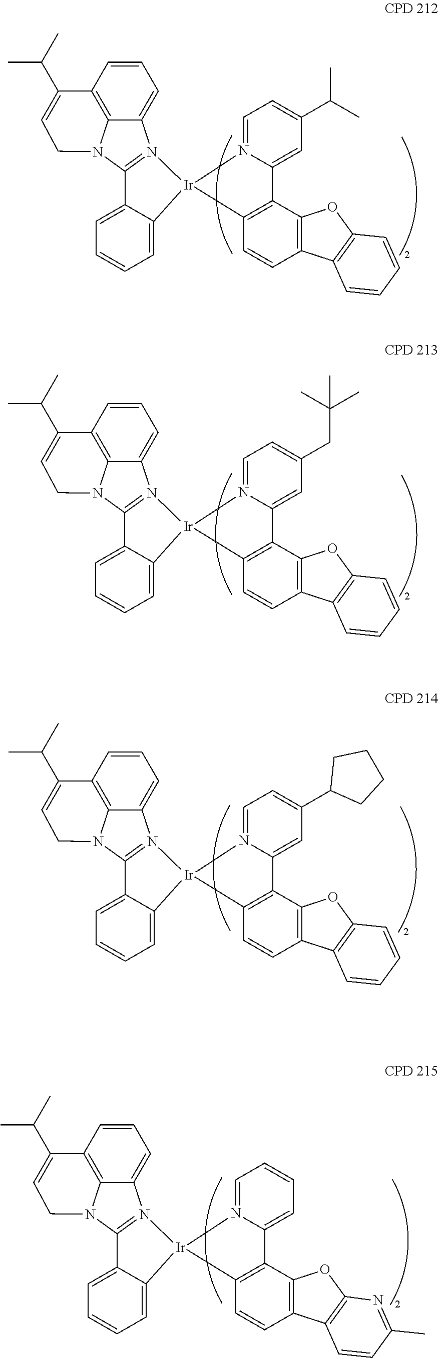

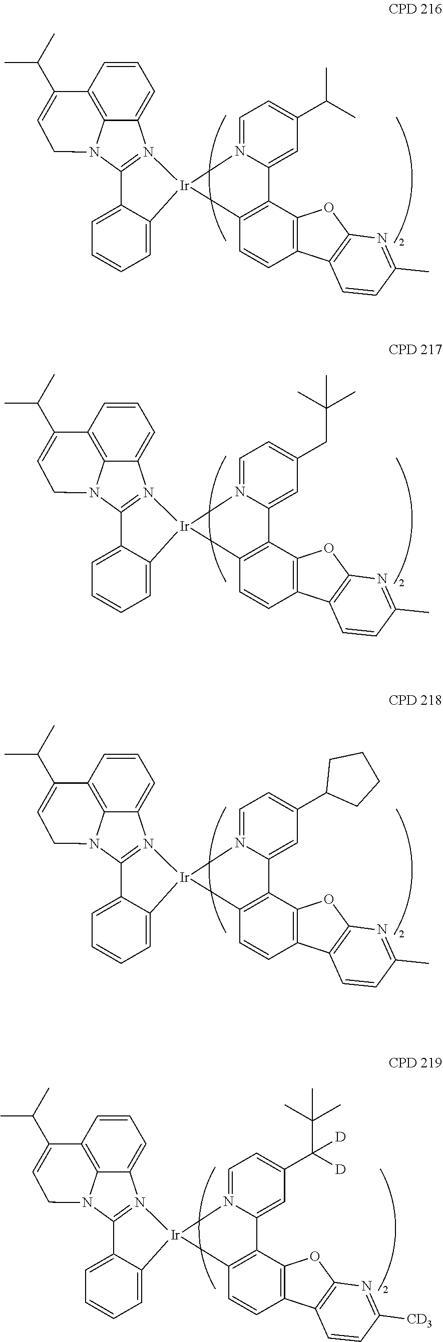

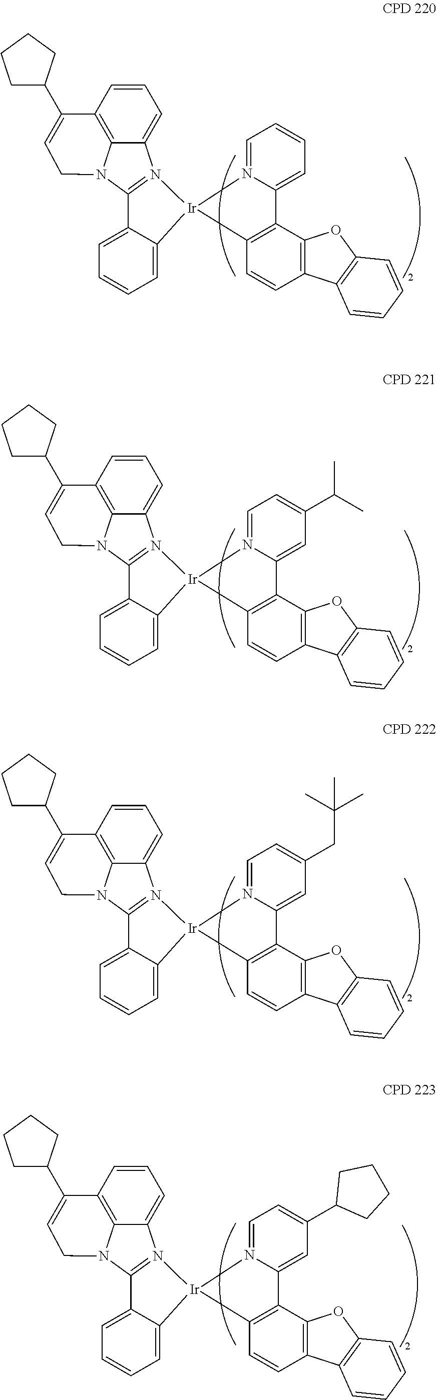

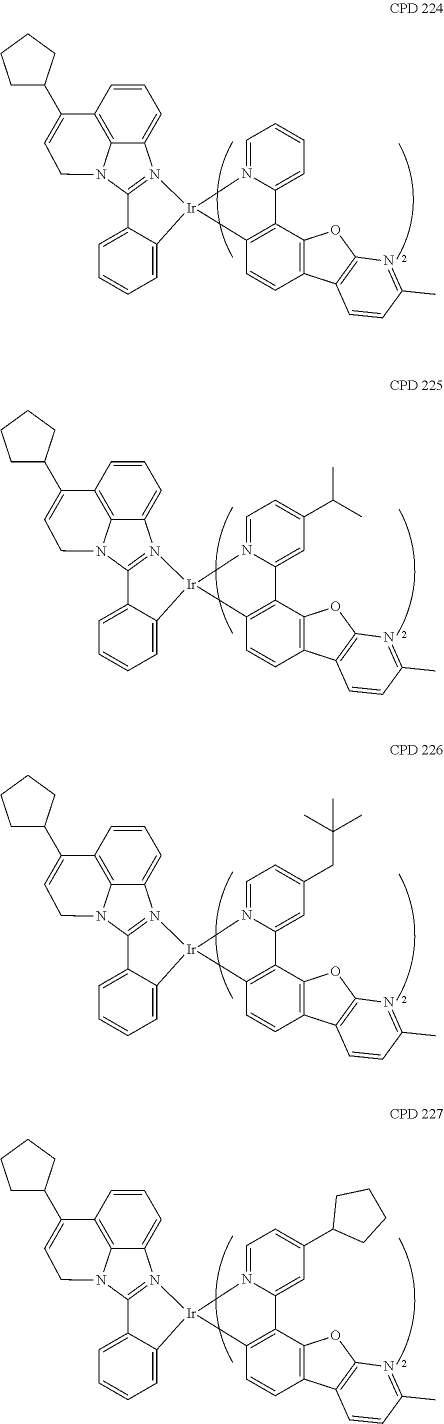

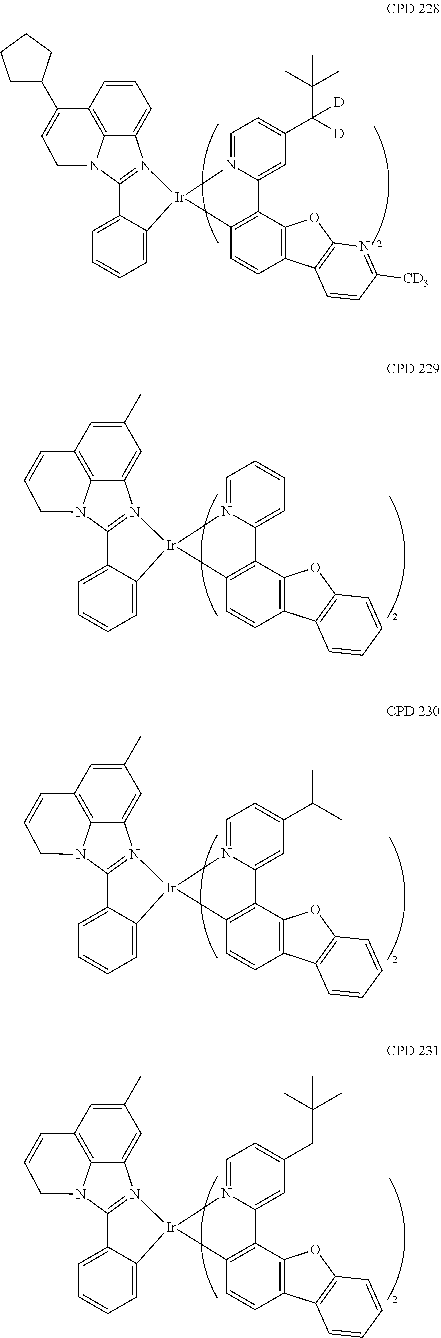

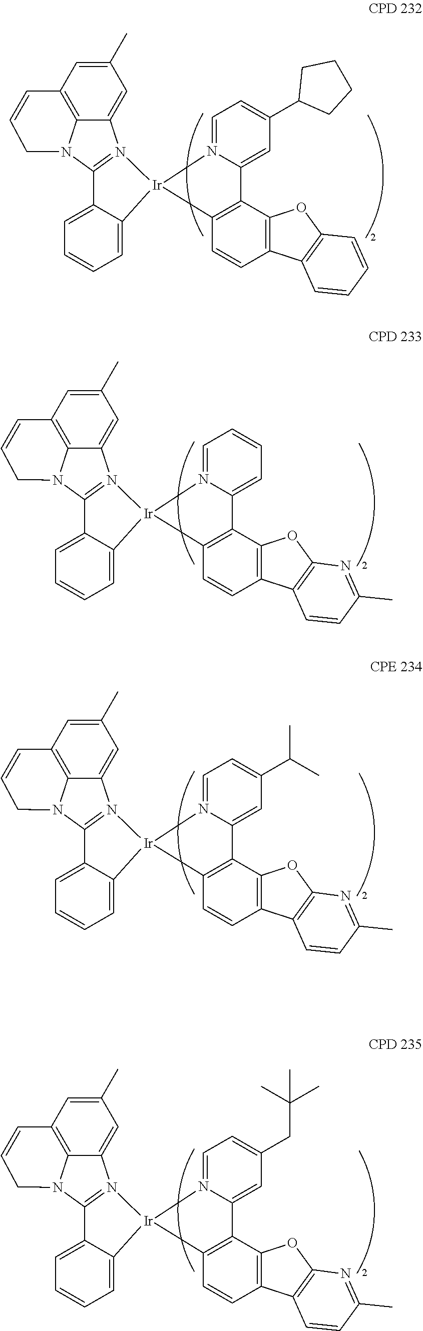

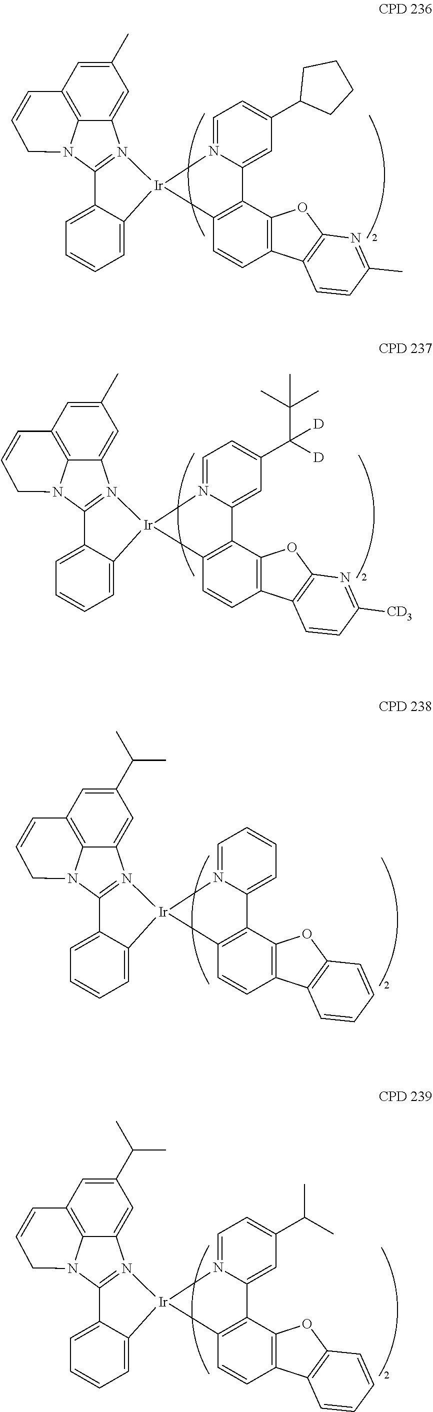

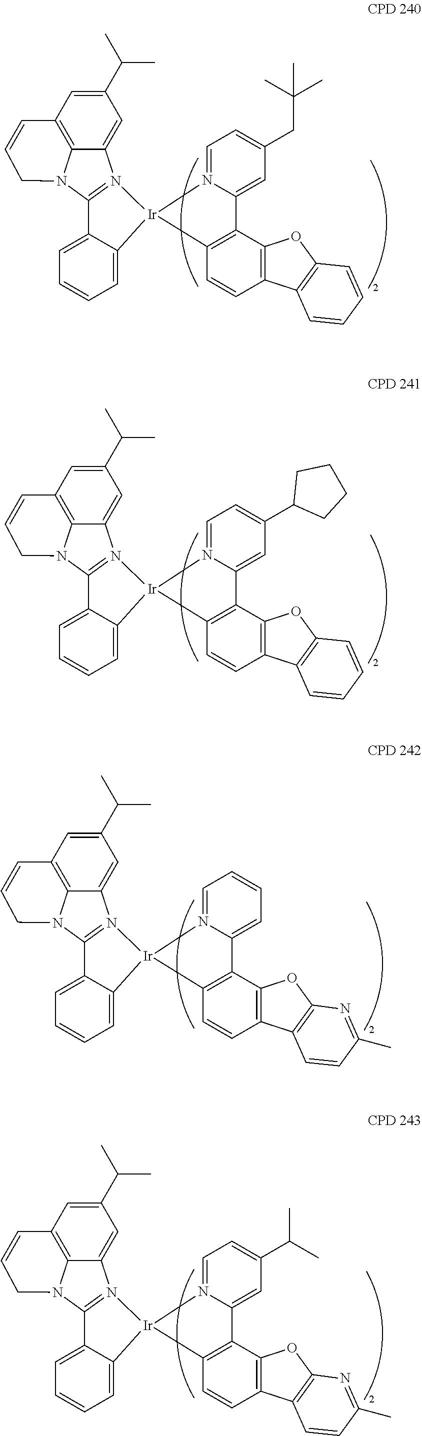

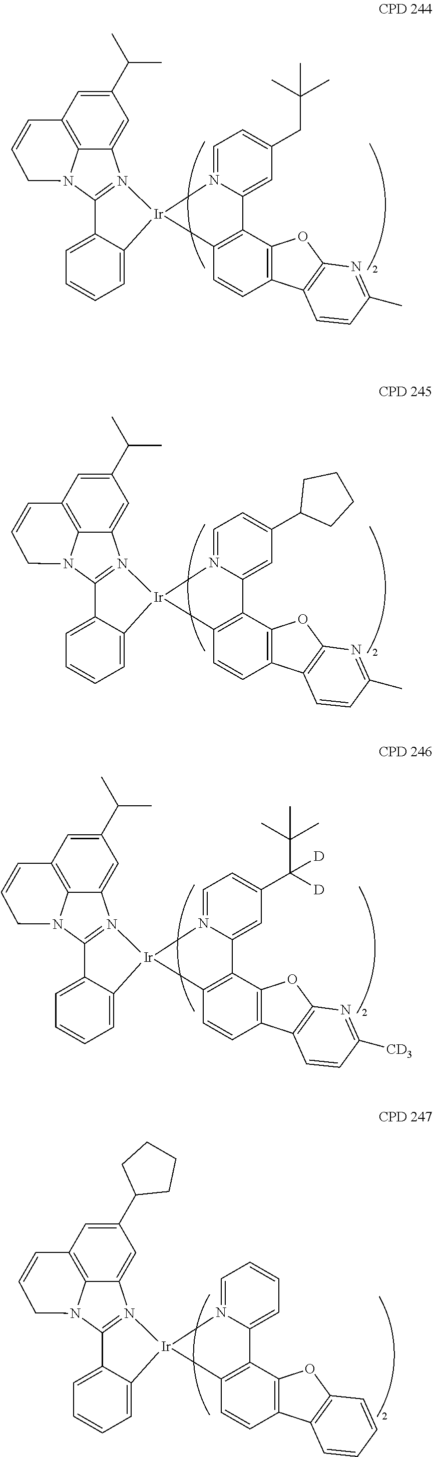

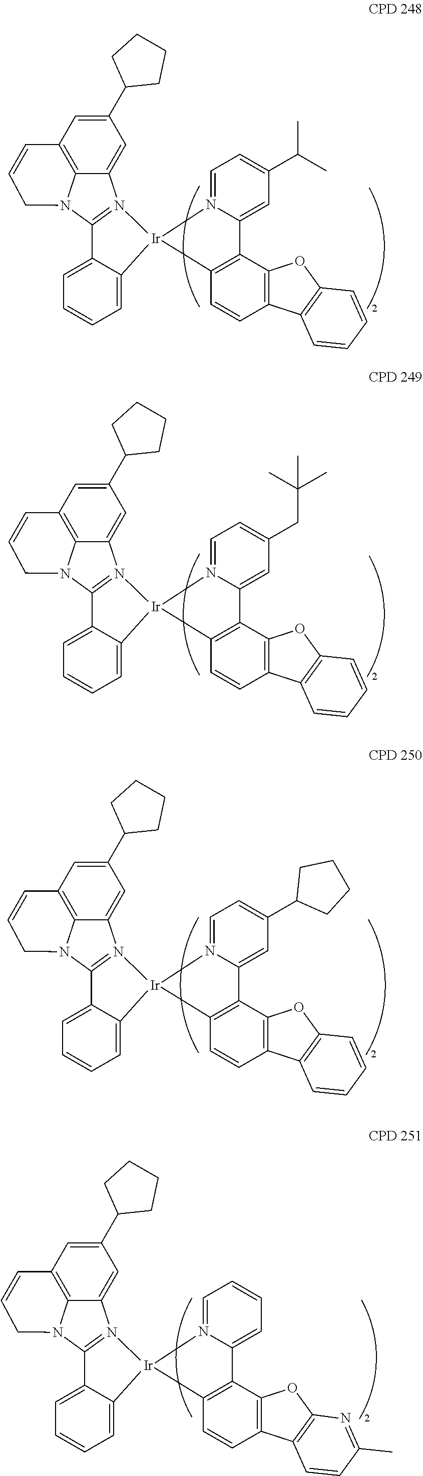

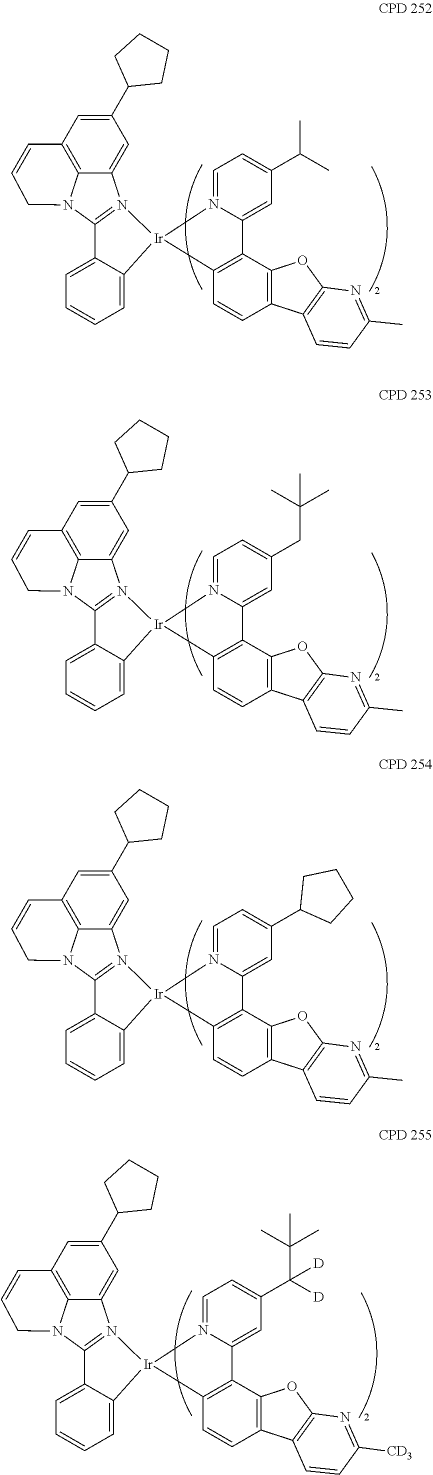

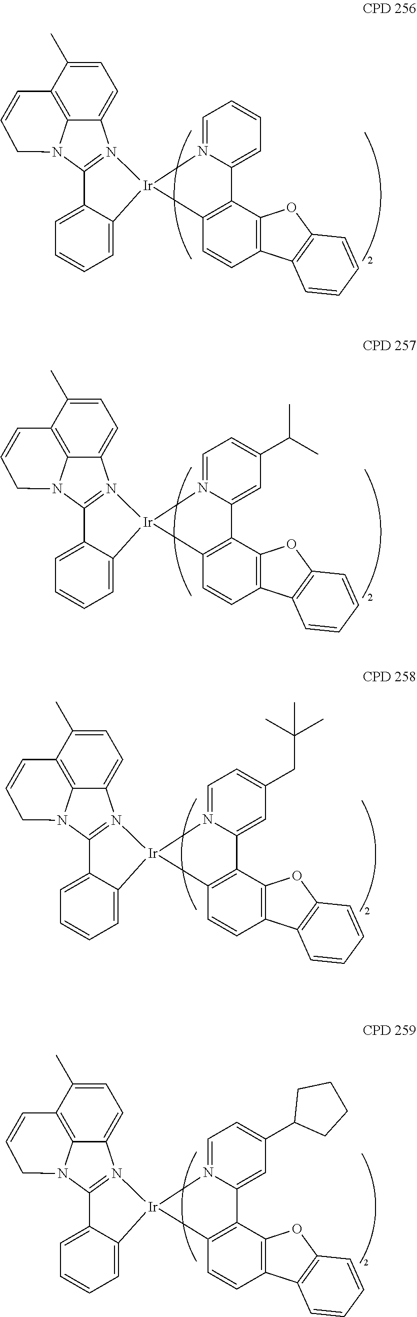

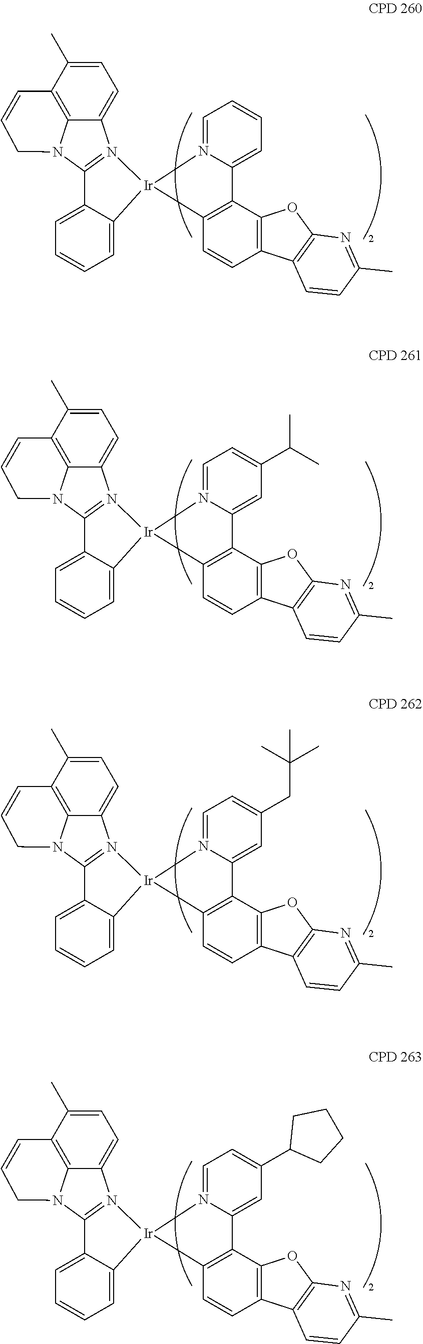

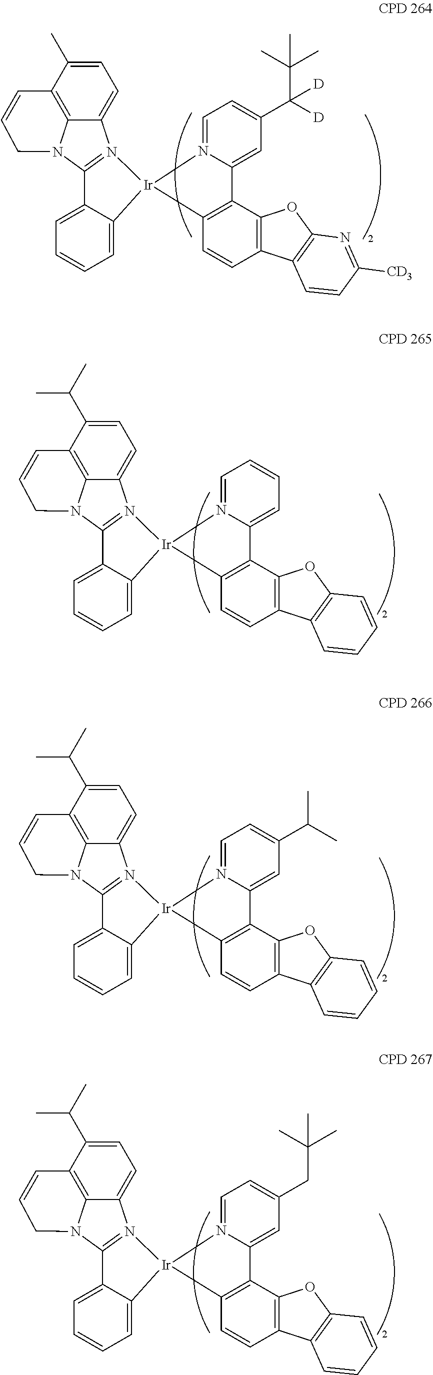

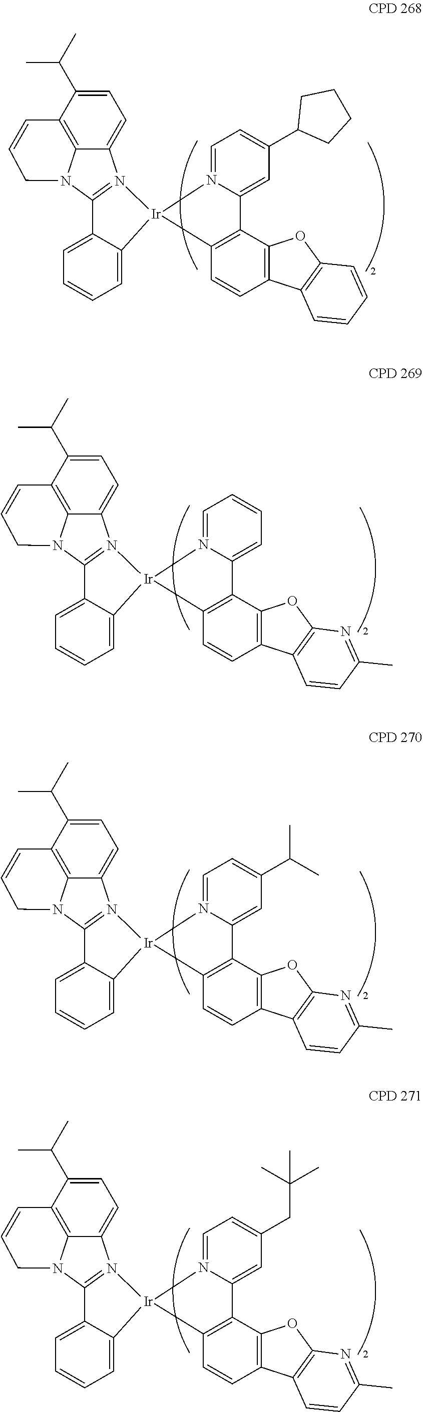

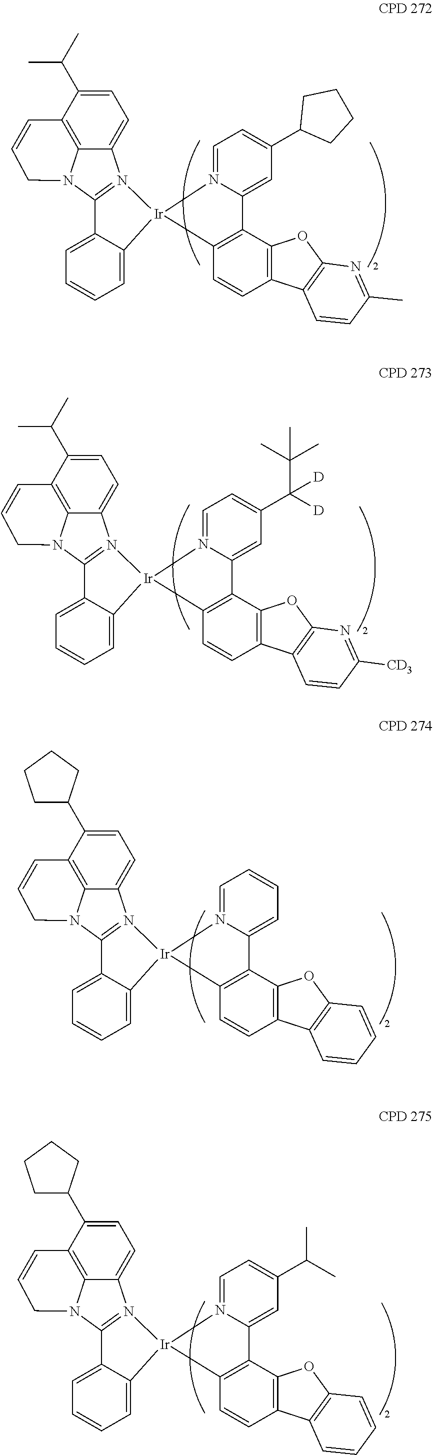

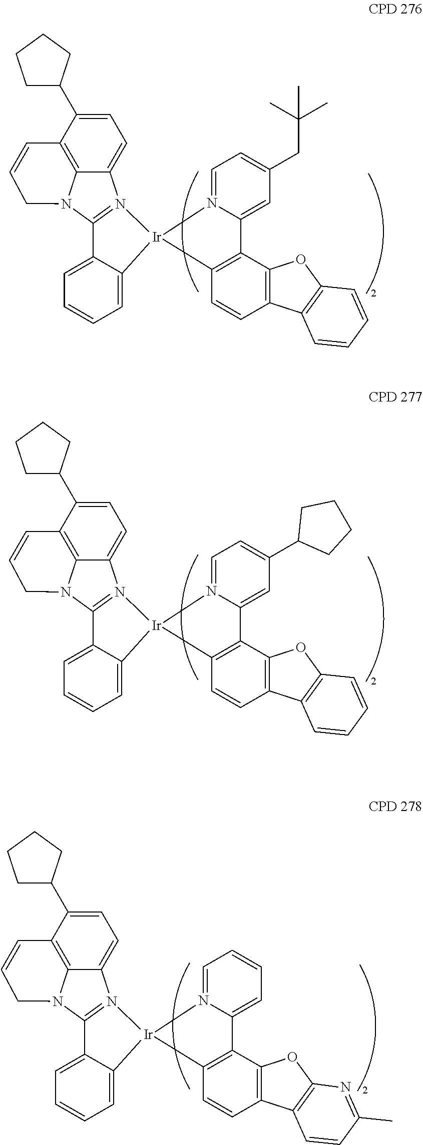

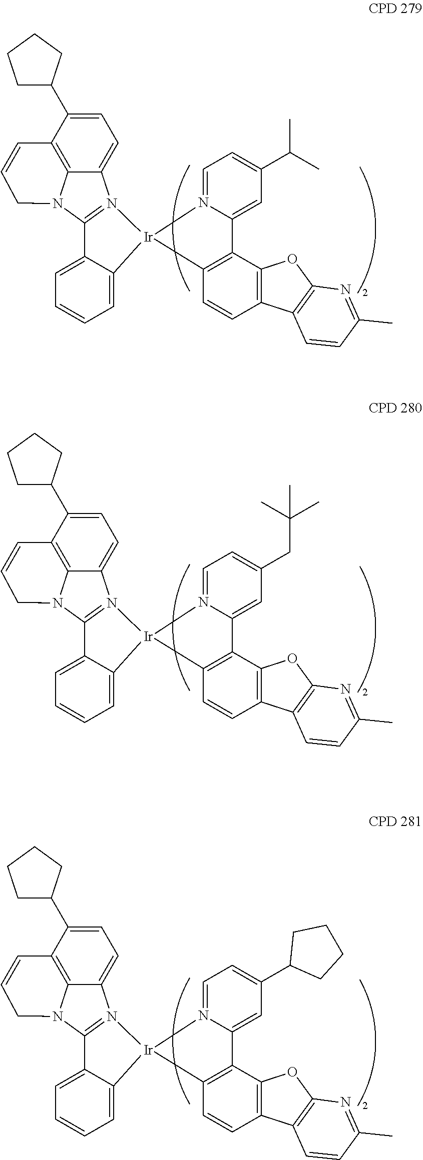

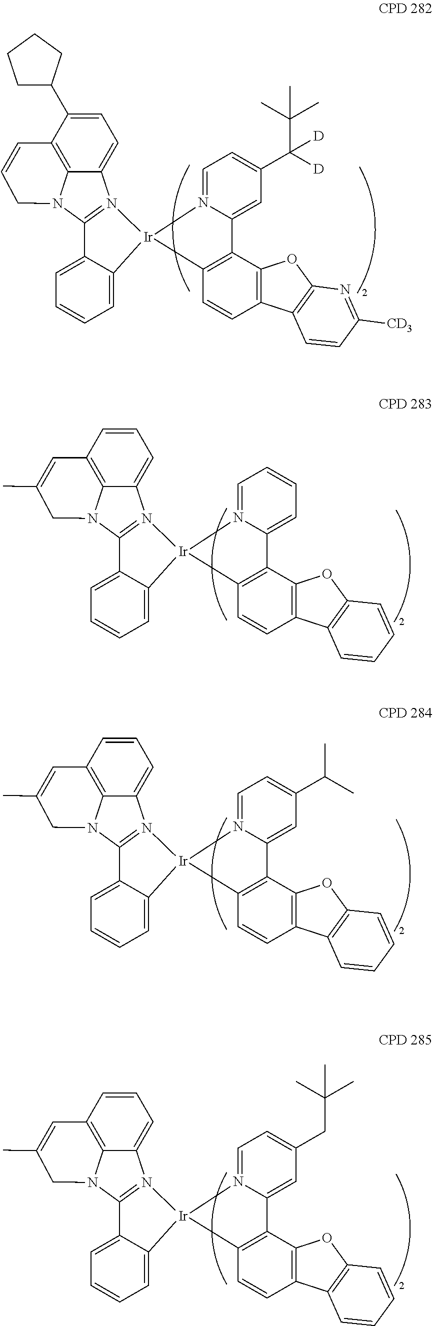

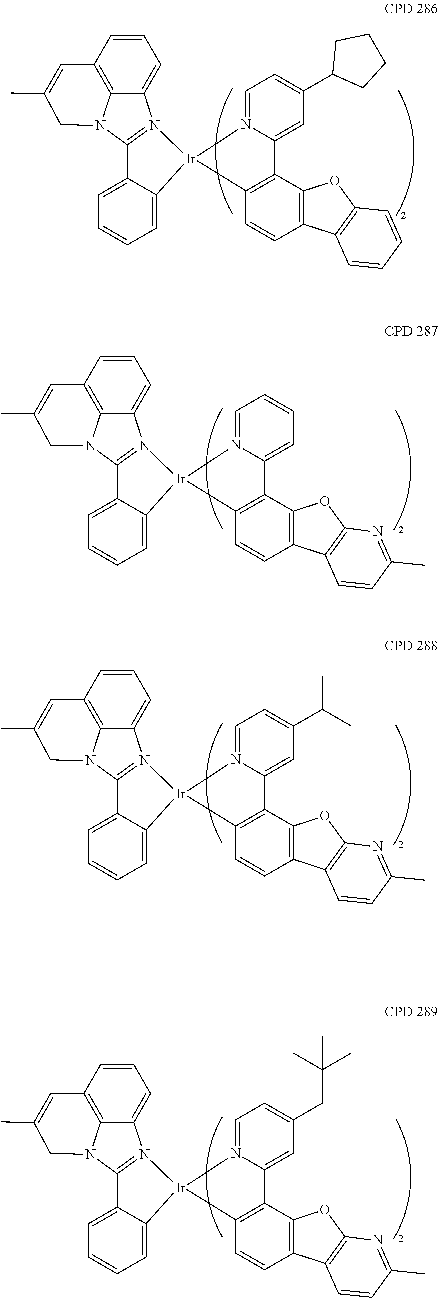

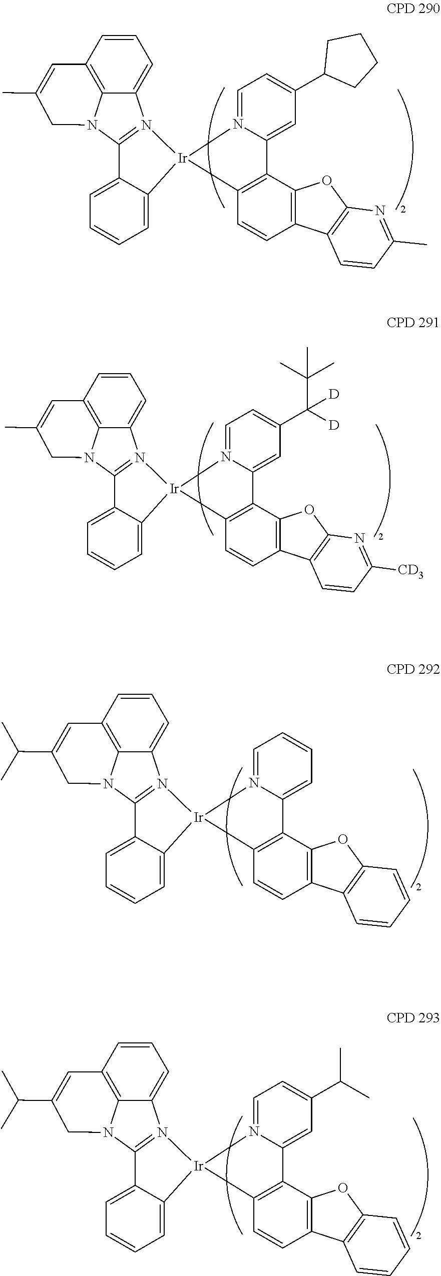

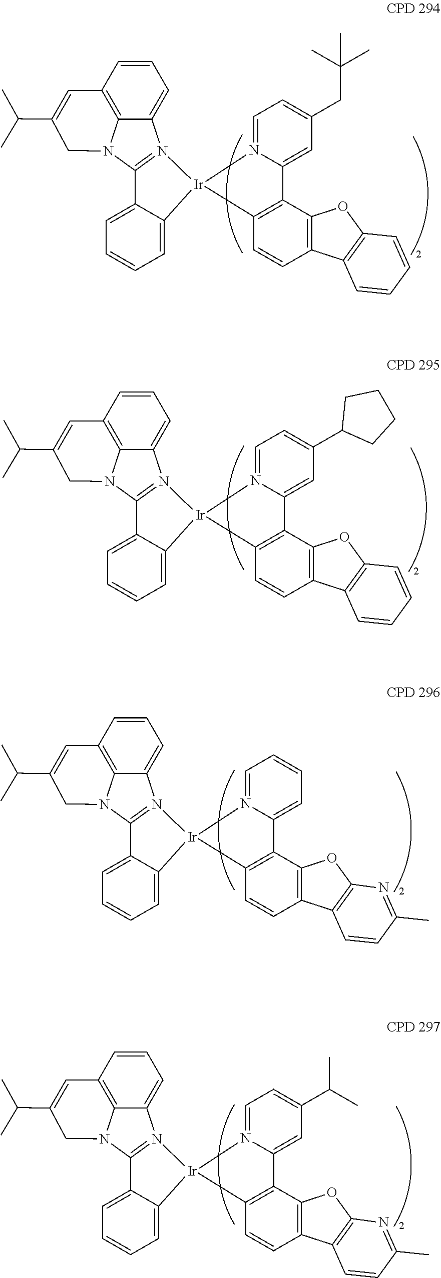

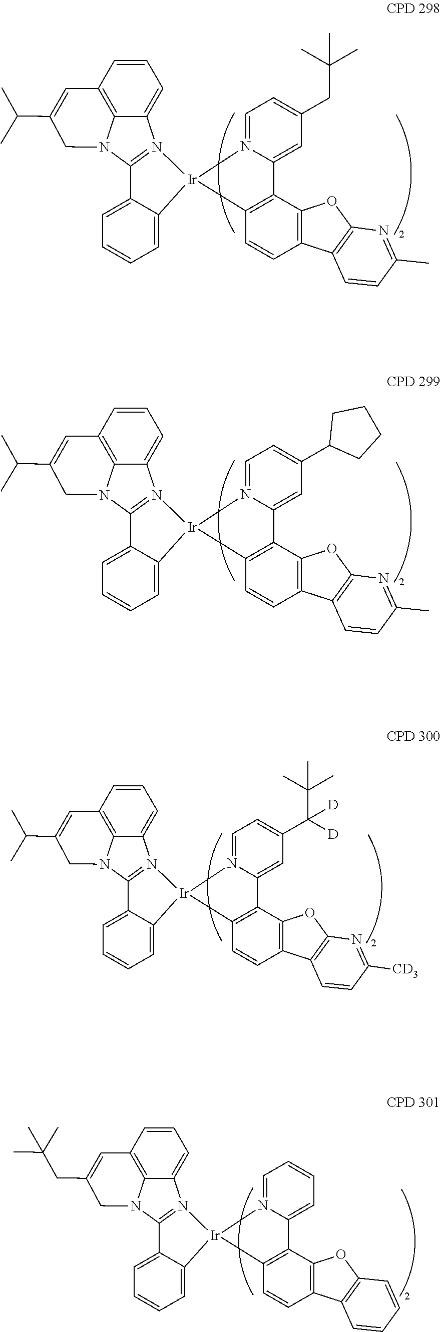

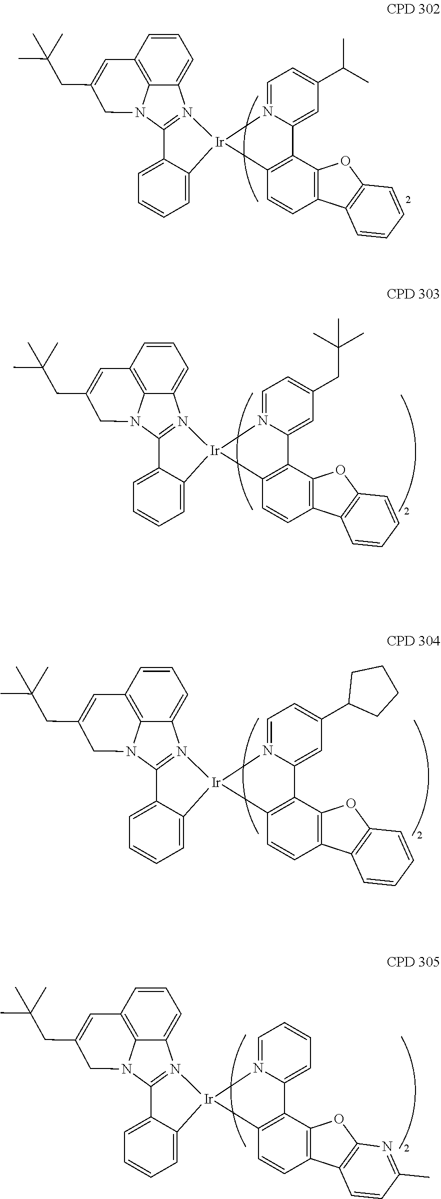

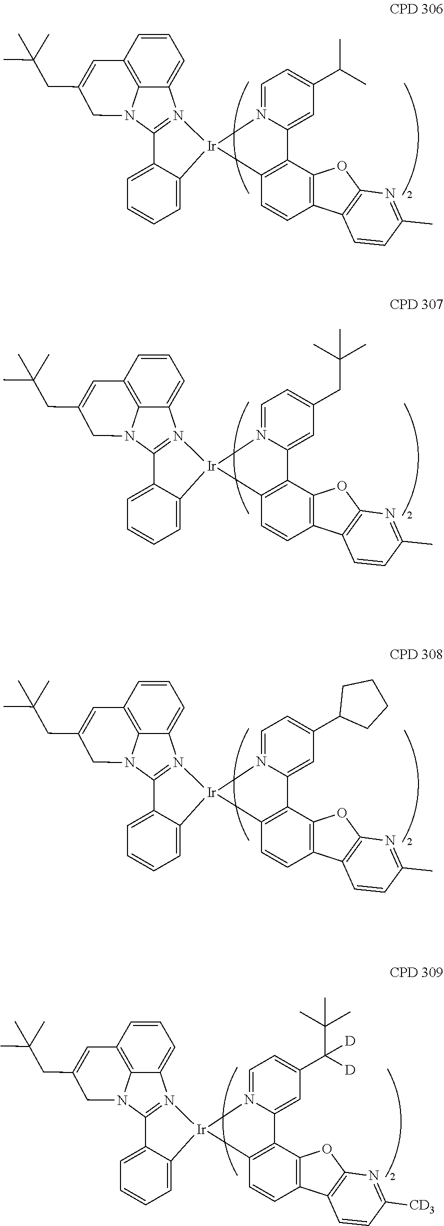

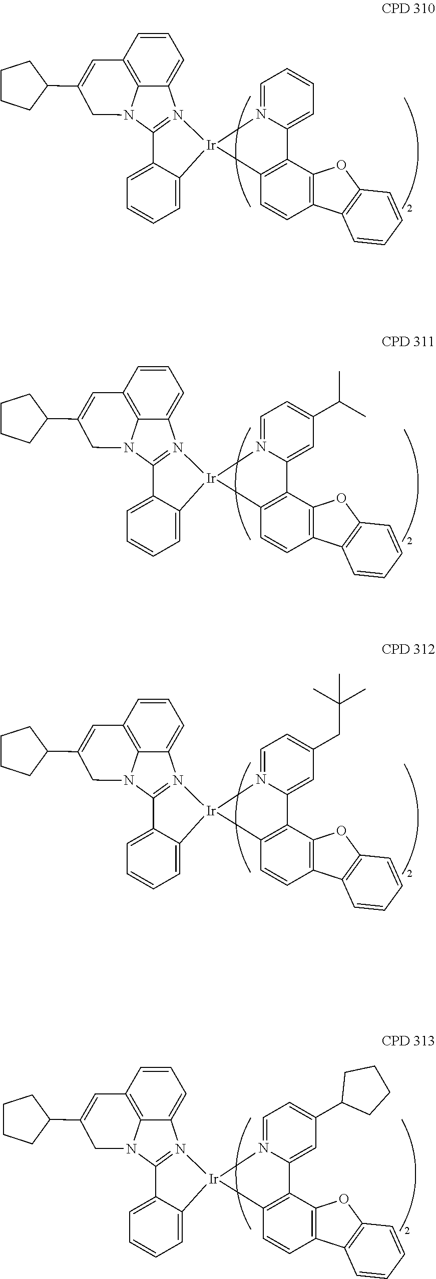

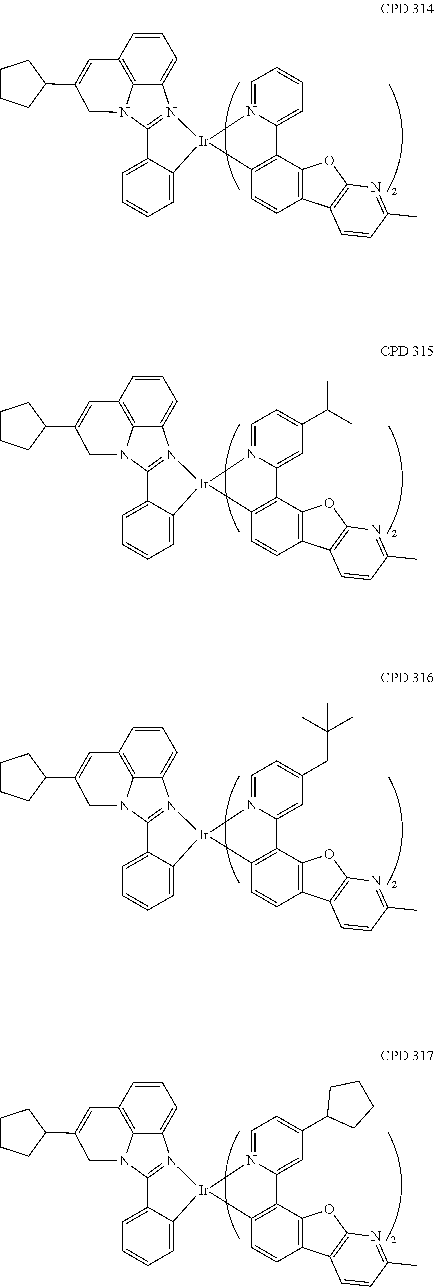

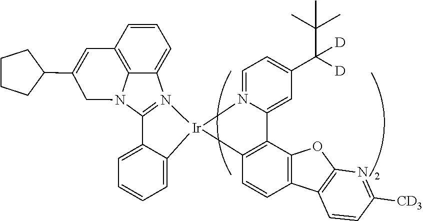

One of the purposes of the present disclosure is to provide a phosphorescent material containing the compound for an OLED.

One of the purposes of the present disclosure is to provide an OLED containing the compound.

The material of the present disclosure has the advantages of high optical and electrochemical stability, small half-peak width of emission spectrum, high color saturation, high luminous efficiency, and long device service life. As a phosphorescent material, the material of the present disclosure can convert a triplet state into light, so that the luminous efficiency of the OLED can be improved, and the energy consumption can be reduced. In particular, the compound has the potential for application in the AMOLED industry as a green light-emitting dopant.

### BRIEF DESCRIPTION OF DRAWINGS

FIG. 1 is a diagram showing the 1HNMR spectrum of a compound CPD 10 of the present disclosure in a deuterated chloroform solution.

FIG. 2 shows the ultraviolet absorption spectrum and emission spectrum of the compound CPD 10 of the present disclosure in a dichloromethane solution.

FIG. 3 is a diagram showing the 1HNMR spectrum of a compound CPD 202 of the present disclosure in a deuterated chloroform solution.

FIG. 4 shows the ultraviolet absorption spectrum and emission spectrum of the compound CPD 202 of the present disclosure in a dichloromethane solution.

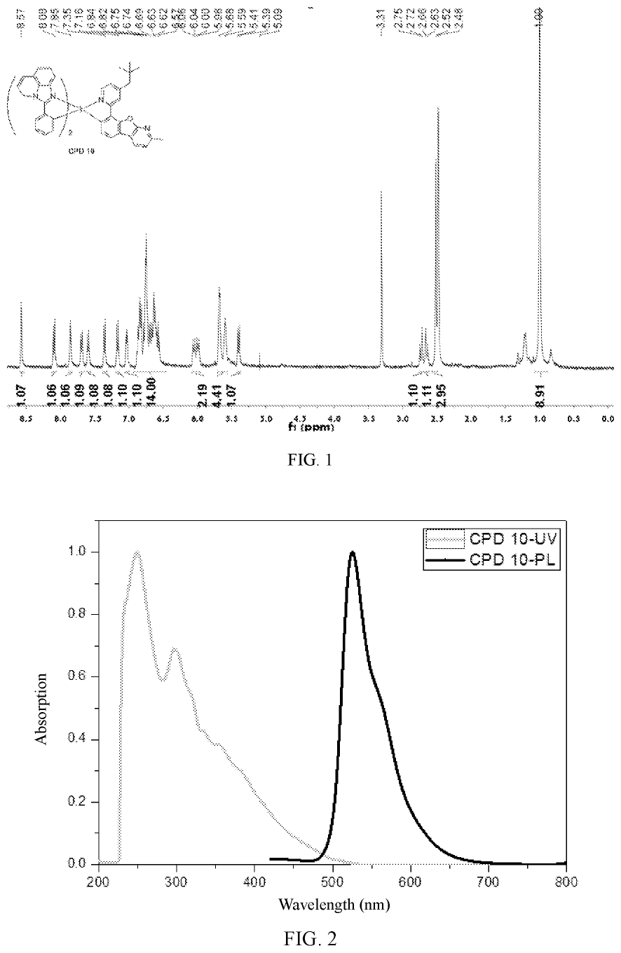

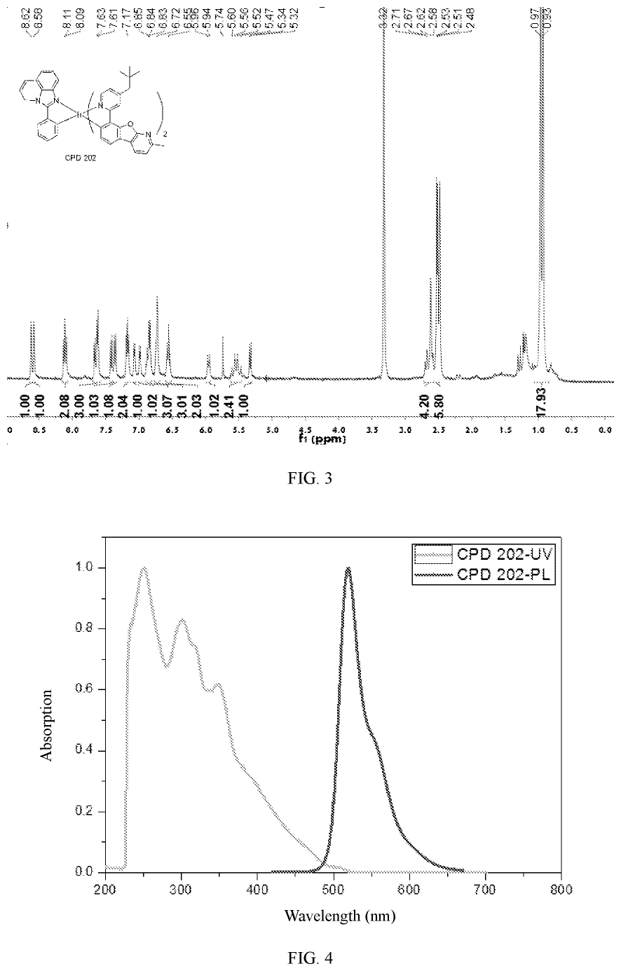

### DETAILED DESCRIPTION OF EMBODIMENTS

A compound of the present disclosure has a structure formula as shown in the following formula (1):

where

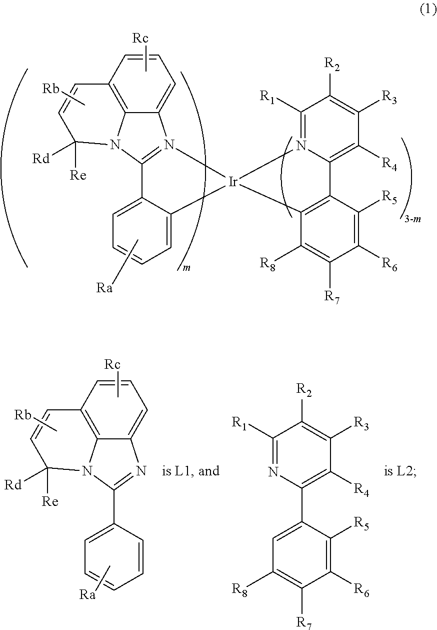

m is 1, 2, or 3, and when m is 1, the two L2 may be the same or different;
Ra, Rb and Rc independently indicates no substitution to maximum possible substitution;
Ra, Rb, Rc, Rd and Re are independently selected from hydrogen, deuterium, halogen, substituted or unsubstituted C₁-C₁₀ alkyl, substituted or unsubstituted C₃-C₂₀cycloalkyl, substituted or unsubstituted C₆-C₁₈ aryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
R₁-R₈ are independently selected from hydrogen, deuterium, halogen, hydroxyl, sulfhydryl, substituted or unsubstituted C₁-C₁₀ alkyl, substituted or unsubstituted C₁-C₁₀heteroalkyl, substituted or unsubstituted C₃-C₂₀cycloalkyl, substituted or unsubstituted C₂-C₁₀ alkenyl, substituted or unsubstituted C₂-C₁₀alkynyl, substituted or unsubstituted C₆-C₁₈ aryl, substituted or unsubstituted C₂-C₁₇heteroaryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
two adjacent groups of R₁-R₄ and R₅-R₈ may be connected with each other to form an aliphatic ring structure or an aromatic ring structure;
the heteroalkyl is an alkyl at least containing one O, N or S heteroatom;
and the “substituted” refers to substitution with deuterium, F, Cl, Br, C₁-C₆ alkyl, C₃-C₆cycloalkyl, amino substituted with C₁-C₆ alkyl, nitrile, isonitrile, or phosphino, and the substitution ranges from a single substitution number to a maximum possible substitution number.

In the formula (1), when more than two Ra, Rb, or Rc exist, a plurality of the Ra, Rb, or Rc may be separately identical or different.

In the formula (1), when more than two substituents exist, a plurality of the substituents may be separately identical or different.

In the formula (1), at least one of the Rb and the Rc is deuterium, fluorine, substituted or unsubstituted C₁-C₆ alkyl, or substituted or unsubstituted C₃-C₆cycloalkyl, indicating that the Rb is selected from the above groups while the Rc is not selected from the above groups; the Rc is selected from the above groups while the Rb is not selected from the above groups; and the Rb and the Rc are selected from the above groups at the same time.

Examples of various groups of the compound as shown in the formula (1) are described below.

It should be noted that in the specification, “Cₐ-C_{b}” in the term “substituted or unsubstituted Cₐ-C_{b} X group” refers to the number of carbons when the X group is unsubstituted, excluding the number of carbons of a substituent when the X group is substituted.

As a linear or branched alkyl, the C₁-C₁₀ alkyl specifically includes methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, and n-decyl and isomers thereof, preferably includes methyl, ethyl, propyl, isopropyl, n-butyl, isobutyl, sec-butyl, and tert-butyl, and more preferably includes propyl, isopropyl, isobutyl, sec-butyl, and tert-butyl.

The C₃-C₂₀cycloalkyl may include cyclopropyl, cyclobutyl, cyclopentyl, cyclohexyl, 1-adamantyl, 2-adamantyl, 1-norbornyl, and 2-norbornyl, and preferably includes cyclopentyl and cyclohexyl.

The C₂-C₁₀ alkenyl may include vinyl, propenyl, allyl, 1-butadienyl, 2-butadienyl, 1-hexatrienyl, 2-hexatrienyl, and 3-hexatrienyl, and preferably includes propenyl and allyl.

As a linear or branched alkyl or cycloalkyl consisting of atoms other than carbon and hydrogen, the C₁-C₁₀heteroalkyl may include mercaptomethyl methyl, methoxymethyl, ethoxymethyl, tert-butoxyl methyl, N,N-dimethyl methyl, epoxy butyl, epoxy pentyl, and epoxy hexyl, and preferably includes methoxymethyl and epoxy pentyl.

Specific examples of the aryl include phenyl, naphthyl, anthracyl, phenanthryl, tetracenyl, pyrenyl, chrysenyl, benzo[c]phenanthryl, benzo[g]chrysenyl, fluorenyl, benzofluorenyl, dibenzofluorenyl, biphenyl, triphenyl, tetraphenyl, and fluoranthracyl, and preferably include phenyl and naphthyl.

Specific examples of the heteroaryl may include pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothienyl, azodibenzofuryl, azodibenzothienyl, diazodibenzofuryl, diazodibenzothienyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furzanyl, thienyl, benzothienyl, dihydroacridinyl, azocarbazolyl, diazocarbazolyl, and quinazolinyl, and preferably include pyridyl, pyrimidinyl, triazinyl, dibenzofuryl, dibenzothienyl, azodibenzofuryl, azodibenzothienyl, di azodibenzofuryl, diazodibenzothienyl, carbazolyl, azocarbazolyl, and diazocarbazolyl.

The following embodiments are merely described to facilitate the understanding of the technical disclosure, and should not be considered as specific limitations of the present disclosure.

All raw materials, solvents and the like involved in the synthesis of compounds in the present disclosure are purchased from Alfa, Acros, and other suppliers known to persons skilled in the field.

### Synthesis of a Common Intermediate L1-1

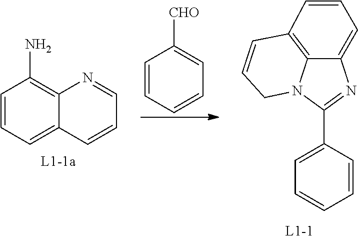

### Synthesis of a Compound L1-1

A compound L1-1a (32.0 g, 0.22 mol, 1.0 eq), benzaldehyde (28.2 g, 0.26 mol, 1.20 eq), acetic acid (19.9 g, 0.33 mol, 1.5 eq) and toluene (160 ml) were added to a 500 ml three-mouth flask, vacuumization was conducted for nitrogen replacement for 3 times, and stirring was conducted for reflux at 110° C. for 18 h under the protection of nitrogen. According to monitoring by TLC, the raw material L1-1a was completely reacted. Cooling was conducted to room temperature. 100 ml of deionized water was added for water washing and layering. An upper organic phase was collected and concentrated to remove an organic solvent, followed by spin-drying and separation by column chromatography (with an eluting agent including ethyl acetate and n-hexane at a ratio of 1:20). Then drying was conducted to obtain 30.26 g of a grayish white solid, namely a compound L1-1, with a yield of 58.7%. The mass spectrum was: 233.28 (M+H). ¹H NMR (400 MHz, CDCl₃) δ 7.93-7.86 (m, 2H), 7.58-7.44 (m, 4H), 7.10 (dd, J=8.1, 7.3 Hz, 1H), 6.87 (d, J=7.1 Hz, 1H), 6.64 (dd, J=11.1, 3.5 Hz, 1H), 5.84 (dt, J=10.0, 3.4 Hz, 1H), 5.37-5.32 (m, 2H).

### Synthesis of a Compound CPD 1

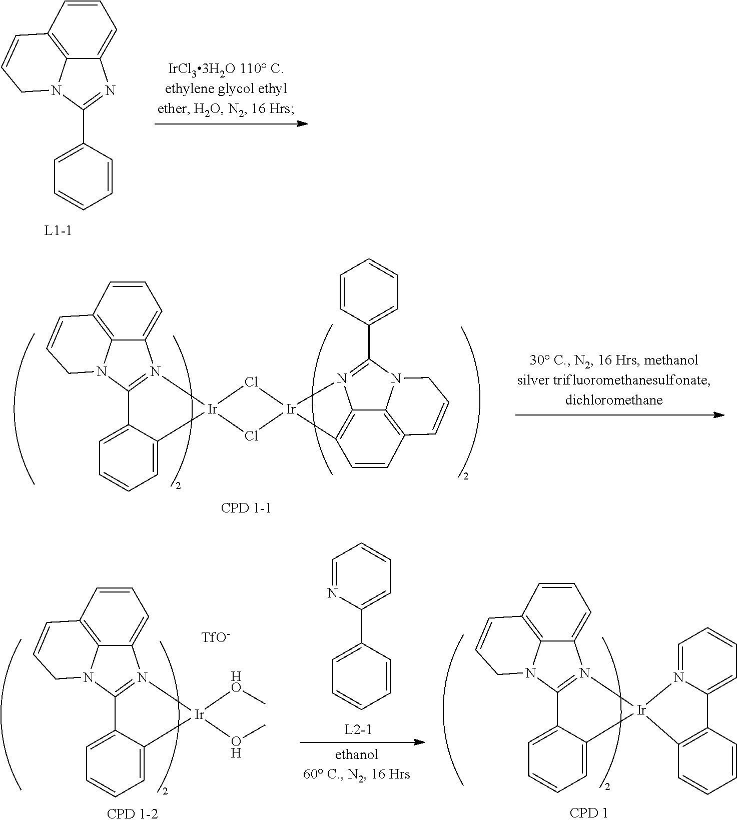

### Synthesis of a Compound CPD 1-1

The compound L1-1 (30.0 g, 0.129 mol, 3.0 eq) and IrCl₃.3H₂O (15.18 g, 0.043 mol, 1.0 eq) were put into a 1 L one-mouth flask, and ethylene glycol ethyl ether (300 ml) and deionized water (100 ml) were added. Vacuum replacement was conducted for 3 times, and a mixture was stirred for reflux at 110° C. for 16 h under the protection of N₂. After cooling was conducted to room temperature, filtration was conducted. A filter residue was sequentially washed with methanol (100 ml*3) and n-hexane (100 ml*3), and then dried to obtain 25.46 g of a compound CPD 1-1 with a yield of 85.7%. The obtained compound was directly used in the next step without purification.

### Synthesis of a Compound CPD 1-2

A dimer CPD 1-1 (15.1 g, 0.021 mol, 1.0 eq) and dichloromethane (1.5 L) were added to a 3 L three-mouth flask and stirred for dissolution. Silver trifluoromethanesulfonate (11.24 g, 0.043 mol, 2.0 eq) was dissolved in isopropanol (1.1 L) and then added to an original solution in the reaction flask. Vacuum replacement was conducted for 3 times, and a mixture was stirred at room temperature for 16 h under the protection of N₂. Then a reaction solution was filtered with diatomite, a filter residue was rinsed with dichloromethane (150 ml), and a filtrate was spin-dried to obtain 14.56 g of a compound CPD 1-2 with a yield of 76.7%. The obtained compound was directly used in the next step without purification.

### Synthesis of a Compound CPD 1

The compound CPD 1-2 (7.06 g, 8.13 mmol, 1.0 eq) and a compound L2-1 (3.79 g, 24.4 mmol, 3.0 eq) were added to a 250 ml three-mouth flask, and ethanol (70 ml) was added. Vacuum replacement was conducted for 3 times, and a mixture was stirred for reflux for 16 h under the protection of N₂. After cooling was conducted to room temperature, filtration was conducted. A solid was collected, dissolved in dichloromethane (150 ml), and filtered with silica gel. A filter cake was rinsed with dichloromethane (50 ml). A filtrate was spin-dried, recrystallized for 2 times with tetrahydrofuran/methanol (at a ratio of a product to tetrahydrofuran to methanol was 1:5:5), and beaten for 1 time with n-hexane (80 ml). Then drying was conducted to obtain 4.33 g of a compound CPD 1 with a yield of 65.8%. 4.33 g of the crude product CPD 1 was sublimated and purified to obtain 2.87 g of a sublimated pure product CPD 1 with a yield of 66.2%. The mass spectrum was: 809.95 (M+H). ¹H NMR (400 MHz, CDCl₃) δ 8.37 (d, 1H), 8.16 (d, 1H), 7.77 (dd, 2H), 7.50 (m, 6H), 7.40 (m, J=20.0 Hz, 6H), 7.15 (m, J=15.0 Hz, 3H), 7.07 (dd, 2H), 6.90 (m, 1H), 6.56 (dd, 2H), 5.76 (m, 2H), 5.16 (dd, J=2.7 Hz, 2H), 5.01 (dd, J=2.7 Hz, 2H).

### Synthesis of a Compound CPD 10

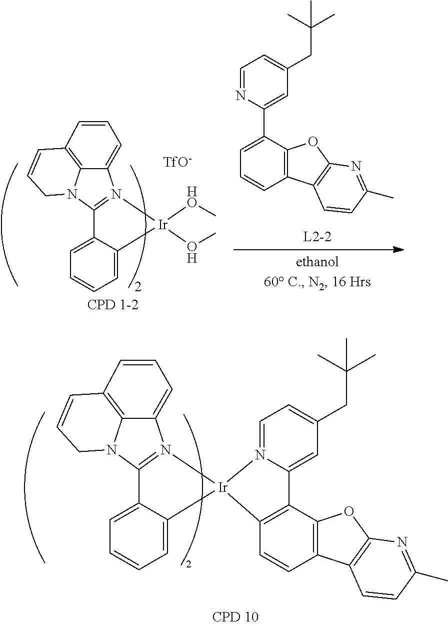

With reference to the synthesis and purification methods of the compound CPD 1, only the corresponding raw materials were required to be changed, and 4.21 g of a target compound CPD 10 with a yield of 71.2% was obtained. 4.21 g of the crude product CPD 10 was sublimated and purified to obtain 2.74 g of a sublimated pure product CPD 10 with a yield of 65.0%. The mass spectrum was: 985.2 (M+H). ¹H NMR (400 MHz, DMSO) δ 8.57 (s, 1H), 8.09 (d, J=7.5 Hz, 1H), 7.86 (d, J=5.4 Hz, 1H), 7.69 (d, J=7.9 Hz, 1H), 7.59 (d, J=7.9 Hz, 1H), 7.36 (d, J=7.9 Hz, 1H), 7.17 (d, J=7.9 Hz, 1H), 7.03 (d, J=4.0 Hz, 1H), 6.93-6.46 (m, 14H), 6.02 (dd, J=23.2, 10.3 Hz, 2H), 5.64 (d, J=34.4 Hz, 4H), 5.40 (d, J=8.3 Hz, 1H), 2.73 (d, J=12.6 Hz, 1H), 2.65 (d, J=12.0 Hz, 1H), 2.52 (s, 3H), 1.00 (s, 9H).

### Synthesis of a Common Intermediate L1-2

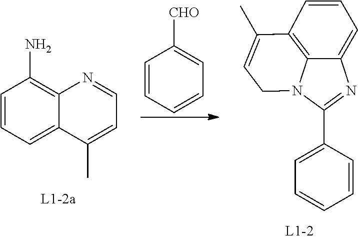

### Synthesis of a Compound L1-2

With reference to the synthesis and purification methods of the compound L1-1, only the corresponding raw materials were required to be changed, and 26.2 g of a target compound L1-2 with a yield of 54.2% was obtained. The mass spectrum was: 247.3 (M+H). ¹H NMR (400 MHz, CDCl₃) δ 8.28 (m, 2H), 7.46 (m, 4H), 7.17 (t, 1H), 7.07 (dd, 1H), 5.54 (m, 1H), 5.08-4.89 (d, 2H), 1.97 (s, 3H).

### Synthesis of a Compound CPD 15

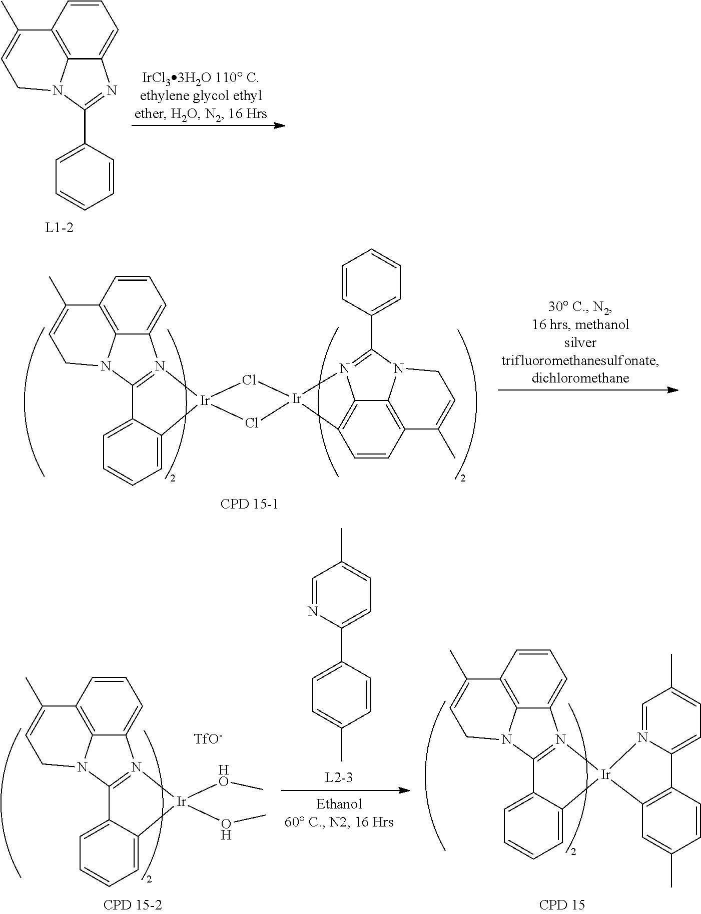

### Synthesis of a Compound CPD 15-1

With reference to the synthesis and purification methods of the compound CPD 1-1, only the corresponding raw materials were required to be changed, and an obtained compound was directly used in the next step without purification.

### Synthesis of a Compound CPD 15-2

With reference to the synthesis and purification methods of the compound CPD 1-2, only the corresponding raw materials were required to be changed, and an obtained compound was directly used in the next step without purification.

### Synthesis of a Compound CPD 15

With reference to the synthesis and purification methods of the compound CPD 1, only the corresponding raw materials were required to be changed, and 3.84 g of a target compound CPD 15 with a yield of 66.7% was obtained. 3.84 g of the crude product CPD 15 was sublimated and purified to obtain 2.65 g of a sublimated pure product CPD 15 with a yield of 69.0%. The mass spectrum was: 866.3 (M+H). ¹H NMR (400 MHz, CDCl₃) δ 8.30 (d, 1H), 8.11 (d, 1H), 7.75 (m, J=20.0 Hz, 3H), 7.50 (m, 5H), 7.42 (m, 4H), 7.28 (dd, J=15.0 Hz, 2H), 7.17 (t, 2H), 7.07 (dd, 2H), 5.54 (m, 2H), 5.34 (dd, J=4.6 Hz, 2H), 4.88 (dd, J=4.6 Hz, 2H), 2.31 (s, J=5.0 Hz, 6H), 1.97 (d, 6H).

### Synthesis of a Compound CPD 18

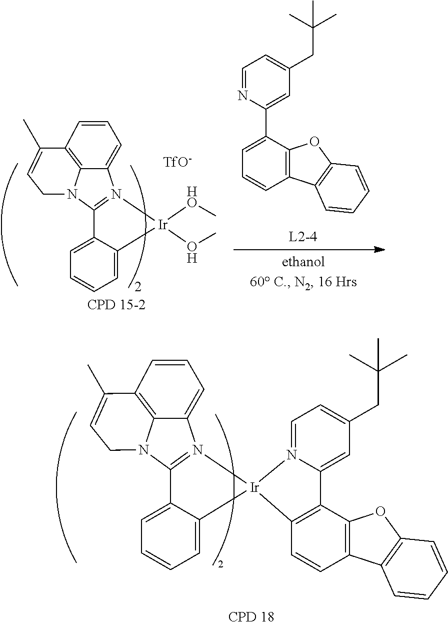

With reference to the synthesis and purification methods of the compound CPD 1, only the corresponding raw materials were required to be changed, and 3.79 g of a target compound CPD 18 with a yield of 68.1% was obtained. 3.79 g of the crude product CPD 18 was sublimated and purified to obtain 2.45 g of a sublimated pure product CPD 18 with a yield of 64.6%. The mass spectrum was: 998.3 (M+H). ¹H NMR (400 MHz, CDCl₃) δ 8.50 (d, 1H), 7.98 (dd, 1H), 7.84 (d, 1H), 7.77 (dd, 2H), 7.69 (s, 1H), 7.52 (m, J=20.0 Hz, 6H), 7.40 (m, J=15.0 Hz, 5H), 7.31 (m, 1H), 7.17 (t, 2H), 7.06 (m, J=10.0 Hz, 3H), 5.54 (t, 2H), 5.11 (d, 2H), 4.73 (d, 2H), 3.21 (s, 2H), 1.97 (s, 6H), 0.85 (s, 9H).

### Synthesis of a Compound CPD 22

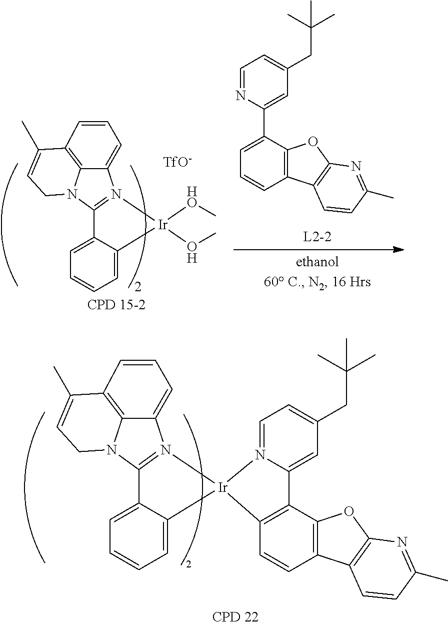

With reference to the synthesis and purification methods of the compound CPD 1, only the corresponding raw materials were required to be changed, and 3.37 g of a target compound CPD 22 with a yield of 62.4% was obtained. 3.37 g of the crude product CPD 22 was sublimated and purified to obtain 2.14 g of a sublimated pure product CPD 22 with a yield of 63.5%. The mass spectrum was: 1013.3 (M+H). ¹H NMR (400 MHz, CDCl₃) δ 8.50 (d, 1H), 8.41 (d, 1H), 7.84 (d, 1H), 7.77 (dd, 2H), 7.69 (s, 1H), 7.50 (m, 5H), 7.42 (m, 4H), 7.17 (t, 2H), 7.11-6.97 (m, 4H), 5.65 (d, 2H), 5.54 (m, 2H), 5.09 (d, 2H), 3.21 (s, 2H), 2.68 (s, 3H), 1.97 (d, 6H), 0.85 (s, 9H).

### Synthesis of a Compound CPD 24

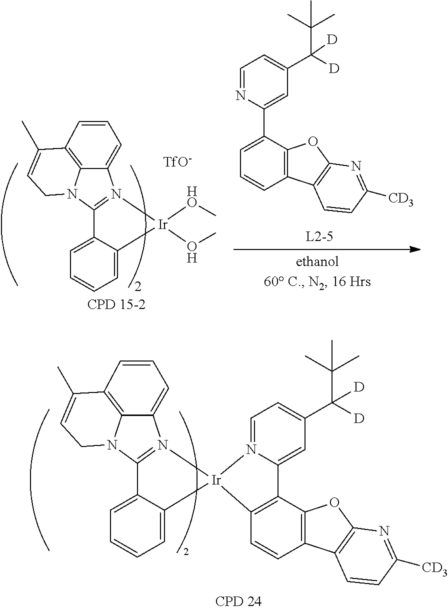

With reference to the synthesis and purification methods of the compound CPD 1, only the corresponding raw materials were required to be changed, and 3.42 g of a target compound CPD 24 with a yield of 65.4% was obtained. 3.42 g of the crude product CPD 24 was sublimated and purified to obtain 2.35 g of a sublimated pure product CPD 24 with a yield of 68.7%. The mass spectrum was: 1018.4 (M+H). ¹H NMR (400 MHz, CDCl₃) δ 8.61 (dd, J=15.0, 2.9 Hz, 1H), 8.50 (d, J=15.0 Hz, 1H), 8.42 (dd, J=15.0, 2.9 Hz, 1H), 7.86-7.67 (m, 4H), 7.50 (t, J=14.8 Hz, 4H), 7.42 (m, J=15.0, 3.3, 1.9 Hz, 4H), 7.22 (dt, J=44.0, 14.9 Hz, 3H), 7.06 (ddd, J=15.0, 9.0, 3.1 Hz, 3H), 5.60-5.50 (m, 2H), 5.44 (t, J=12.0 Hz, 2H), 4.78 (t, J=12.1 Hz, 2H), 1.97 (d, J=2.0 Hz, 6H), 1.32 (s, 9H).

### Synthesis of a Common Intermediate L1-3

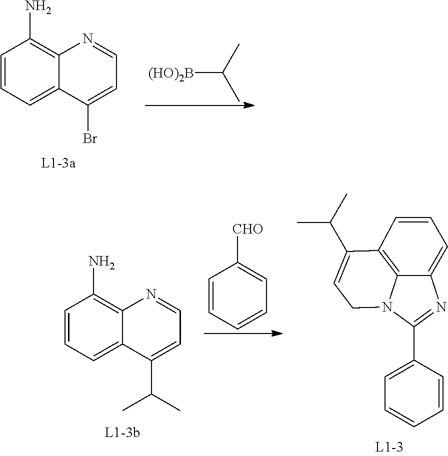

### Synthesis of a Compound L1-3b

A compound L1-3a (32 g, 143.4 mmol, 1.0 eq), isopropylboronic acid (15.13 g, 172.1 mmol, 1.2 eq), dichlorodi-tert-butyl-(4-dimethylaminophenyl)phosphopalladium (II) (2.03 g, 2.87 mmol, 0.02 eq), K₃PO₄ (60.9 g, 286.9 mmol, 2.0 eq), and toluene (320 ml) were sequentially added into a 1 L three-mouth flask. Vacuumization was conducted for nitrogen replacement for 3 times. A mixture obtained was heated to about 70° C. in an oil bath, stirred for 16 h, and then sampled. According to monitoring by TLC, the raw material L1-3a was basically reacted completely. Cooling was conducted to room temperature. Deionized water was added for water washing for 3 times (150 ml/time). After liquid separation, an organic phase was concentrated under reduced pressure to obtain a solid. A crude product was separated by column chromatography (with a mixture of EA and Hex at a ratio of 1:20) to obtain a product. The product obtained was dried to obtain 19.26 g of a white-like solid compound L1-3b with a yield of 72.1%. The mass spectrum was: 187.2 (M+H).

### Synthesis of a Compound L1-3

With reference to the synthesis and purification methods of the compound L1-1, only the corresponding raw materials were required to be changed, and 18.44 g of a target compound L1-3 with a yield of 65.2% was obtained. The mass spectrum was: 275.3 (M+H). ¹H NMR (400 MHz, CDCl₃) δ 8.28 (m, 2H), 7.46 (m, 4H), 7.17 (t, 1H), 7.07 (dd, 1H), 5.54 (d, 1H), 4.99 (dd, J=19.2 Hz, 2H), 3.00 (m, 1H), 1.04 (d, 6H).

### Synthesis of a Compound CPD 30

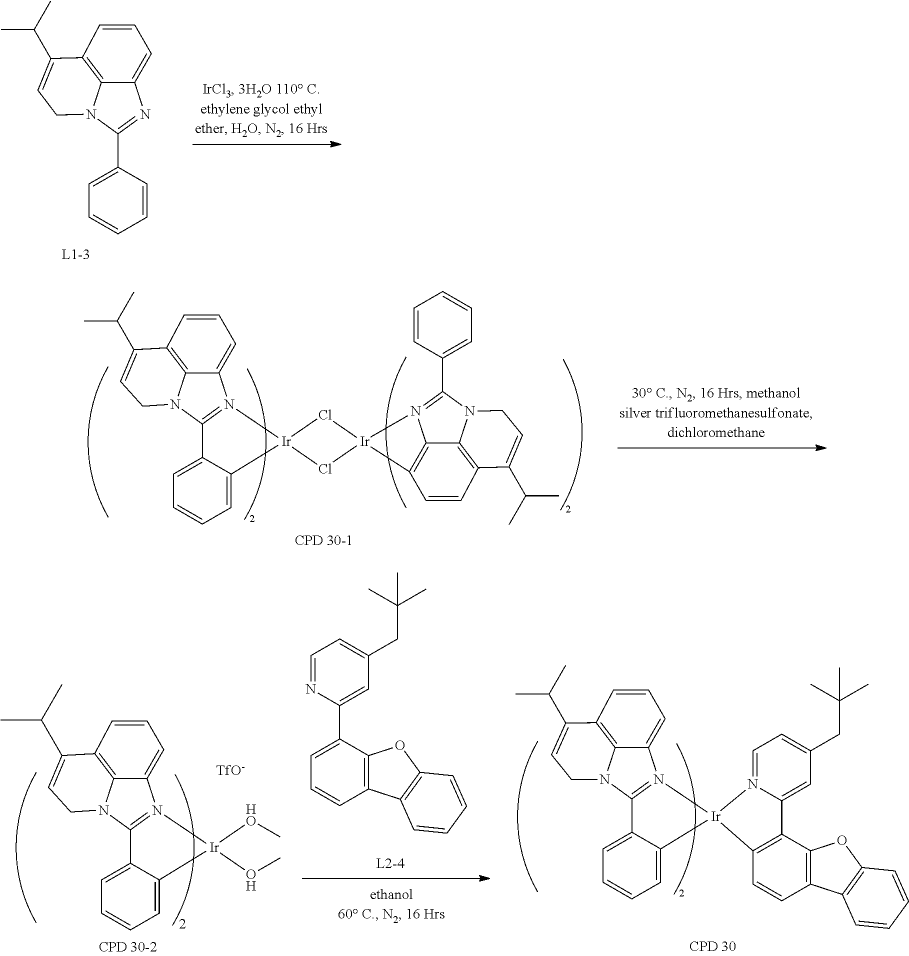

### Synthesis of a Compound CPD 30-1

With reference to the synthesis and purification methods of the compound CPD 1-1, only the corresponding raw materials were required to be changed, and an obtained compound was directly used in the next step without purification.

### Synthesis of a Compound CPD 30-2

With reference to the synthesis and purification methods of the compound CPD 1-2, only the corresponding raw materials were required to be changed, and an obtained compound was directly used in the next step without purification.

### Synthesis of a Compound CPD 30

With reference to the synthesis and purification methods of the compound CPD 1, only the corresponding raw materials were required to be changed, and 3.27 g of a target compound CPD 30 with a yield of 63.1% was obtained. 3.27 g of the crude product CPD 30 was sublimated and purified to obtain 2.21 g of a sublimated pure product CPD 30 with a yield of 67.5%. The mass spectrum was: 1054.4 (M+H). ¹H NMR (400 MHz, CDCl₃) δ 8.50 (d, J=15.0 Hz, 1H), 7.98 (dd, J=14.6, 3.4 Hz, 1H), 7.87-7.67 (m, 4H), 7.58-7.45 (m, 7H), 7.45-7.25 (m, 6H), 7.17 (t, J=14.8 Hz, 2H), 7.06 (ddd, J=15.0, 9.0, 3.1 Hz, 3H), 5.67 (d, J=12.4 Hz, 2H), 5.54 (td, J=12.4, 2.0 Hz, 2H), 5.01 (d, J=12.4 Hz, 2H), 3.21 (s, 2H), 2.88 (m, J=12.7, 1.9 Hz, 2H), 1.04 (d, J=12.8 Hz, 12H), 0.85 (s, 9H).

### Synthesis of a Compound CPD 36

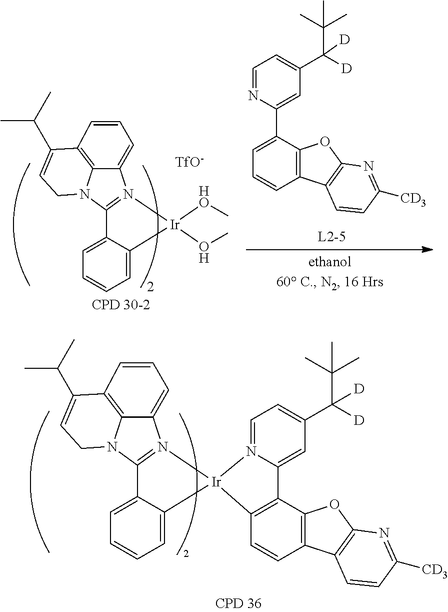

With reference to the synthesis and purification methods of the compound CPD 1, only the corresponding raw materials were required to be changed, and 3.34 g of a target compound CPD 36 with a yield of 62.7% was obtained. 3.34 g of the crude product CPD 36 was sublimated and purified to obtain 2.17 g of a sublimated pure product CPD 36 with a yield of 64.3%. The mass spectrum was: 1074.4 (M+H). ¹H NMR (400 MHz, CDCl₃) δ 8.61 (dd, J=15.0, 2.9 Hz, 1H), 8.54-8.38 (m, 2H), 7.88-7.66 (m, 4H), 7.50 (m, J=14.8 Hz, 4H), 7.42 (m, J=15.0, 3.3, 1.9 Hz, 4H), 7.22 (dt, J=44.0, 14.9 Hz, 3H), 7.06 (m, J=15.0, 9.0, 3.1 Hz, 3H), 5.61-5.45 (m, 4H), 5.07-4.93 (m, 2H), 2.75 (m J=12.8, 1.8 Hz, 2H), 1.32 (s, 9H), 1.04 (d, J=12.8 Hz, 12H).

### Synthesis of a Common Intermediate L1-4

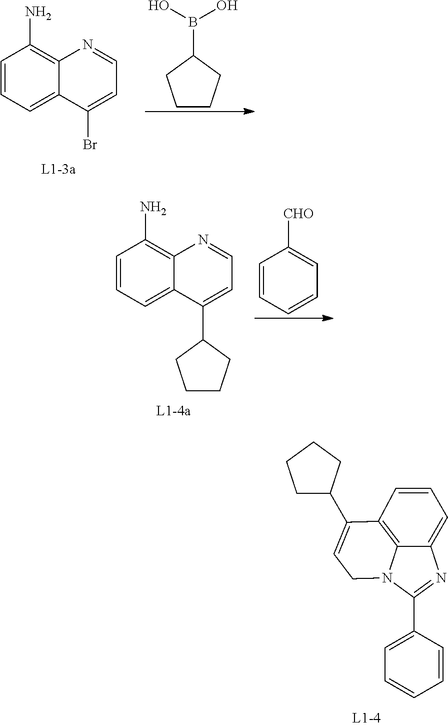

### Synthesis of a Compound L1-4a

With reference to the synthesis and purification methods of the compound L1-3b, only the corresponding raw materials were required to be changed. The mass spectrum was: 213.3 (M+H).

### Synthesis of a Compound L1-4

With reference to the synthesis and purification methods of the compound L1-1, only the corresponding raw materials were required to be changed, and 20.4 g of a target compound L1-4 with a yield of 57.9% was obtained. The mass spectrum was: 301.4 (M+H). ¹H NMR (400 MHz, CDCl₃) δ 8.28 (m, 2H), 7.46 (m, 4H), 7.17 (t, 1H), 7.07 (dd, 1H), 5.54 (t, 1H), 5.08-4.93 (d, 2H), 2.79 (m, 1H), 1.66 (m, J=52.5 Hz, 6H), 1.30 (m, 2H).

### Synthesis of a Compound CPD 42

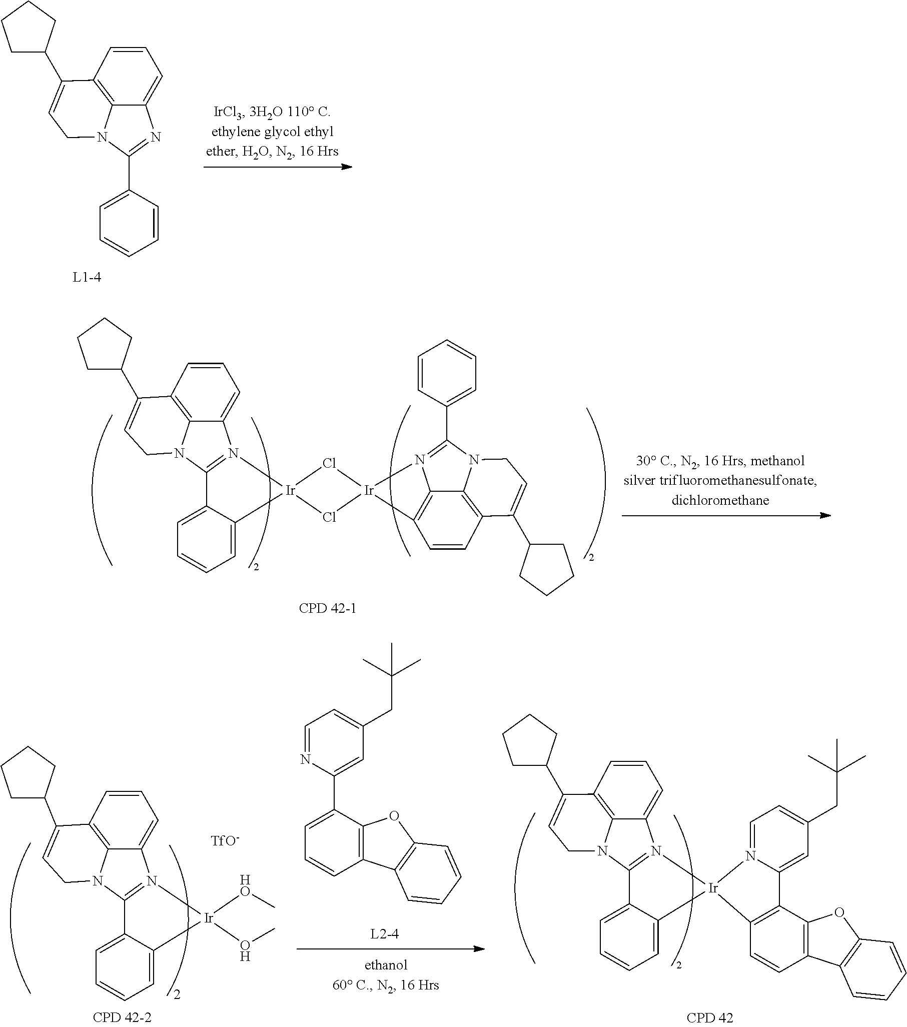

### Synthesis of a Compound CPD 42-1

With reference to the synthesis and purification methods of the compound CPD 1-1, only the corresponding raw materials were required to be changed, and an obtained compound was directly used in the next step without purification.

### Synthesis of a Compound CPD 42-2

With reference to the synthesis and purification methods of the compound CPD 1-2, only the corresponding raw materials were required to be changed, and an obtained compound was directly used in the next step without purification.

### Synthesis of a Compound CPD 42

With reference to the synthesis and purification methods of the compound CPD 1, only the corresponding raw materials were required to be changed, and 2.96 g of a target compound CPD 42 with a yield of 57.6% was obtained. 2.96 g of the crude product CPD 42 was sublimated and purified to obtain 1.86 g of a sublimated pure product CPD 42 with a yield of 62.8%. The mass spectrum was: 1106.4 (M+H). ¹H NMR (400 MHz, CDCl₃) δ 8.50 (d, 1H), 7.98 (dd, 1H), 7.87-7.65 (m, 4H), 7.52 (m, J=20.0 Hz, 6H), 7.40 (m, J=15.0 Hz, 5H), 7.31 (m, 1H), 7.17 (t, 2H), 7.06 (m, J=10.0 Hz, 3H), 5.76 (d, 2H), 5.54 (t, 2H), 5.12 (d, 2H), 3.21 (s, 2H), 2.74 (m, 2H), 1.76 (m, 4H), 1.66 (m, 4H), 1.55 (m, 4H), 1.30 (m, 4H), 0.85 (s, 9H).

### Synthesis of a Common Intermediate L1-5

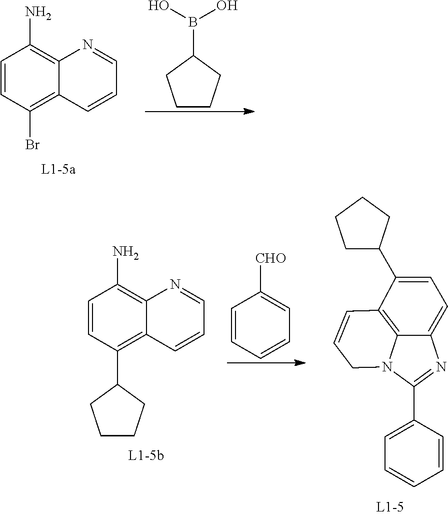

### Synthesis of a Compound L1-5b

With reference to the synthesis and purification methods of the compound L1-3b, only the corresponding raw materials were required to be changed. The mass spectrum was: 213.3 (M+H).

### Synthesis of a Compound L1-5

With reference to the synthesis and purification methods of the compound L1-1, only the corresponding raw materials were required to be changed, and 24.1 g of a target compound L1-5 with a yield of 64.2% was obtained. The mass spectrum was: 301.4 (M+H). ¹H NMR (400 MHz, CDCl₃) δ 8.34-8.19 (m, 2H), 7.65 (d, J=15.0 Hz, 1H), 7.56-7.41 (m, 3H), 7.05 (d, J=14.8 Hz, 1H), 6.58 (d, J=21.8, 2.0 Hz, 1H), 5.92 (dt, J=21.8, 12.4 Hz, 1H), 4.96 (dd, J=12.2, 8.3, 1.9 Hz, 2H), 3.05-2.81 (m, 1H), 2.11-1.89 (m, 2H), 1.89-1.53 (m, 6H).

### Synthesis of a Compound CPD 78

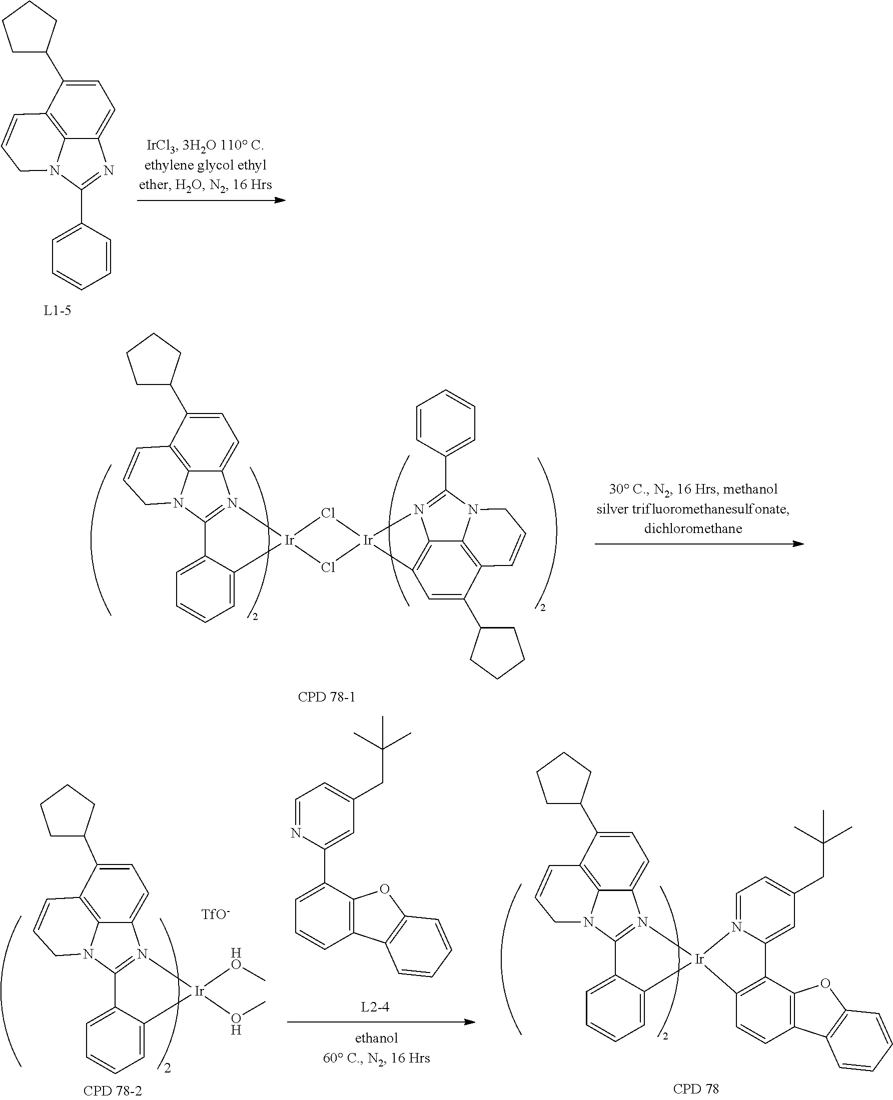

### Synthesis of a Compound CPD 78-1

With reference to the synthesis and purification methods of the compound CPD 1-1, only the corresponding raw materials were required to be changed, and an obtained compound was directly used in the next step without purification.

### Synthesis of a Compound CPD 78-2

With reference to the synthesis and purification methods of the compound CPD 1-2, only the corresponding raw materials were required to be changed, and an obtained compound was directly used in the next step without purification.

### Synthesis of a Compound CPD 78

With reference to the synthesis and purification methods of the compound CPD 1, only the corresponding raw materials were required to be changed, and 3.11 g of a target compound CPD 78 with a yield of 60.4% was obtained. 3.11 g of the crude product CPD 78 was sublimated and purified to obtain 1.88 g of a sublimated pure product CPD 78 with a yield of 60.4%. The mass spectrum was: 1106.4 (M+H). ¹H NMR (400 MHz, CDCl₃) δ 8.50 (d, 1H), 7.98 (dd, 1H), 7.81 (m, J=35.0 Hz, 3H), 7.67 (t, J=20.0 Hz, 3H), 7.52 (m, J=20.0 Hz, 6H), 7.40 (m, J=15.0 Hz, 3H), 7.31 (m, 1H), 7.05 (d, 3H), 6.39 (d, 2H), 5.92 (m, 2H), 4.74 (dd, J=46.8 Hz, 4H), 3.21 (s, 2H), 2.90 (m, 2H), 1.99 (m, 4H), 1.84-1.60 (m, 12H), 0.85 (s, 9H).

### Synthesis of a Common Intermediate L1-6

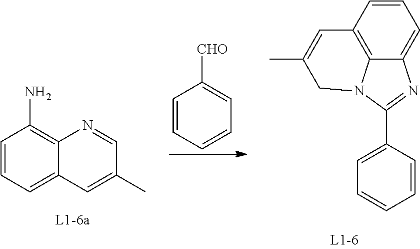 [SMILES: Cc1cnc2c(N)cccc2c1 ; O=Cc1ccccc1 ; CC1=Cc2cccc3nc(-c4ccccc4)n(c23)C1]

### Synthesis of a Compound L1-6

With reference to the synthesis and purification methods of the compound L1-1, only the corresponding raw materials were required to be changed, and 17.3 g of a target compound L1-6 with a yield of 53.2% was obtained. The mass spectrum was: 247.3 (M+H). ¹H NMR (400 MHz, CDCl₃) δ 8.28 (m, 2H), 7.46 (m, 3H), 7.42 (dd, 1H), 7.17 (t, 1H), 7.07 (d, 1H), 6.85 (d, 1H), 4.80 (s, 2H), 1.66 (s, 3H).

### Synthesis of a Compound CPD 93

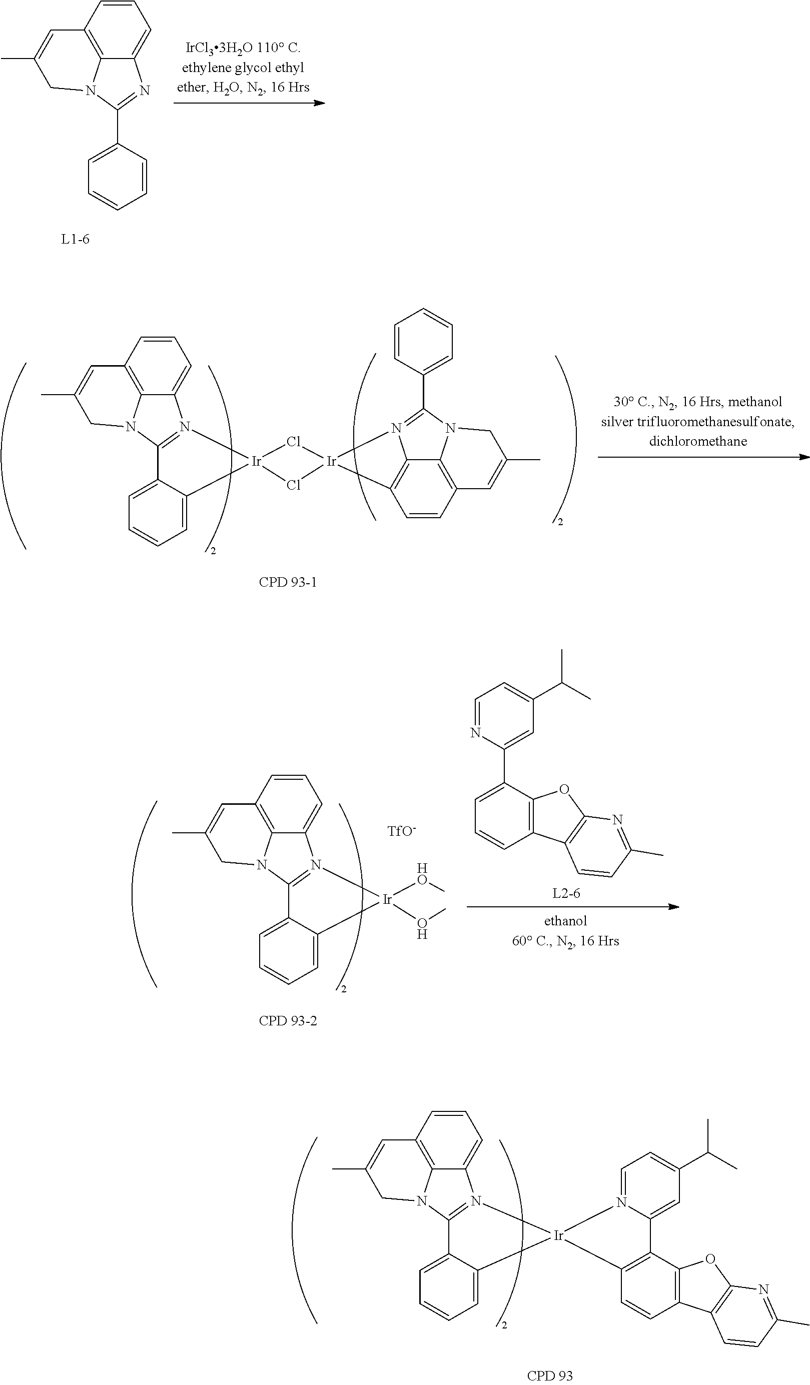

### Synthesis of a Compound CPD 93-1

With reference to the synthesis and purification methods of the compound CPD 1-1, only the corresponding raw materials were required to be changed, and an obtained compound was directly used in the next step without purification.

### Synthesis of a Compound CPD 93-2

With reference to the synthesis and purification methods of the compound CPD 1-2, only the corresponding raw materials were required to be changed, and an obtained compound was directly used in the next step without purification.

### Synthesis of a Compound CPD 93

With reference to the synthesis and purification methods of the compound CPD 1, only the corresponding raw materials were required to be changed, and 2.87 g of a target compound CPD 93 with a yield of 56.7% was obtained. 2.87 g of the crude product CPD 93 was sublimated and purified to obtain 1.76 g of a sublimated pure product CPD 93 with a yield of 61.3%. The mass spectrum was: 985.2 (M+H). ¹H NMR (400 MHz, CDCl₃) δ 8.46 (dd, J=38.7, 14.9 Hz, 2H), 7.87-7.66 (m, 4H), 7.56-7.38 (m, 9H), 7.17 (t, J=14.8 Hz, 2H), 7.12-6.97 (m, 4H), 6.90-6.81 (m, 2H), 5.28 (dd, J=7.9, 2.0 Hz, 2H), 4.77 (dd, J=8.1, 2.0 Hz, 2H), 2.96-2.78 (m, 1H), 2.68 (s, 3H), 1.66 (d, J=2.0 Hz, 6H), 1.20 (d, J=12.8 Hz, 6H).

### Synthesis of a Common Intermediate L1-7

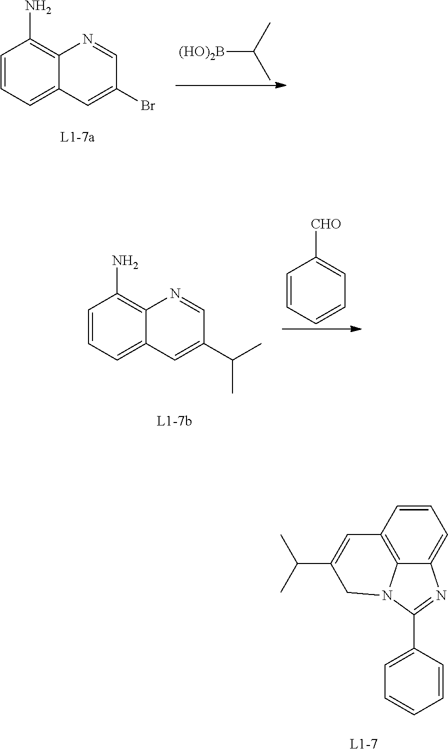

### Synthesis of a Compound L1-7b

With reference to the synthesis and purification methods of the compound L1-3b, only the corresponding raw materials were required to be changed. The mass spectrum was: 187.3 (M+H).

### Synthesis of a Compound L1-7

With reference to the synthesis and purification methods of the compound L1-1, only the corresponding raw materials were required to be changed, and 24.1 g of a target compound L1-7 with a yield of 64.2% was obtained. The mass spectrum was: 275.4 (M+H). ¹H NMR (400 MHz, CDCl₃) δ 8.28 (m, 2H), 7.50 (dd, 3H), 7.42 (dd, 1H), 7.17 (t, 1H), 7.07 (dd, 1H), 6.85 (s, 1H), 4.98 (s, 2H), 2.09 (m, 1H), 1.04 (d, 6H).

### Synthesis of a Compound CPD 98

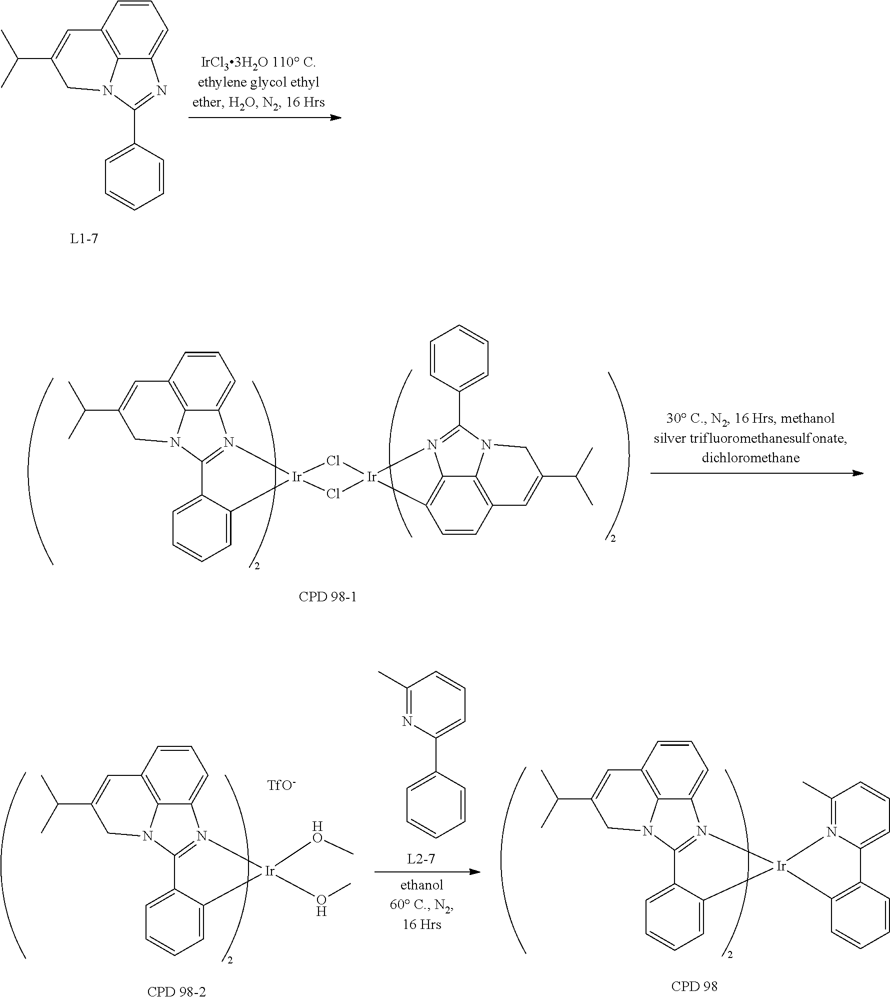

### Synthesis of a Compound CPD 98-1

With reference to the synthesis and purification methods of the compound CPD 1-1, only the corresponding raw materials were required to be changed, and an obtained compound was directly used in the next step without purification.

### Synthesis of a Compound CPD 98-2

With reference to the synthesis and purification methods of the compound CPD 1-2, only the corresponding raw materials were required to be changed, and an obtained compound was directly used in the next step without purification.

### Synthesis of a Compound CPD 98

With reference to the synthesis and purification methods of the compound CPD 1, only the corresponding raw materials were required to be changed, and 3.21 g of a target compound CPD 98 with a yield of 61.7% was obtained. 3.21 g of the crude product CPD 98 was sublimated and purified to obtain 1.84 g of a sublimated pure product CPD 98 with a yield of 57.3%. The mass spectrum was: 908.3 (M+H). ¹H NMR (400 MHz, CDCl₃) δ 8.16 (d, 1H), 7.77 (d, 2H), 7.46 (m, J=40.0 Hz, 11H), 7.29 (t, 1H), 7.17 (t, 2H), 7.07 (dd, 2H), 6.98 (dd, 1H), 6.85 (dd, 2H), 6.61 (s, 1H), 5.44 (s, 2H), 4.95 (s, 2H), 2.76 (s, 3H), 2.26 (m, 2H), 1.04 (s, 12H).

### Synthesis of a Common Intermediate L1-8

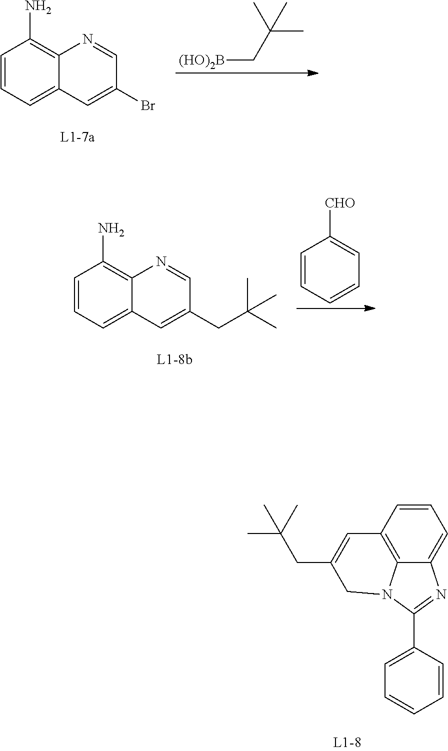

### Synthesis of a Compound L1-8b

With reference to the synthesis and purification methods of the compound L1-3b, only the corresponding raw materials were required to be changed. The mass spectrum was: 215.3 (M+H).

### Synthesis of a Compound L1-8

With reference to the synthesis and purification methods of the compound L1-1, only the corresponding raw materials were required to be changed, and 22.7 g of a target compound L1-8 with a yield of 57.9% was obtained. The mass spectrum was: 303.4 (M+H). ¹H NMR (400 MHz, CDCl₃) δ 8.28 (m, 2H), 7.50 (dd, 3H), 7.42 (dd, 1H), 7.17 (t, 1H), 7.07 (dd, 1H), 6.85 (s, 1H), 4.85 (s, 2H), 2.27 (s, 2H), 1.01 (s, 9H).

### Synthesis of a Compound CPD 119

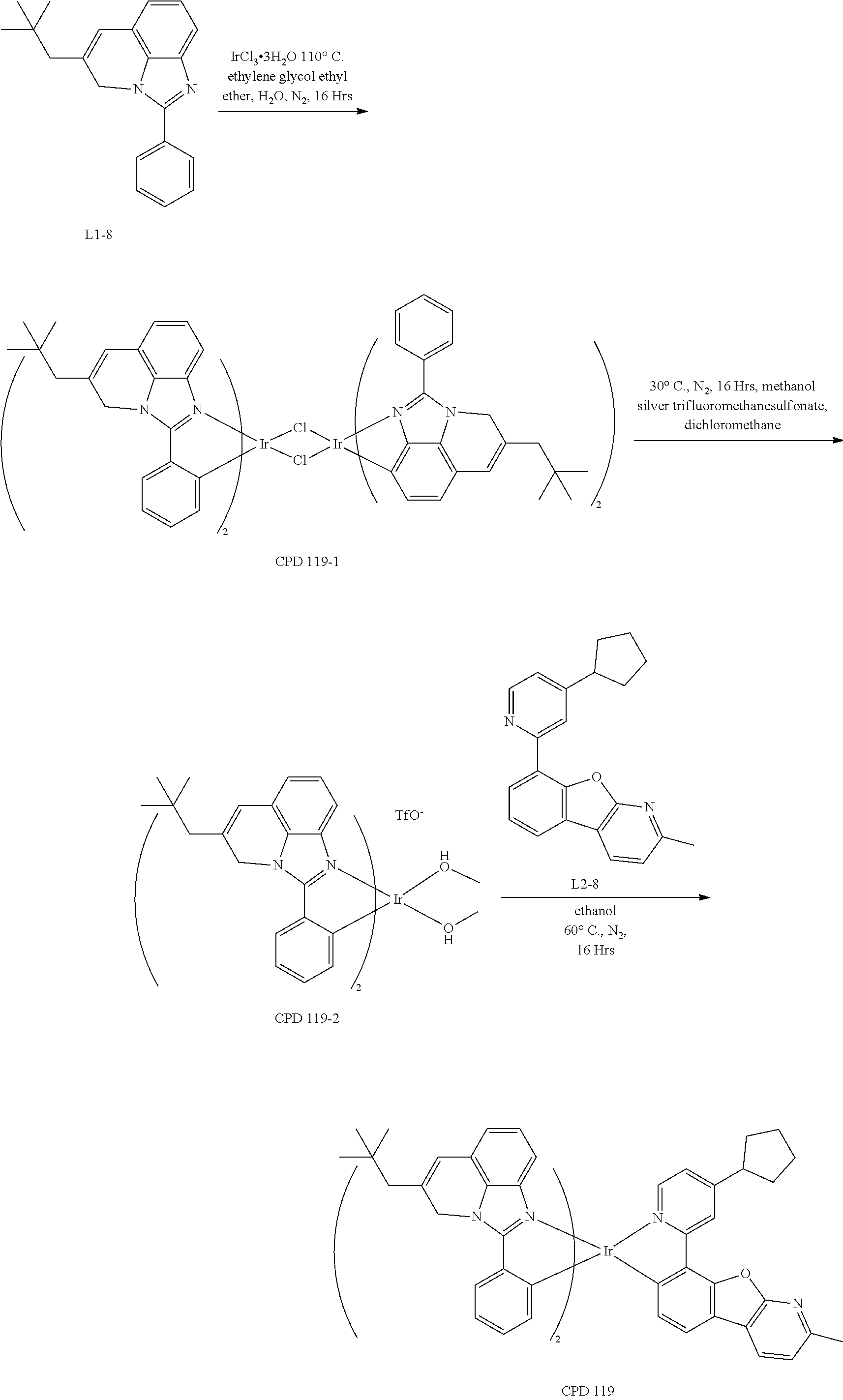

### Synthesis of a Compound CPD 119-1

With reference to the synthesis and purification methods of the compound CPD 1-1, only the corresponding raw materials were required to be changed, and an obtained compound was directly used in the next step without purification.

### Synthesis of a Compound CPD 119-2

With reference to the synthesis and purification methods of the compound CPD 1-2, only the corresponding raw materials were required to be changed, and an obtained compound was directly used in the next step without purification.

### Synthesis of a Compound CPD 119

With reference to the synthesis and purification methods of the compound CPD 1, only the corresponding raw materials were required to be changed, and 2.87 g of a target compound CPD 119 with a yield of 56.9% was obtained. 2.87 g of the crude product CPD 119 was sublimated and purified to obtain 1.68 g of a sublimated pure product CPD 119 with a yield of 58.5%. The mass spectrum was: 1109.4 (M+H). ¹H NMR (400 MHz, CDCl₃) δ 8.50 (d, 1H), 8.29 (d, 1H), 7.87-7.67 (m, 4H), 7.46 (m, J=40.0 Hz, 9H), 7.17 (t, 2H), 7.10-6.99 (m, 4H), 6.85 (s, 2H), 5.19 (s, 2H), 4.81 (s, 2H), 2.68 (s, 3H), 2.55 (m, 1H), 2.14 (s, 4H), 2.01 (m, 2H), 1.87-1.57 (m, 6H), 1.01 (s, 18H).

### Synthesis of a Common Intermediate L1-9

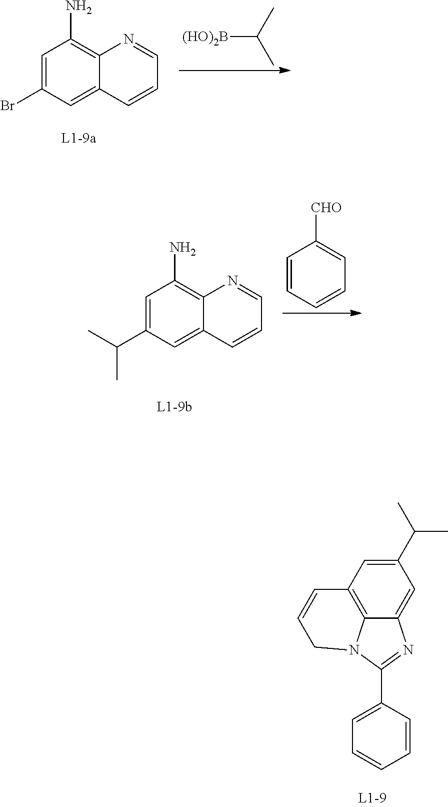

### Synthesis of a Compound L1-9b

With reference to the synthesis and purification methods of the compound L1-3b, only the corresponding raw materials were required to be changed. The mass spectrum was: 187.3 (M+H).

### Synthesis of a Compound L1-9

With reference to the synthesis and purification methods of the compound L1-1, only the corresponding raw materials were required to be changed, and 21.0 g of a target compound L1-7 with a yield of 57.7% was obtained. The mass spectrum was: 275.4 (M+H). ¹H NMR (400 MHz, CDCl₃) δ 8.28 (m, 2H), 7.50 (m, 3H), 7.39 (d, J=50.0 Hz, 2H), 6.56 (d, 1H), 5.76 (m, 1H), 4.98 (d, J=16.5 Hz, 2H), 2.87 (m, 1H), 1.20 (s, 6H).

### Synthesis of a Compound CPD 155

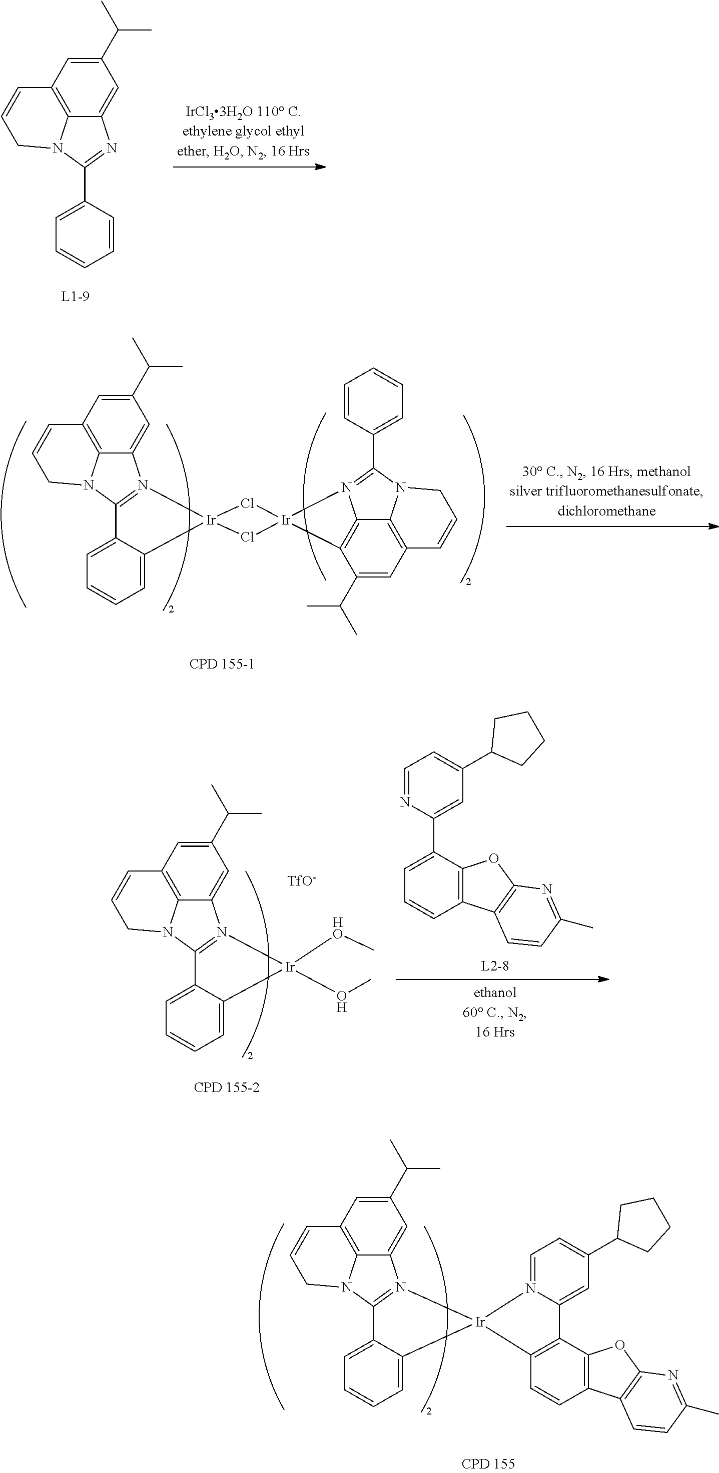

### Synthesis of a Compound CPD 155-1

With reference to the synthesis and purification methods of the compound CPD 1-1, only the corresponding raw materials were required to be changed, and an obtained compound was directly used in the next step without purification.

### Synthesis of a Compound CPD 155-2

With reference to the synthesis and purification methods of the compound CPD 1-2, only the corresponding raw materials were required to be changed, and an obtained compound was directly used in the next step without purification.

### Synthesis of a Compound CPD 155

With reference to the synthesis and purification methods of the compound CPD 1, only the corresponding raw materials were required to be changed, and 2.63 g of a target compound CPD 155 with a yield of 54.7% was obtained. 2.63 g of the crude product CPD 155 was sublimated and purified to obtain 1.59 g of a sublimated pure product CPD 155 with a yield of 60.4%. The mass spectrum was: 1067.4 (M+H). ¹H NMR (400 MHz, CDCl₃) δ 8.50 (d, J=7.5 Hz, 1H), 8.31 (d, J=7.5 Hz, 1H), 7.88-7.65 (m, 4H), 7.55-7.30 (m, 11H), 7.08-6.95 (m, 2H), 6.49 (d, J=10.8 Hz, 2H), 5.76 (dt, J=11.0, 6.2 Hz, 2H), 5.45 (dd, J=6.1, 0.8 Hz, 2H), 5.08 (dd, J=6.2, 0.6 Hz, 2H), 2.94-2.76 (m, 3H), 2.68 (s, 3H), 2.08-1.94 (m, 2H), 1.84-1.60 (m, 6H), 1.20 (d, J=6.3 Hz, 12H).

### Synthesis of a Common Intermediate L1-10

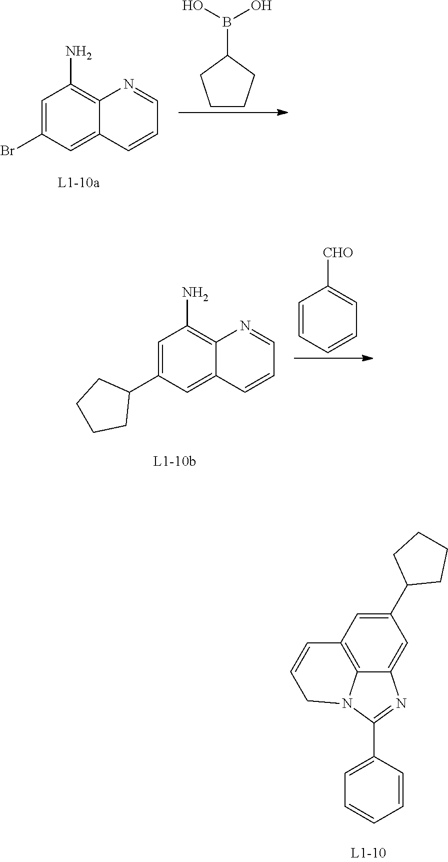

### Synthesis of a Compound L1-10b

With reference to the synthesis and purification methods of the compound L1-3b, only the corresponding raw materials were required to be changed. The mass spectrum was: 213.3 (M+H).

### Synthesis of a Compound L1-9

With reference to the synthesis and purification methods of the compound L1-1, only the corresponding raw materials were required to be changed, and 18.40 g of a target compound L1-7 with a yield of 55.4% was obtained. The mass spectrum was: 301.4 (M+H). ¹H NMR (400 MHz, CDCl₃) δ 8.28 (m, 2H), 7.50 (m, 3H), 7.39 (dd, J=50.0 Hz, 2H), 6.56 (d, 1H), 5.76 (m, 1H), 4.98 (d, J=2.4 Hz, 2H), 2.80 (m, 1H), 2.00 (m, 2H), 1.71 (m, J=25.0 Hz, 6H).

### Synthesis of a Compound CPD 163

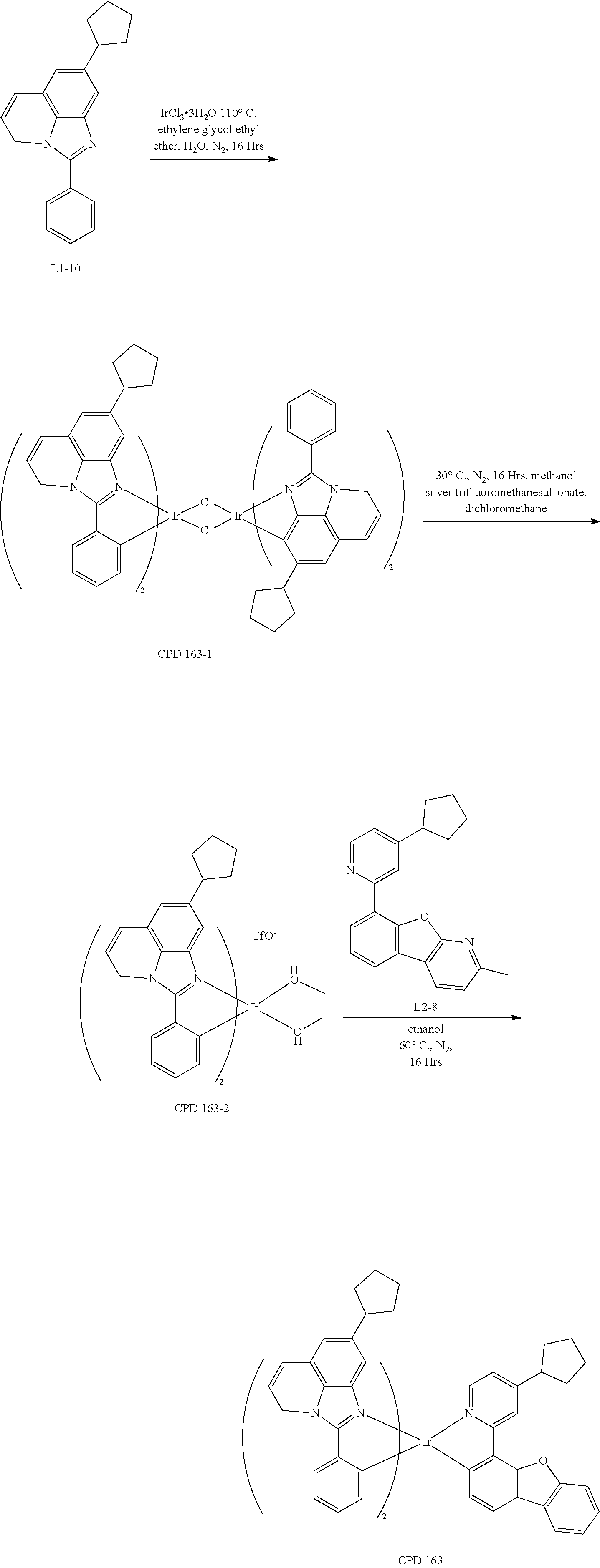

### Synthesis of a Compound CPD 163-1

With reference to the synthesis and purification methods of the compound CPD 1-1, only the corresponding raw materials were required to be changed, and an obtained compound was directly used in the next step without purification.

### Synthesis of a Compound CPD 163-2

With reference to the synthesis and purification methods of the compound CPD 1-2, only the corresponding raw materials were required to be changed, and an obtained compound was directly used in the next step without purification.

### Synthesis of a Compound CPD 163

With reference to the synthesis and purification methods of the compound CPD 1, only the corresponding raw materials were required to be changed, and 3.1 g of a target compound CPD 163 with a yield of 61.4% was obtained. 3.1 g of the crude product CPD 163 was sublimated and purified to obtain 1.97 g of a sublimated pure product CPD 163 with a yield of 63.5%. The mass spectrum was: 1104.4 (M+H). ¹H NMR (400 MHz, CDCl₃) δ 8.50 (d, J=7.5 Hz, 1H), 7.98 (dd, J=7.4, 1.5 Hz, 1H), 7.87-7.67 (m, 4H), 7.59-7.47 (m, 6H), 7.47-7.36 (m, 5H), 7.36-7.26 (m, 3H), 7.05 (dd, J=7.5, 1.4 Hz, 1H), 6.67-6.54 (m, 2H), 5.80-5.69 (m, 4H), 5.37-5.27 (m, 2H), 2.65-2.52 (m, 1H), 2.49-2.38 (m, 2H), 2.09-1.91 (m, 6H), 1.84-1.56 (m, 18H).

### Synthesis of a Compound CPD 168

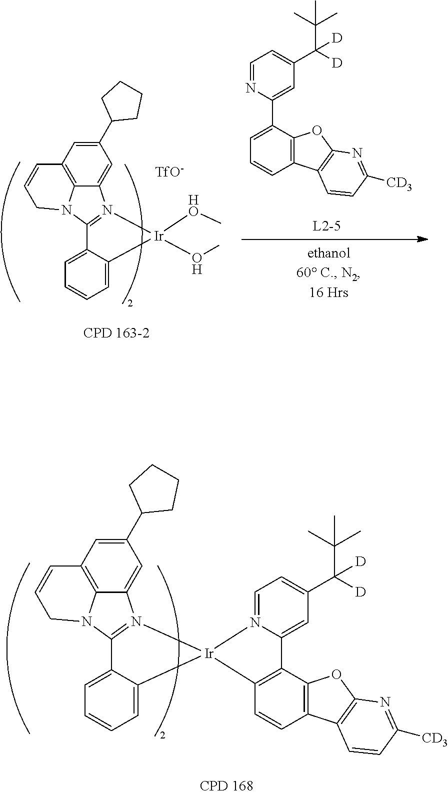

With reference to the synthesis and purification methods of the compound CPD 1, only the corresponding raw materials were required to be changed, and 2.45 g of a target compound CPD 168 with a yield of 53.7% was obtained. 2.45 g of the crude product CPD 168 was sublimated and purified to obtain 1.65 g of a sublimated pure product CPD 168 with a yield of 67.3%. The mass spectrum was: 1126.5 (M+H). ¹H NMR (400 MHz, CDCl₃) δ 8.61 (d, 1H), 8.46 (dd, J=40.0 Hz, 2H), 7.88-7.66 (m, 4H), 7.45 (m, J=20.0 Hz, 8H), 7.30 (m, J=40.0 Hz, 3H), 7.05 (dd, 1H), 6.44 (d, 2H), 5.76 (m, 2H), 5.64 (d, 2H), 5.02 (d, 2H), 2.38 (m, 2H), 1.98 (m, 4H), 1.83-1.59 (m, 12H), 1.32 (s, 9H).

### Synthesis of a Compound CPD 169

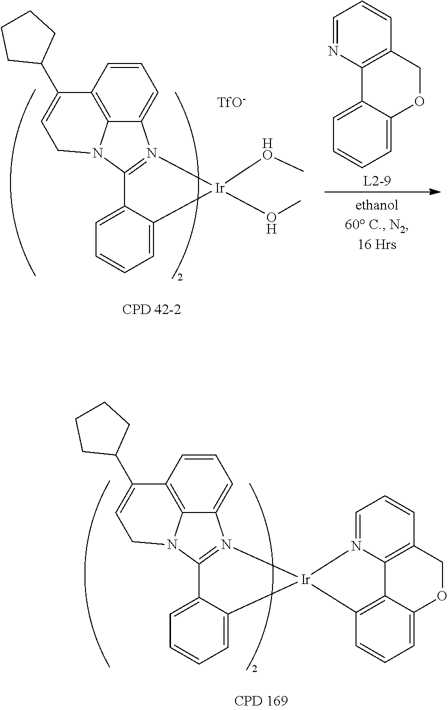

With reference to the synthesis and purification methods of the compound CPD 1, only the corresponding raw materials were required to be changed, and 2.76 g of a target compound CPD 169 with a yield of 57.8% was obtained. 2.76 g of the crude product CPD 169 was sublimated and purified to obtain 1.66 g of a sublimated pure product CPD 169 with a yield of 60.1%. The mass spectrum was: 974.3 (M+H). ¹H NMR (400 MHz, CDCl₃) δ 8.33 (dd, J=7.4, 1.5 Hz, 1H), 7.77 (dd, J=7.4, 1.5 Hz, 2H), 7.54-7.36 (m, 11H), 7.21-7.02 (m, 5H), 6.80 (t, J=7.4 Hz, 1H), 5.52 (m, J=44.9, 25.3, 3.4 Hz, 4H), 5.20 (s, 2H), 4.91 (d, J=6.2 Hz, 2H), 2.88 (dq, J=16.6, 8.3 Hz, 2H), 1.84-1.71 (m, 4H), 1.71-1.60 (m, 4H), 1.61-1.49 (m, 4H), 1.37-1.23 (m, 4H).

### Synthesis of a Compound CPD 179

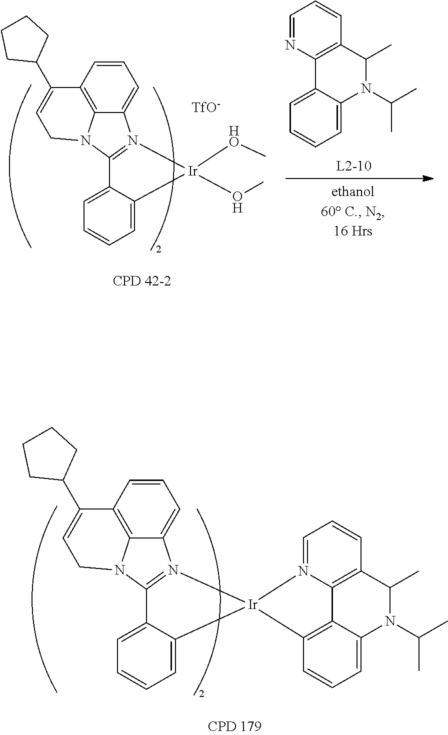

With reference to the synthesis and purification methods of the compound CPD 1, only the corresponding raw materials were required to be changed, and 2.65 g of a target compound CPD 179 with a yield of 62.4% was obtained. 2.65 g of the crude product CPD 179 was sublimated and purified to obtain 1.55 g of a sublimated pure product CPD 179 with a yield of 58.4%. The mass spectrum was: 1029.4 (M+H). ¹H NMR (400 MHz, CDCl₃) δ 8.37 (dd, 1H), 7.77 (dd, 2H), 7.54-7.37 (m, 11H), 7.20 (dt, J=35.0 Hz, 3H), 7.07 (dd, 2H), 6.92 (d, 1H), 6.80 (t, 1H), 5.51 (dt, J=32.8 Hz, 4H), 4.96 (d, 2H), 4.31 (m, 1H), 4.02 (m, 1H), 2.76 (m, 2H), 1.76 (m, 4H), 1.66 (m, 4H), 1.55 (m, 4H), 1.40 (d, 3H), 1.30 (m, 4H), 1.19 (d, 6H).

### Synthesis of a Compound CPD 195

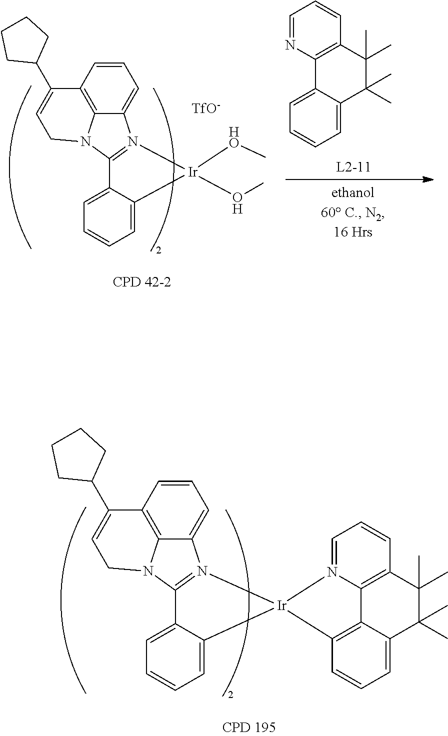

With reference to the synthesis and purification methods of the compound CPD 1, only the corresponding raw materials were required to be changed, and 2.71 g of a target compound CPD 195 with a yield of 58.9% was obtained. 2.65 g of the crude product CPD 195 was sublimated and purified to obtain 1.79 g of a sublimated pure product CPD 195 with a yield of 66.0%. The mass spectrum was: 1028.4 (M+H). ¹H NMR (400 MHz, CDCl₃) δ 8.35 (dd, J=14.9, 3.0 Hz, 1H), 7.77 (dd, J=14.7, 3.3 Hz, 2H), 7.60-7.38 (m, 10H), 7.37-7.25 (m, 2H), 7.23-7.03 (m, 4H), 6.67 (t, J=14.9 Hz, 1H), 5.54 (td, J=12.4, 2.0 Hz, 2H), 5.23 (dd, J=14.3, 12.5 Hz, 2H), 4.72 (dd, J=14.3, 12.3 Hz, 2H), 2.62 (m J=16.9, 2.0 Hz, 2H), 1.84-1.72 (m, 3H), 1.73-1.60 (m, 5H), 1.54 (m, J=24.4, 16.6, 9.7, 2.6 Hz, 4H), 1.42-1.21 (m, 16H).

### Synthesis of a Compound CPD 202

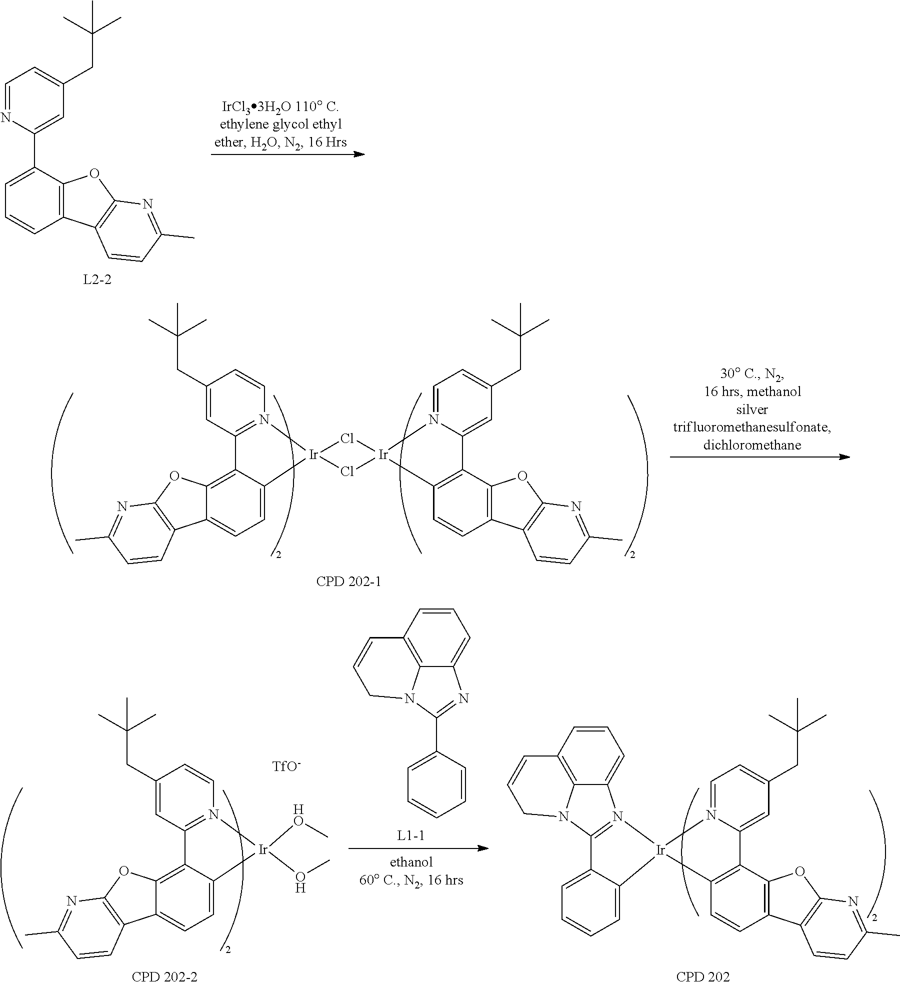

### Synthesis of a Compound CPD 202-1

With reference to the synthesis and purification methods of the compound CPD 1-1, only the corresponding raw materials were required to be changed, and an obtained compound was directly used in the next step without purification.

### Synthesis of a Compound CPD 202-2

With reference to the synthesis and purification methods of the compound CPD 1-2, only the corresponding raw materials were required to be changed, and an obtained compound was directly used in the next step without purification.

### Synthesis of a Compound CPD 202

With reference to the synthesis and purification methods of the compound CPD 1, only the corresponding raw materials were required to be changed, and 3.41 g of a target compound CPD 202 with a yield of 63.7% was obtained. 3.1 g of the crude product CPD 202 was sublimated and purified to obtain 2.2 g of a sublimated pure product CPD 202 with a yield of 64.5%. The mass spectrum was: 1083.4 (M+H). ¹H NMR (400 MHz, CDCl₃) δ 8.50 (d, 1H), 8.39 (d, 1H), 7.88-7.67 (m, 4H), 7.46 (m, J=40.0 Hz, 9H), 7.17 (t, 2H), 7.11-6.98 (m, 4H), 6.58 (d, 2H), 5.76 (m, 2H), 4.91 (dd, J=68.8 Hz, 4H), 3.21 (s, 2H), 2.68 (s, 3H), 0.85 (s, 9H).

### Synthesis of a Compound CPD 204

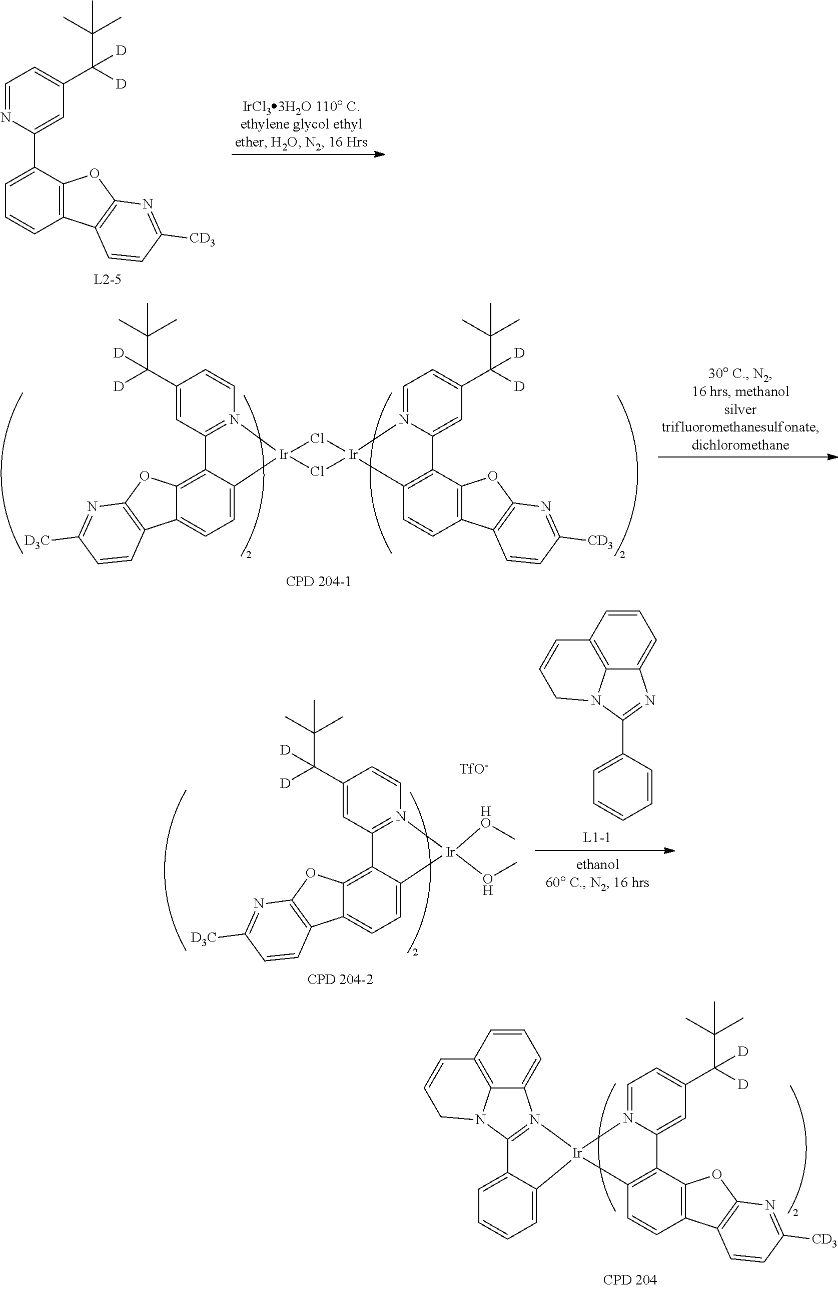

### Synthesis of a Compound CPD 204-1

With reference to the synthesis and purification methods of the compound CPD 1-1, only the corresponding raw materials were required to be changed, and an obtained compound was directly used in the next step without purification.

### Synthesis of a Compound CPD 204-2

With reference to the synthesis and purification methods of the compound CPD 1-2, only the corresponding raw materials were required to be changed, and an obtained compound was directly used in the next step without purification.

### Synthesis of a Compound CPD 204

With reference to the synthesis and purification methods of the compound CPD 1, only the corresponding raw materials were required to be changed, and 3.02 g of a target compound CPD 204 with a yield of 65.8% was obtained. 3.02 g of the crude product CPD 204 was sublimated and purified to obtain 2.18 g of a sublimated pure product CPD 204 with a yield of 70.7%. The mass spectrum was: 1093.4 (M+H). ¹H NMR (400 MHz, CDCl₃) δ 8.61 (dd, J=15.0, 2.9 Hz, 1H), 8.54-8.38 (m, 2H), 7.88-7.64 (m, 4H), 7.58-7.37 (m, 8H), 7.22 (dt, J=44.0, 14.9 Hz, 3H), 7.06 (m, J=15.0, 9.0, 3.1 Hz, 3H), 6.53 (dt, J=21.8, 1.9 Hz, 2H), 5.76 (dt, J=21.6, 12.4 Hz, 2H), 5.59 (m, J=15.7, 12.5, 1.8 Hz, 2H), 4.98 (m, J=15.7, 12.4, 2.0 Hz, 2H), 1.32 (s, 9H).

Other compounds can be synthesized and sublimated by using corresponding materials according to same or similar methods.

### Application Example: Manufacture of an Organic Electroluminescent Device

A glass substrate with a size of 50 mm*50 mm*1.0 mm including an ITO (100 nm) transparent electrode was ultrasonically cleaned in ethanol for 10 min, dried at 150° C., and then treated with N₂ plasma for 30 min. The washed glass substrate was installed on a substrate support of a vacuum evaporation device. At first, a compound HATCN for covering the transparent electrode was evaporated on the surface of the side having a transparent electrode line to form a thin film with a thickness of 5 nm. Next, a layer of HTM1 was evaporated to form a thin film with a thickness of 60 nm. Then, a layer of HTM2 was evaporated on the HTM1 thin film to form a thin film with a thickness of 10 nm. After that, a main material 1, a main material 2 and a doping compound (including reference compounds X and CPD X) were co-evaporated on the HTM2 film layer to obtain a film with a thickness of 30 nm, where a ratio of the main material 1 to the main material 2 to the doping material was 45%:45%:10%. Then, an electron transport layer (ETL) and an electron injection layer (EIL) were evaporated on a light-emitting layer in sequence to form a film with a thickness of 35 nm, where the ratio of the ETL to the EIL was 50%:50%. Finally, a layer of metal Al (100 nm) was evaporated to serve as an electrode.

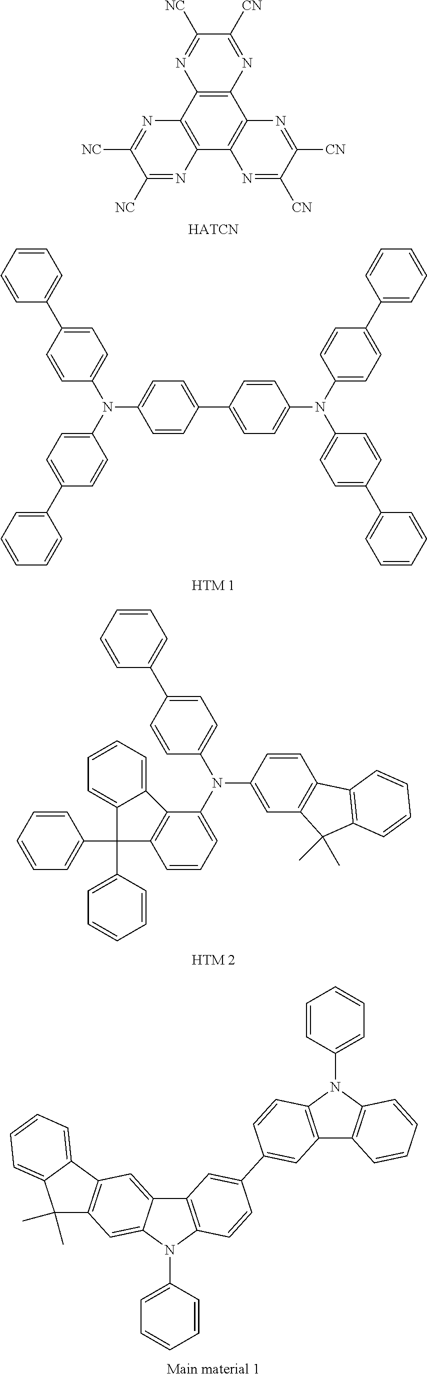

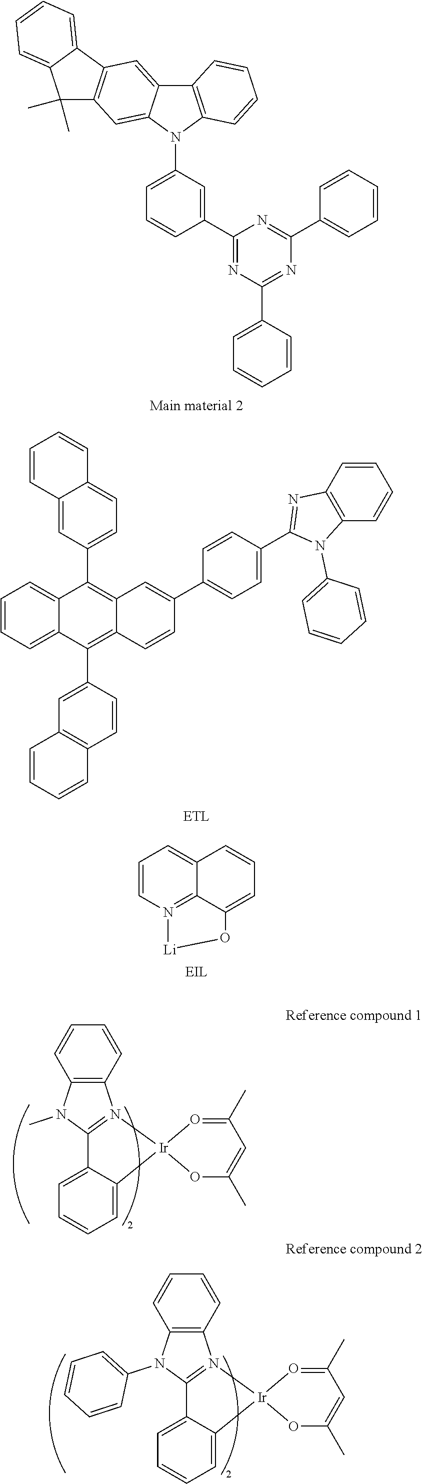

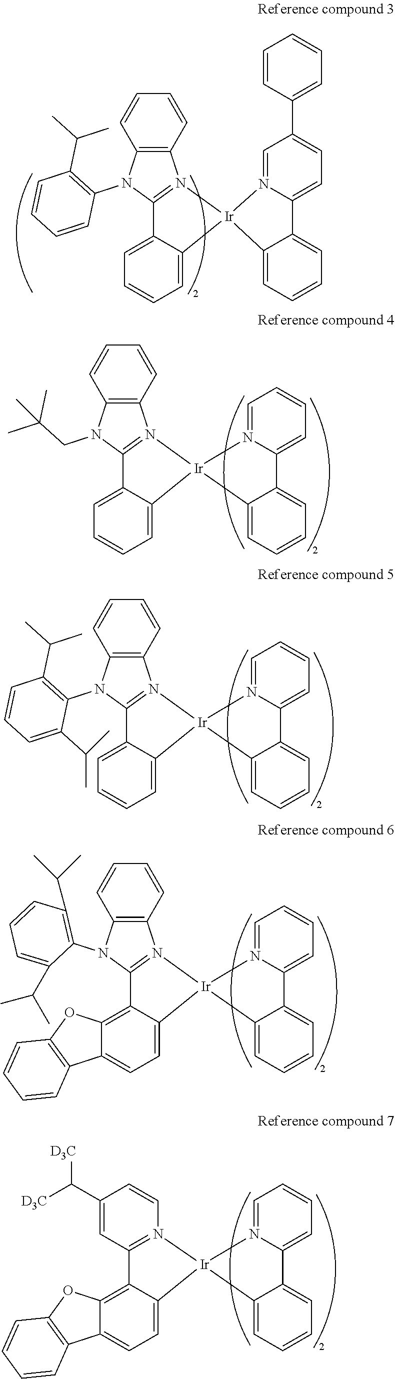

Evaluation: Properties of a device obtained above were tested. In various examples and comparative examples, a constant-current power supply (Keithley 2400) was used, a current at a fixed density was used for flowing through light-emitting elements, and a spectroradiometer (CS 2000) was used for testing the light-emitting spectrum. Meanwhile, the voltage value was measured, and the time (LT95) when the brightness was reduced to 95% of an initial brightness was tested. Results are shown as follows.

| | | Peak | | Start- | Current | |
|---|---|---|---|---|---|---|
| | Doping | wave- | FW | ing | effi- | LT95@ |
| | mate- | length | HM | voltage | ciency | 10000 |
| | rial | nm | nm | V | Cd/A | nits |
| Example 1 | CPD 1 | 520 | 52 | 4.52 | 79 | 230 |
| Example 2 | CPD 10 | 526 | 53 | 4.46 | 81 | 260 |
| Example 3 | CPD 13 | 526 | 55 | 4.43 | 80 | 285 |
| Example 4 | CPD 15 | 521 | 53 | 4.50 | 80 | 234 |
| Example 5 | CPD 18 | 525 | 53 | 4.48 | 82 | 265 |
| Example 6 | CPD 22 | 526 | 54 | 4.45 | 81 | 278 |
| Example 7 | CPD 24 | 526 | 54 | 4.44 | 81 | 310 |
| Example 8 | CPD 30 | 525 | 53 | 4.46 | 83 | 279 |
| Example 9 | CPD 36 | 526 | 52 | 4.42 | 82 | 330 |
| Example 10 | CPD 42 | 526 | 51 | 4.45 | 84 | 278 |
| Example 11 | CPD 78 | 523 | 52 | 4.41 | 83 | 296 |
| Example 12 | CPD 93 | 522 | 54 | 4.50 | 81 | 269 |
| Example 13 | CPD 98 | 523 | 55 | 4.51 | 79 | 236 |
| Example 14 | CPD 119 | 526 | 56 | 4.48 | 82 | 295 |
| Example 15 | CPD 155 | 525 | 54 | 4.47 | 81 | 286 |
| Example 16 | CPD 163 | 526 | 55 | 4.45 | 81 | 278 |
| Example 17 | CPD 168 | 527 | 53 | 4.42 | 83 | 369 |
| Example 18 | CPD 169 | 525 | 49 | 4.52 | 80 | 320 |
| Example 19 | CPD 179 | 526 | 52 | 4.53 | 81 | 283 |
| Example 20 | CPD 195 | 523 | 51 | 4.51 | 80 | 299 |
| Example 21 | CPD 202 | 519 | 36 | 4.53 | 83 | 317 |
| Example 22 | CPD 204 | 519 | 35 | 4.52 | 83 | 400 |
| Comparative | Reference | 509 | 73 | 5.01 | 53 | 60 |
| Example 1 | compound 1 | | | | | |
| Comparative | Reference | 530 | 76 | 5.11 | 77 | 152 |
| Example 2 | compound 2 | | | | | |
| Comparative | Reference | 549 | 69 | 4.86 | 76 | 183 |
| Example 3 | compound 3 | | | | | |
| Comparative | Reference | 523 | 75 | 5.06 | 52 | 98 |
| Example 4 | compound 4 | | | | | |
| Comparative | Reference | 519 | 72 | 4.82 | 54 | 121 |
| Example 5 | compound 5 | | | | | |
| Comparative | Reference | 528 | 66 | 4.76 | 72 | 130 |
| Example 6 | compound 6 | | | | | |
| Comparative | Reference | 524 | 68 | 4.92 | 71 | 200 |
| Example 7 | compound 7 | | | | | |

Through comparison of the data in the above table, it can be seen that compared with reference compounds, the compound of the present disclosure used as a dopant in an organic electroluminescent device has more excellent properties, such as driving voltage, luminous efficiency, and device service life.

According to the above results, it is indicated that the compound of the present disclosure has the advantages of high optical and electrochemical stability, small half-peak width of emission spectrum, high color saturation, high luminous efficiency and long device service life, and can be used in organic electroluminescent devices. In particular, the compound has the potential for application in the OLED industry as a green light-emitting dopant.

1. An organometallic compound, having a structure formula as shown in the following formula (1):
wherein 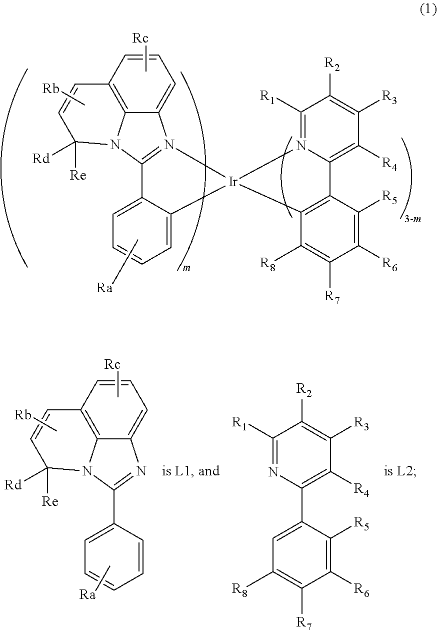
m is 1, 2, or 3, and when m is 1, the two L2 are the same or different;
the number of Ra, Rb and Rc is from 1 to a maximum substitution number;
Ra, Rb, Rc, Rd and Re are independently selected from hydrogen, deuterium, halogen, substituted or unsubstituted C₁-C₁₀ alkyl, substituted or unsubstituted C₃-C₂₀cycloalkyl, substituted or unsubstituted C₆-C₁₈ aryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
R₁-R₈ are independently selected from hydrogen, deuterium, halogen, hydroxyl, sulfhydryl, substituted or unsubstituted C₁-C₁₀ alkyl, substituted or unsubstituted C₁-C₁₀heteroalkyl, substituted or unsubstituted C₃-C₂₀cycloalkyl, substituted or unsubstituted C₂-C₁₀ alkenyl, substituted or unsubstituted C₂-C₁₀alkynyl, substituted or unsubstituted C₆-C₁₈ aryl, substituted or unsubstituted C₂-C₁₇heteroaryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl, or two adjacent groups of R₁-R₈ may be connected with each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, C₃-C₆cycloalkyl, amino substituted with C₁-C₆ alkyl, nitrile, isonitrile, or phosphino, and the substitution ranges from a single substitution number to a maximum substitution number.

2. The organometallic compound according to claim 1, wherein when the m is 1 or 2, the two L1 or the two L2 are the same.

3. The organometallic compound according to claim 2, wherein the Ra, the Rd and the Re are hydrogen.

4. The organometallic compound according to claim 3, wherein at least one of the R₁-R₄ is not hydrogen.

5. The organometallic compound according to claim 3, wherein at least one of the R₅-R₈ is not hydrogen.

6. The organometallic compound according to claim 3, wherein at least one of the R₁-R₄ is not hydrogen, and at least one of the R₅-R₈ is not hydrogen.

7. The organometallic compound according to claim 6, wherein one of the R₁-R₄ is deuterium, C₁-C₅ alkyl substituted or unsubstituted with deuterium, or C₃-C₅cycloalkyl substituted or unsubstituted with deuterium, one of the R₅-R₈ is deuterium, C₁-C₅ alkyl substituted or unsubstituted with deuterium, or C₃-C₅cycloalkyl substituted or unsubstituted with deuterium, and the other groups are hydrogen.

8. The organometallic compound according to claim 6, wherein the R₅ and the R₆, the R₆ and the R₇, or the R₇ and the R₈ are connected with each other to form a parallel ring structure as shown in a formula (2): 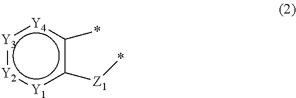
wherein * indicates a connecting position;
Y₁-Y₄ are independently CR₀ or N;
Z₁ is selected from O or S;
R₀ is independently hydrogen, deuterium, F, cyano, substituted or unsubstituted C₁-C₁₀ alkyl, substituted or unsubstituted C₃-C₂₀cycloalkyl, substituted or unsubstituted C₂-C₃₀ alkenyl, substituted or unsubstituted C₂-C₃₀alkynyl, substituted or unsubstituted C₆-C₃₀ aryl, substituted or unsubstituted C₁-C₃₀heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄alkoxyl, C₃-C₆cycloalkyl, amino substituted with C₁-C₄ alkyl, nitrile, isonitrile, or phosphino.

9. The organometallic compound according to claim 6, wherein the R₄ and the R₅ are connected with each other to form an aliphatic ring structure as shown in a formula (3): 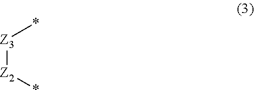
wherein * indicates a connecting position;
Z₂ and Z₃ are independently selected from O, S, N(R₀) and C(R₀)₂, and at least one of the Z₂ and Z₃ is C(R₀)₂;
R₀ is independently hydrogen, deuterium, F, cyano, substituted or unsubstituted C₁-C₁₀ alkyl, substituted or unsubstituted C₃-C₂₀cycloalkyl, substituted or unsubstituted C₂-C₃₀ alkenyl, substituted or unsubstituted C₂-C₃₀alkynyl, substituted or unsubstituted C₆-C₃₀ aryl, substituted or unsubstituted C₁-C₃₀heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄alkoxyl, C₃-C₆cycloalkyl, amino substituted with C₁-C₄ alkyl, nitrile, isonitrile, or phosphino.

10. The organometallic compound according to claim 1, wherein at least one of the Rb and the Rc is not hydrogen.

11. The organometallic compound according to claim 10, wherein at least one of the Rb and the Rc is substituted or unsubstituted C₁-C₆ alkyl, or substituted or unsubstituted C₃-C₆cycloalkyl.

12. The organometallic compound according to claim 11, wherein at least one of the Rb and the Rc is substituted or unsubstituted C₁-C₆ alkyl, or substituted or unsubstituted C₃-C₆cycloalkyl, and the other group is hydrogen.

13. The organometallic compound according to claim 3, wherein the L1 has one of the following structural formulas, or is partially or completely deuterated or fluorinated correspondingly,

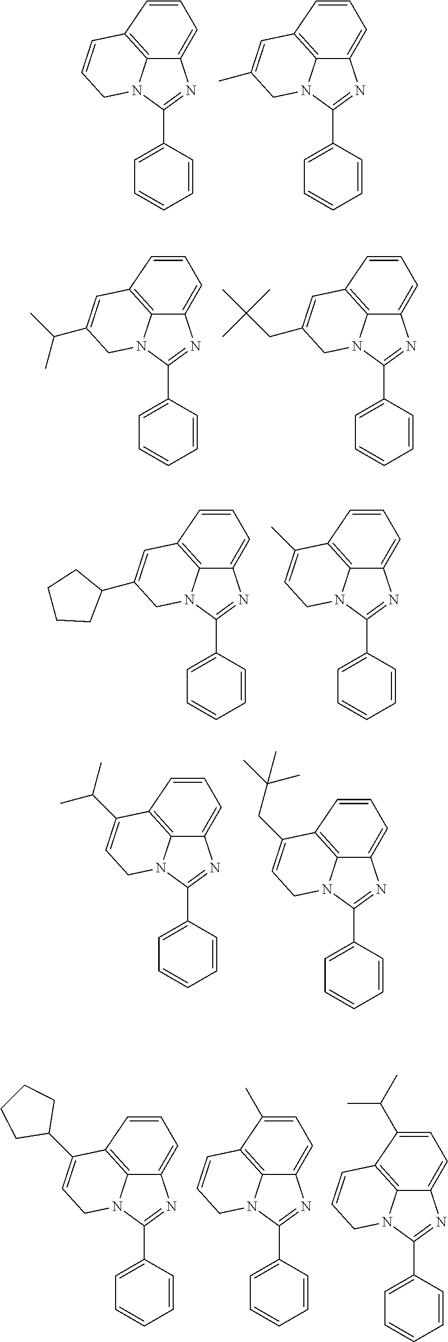

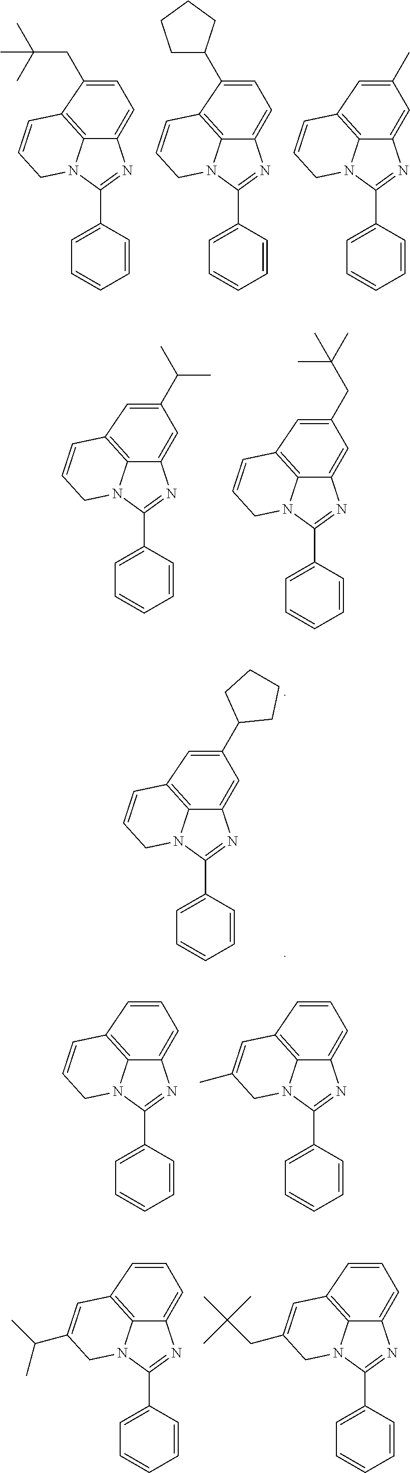

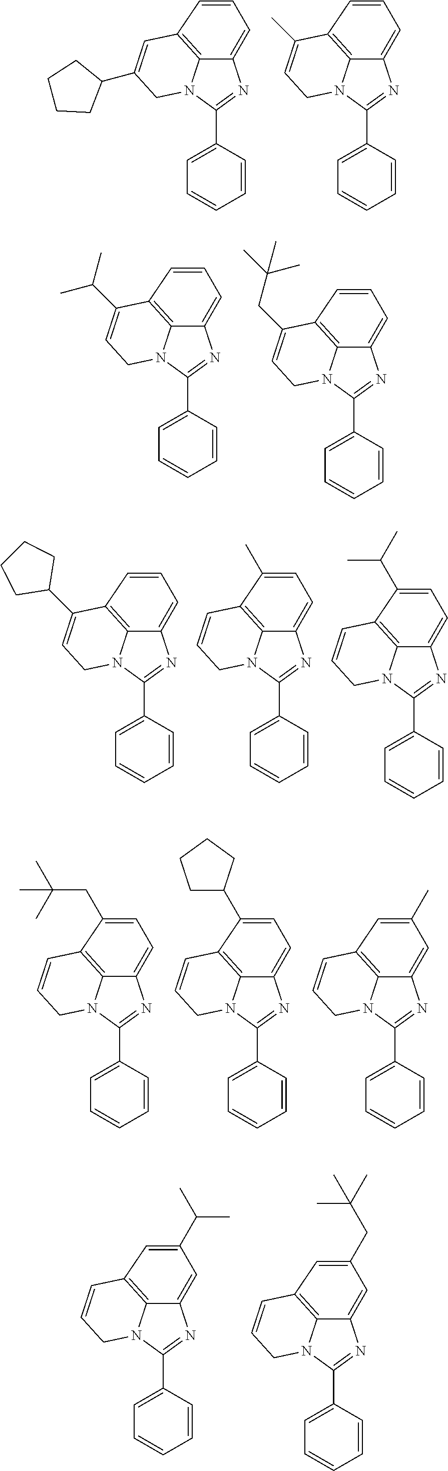

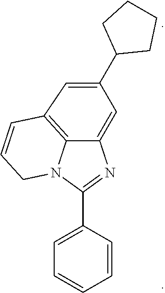 [SMILES: C1=Cc2cc(C3CCCC3)cc3nc(-c4ccccc4)n(c23)C1]

14. The organometallic compound according to claim 3, wherein the L2 preferably has one of the following structural formulas, or is partially or completely deuterated or fluorinated correspondingly,

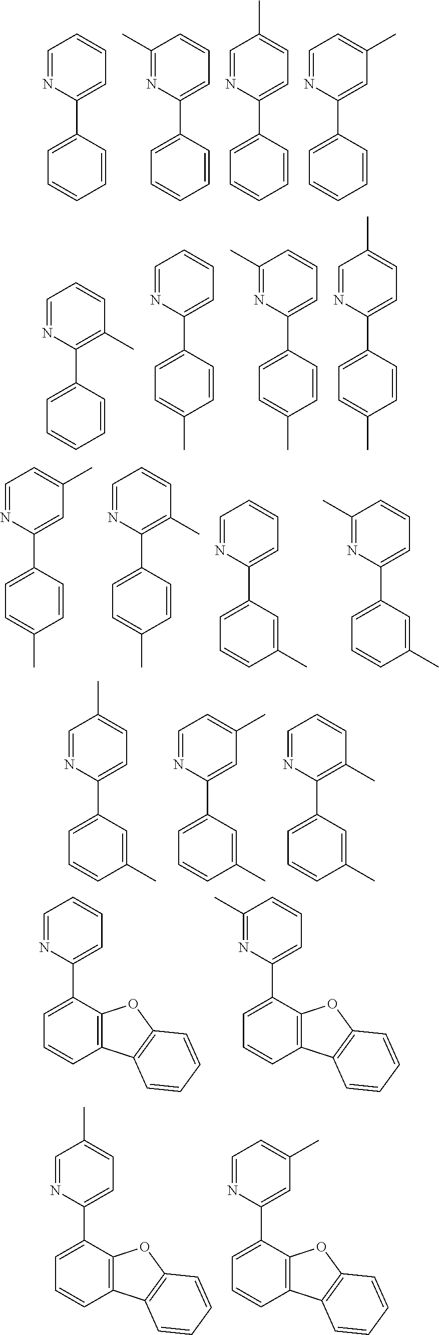

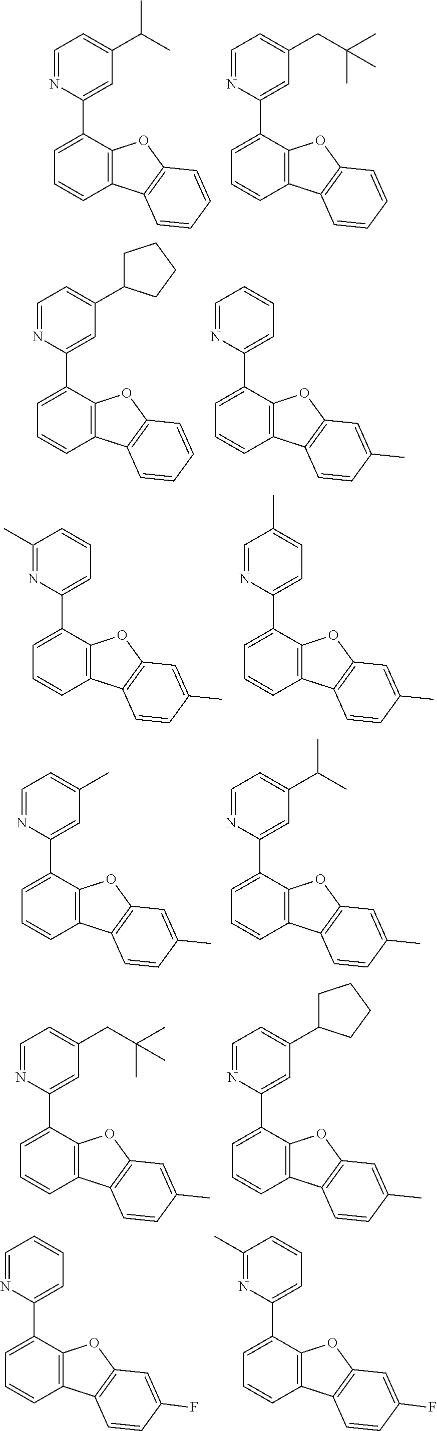

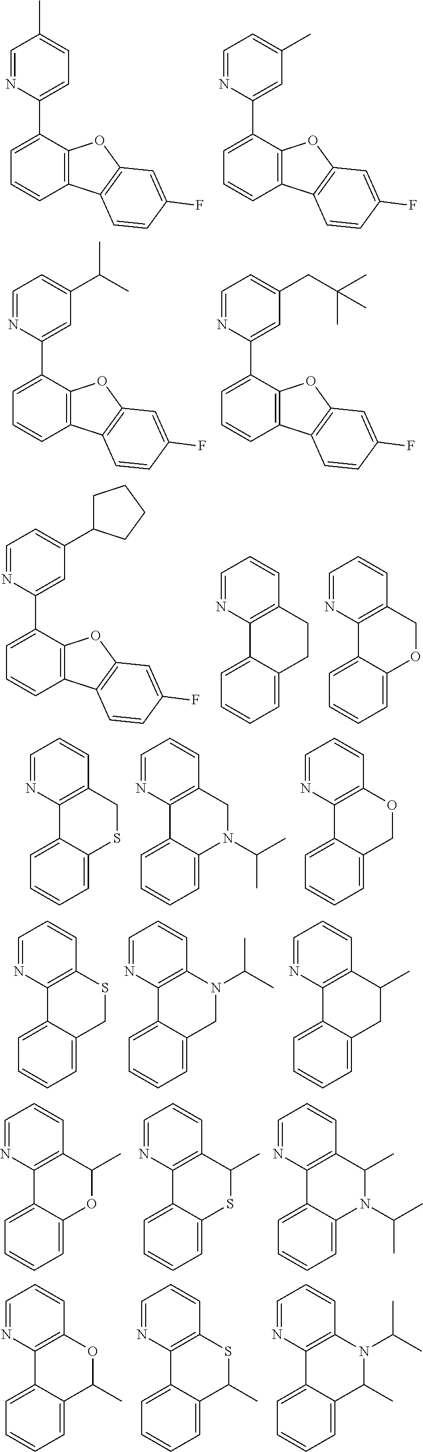

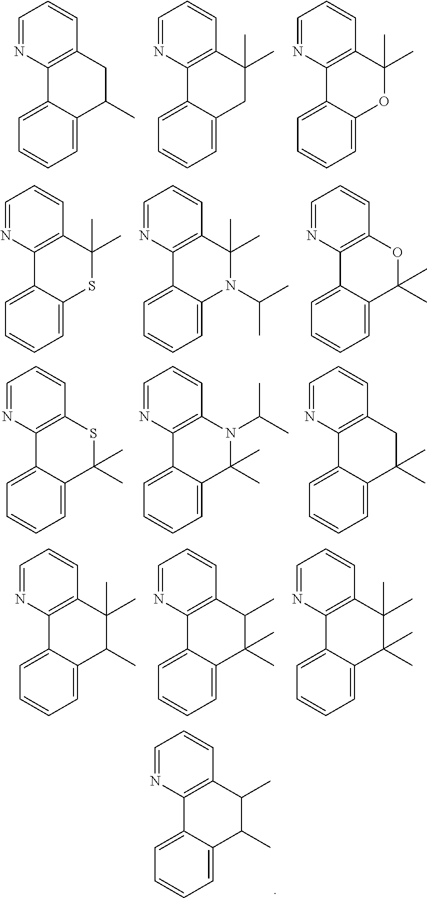

15. The organometallic compound according to claim 1, wherein the compound as shown in the formula (1) has one of the following structural formulas, or is partially or completely deuterated or fluorinated correspondingly,

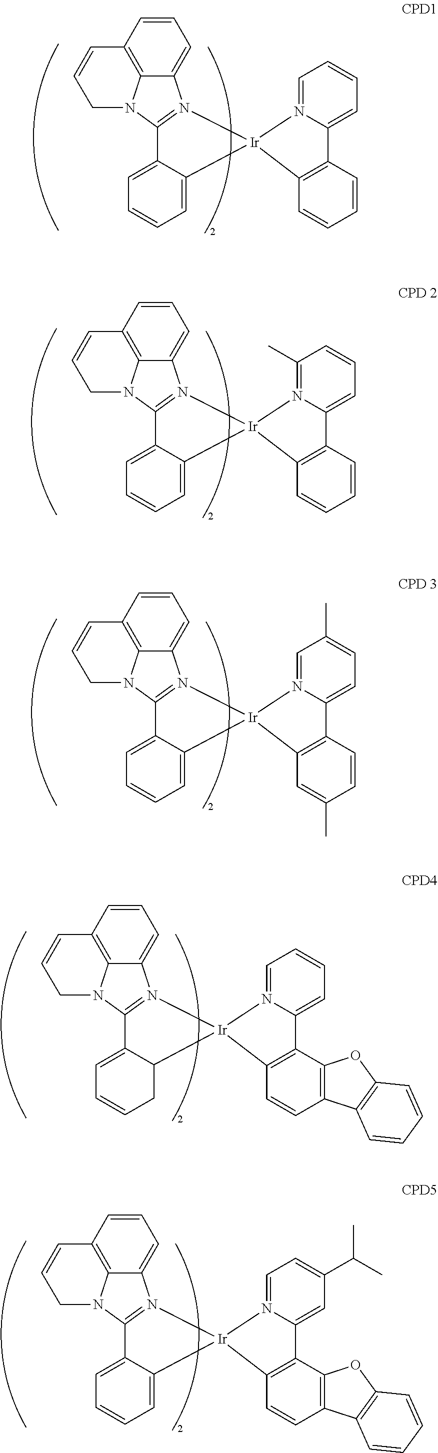

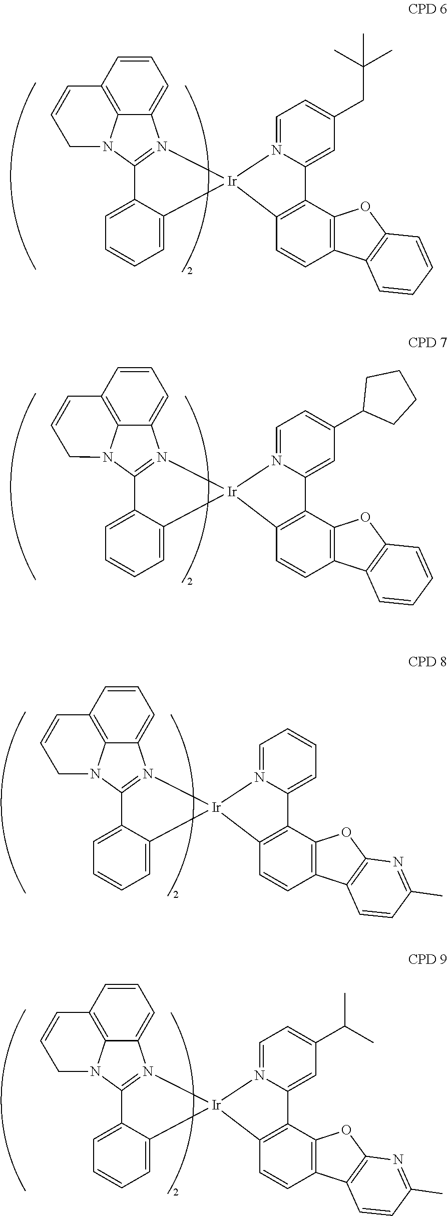

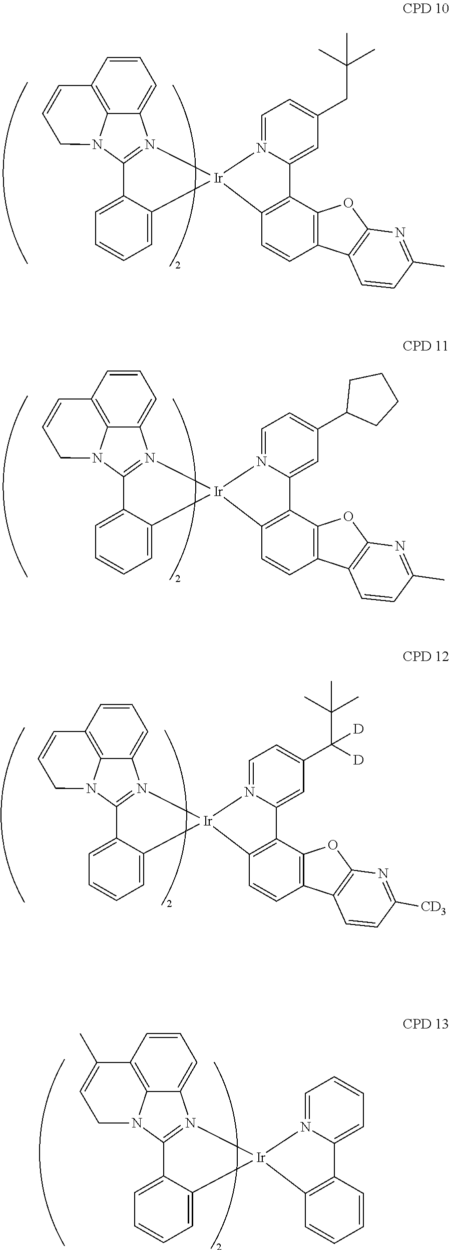

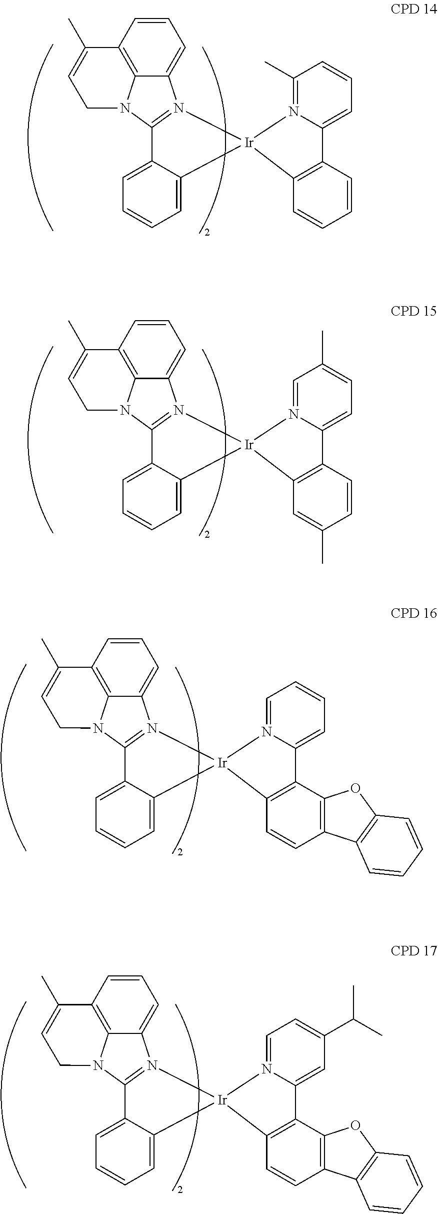

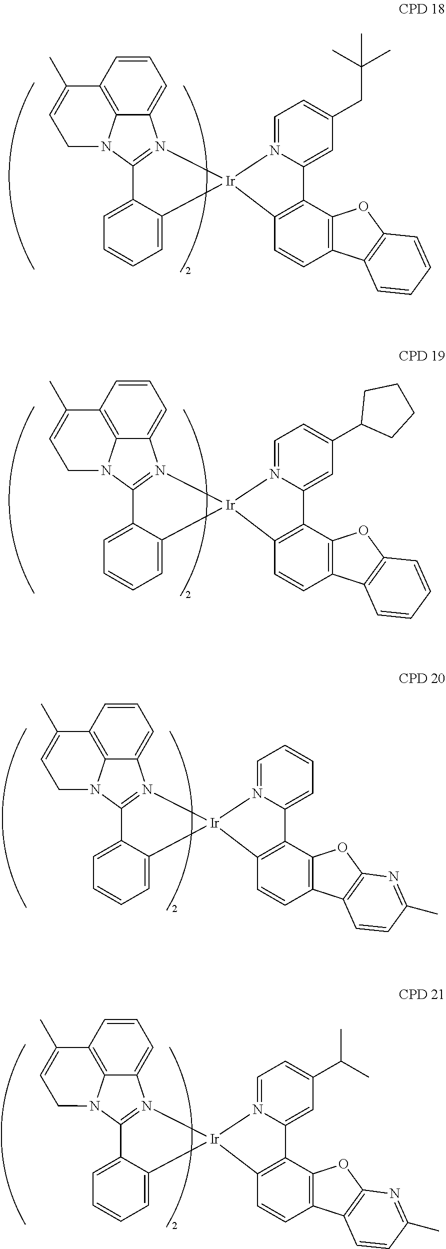

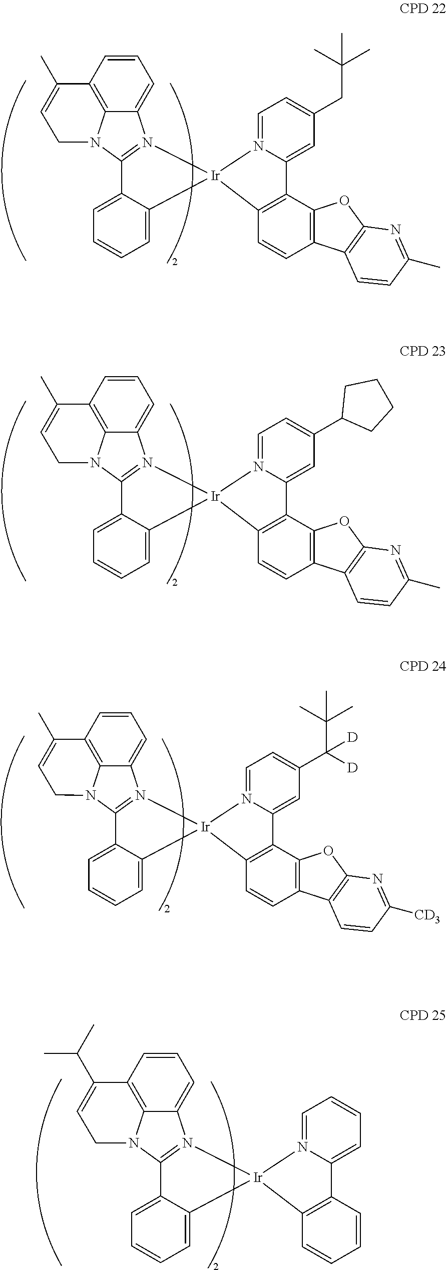

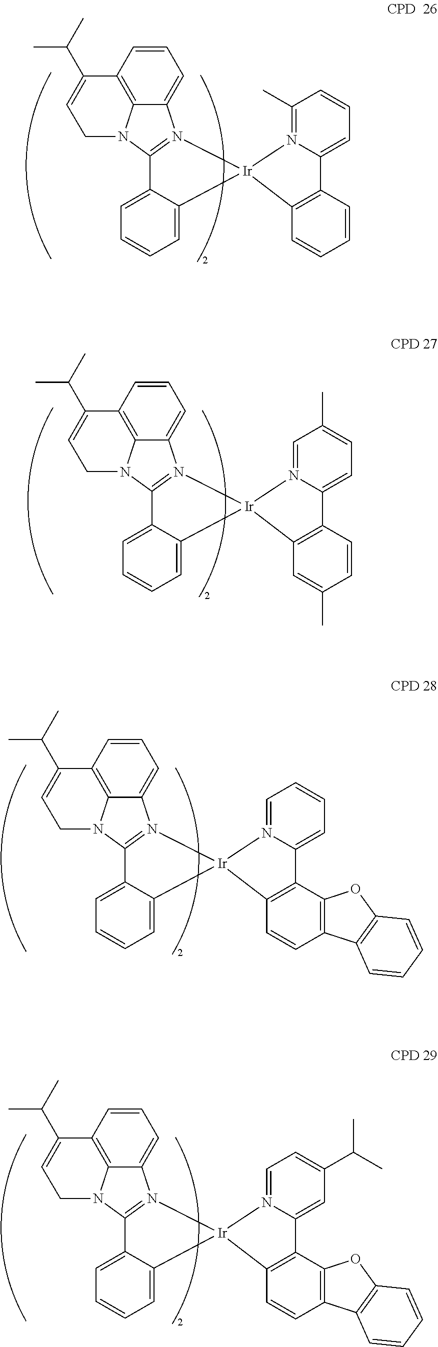

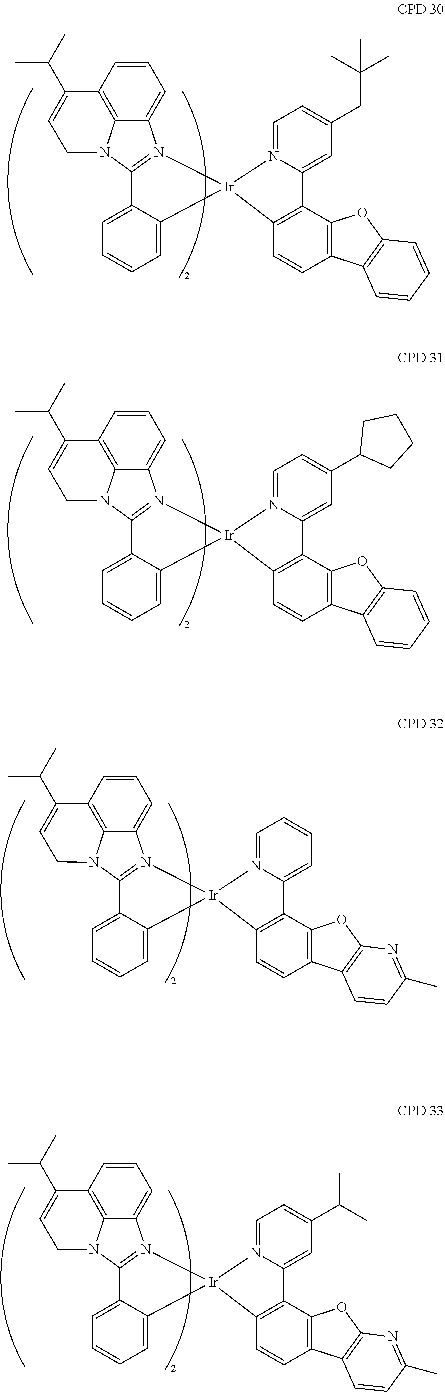

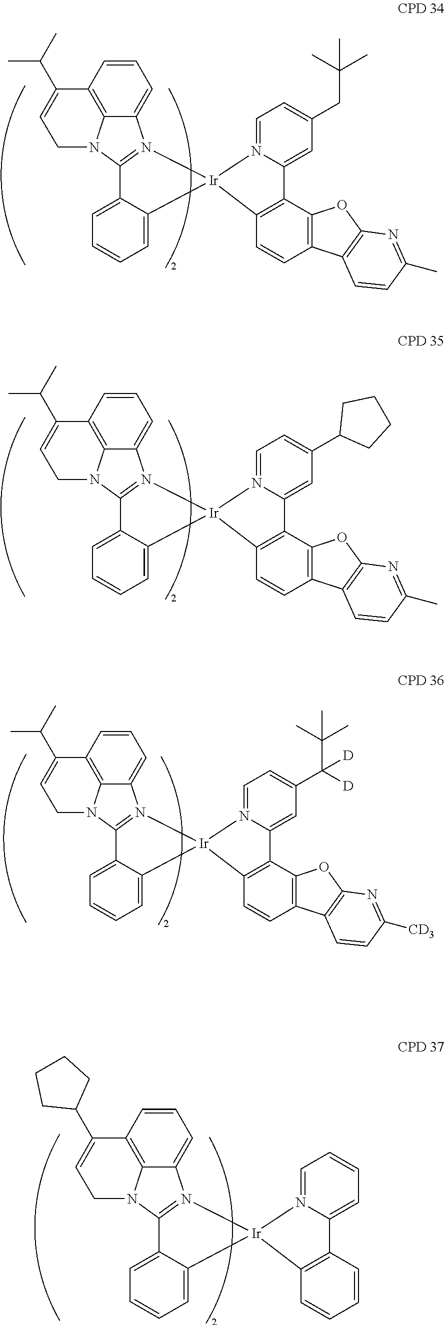

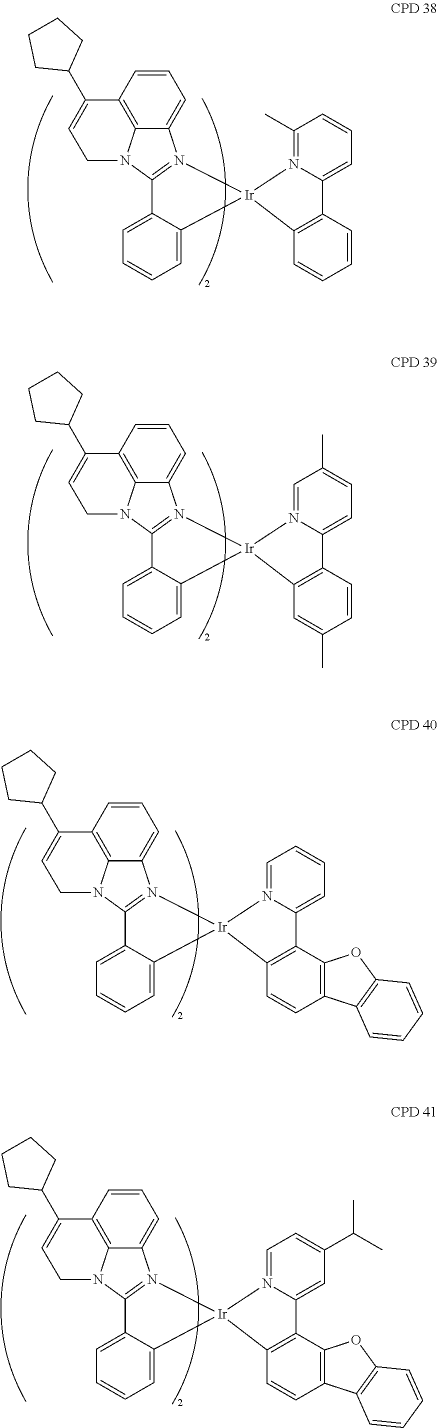

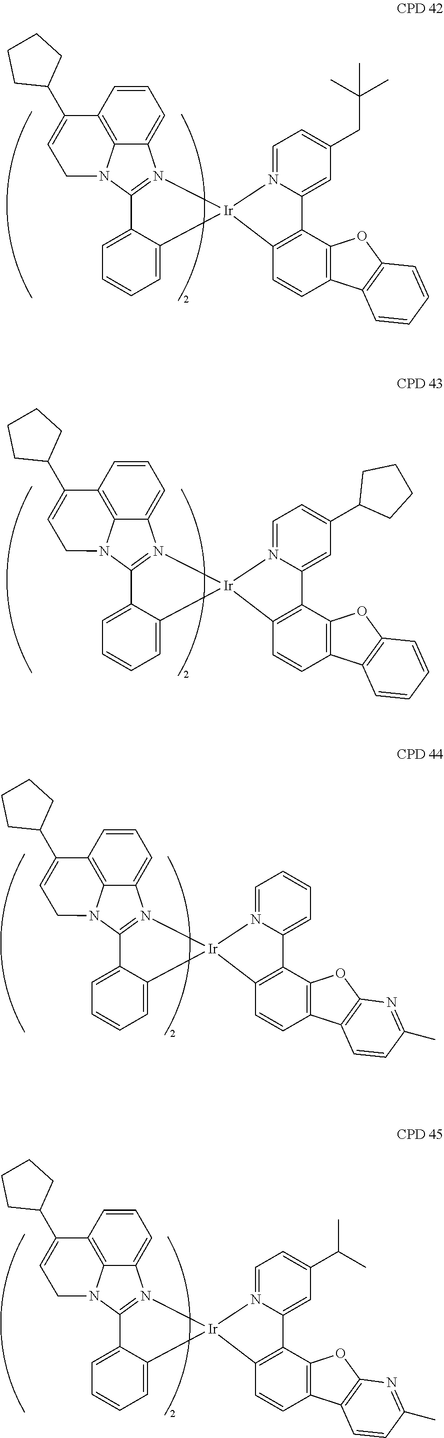

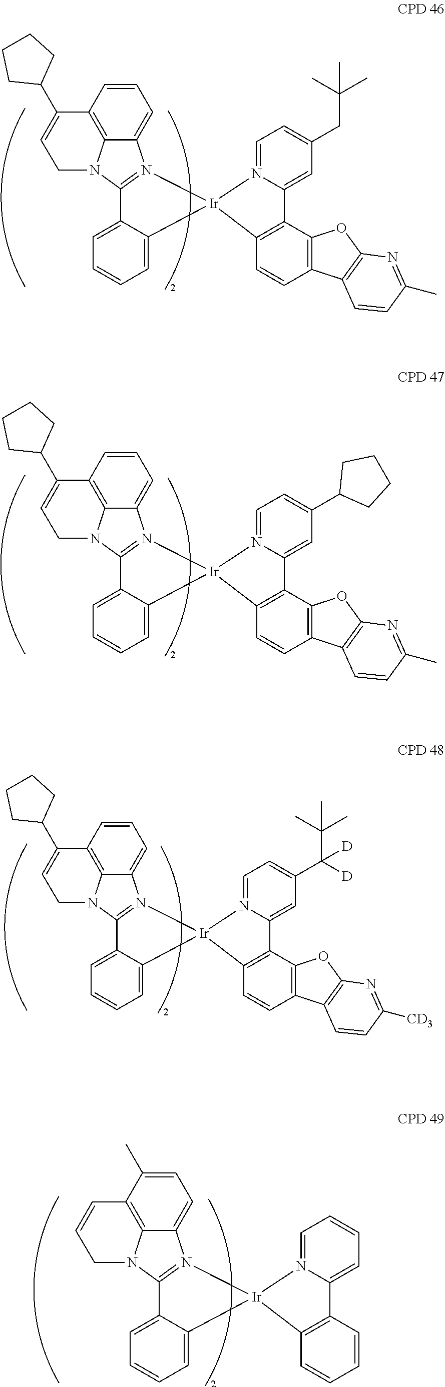

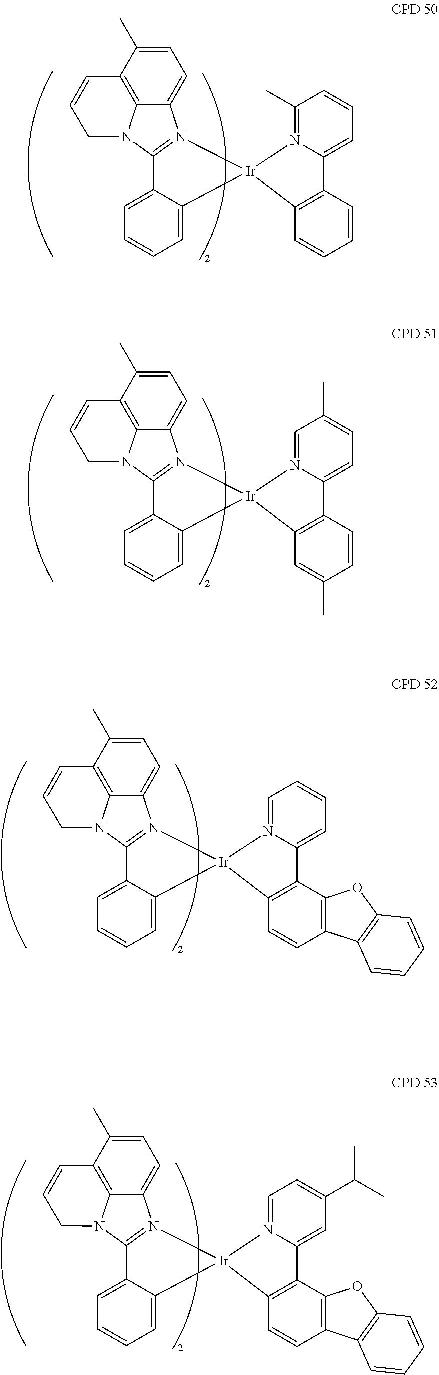

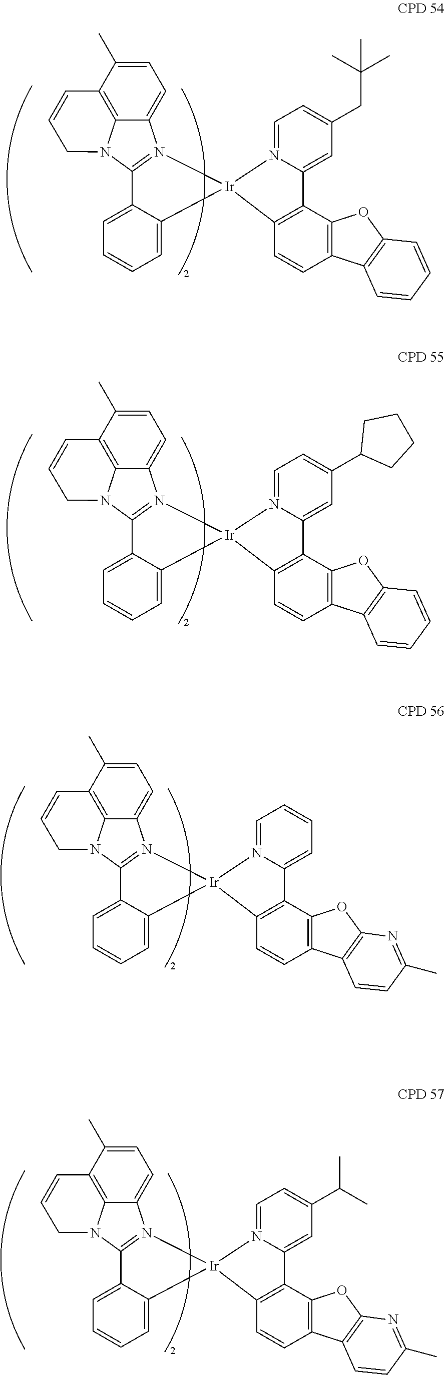

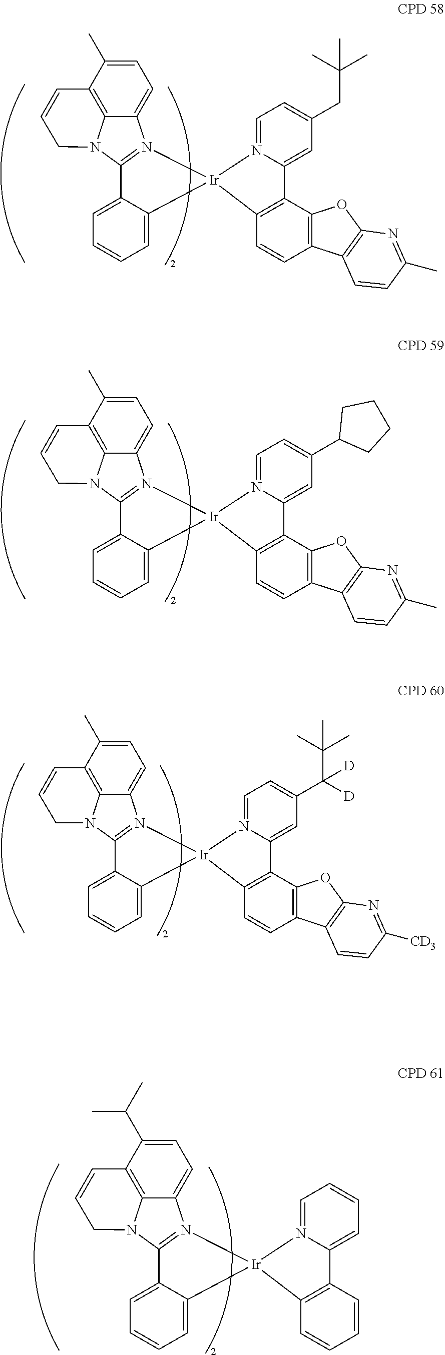

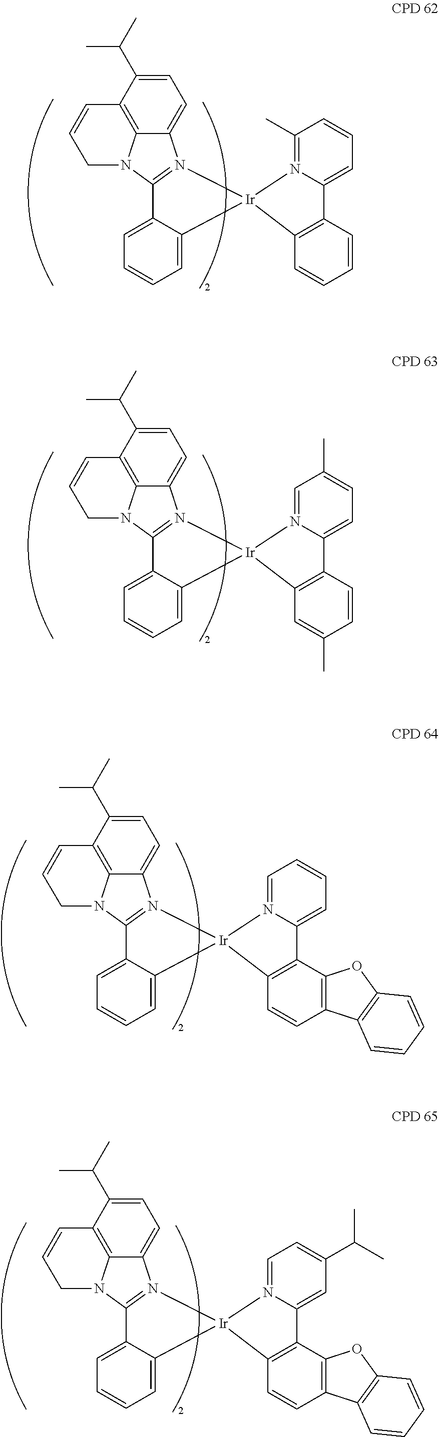

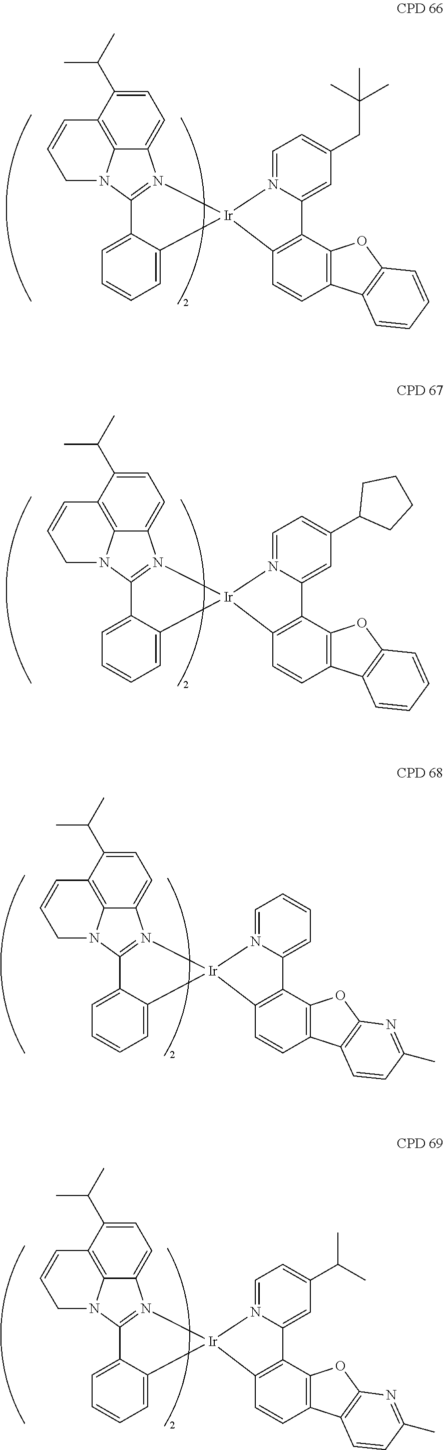

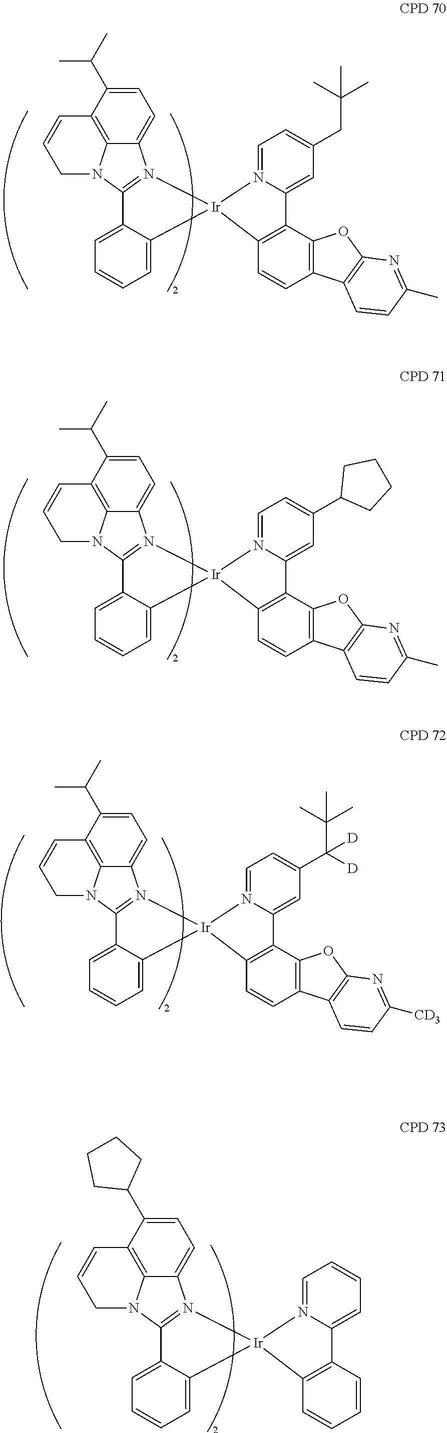

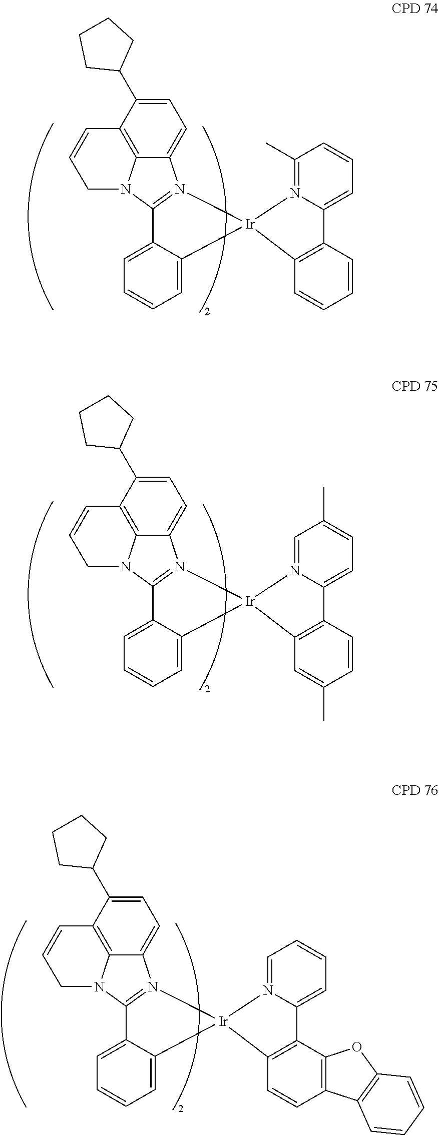

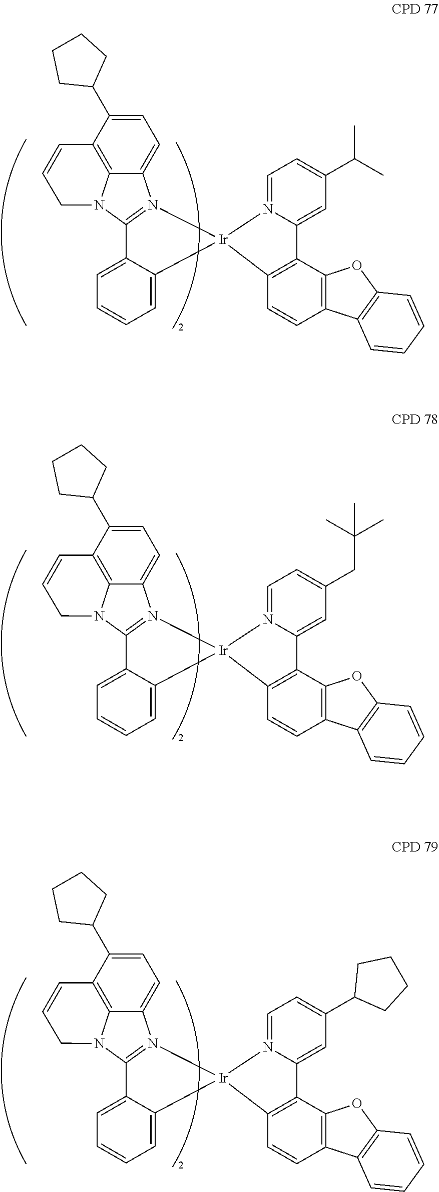

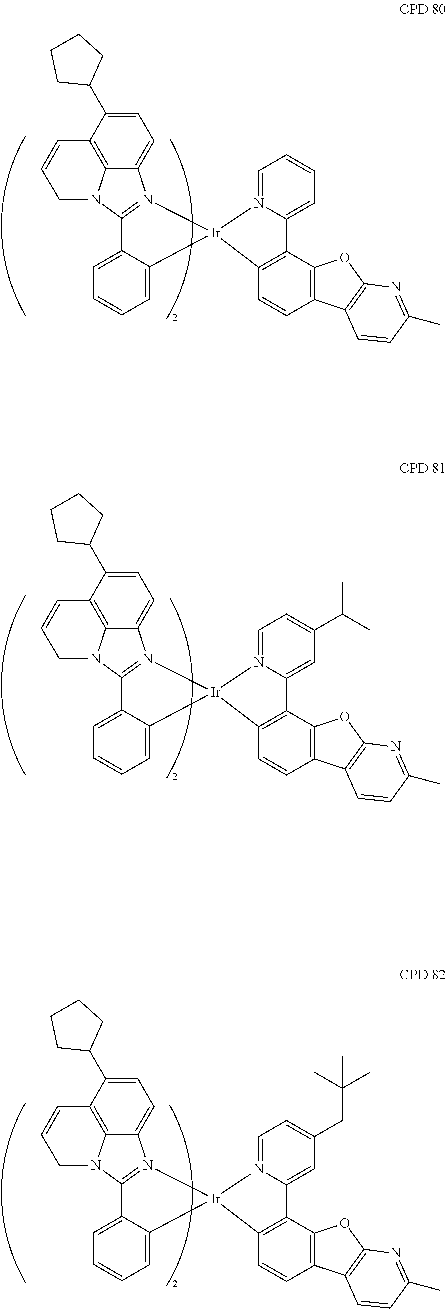

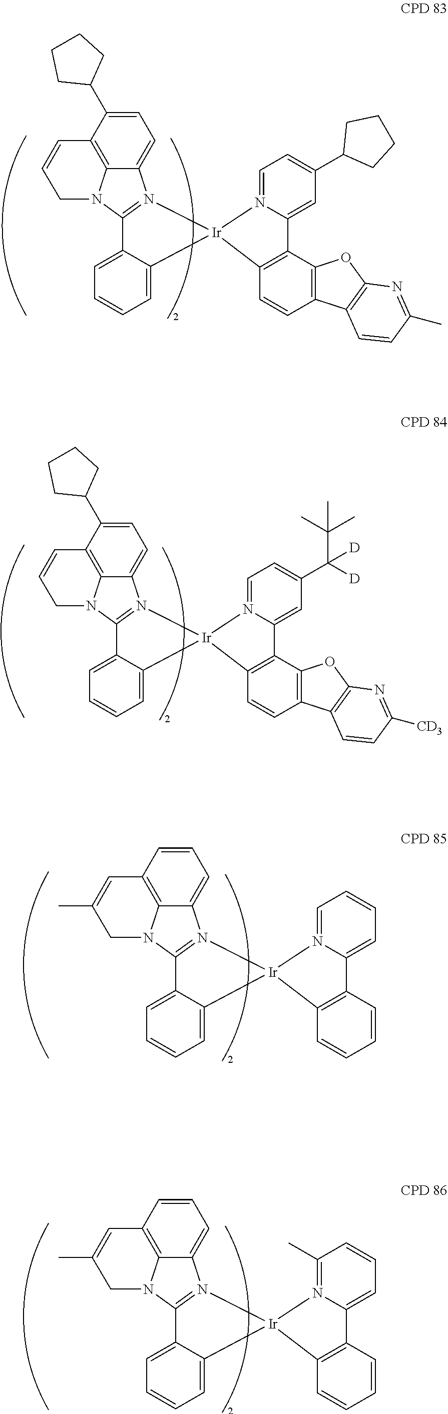

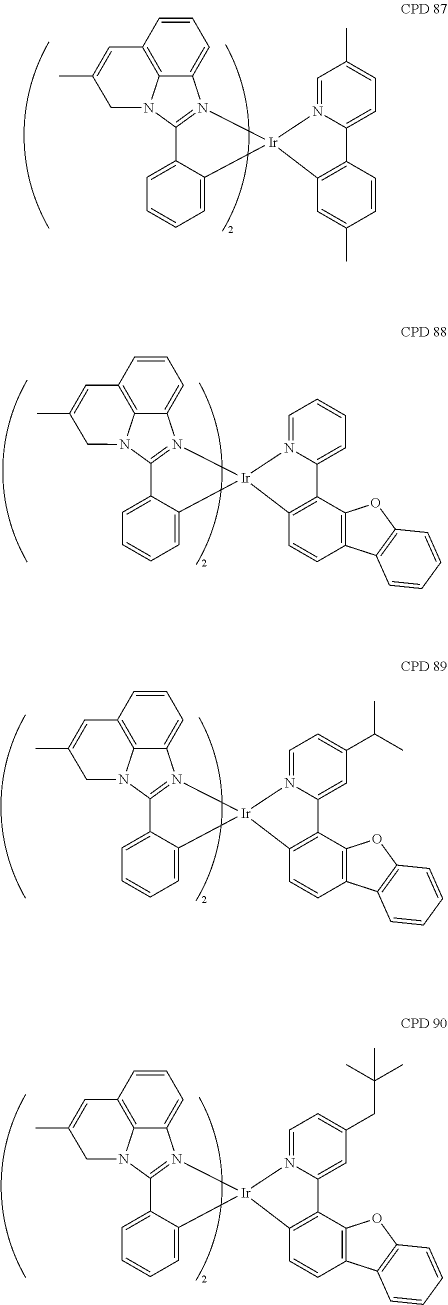

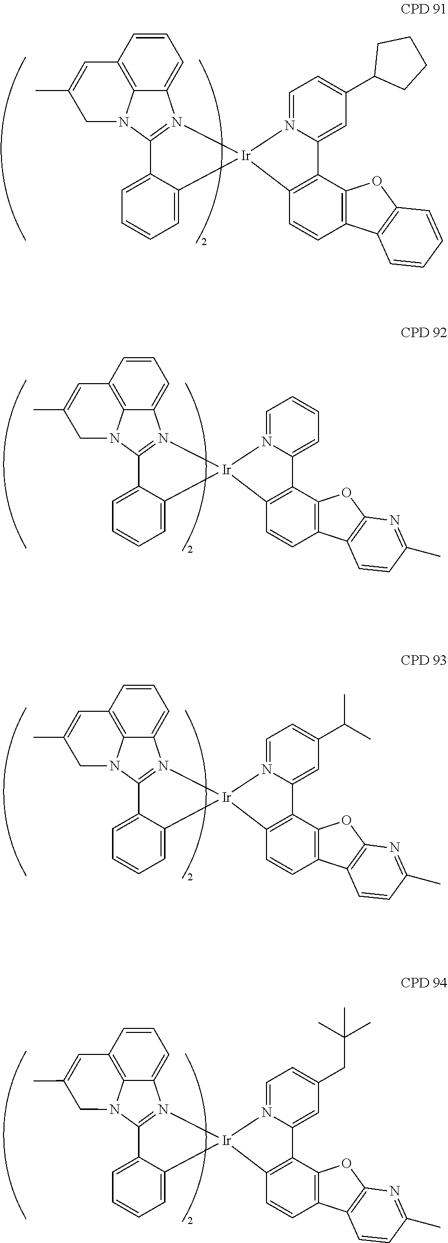

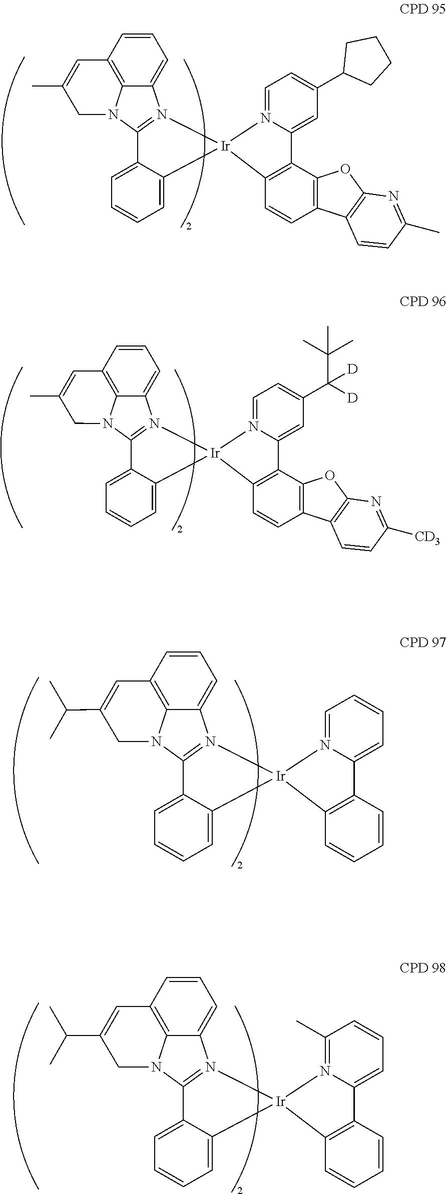

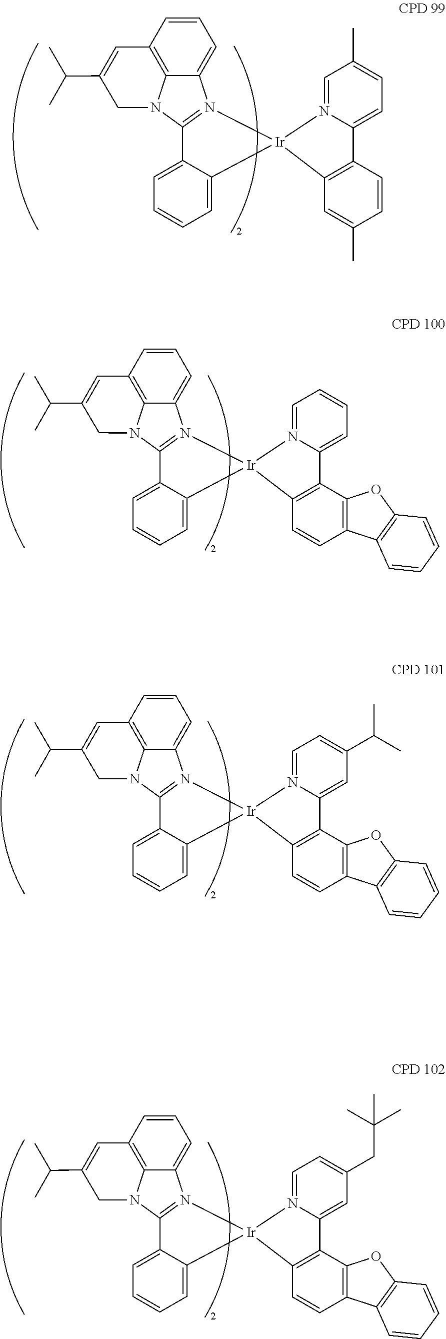

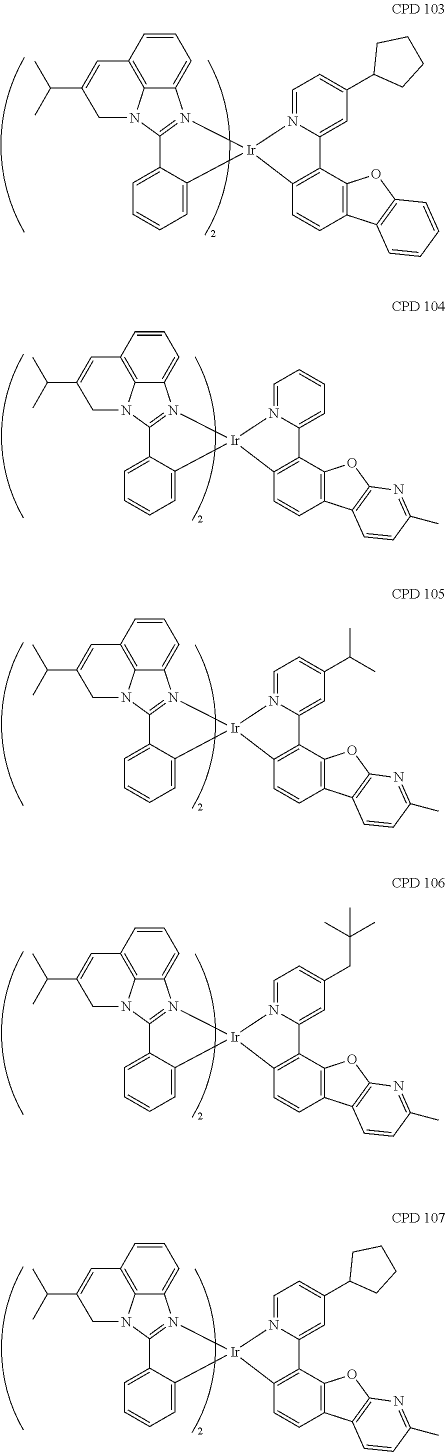

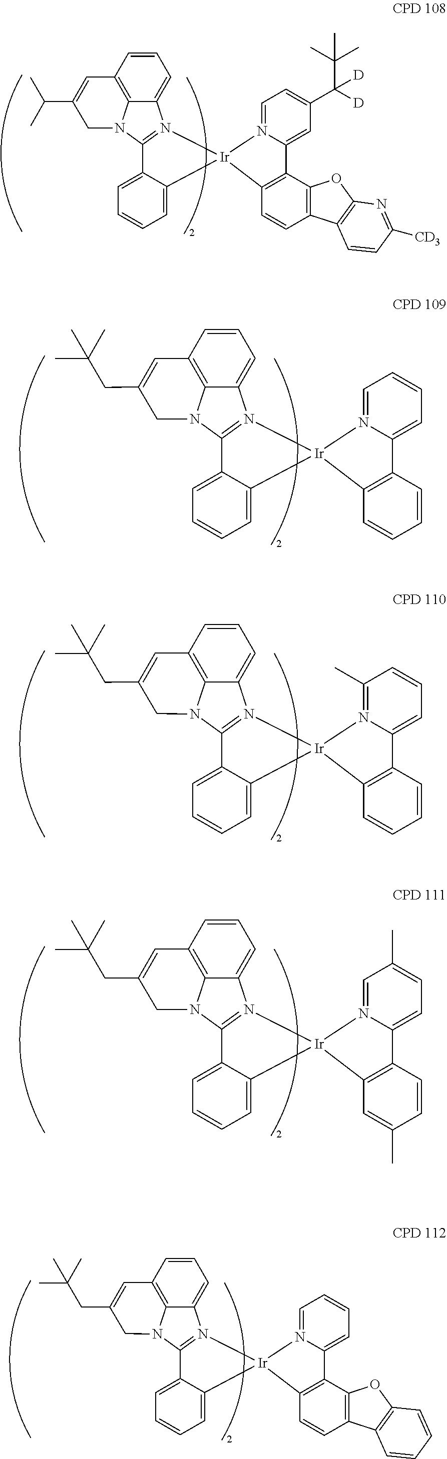

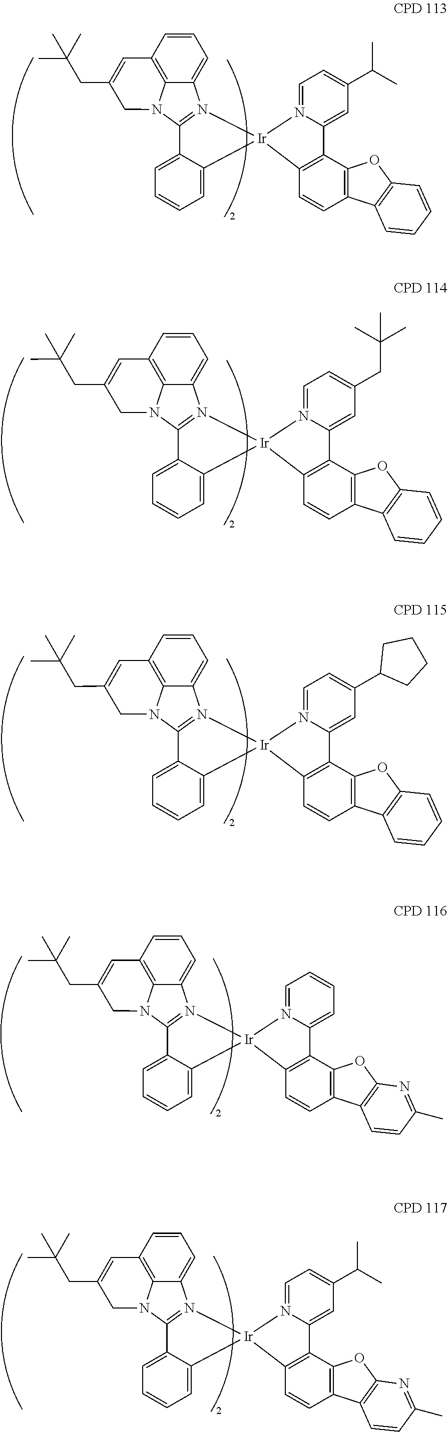

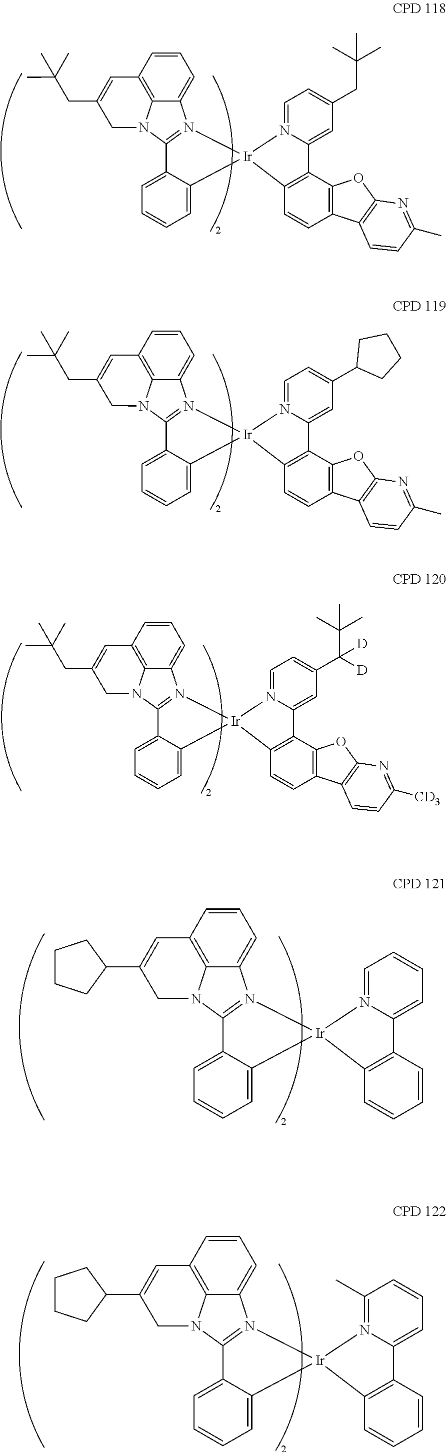

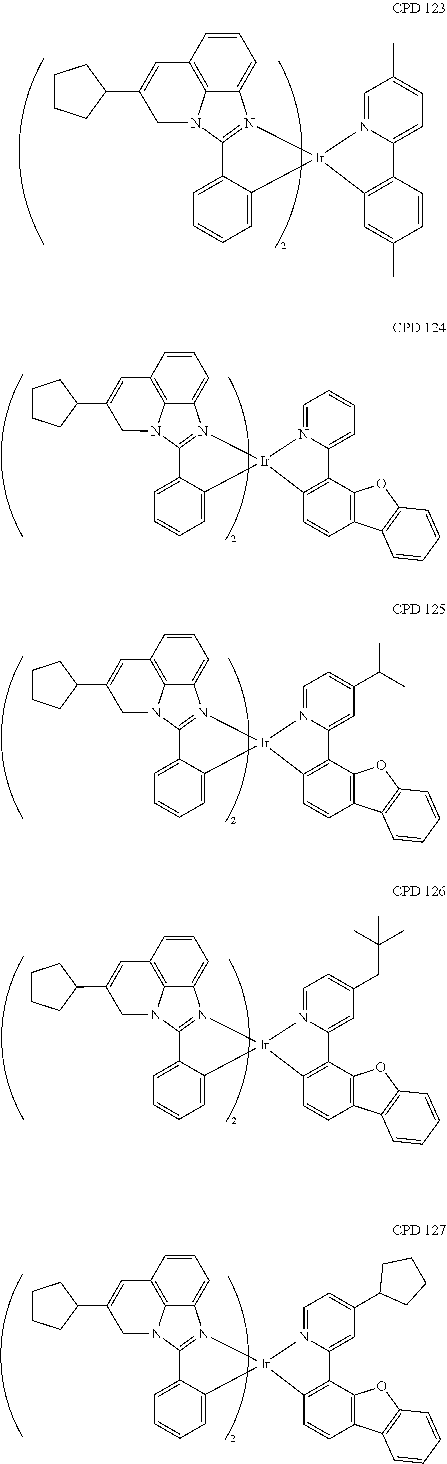

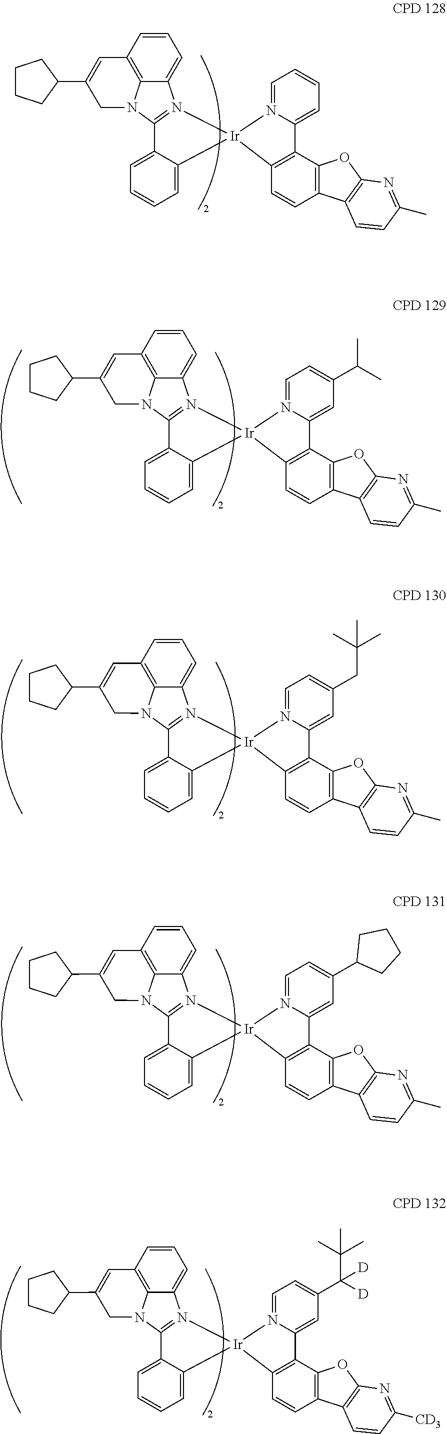

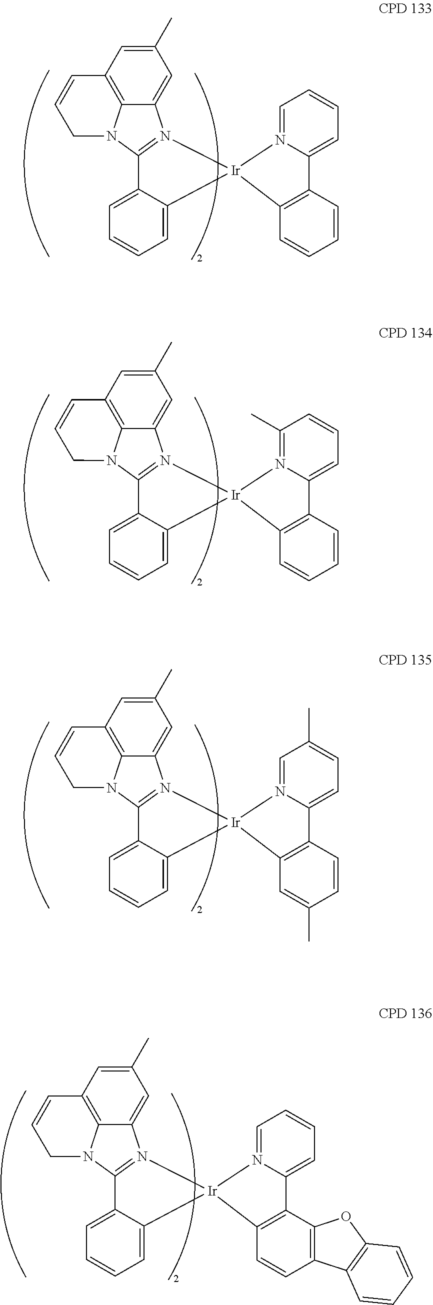

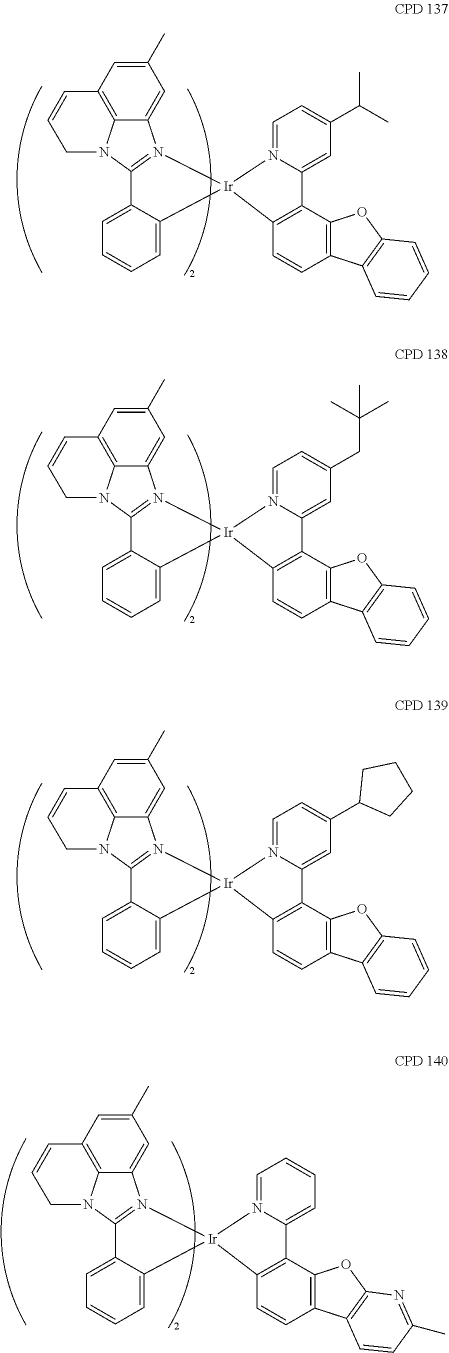

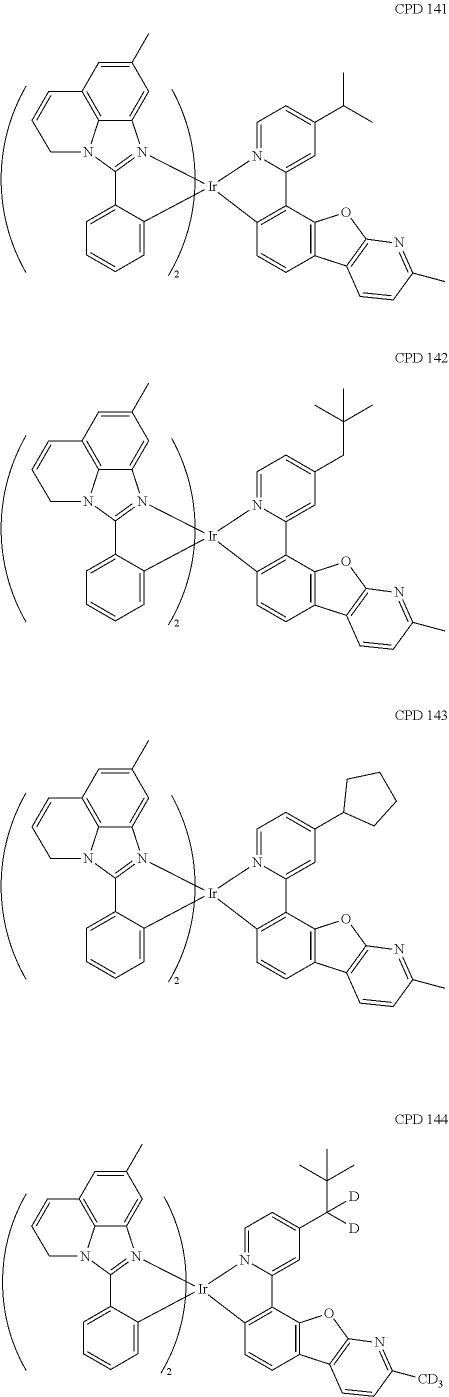

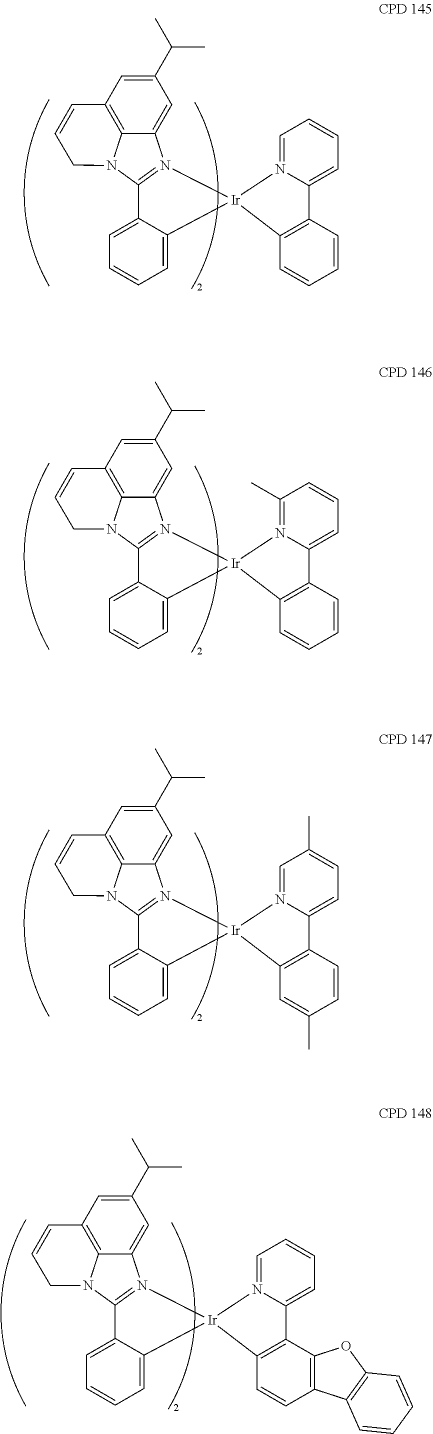

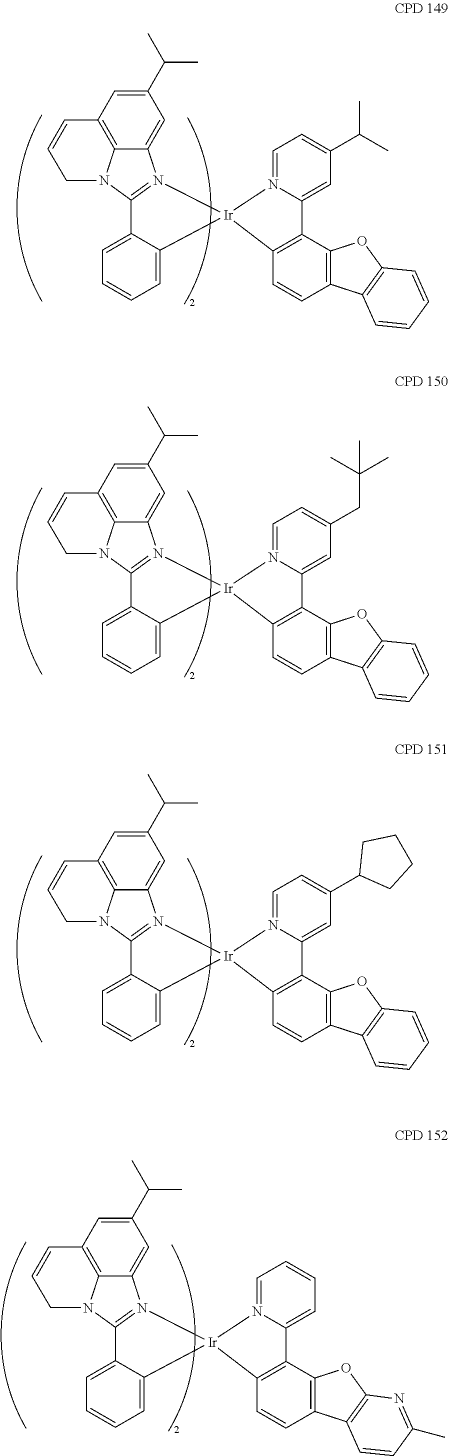

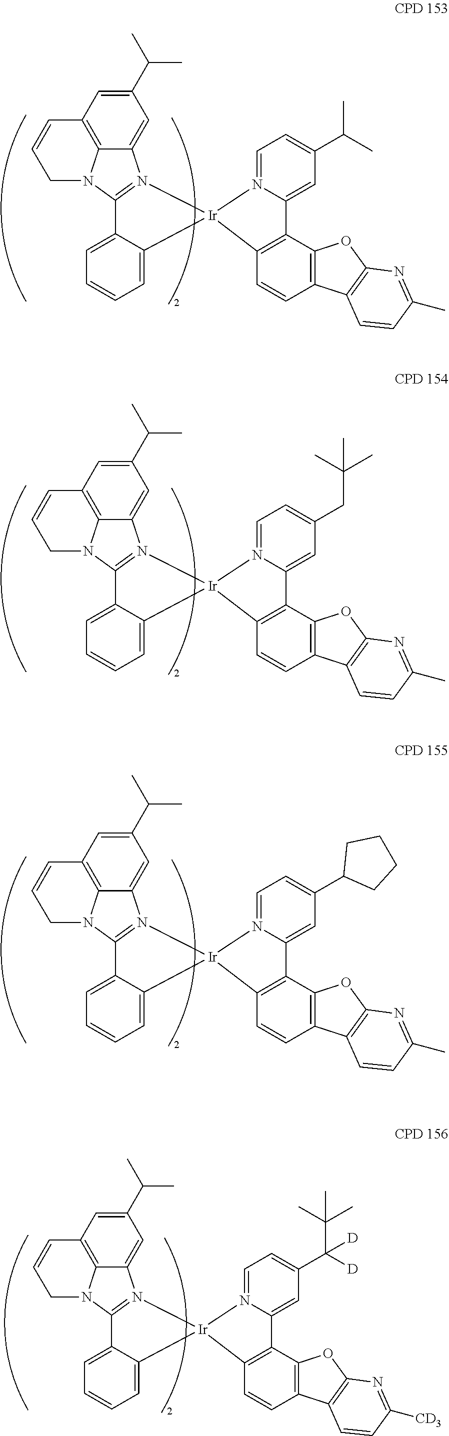

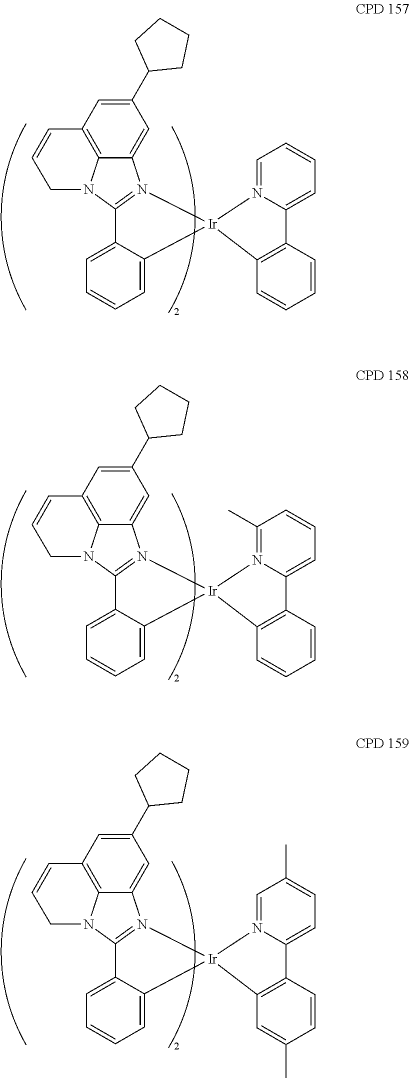

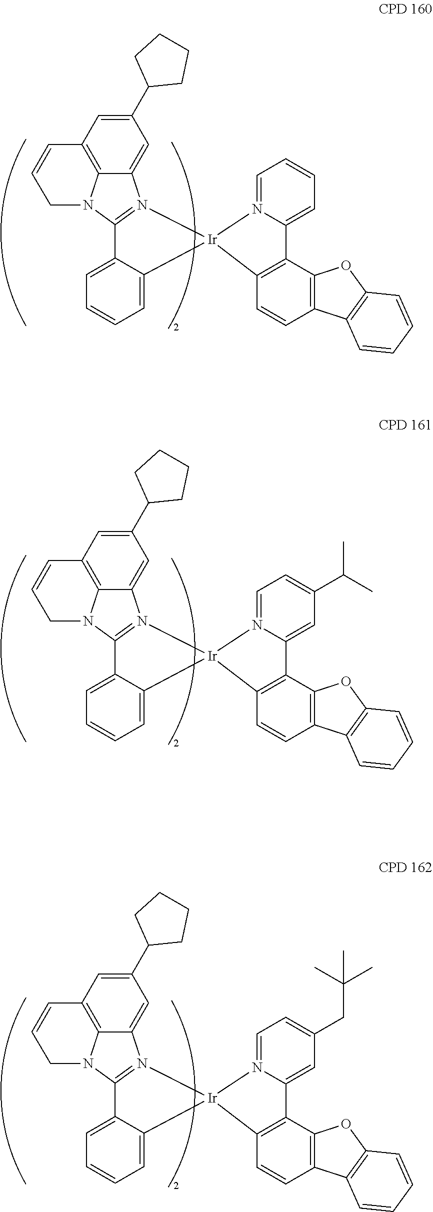

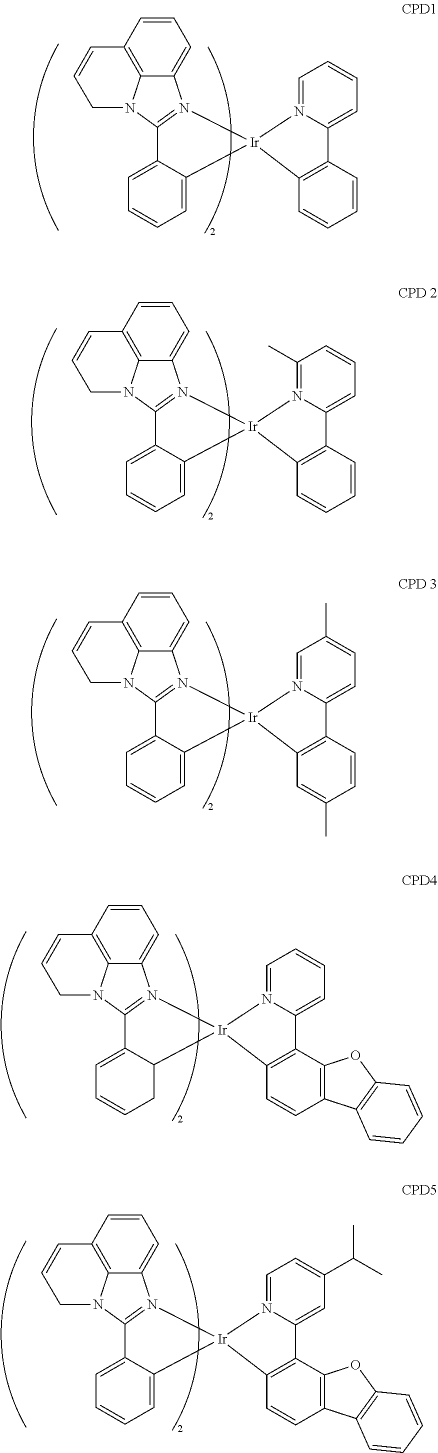

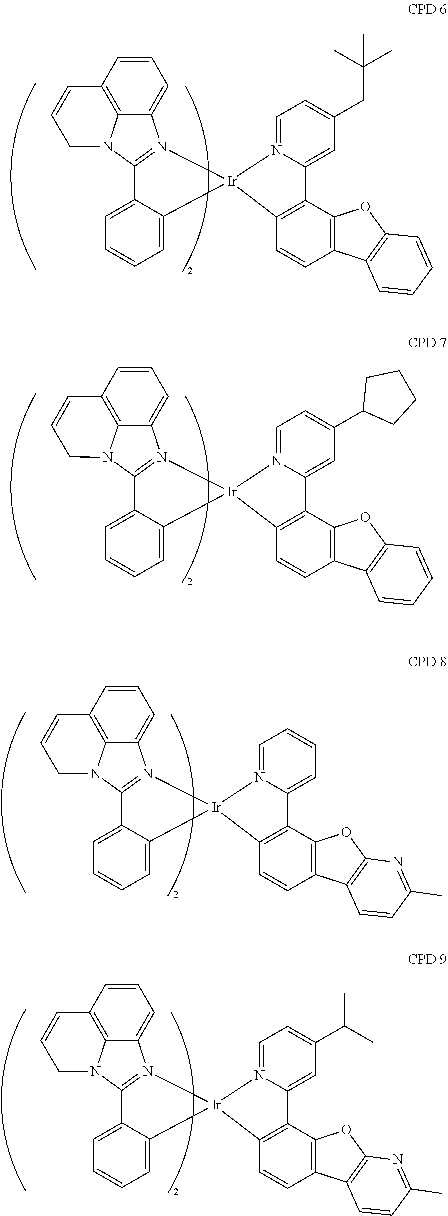

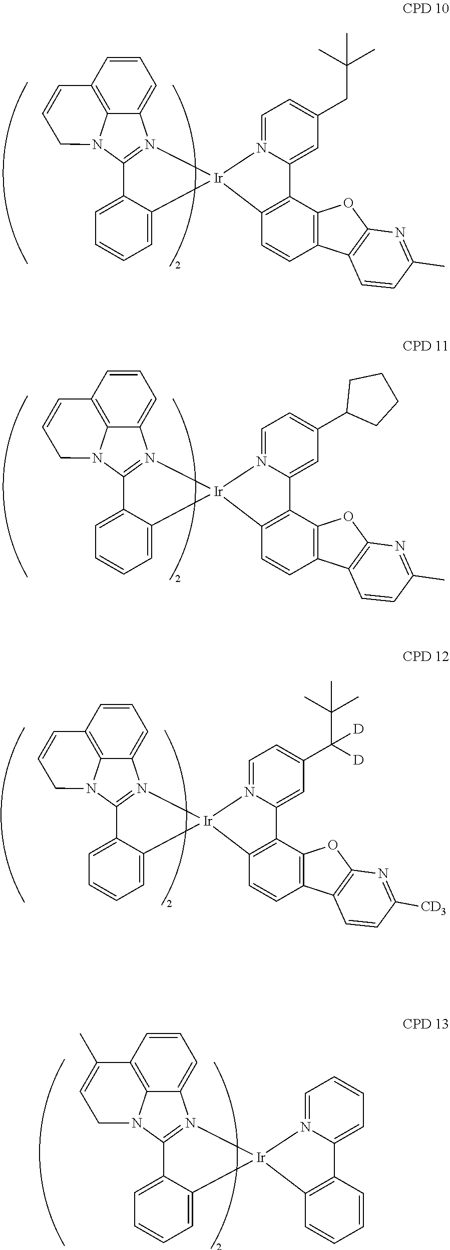

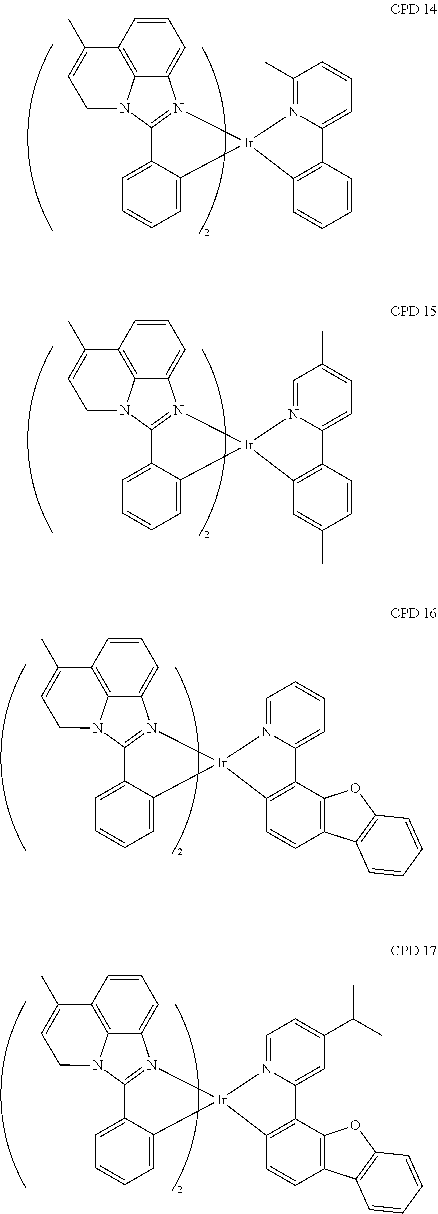

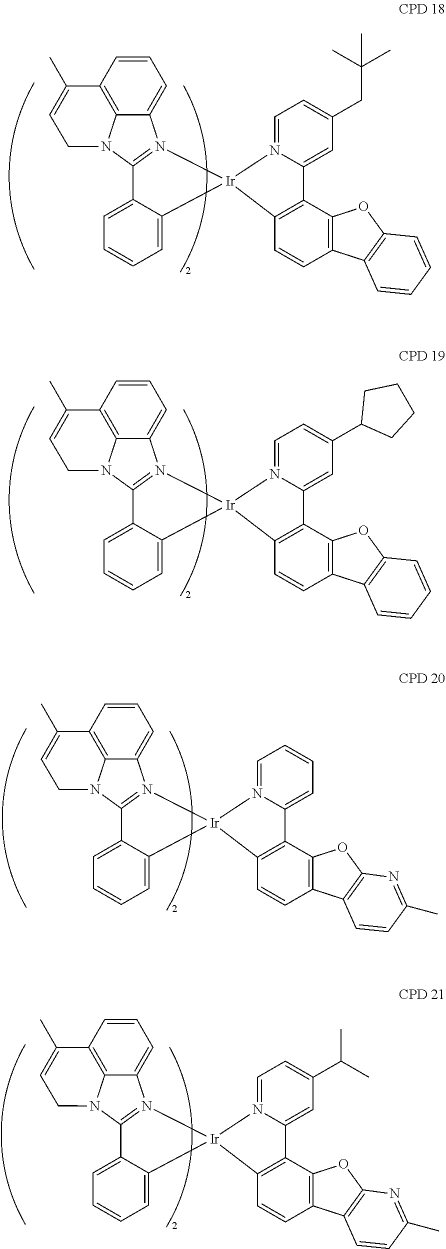

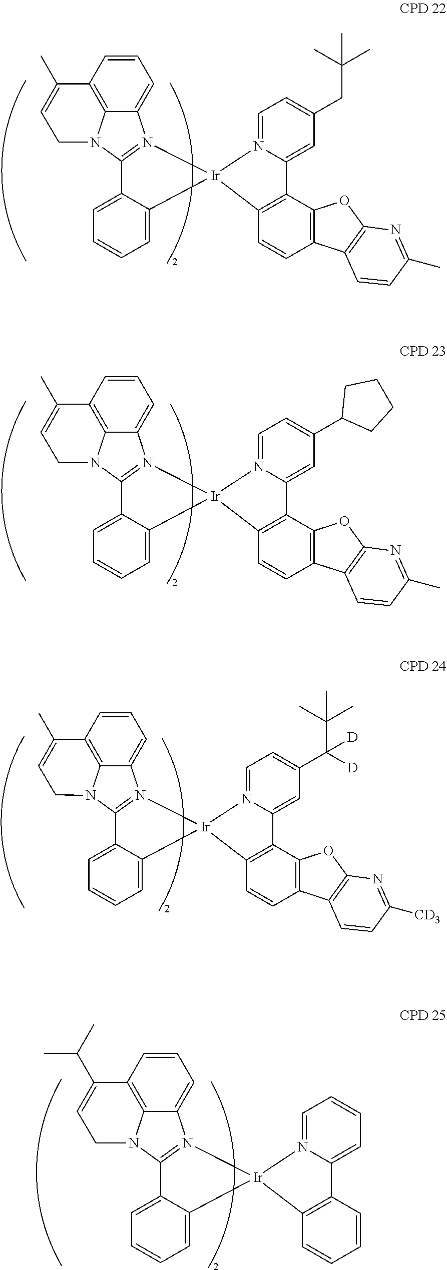

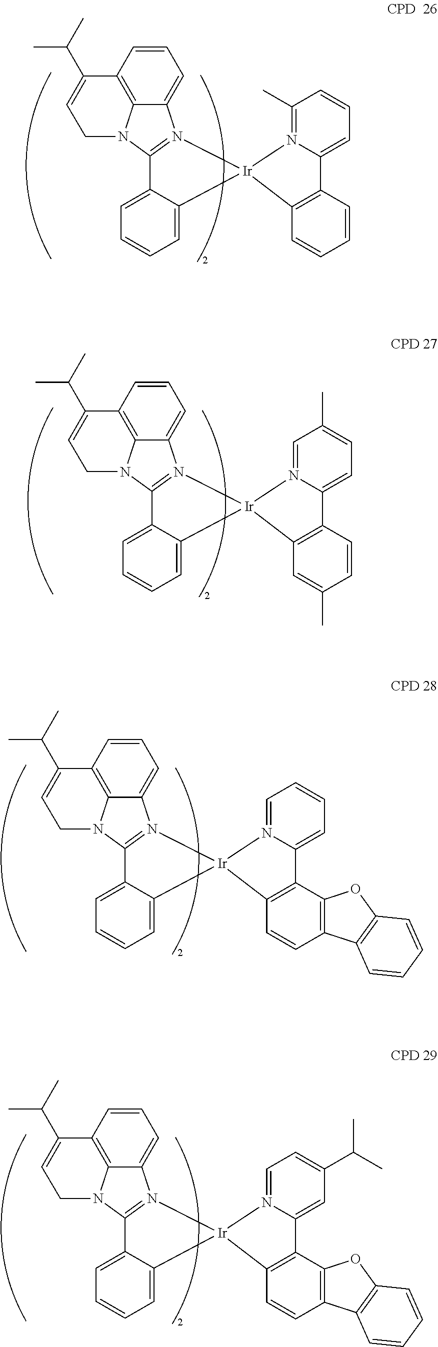

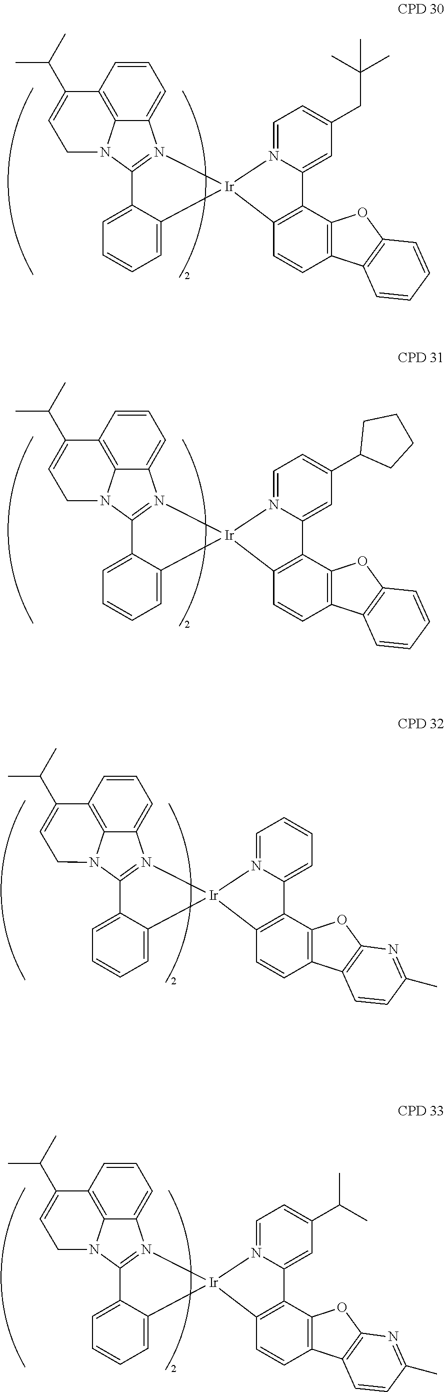

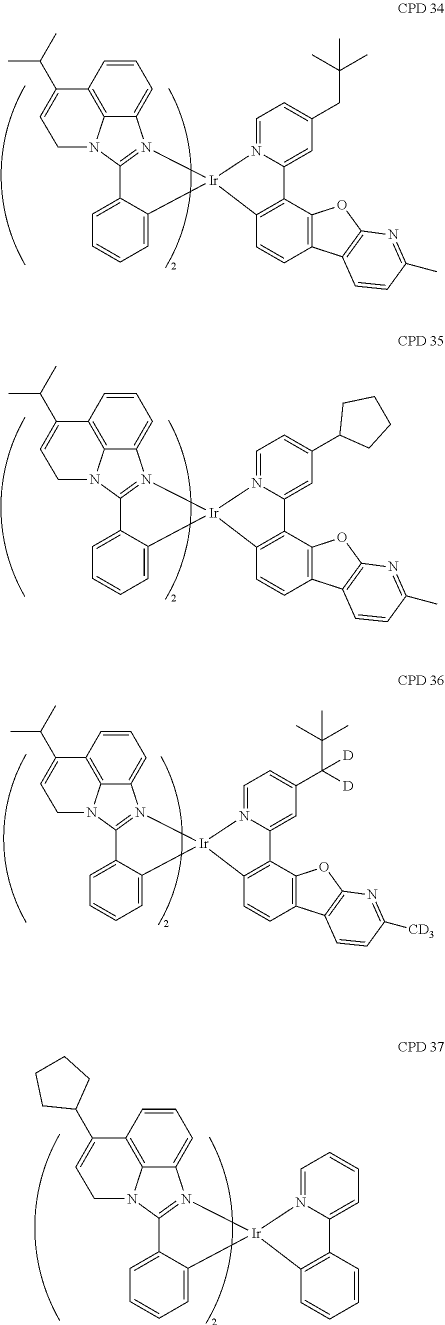

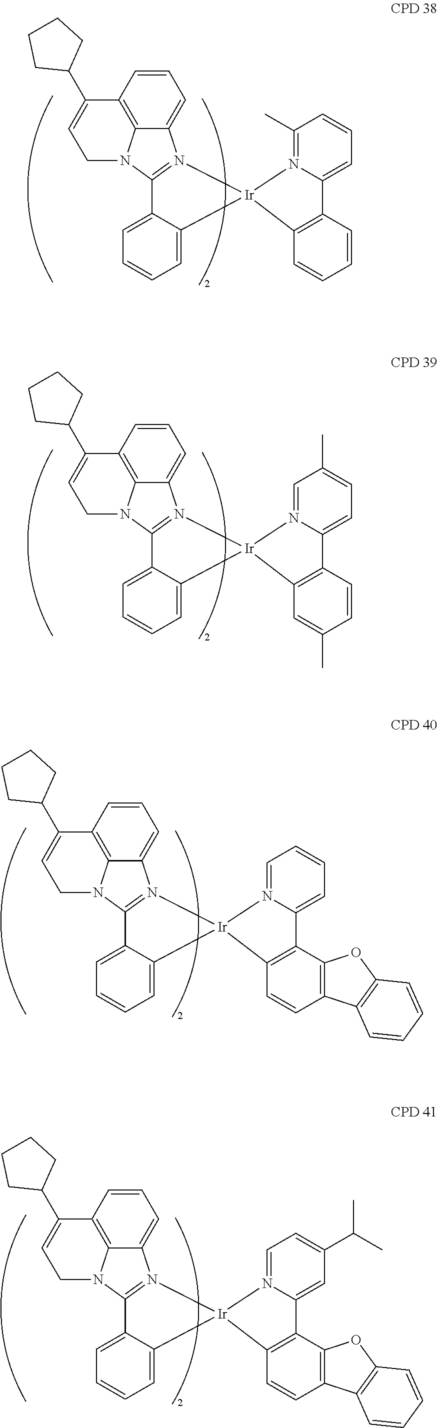

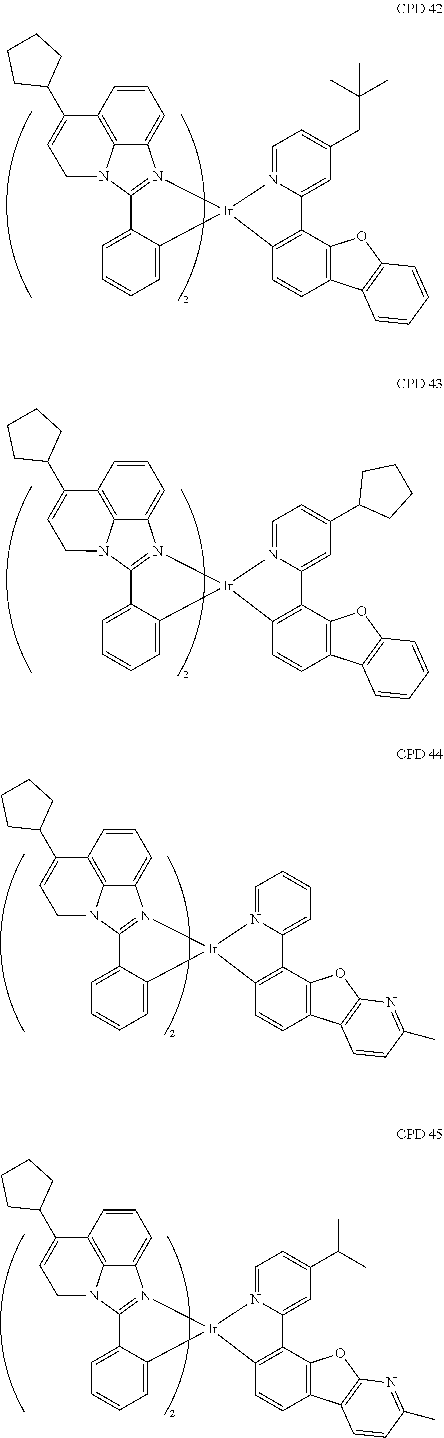

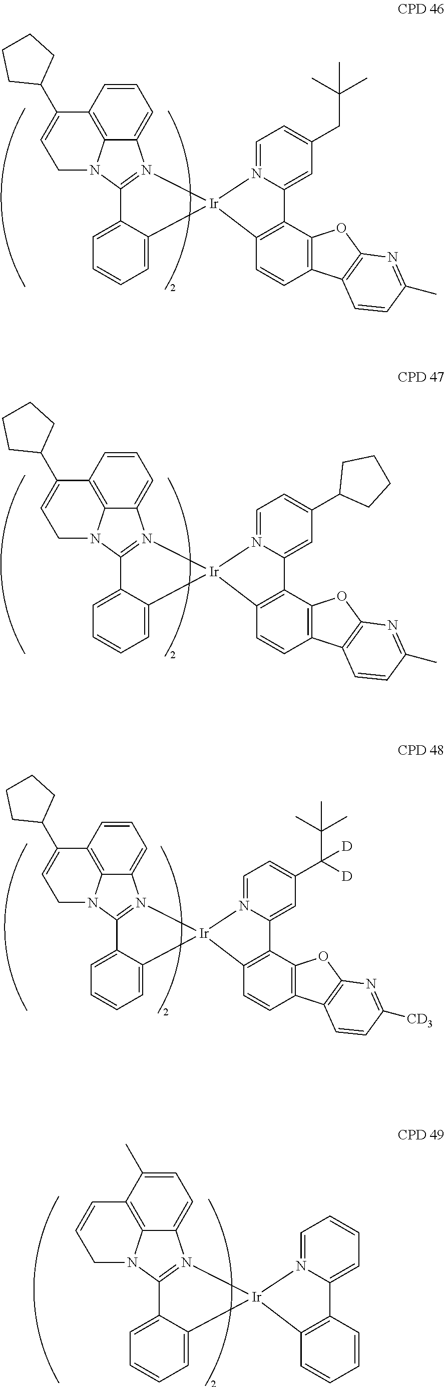

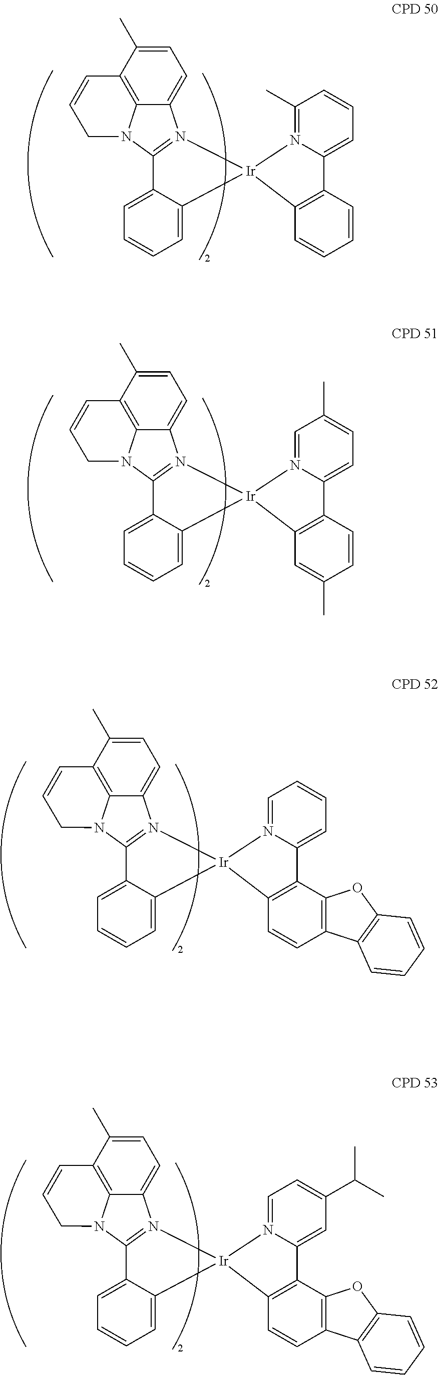

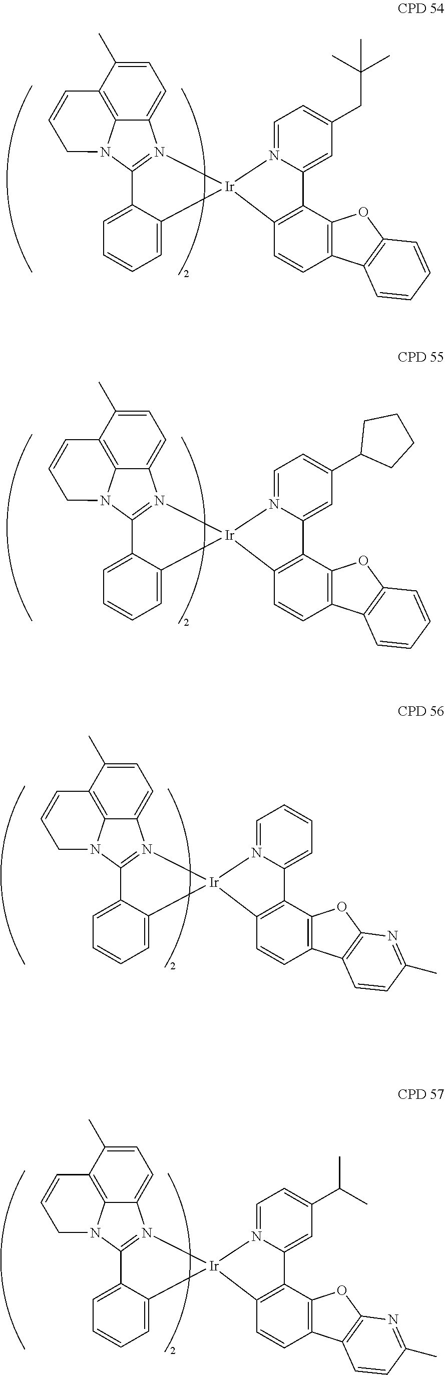

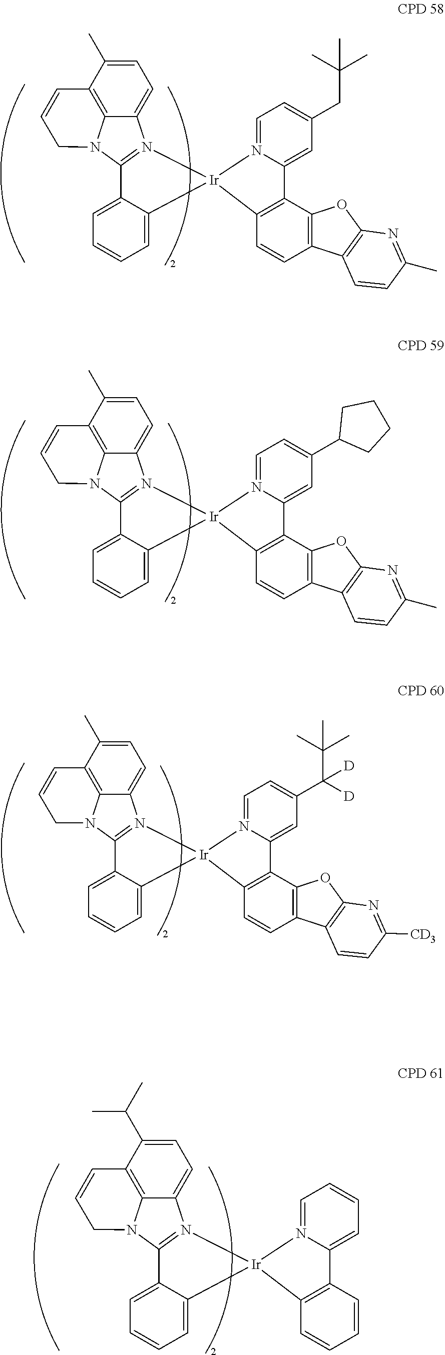

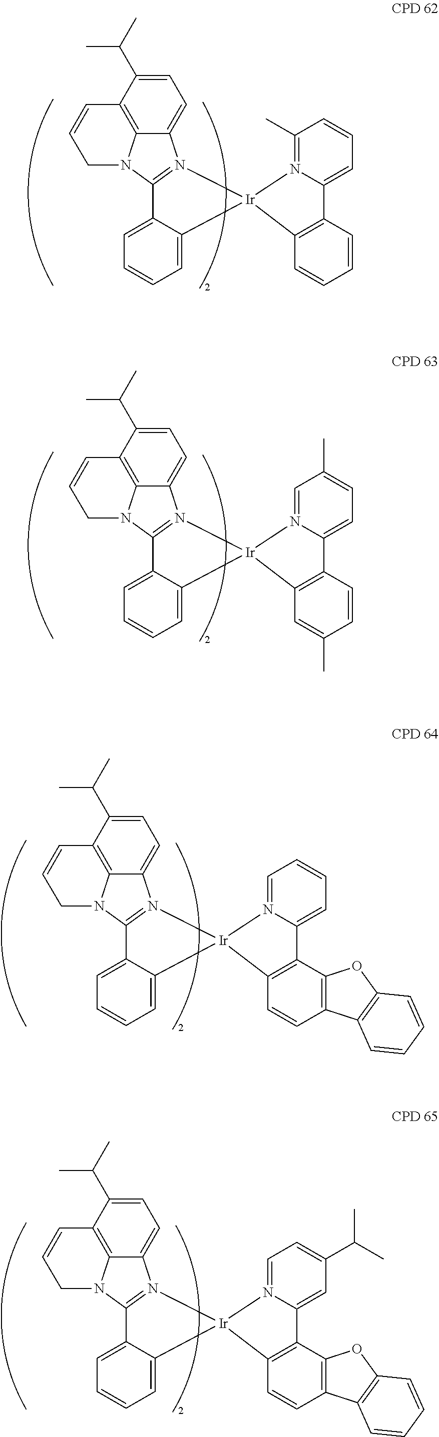

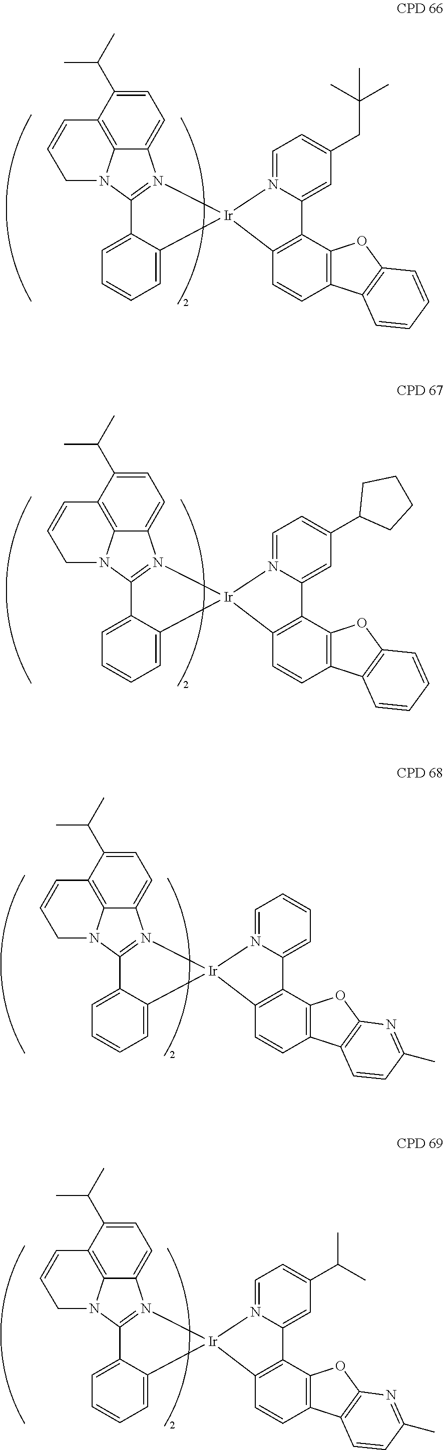

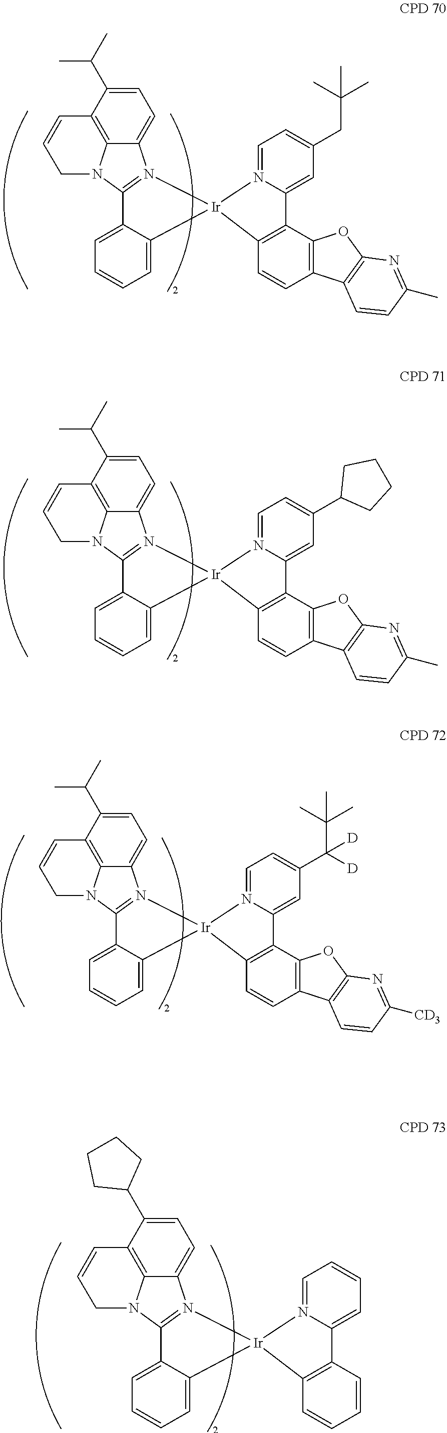

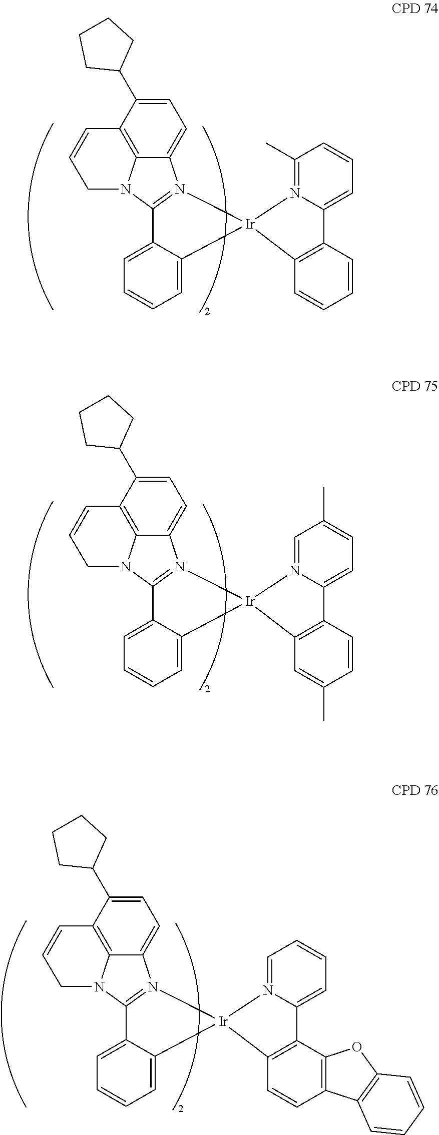

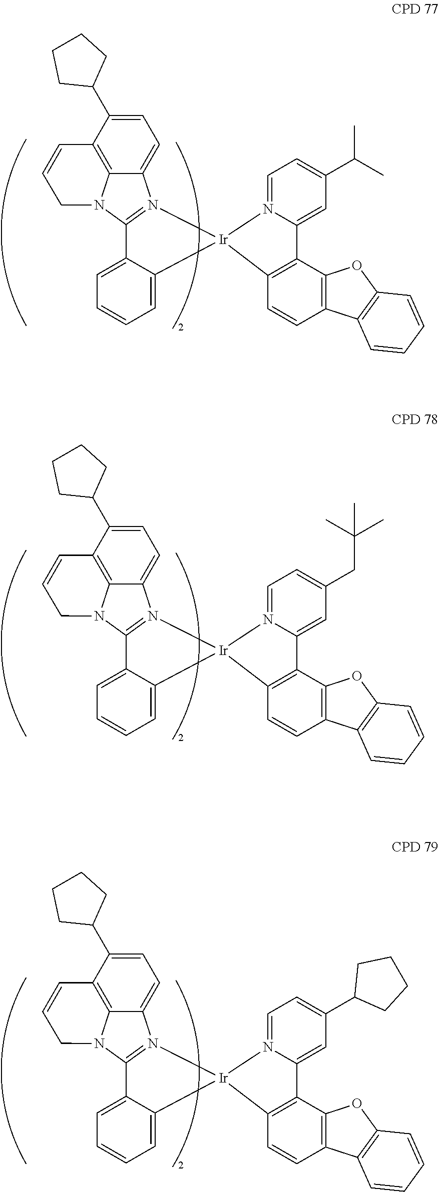

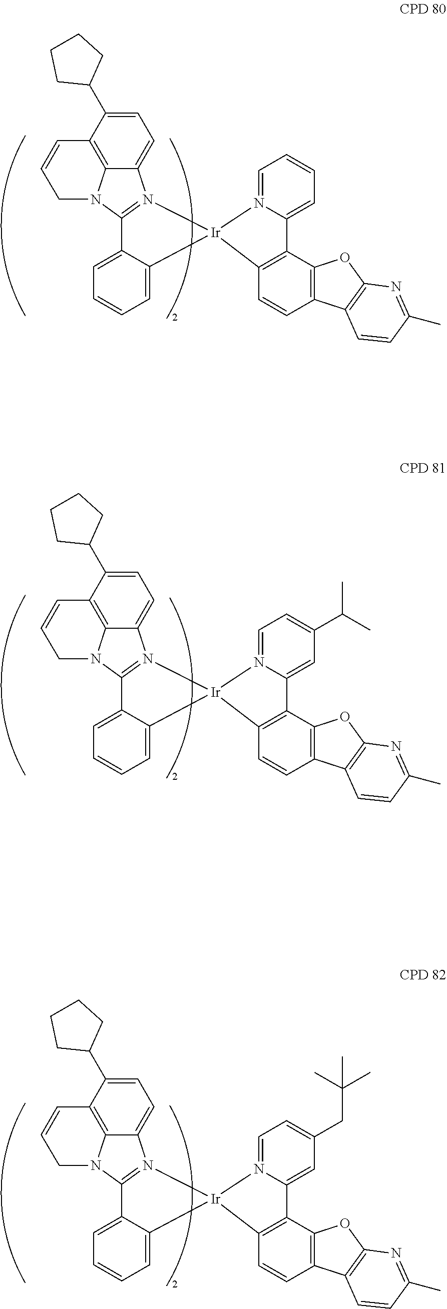

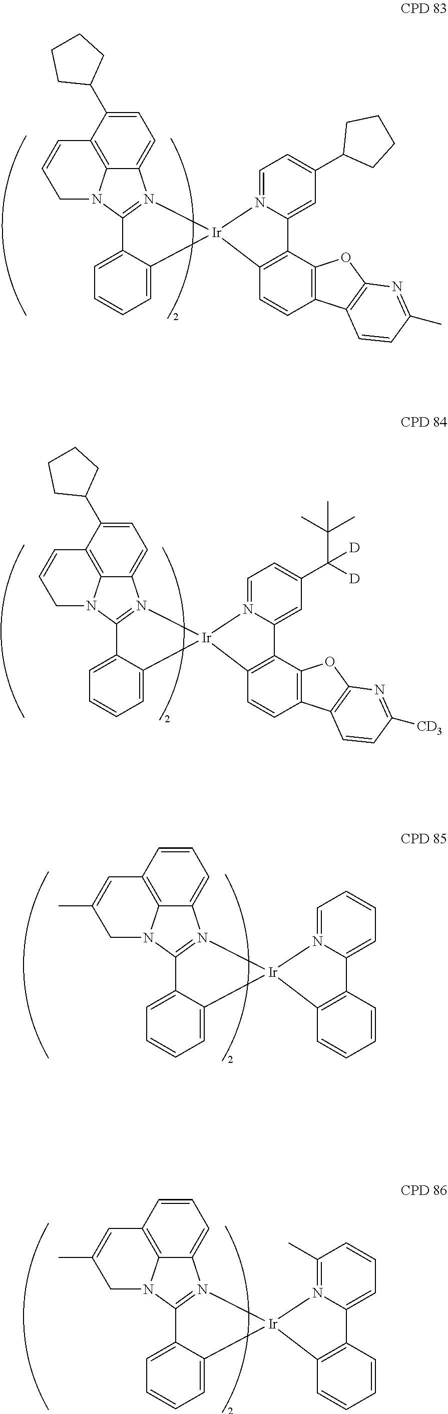

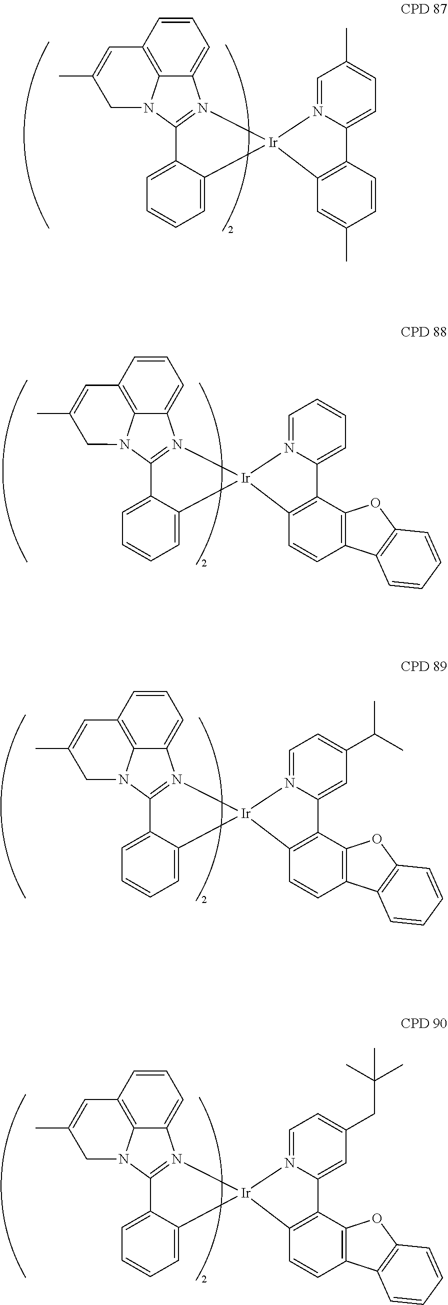

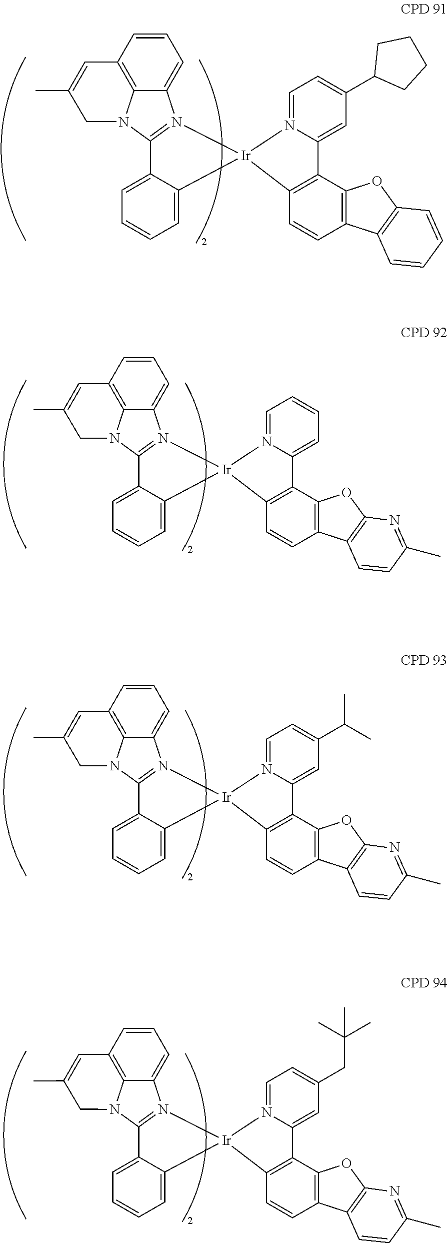

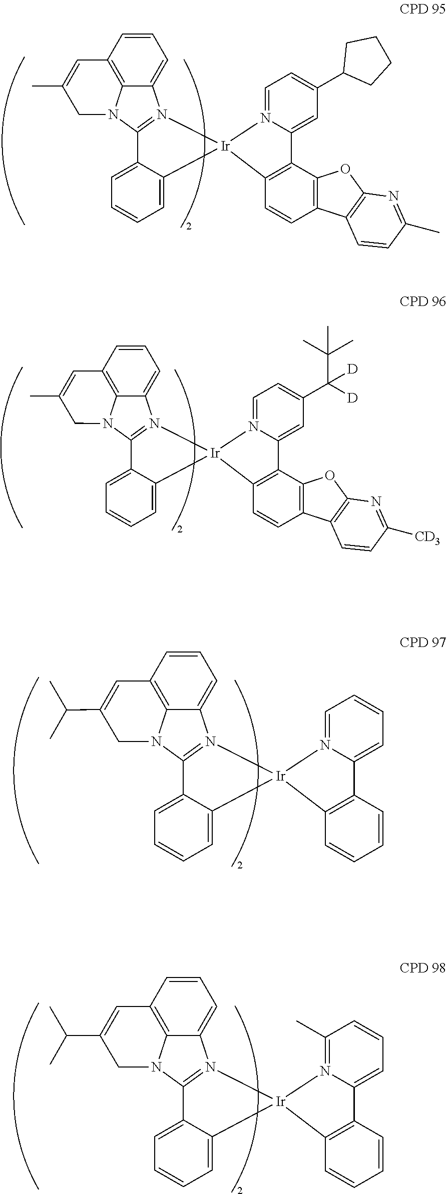

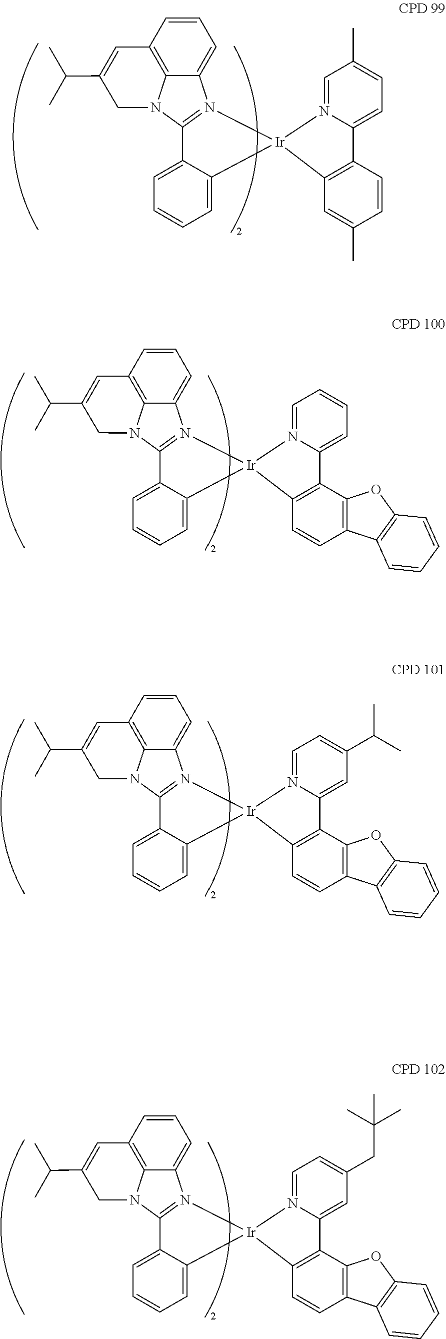

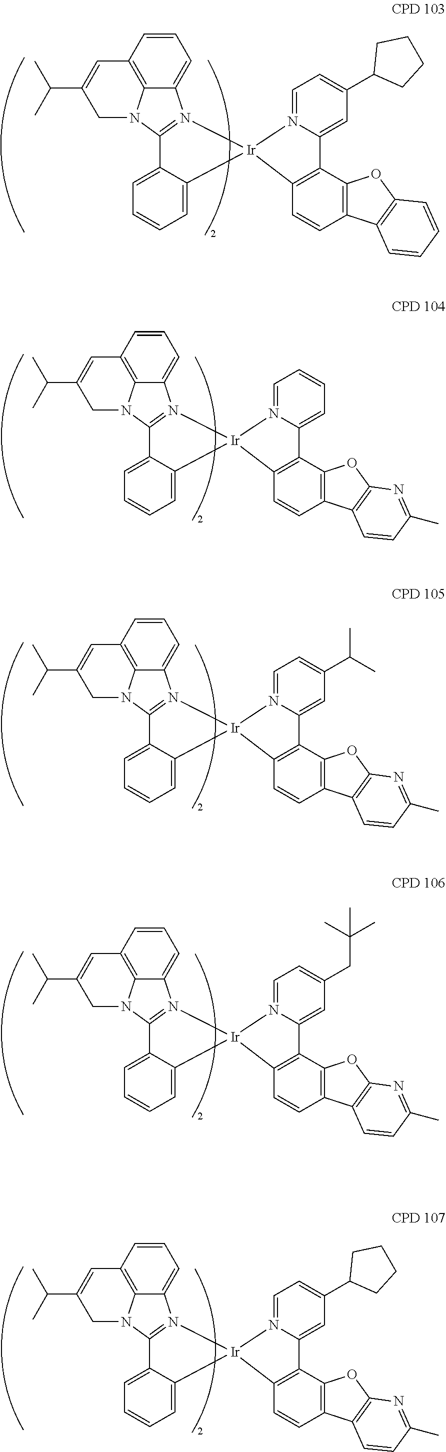

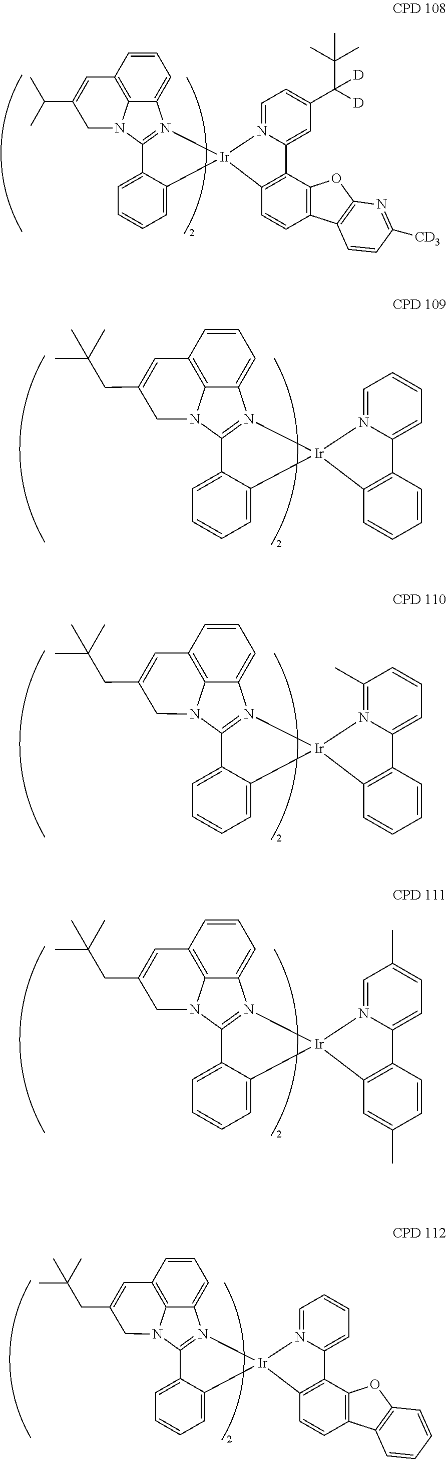

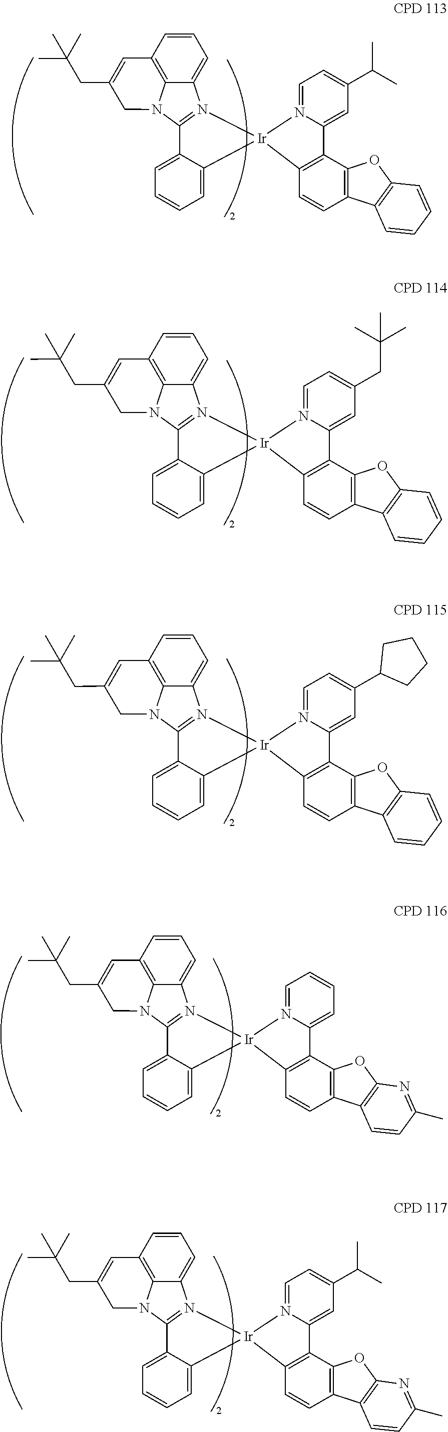

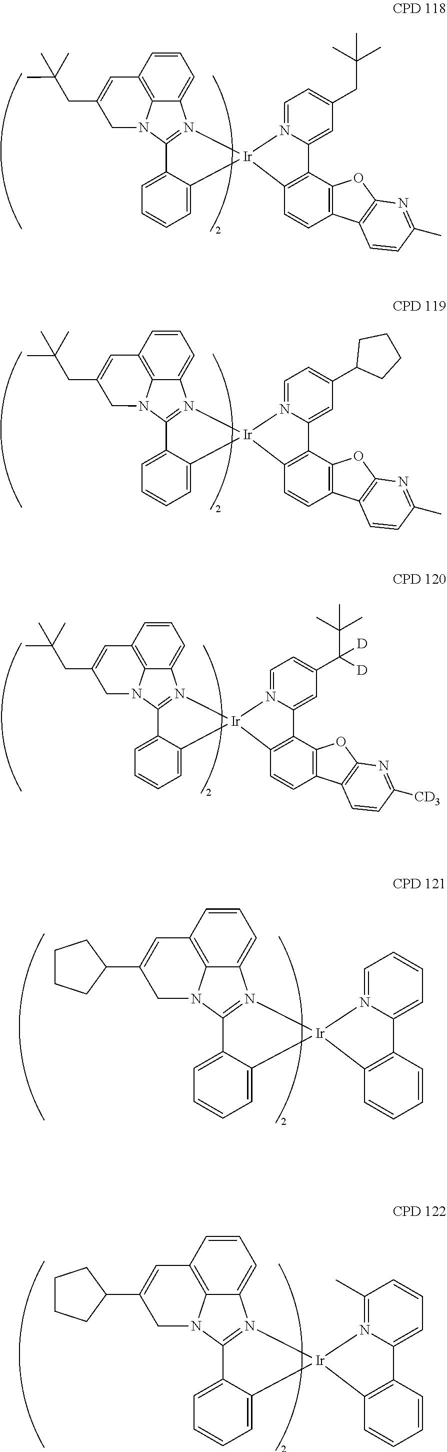

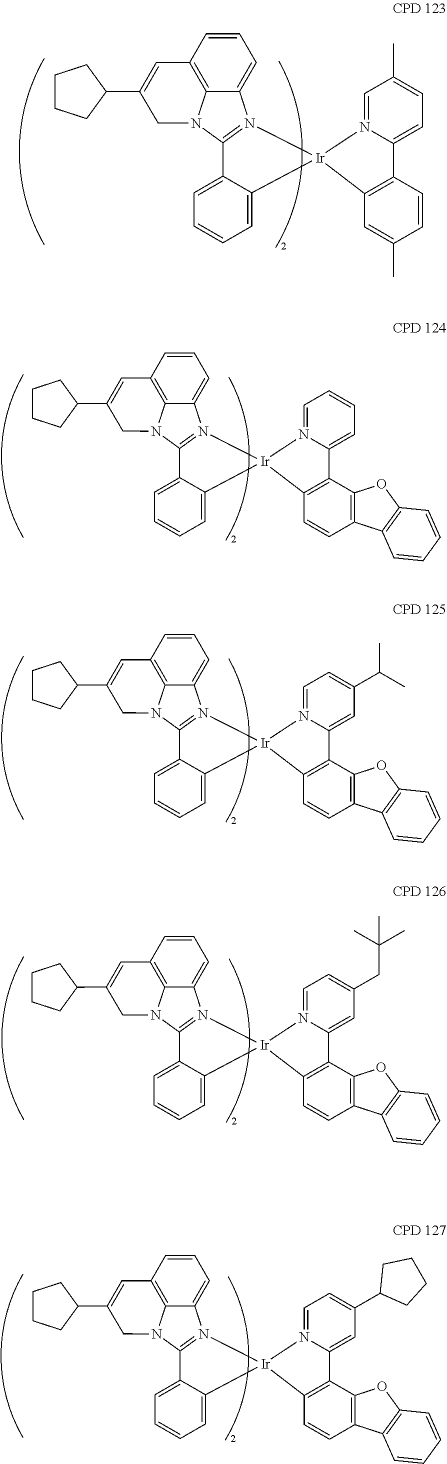

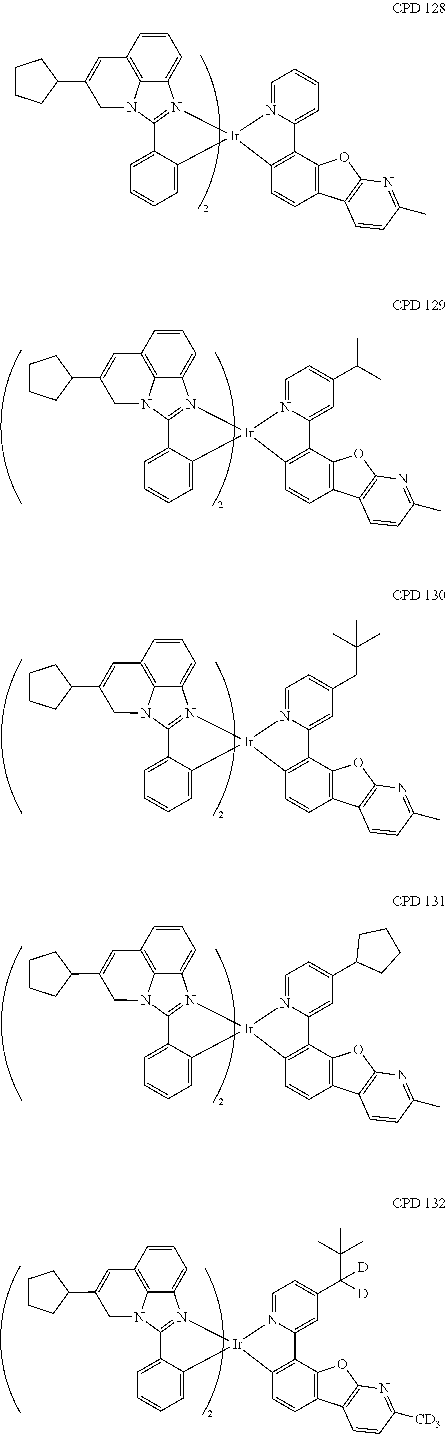

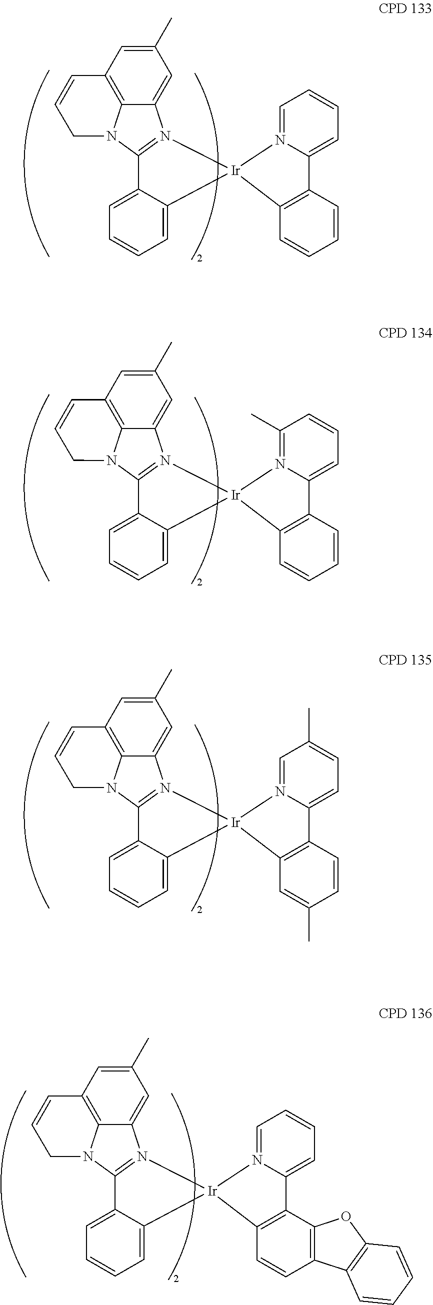

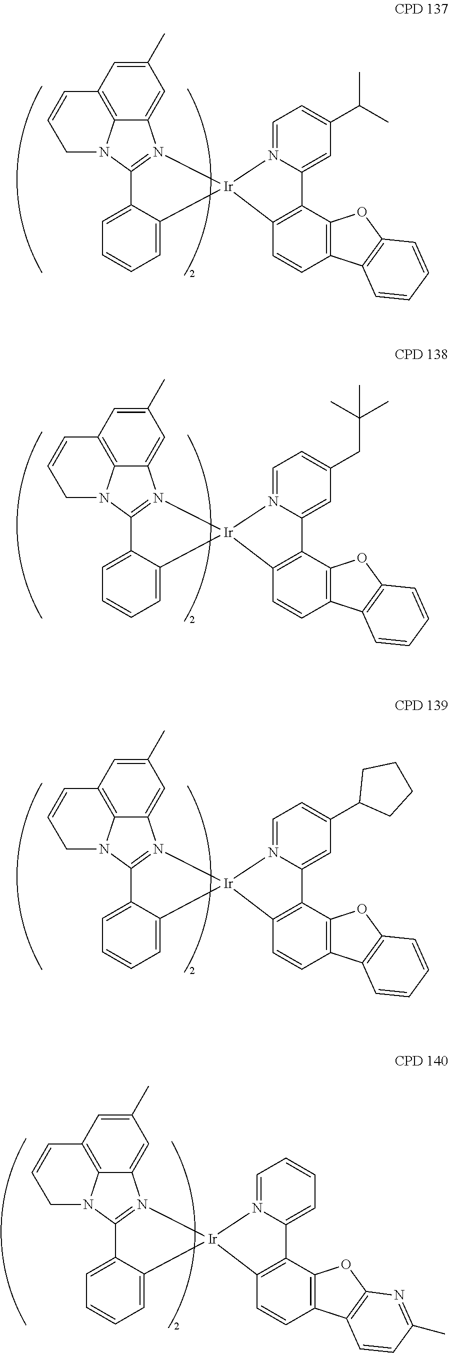

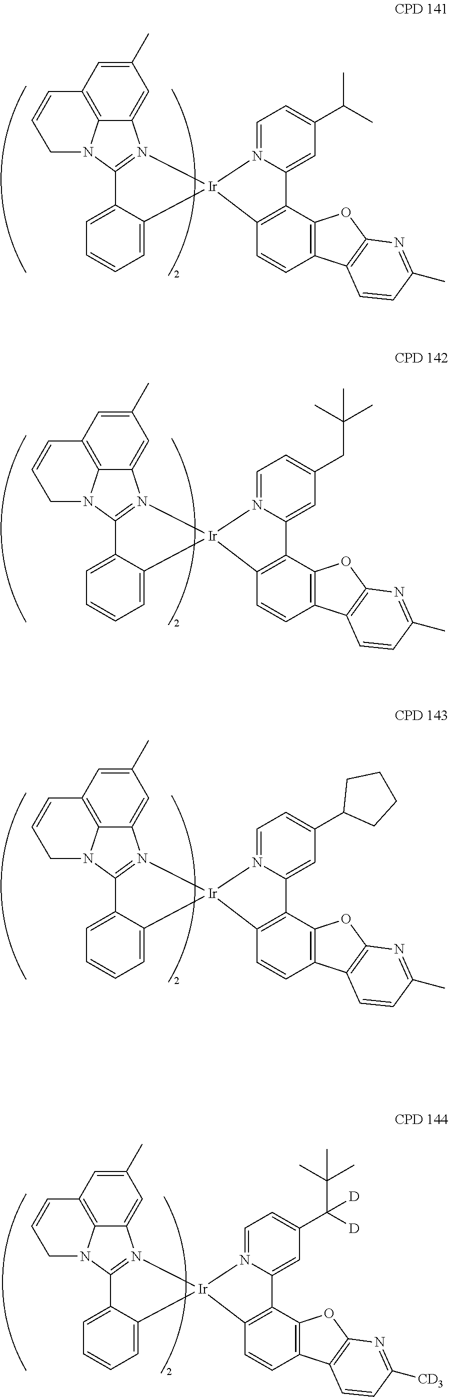

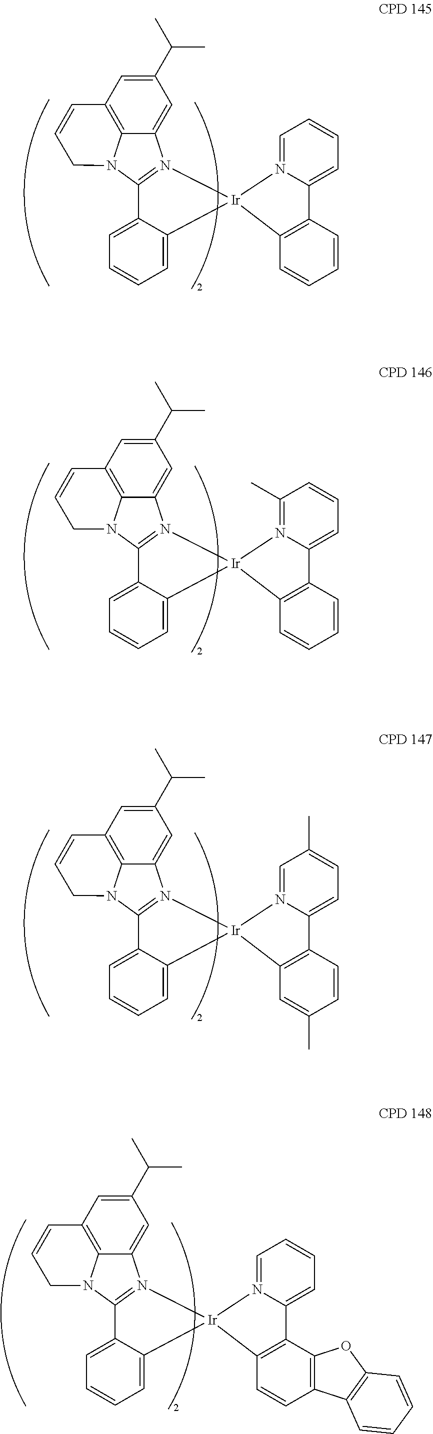

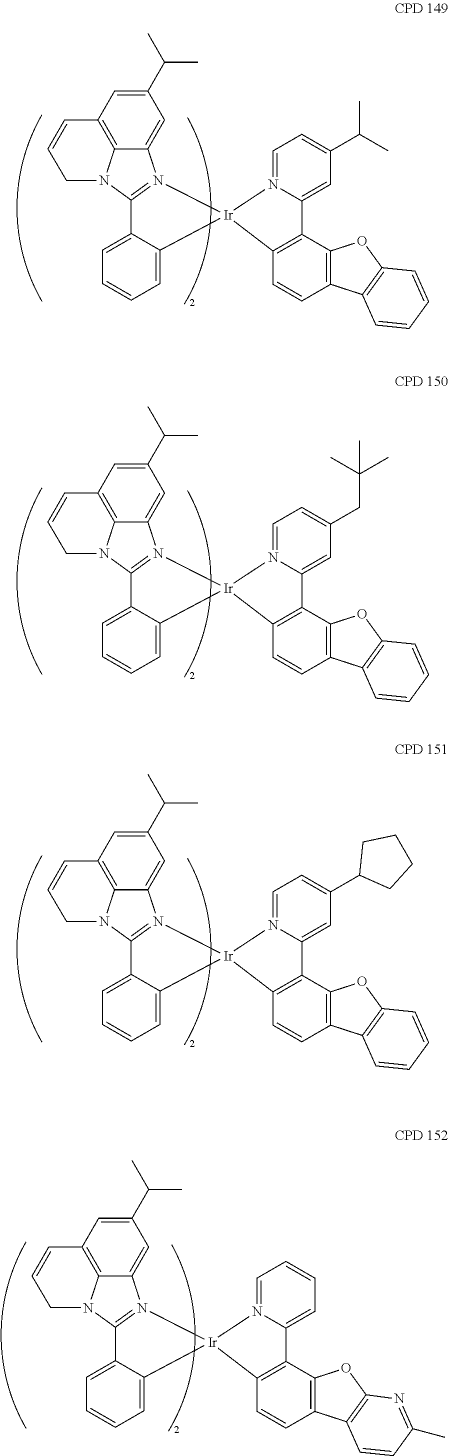

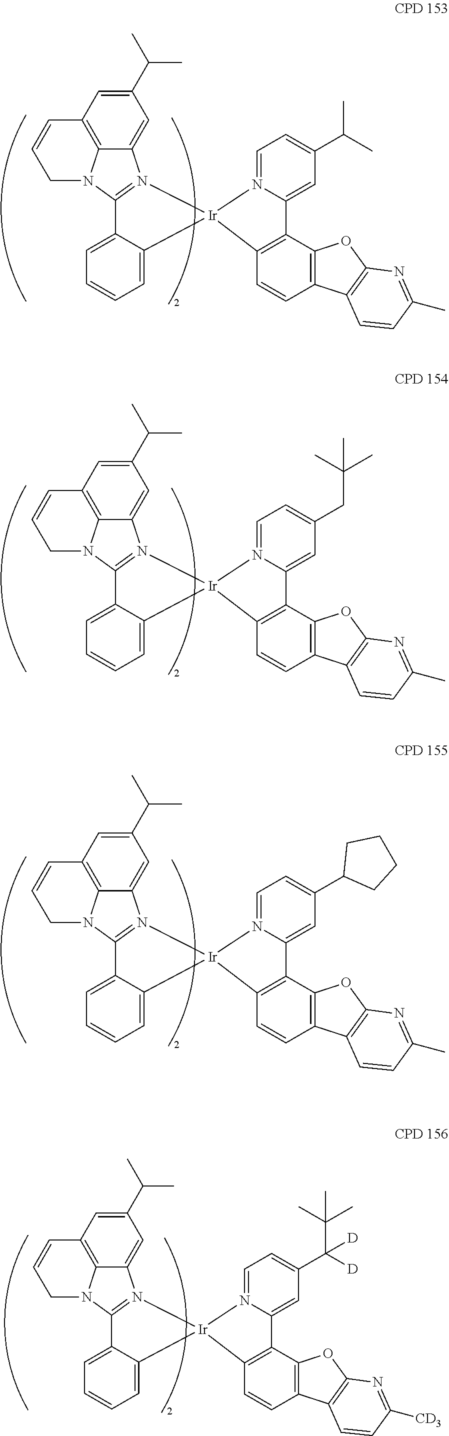

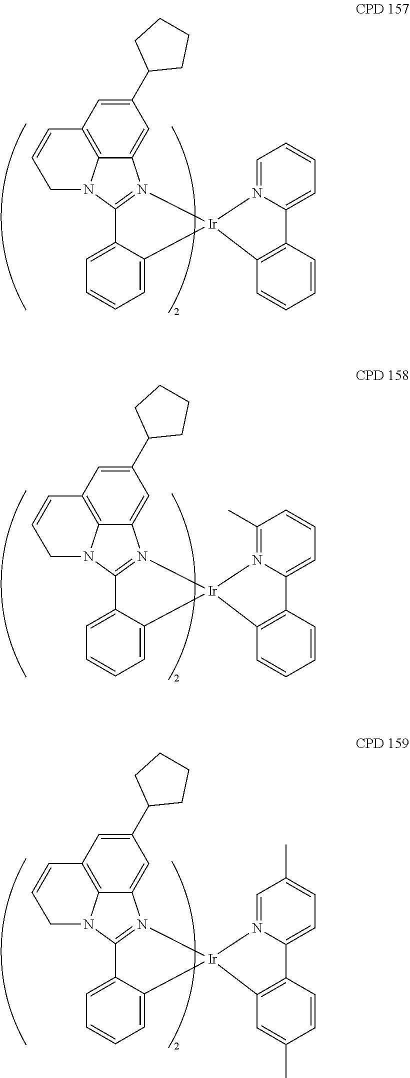

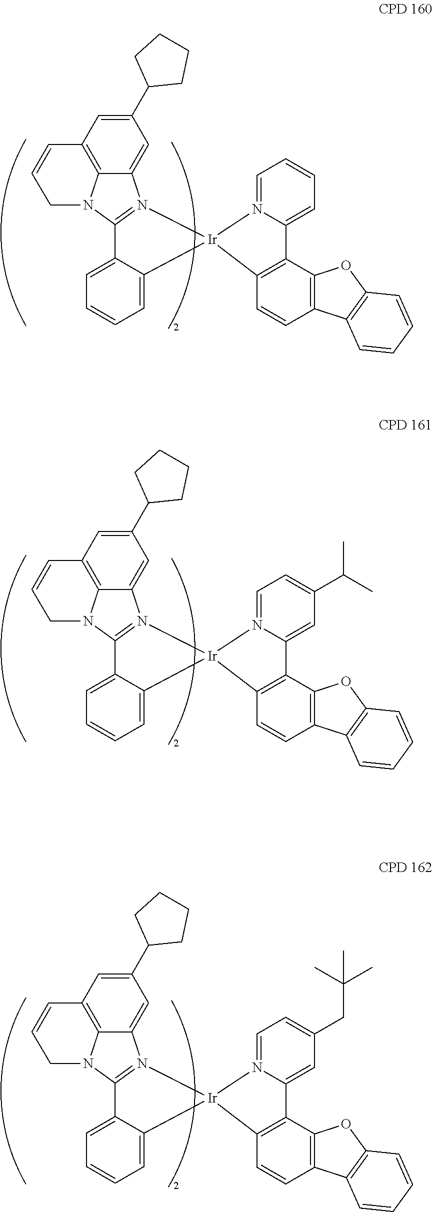

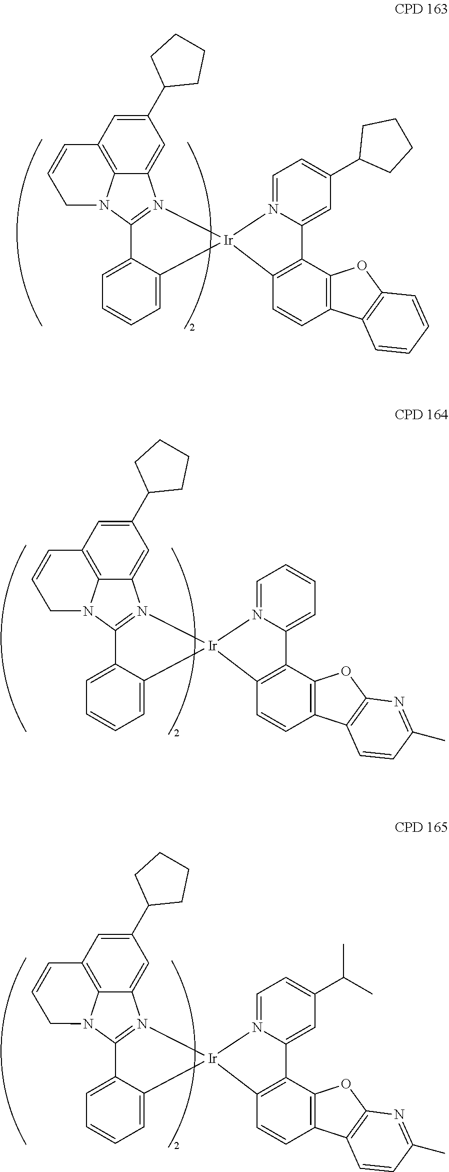

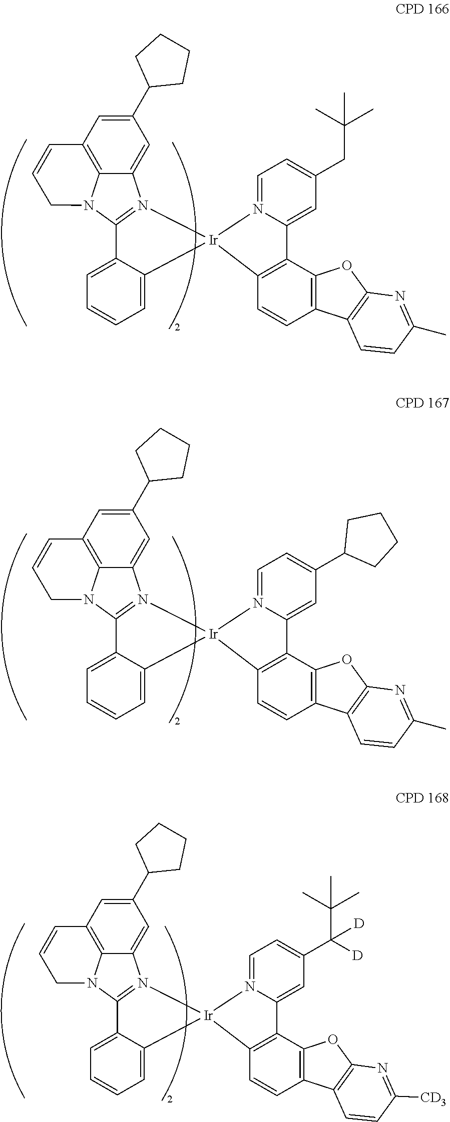

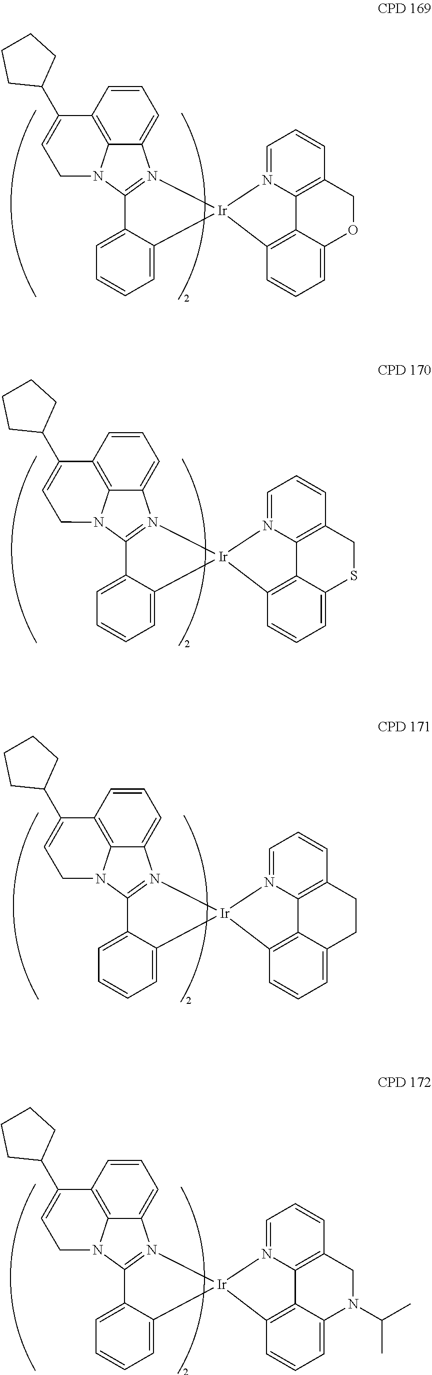

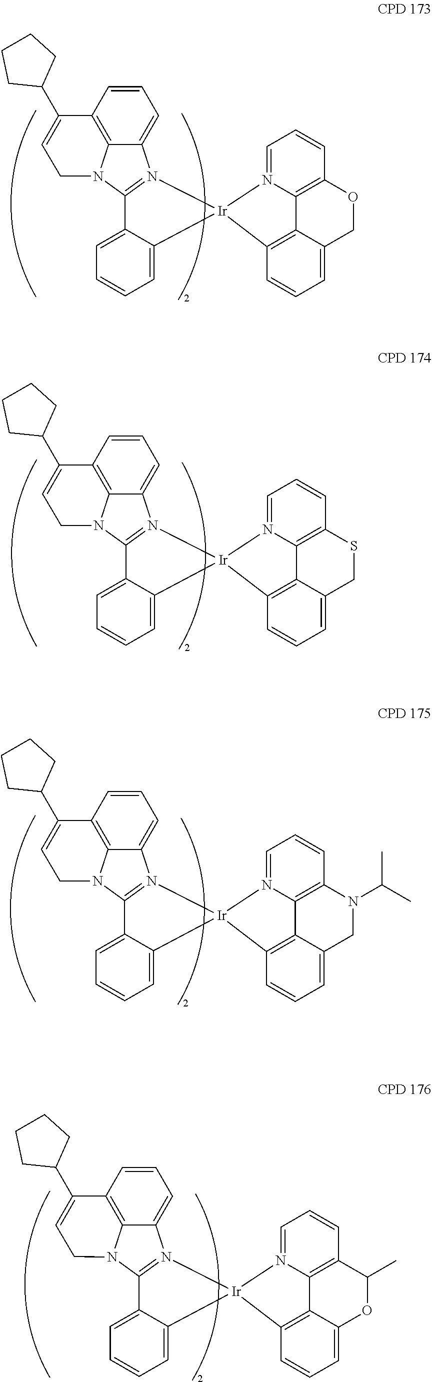

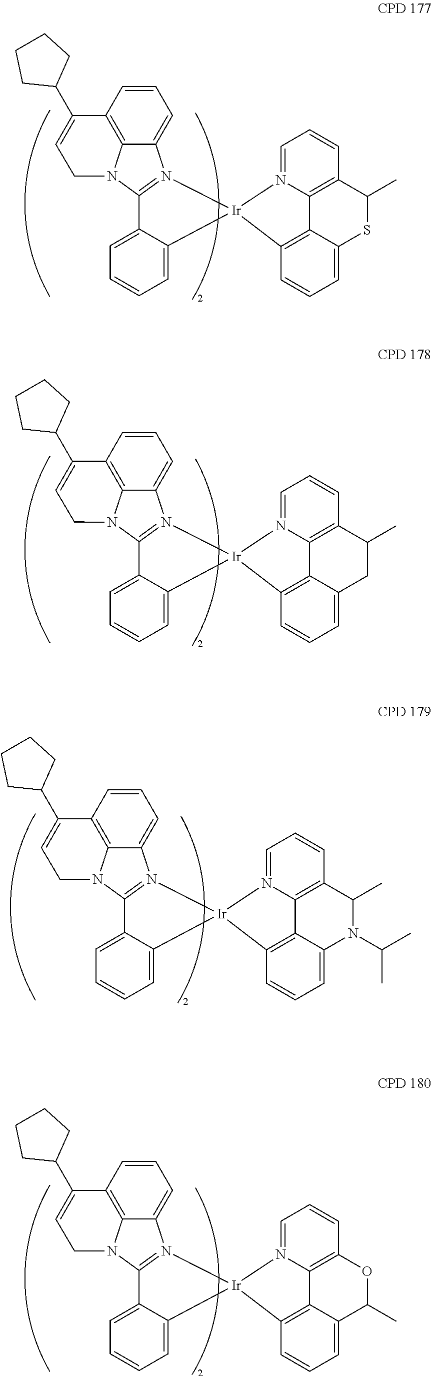

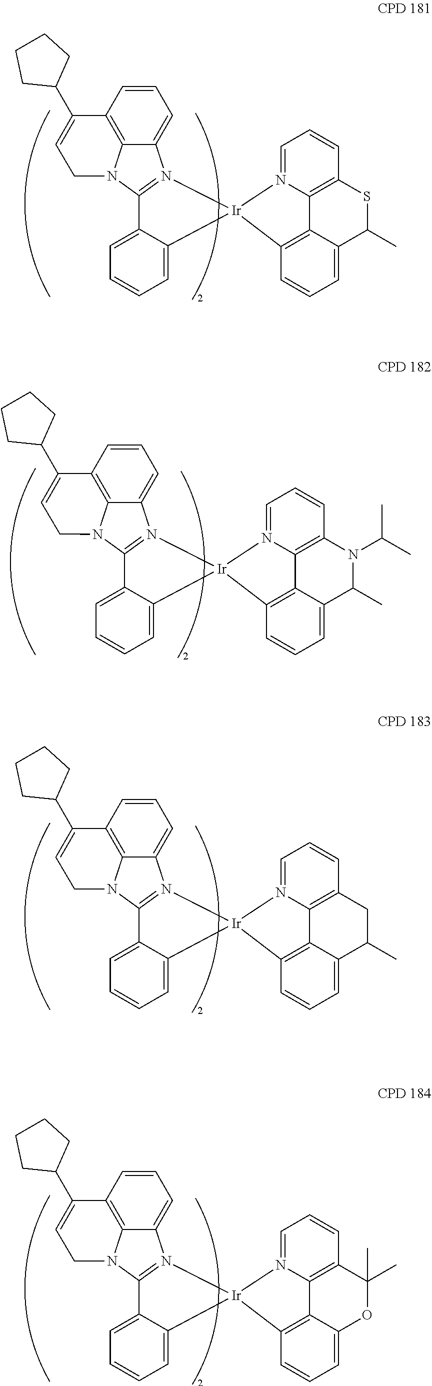

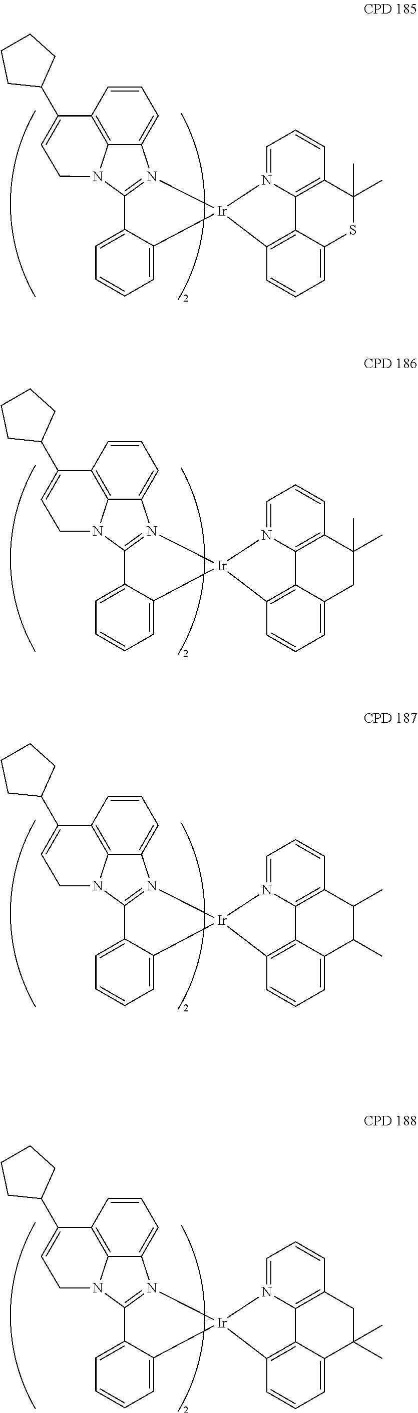

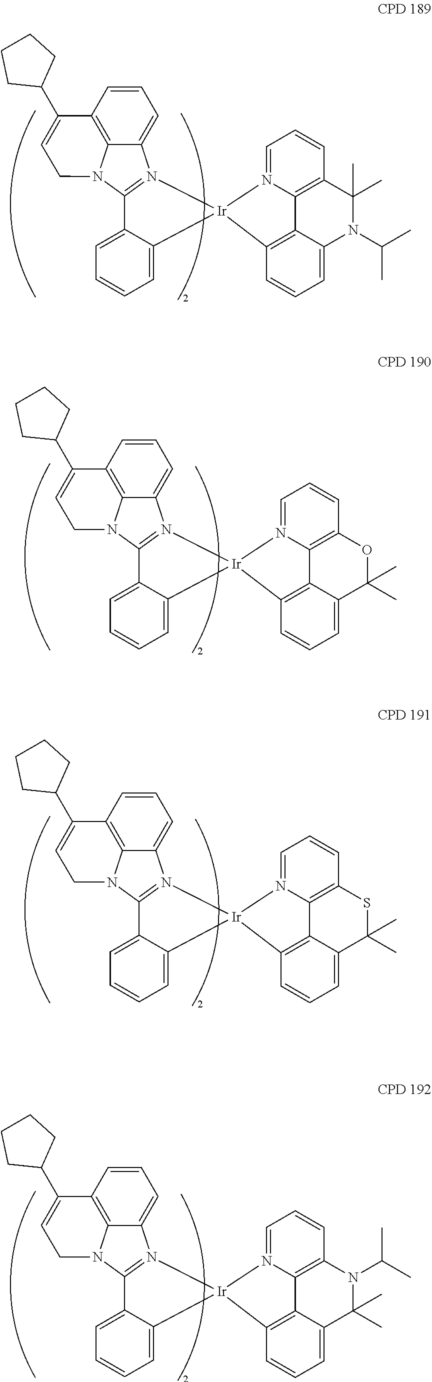

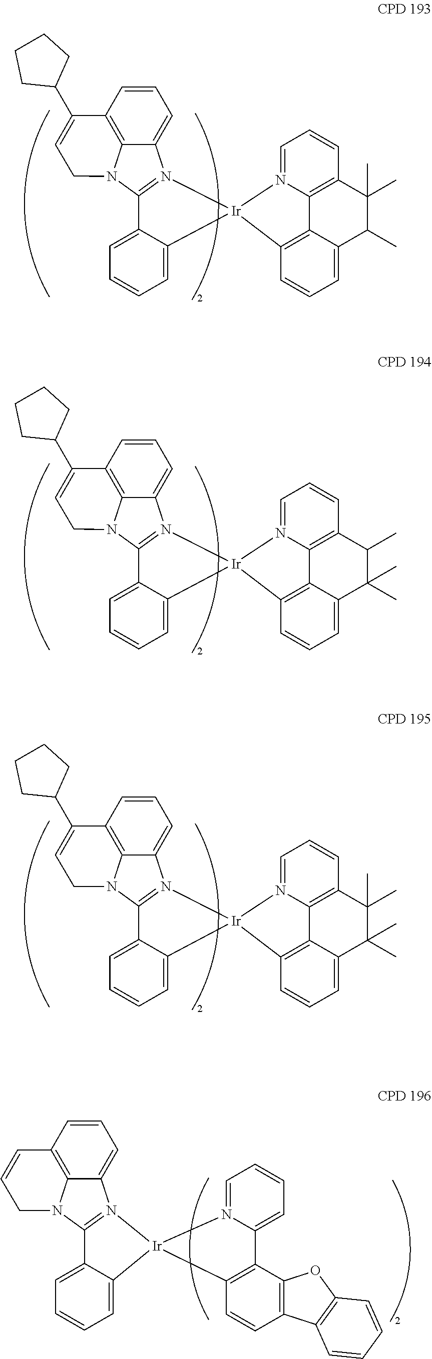

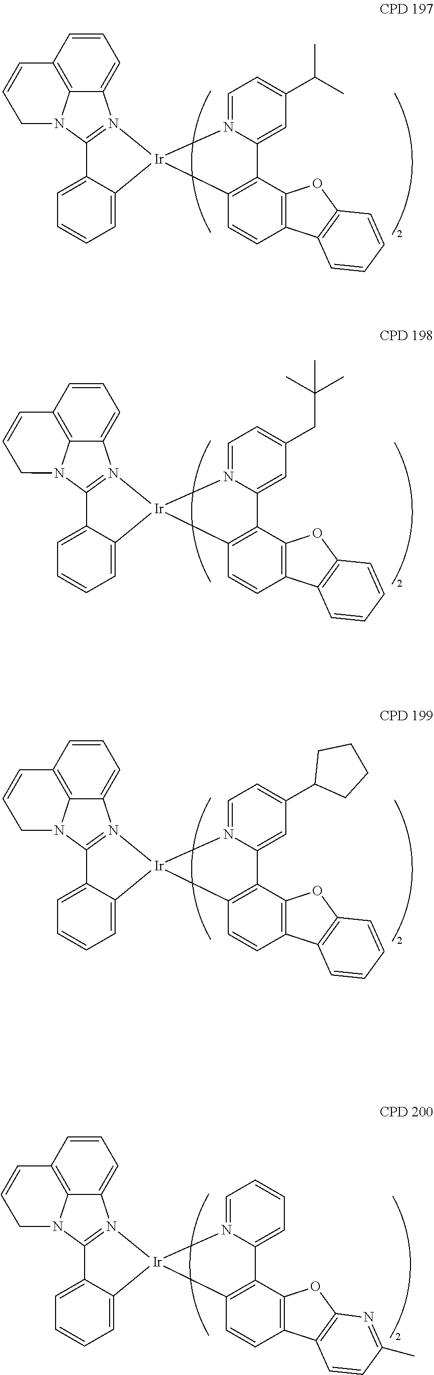

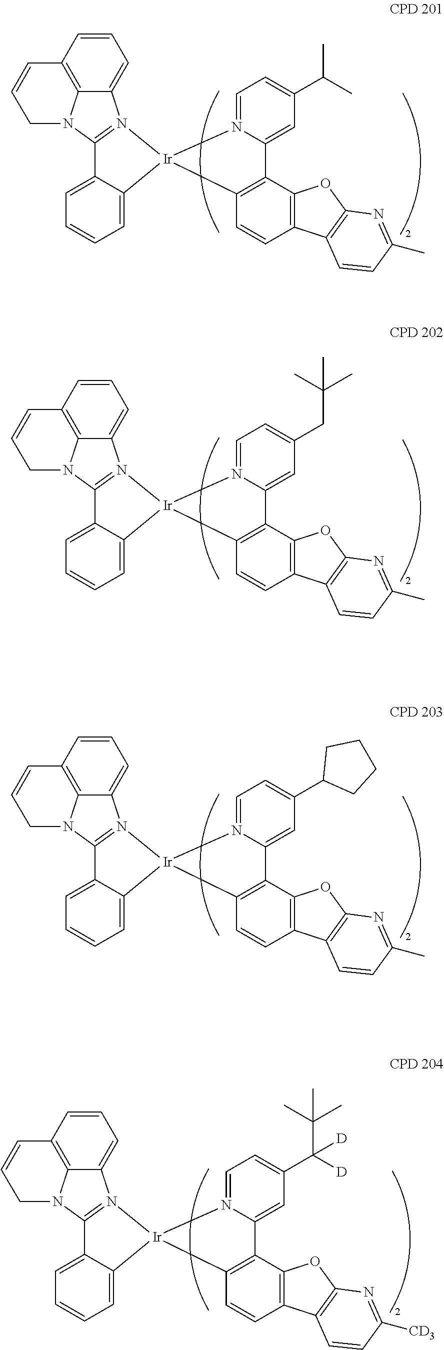

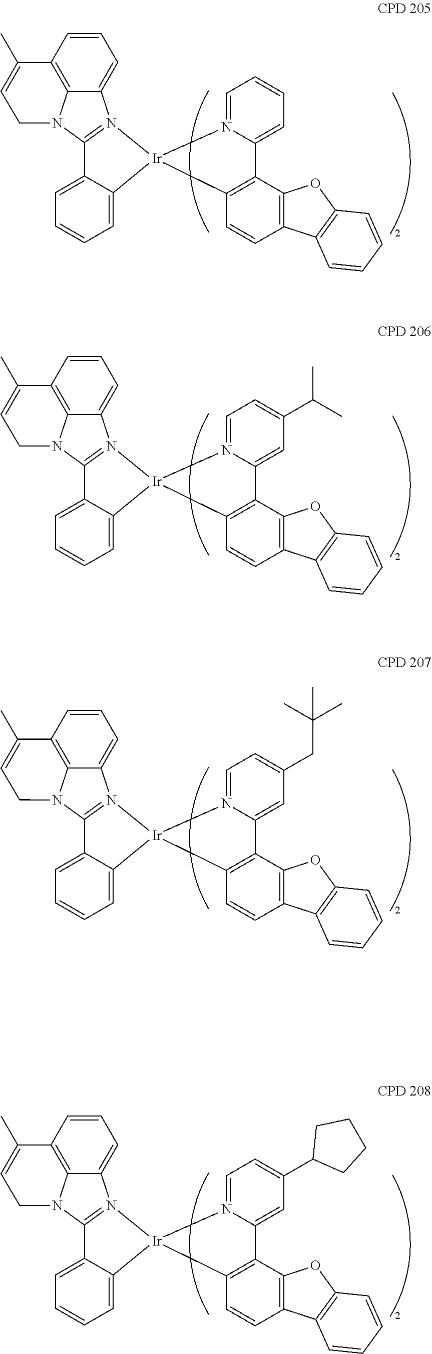

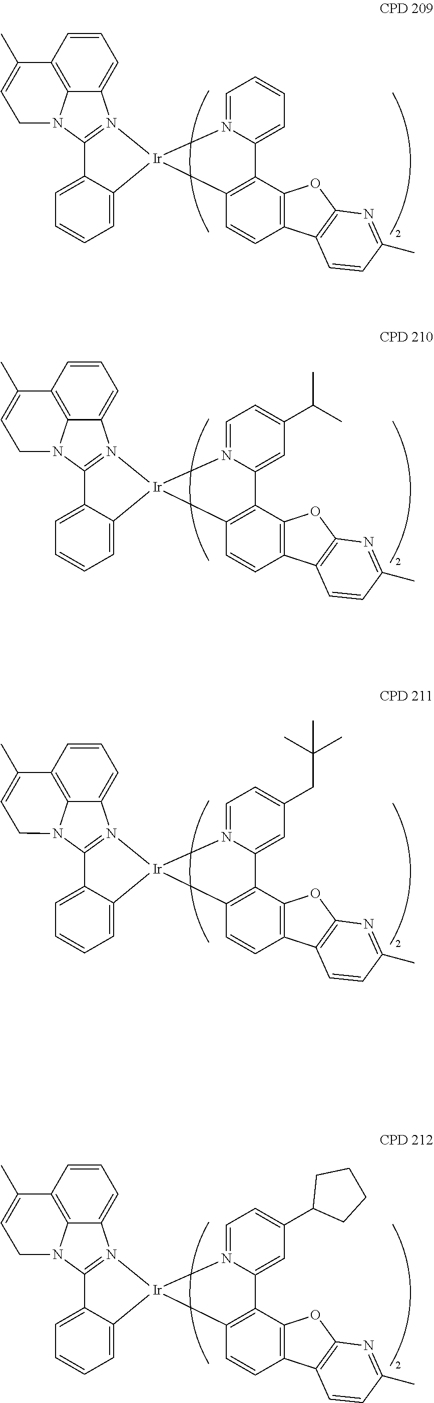

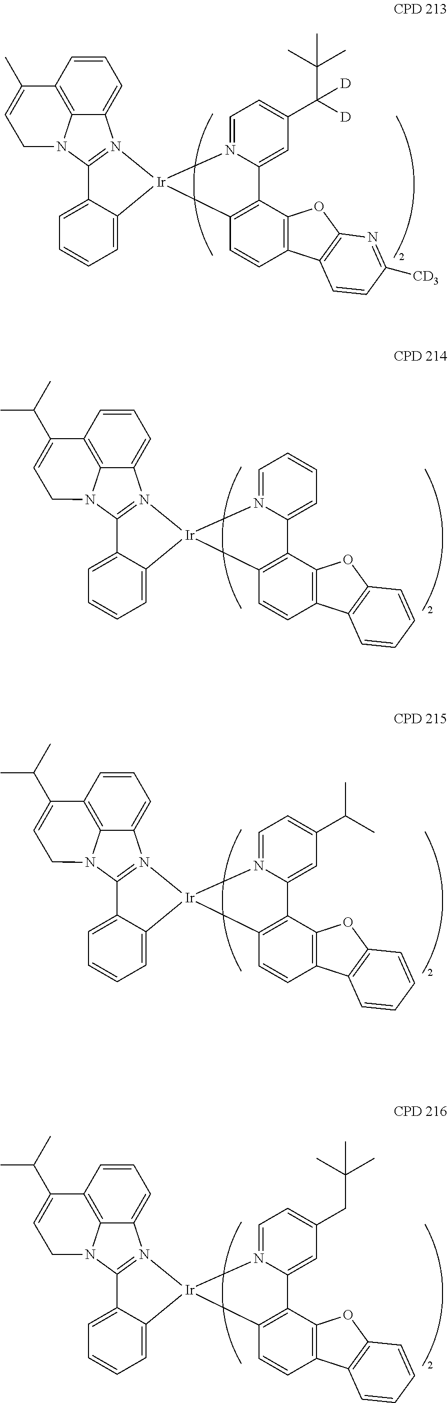

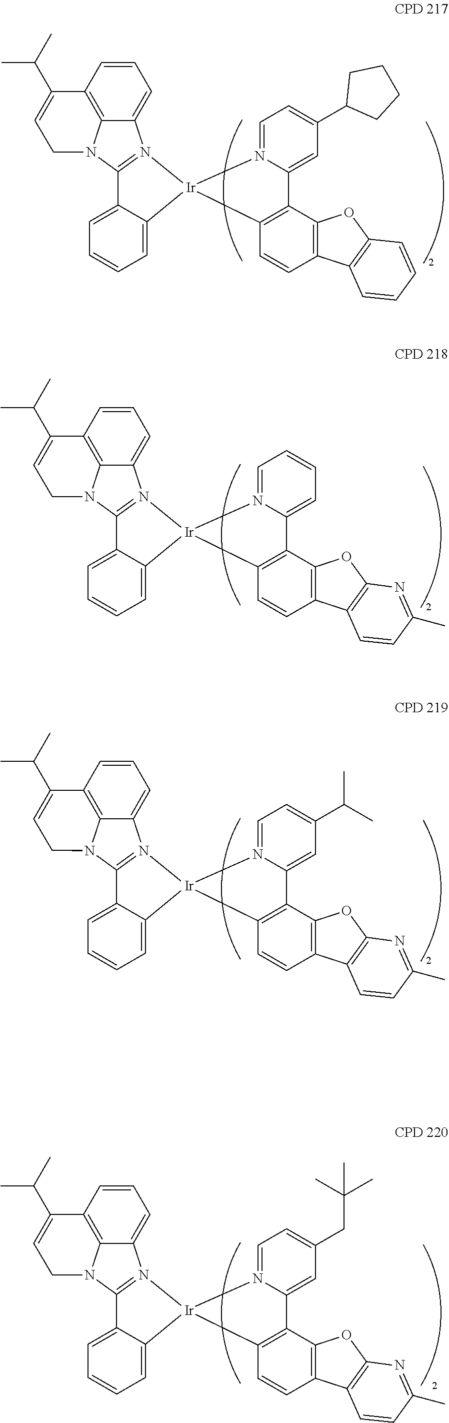

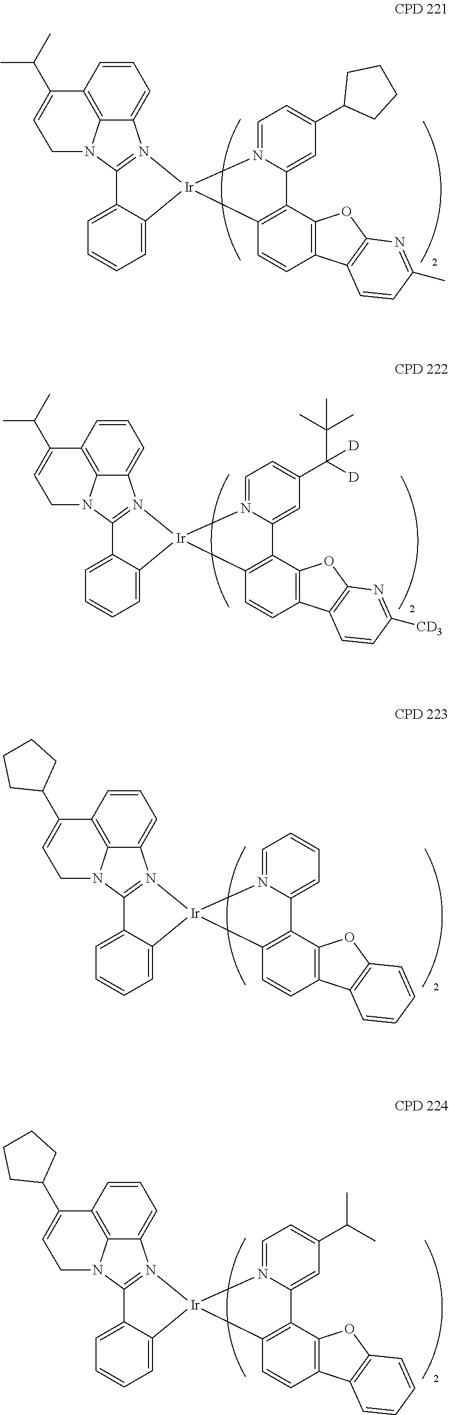

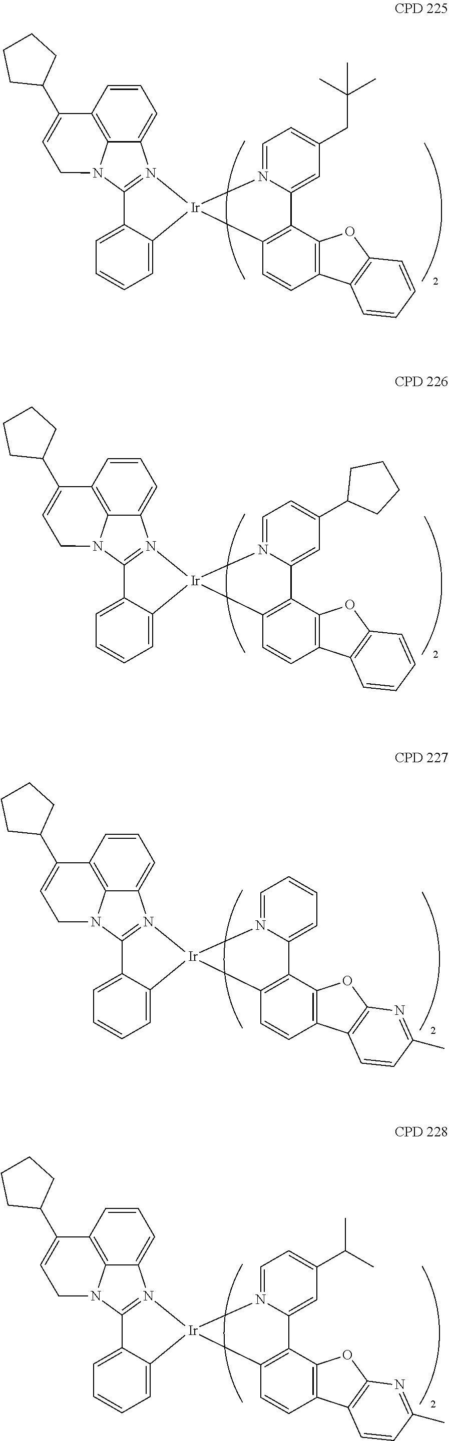

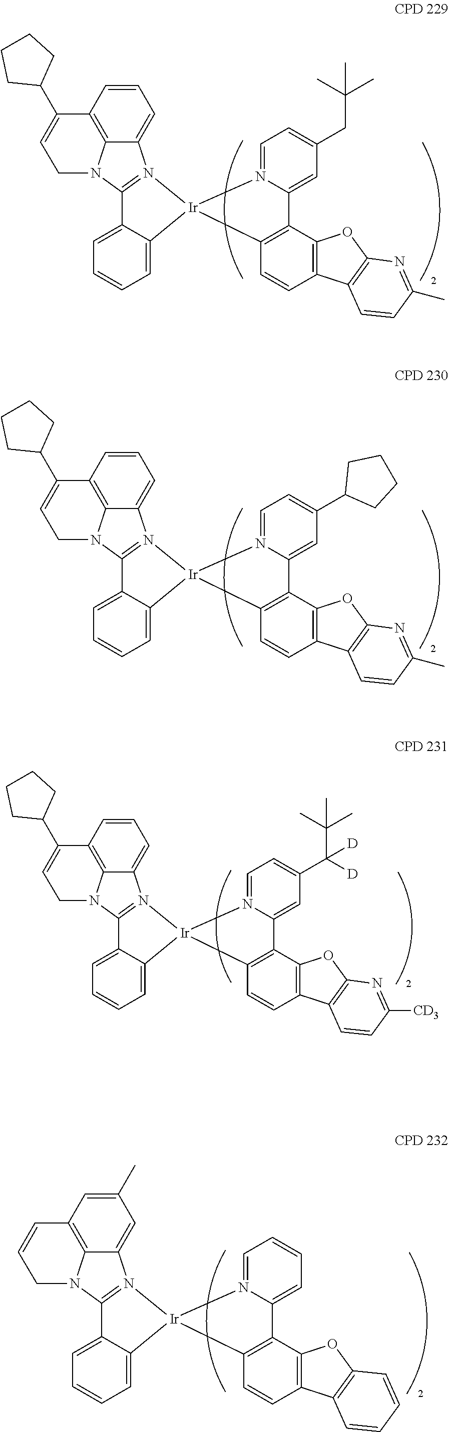

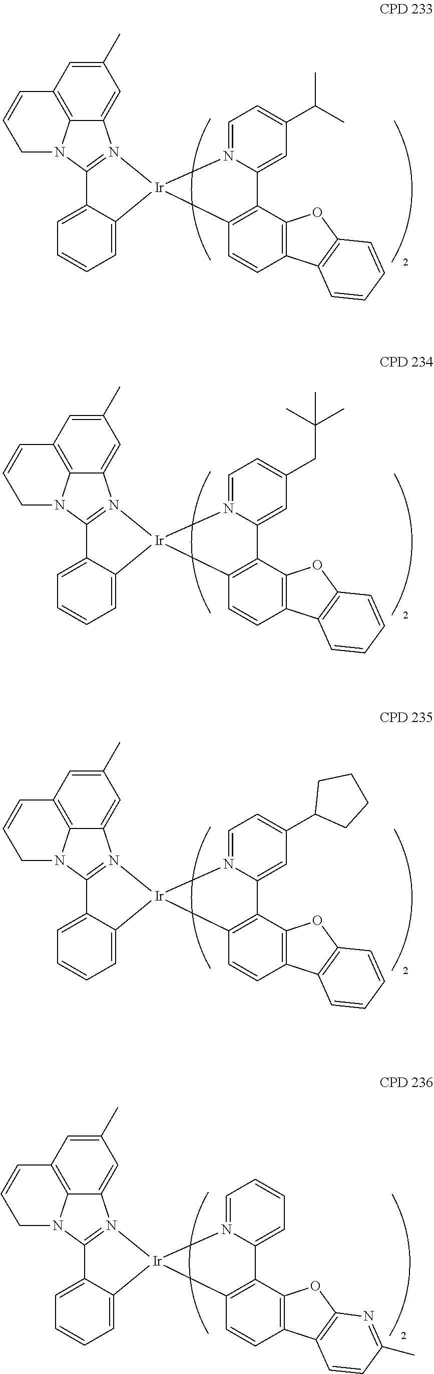

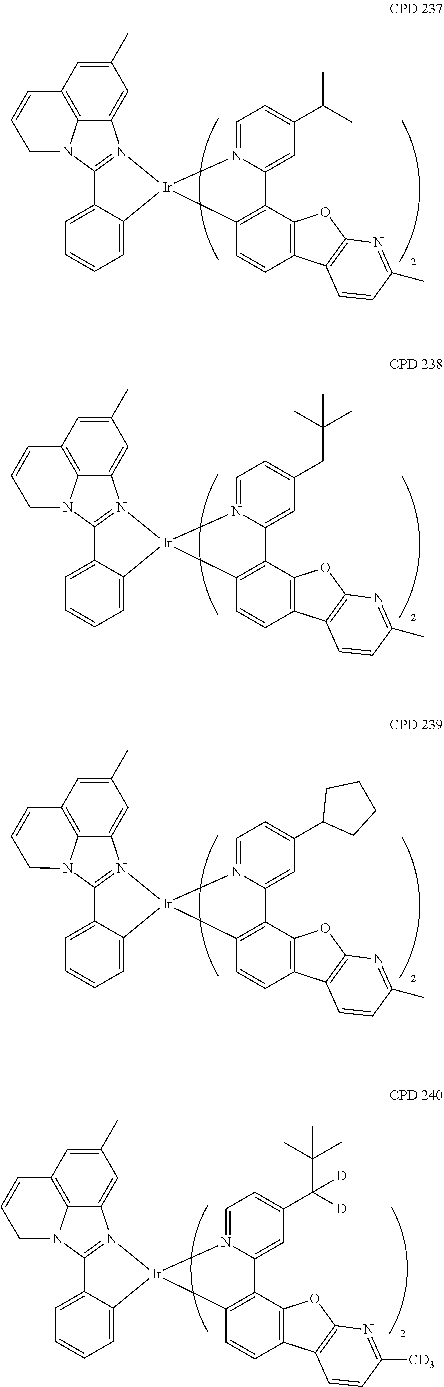

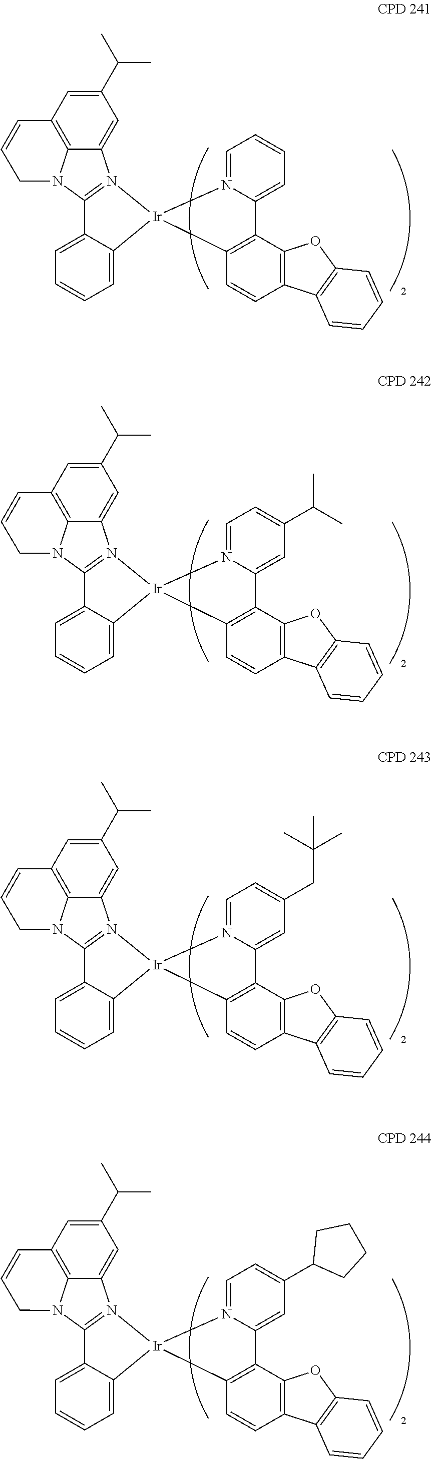

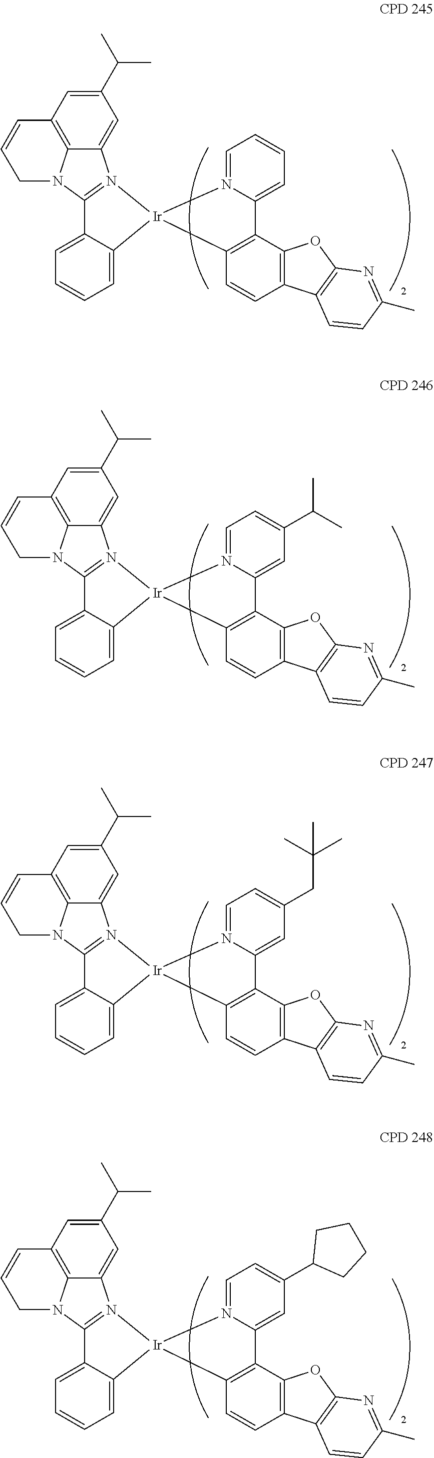

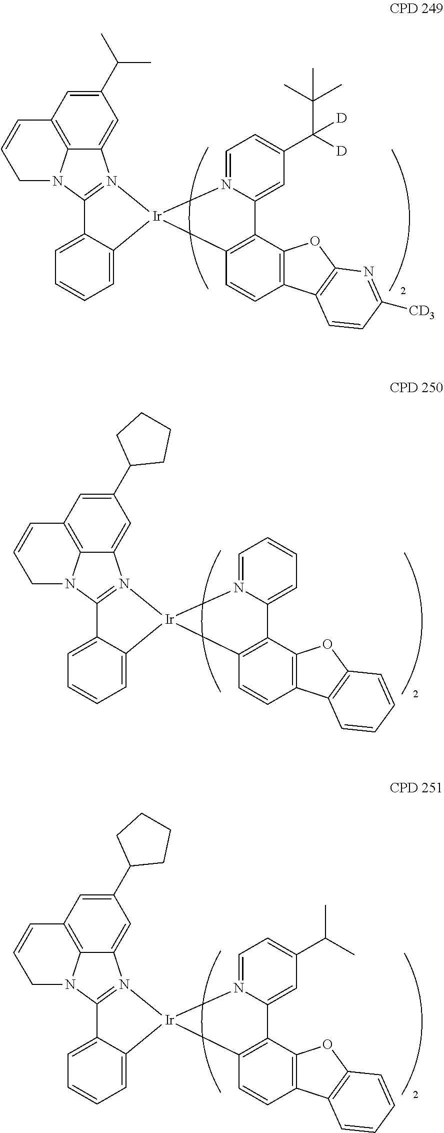

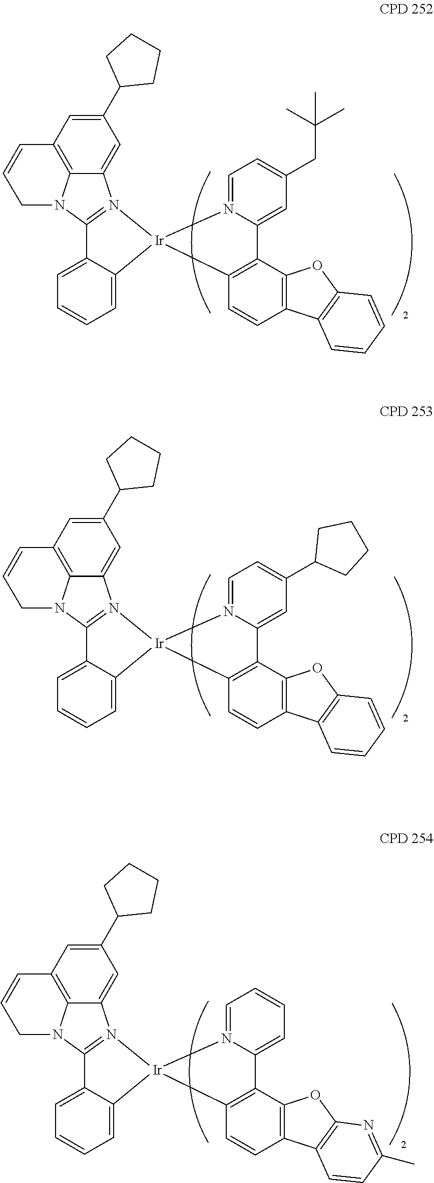

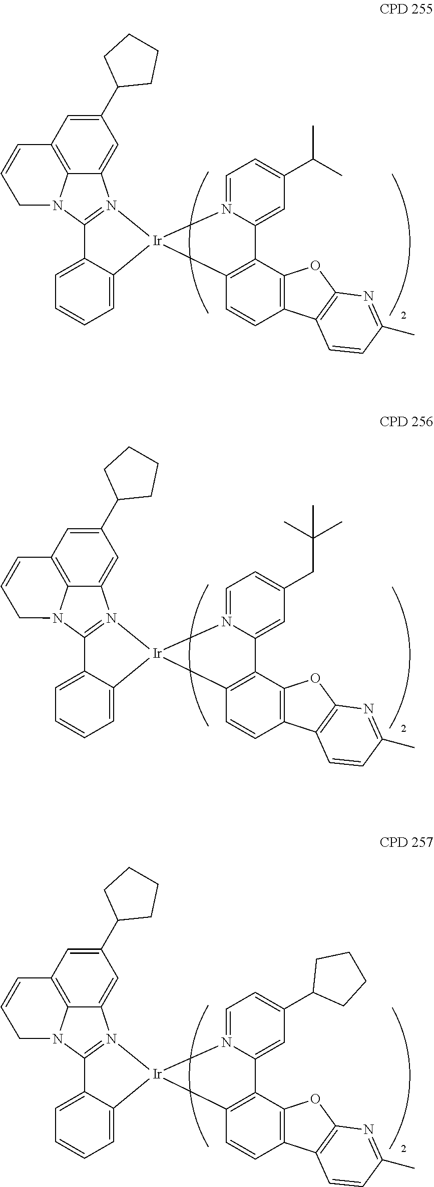

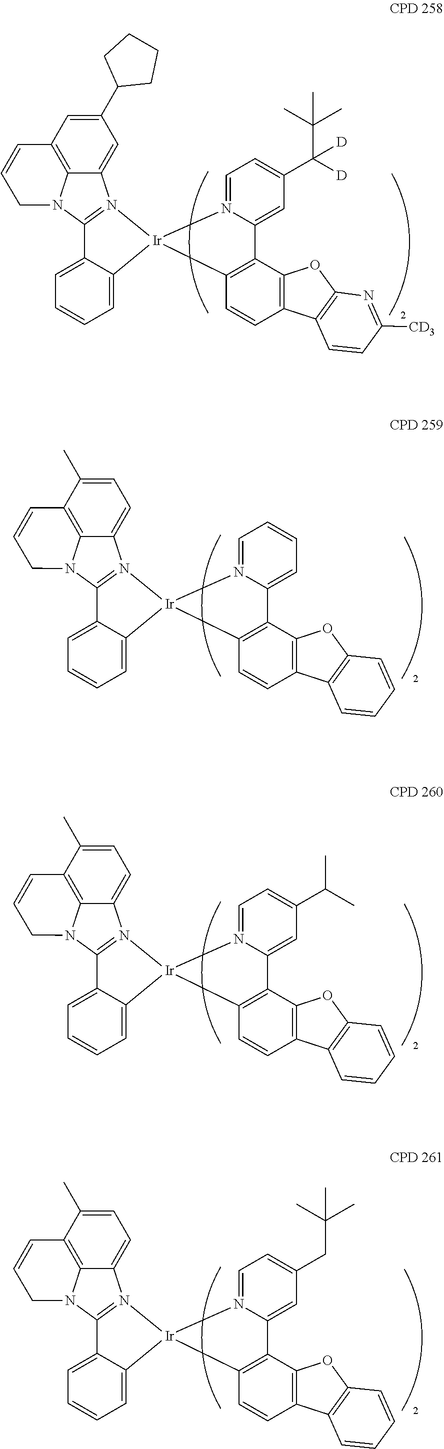

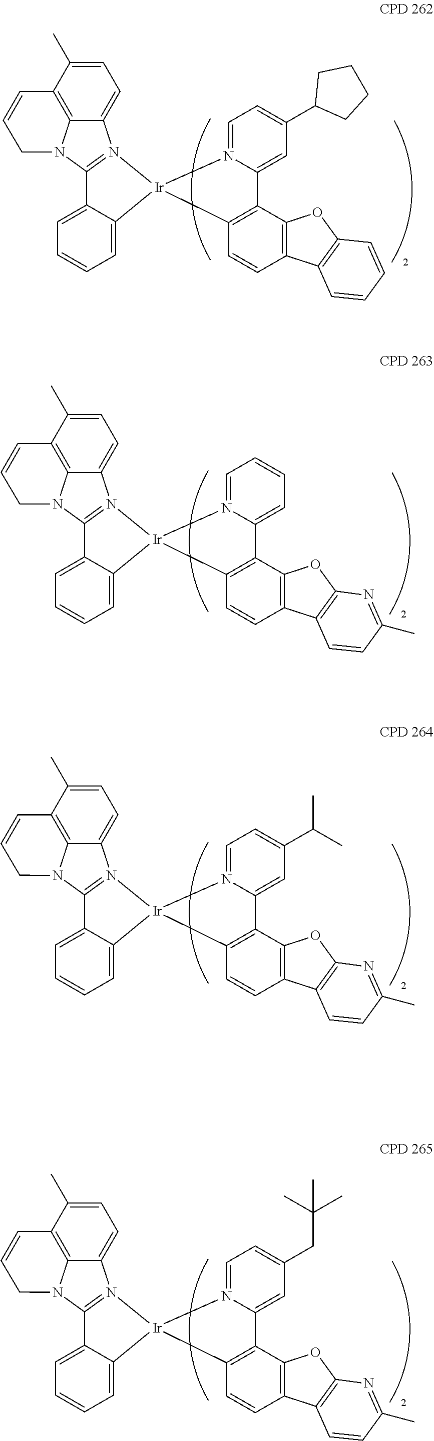

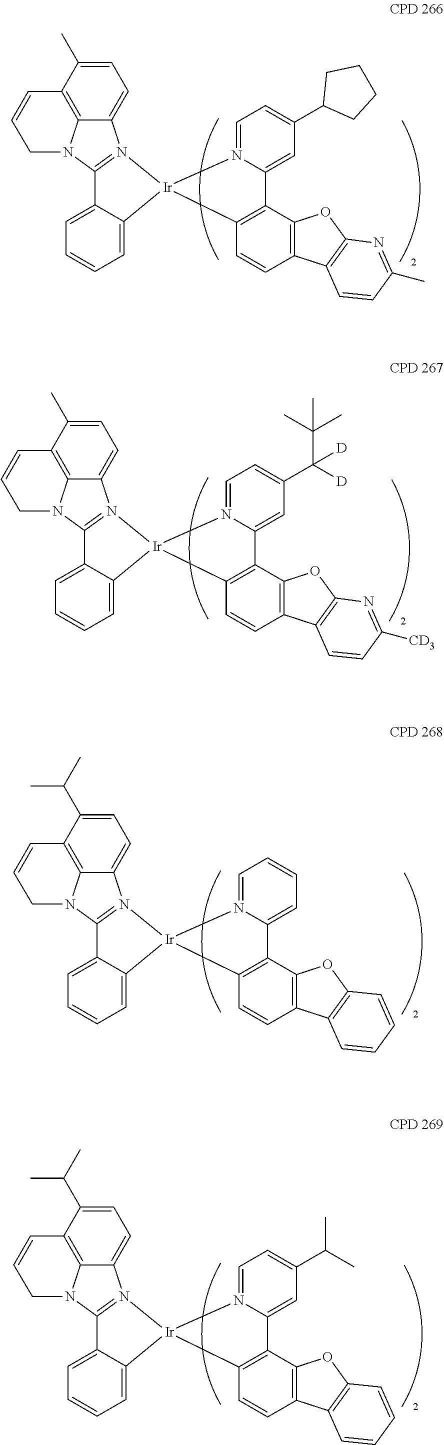

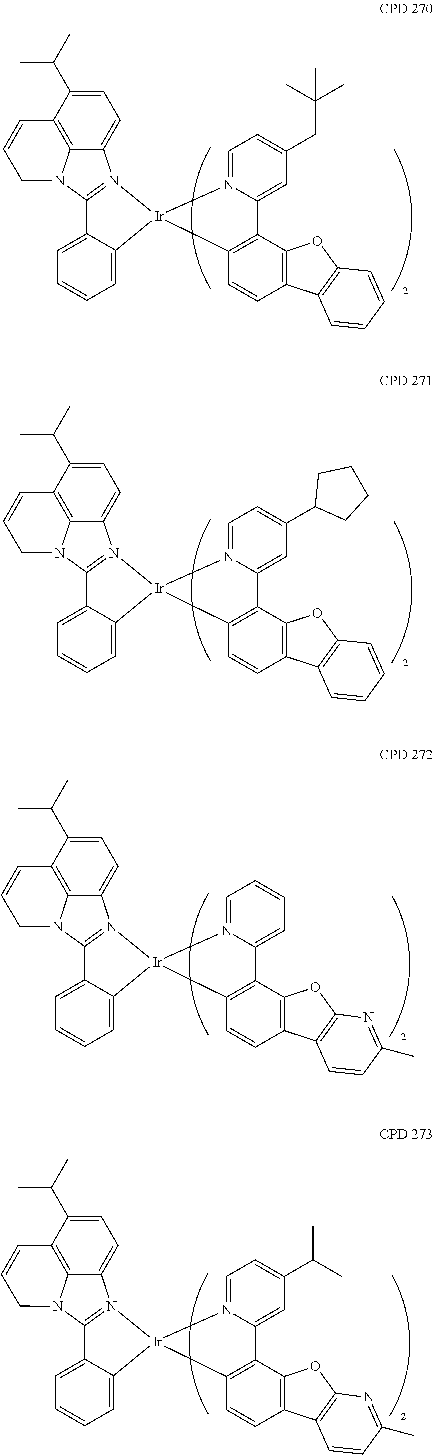

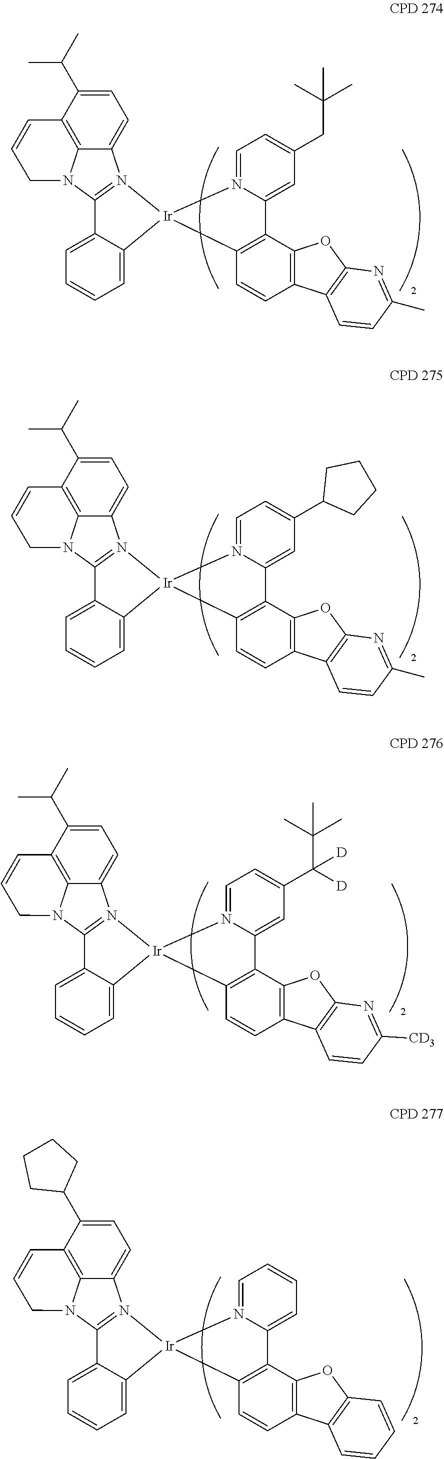

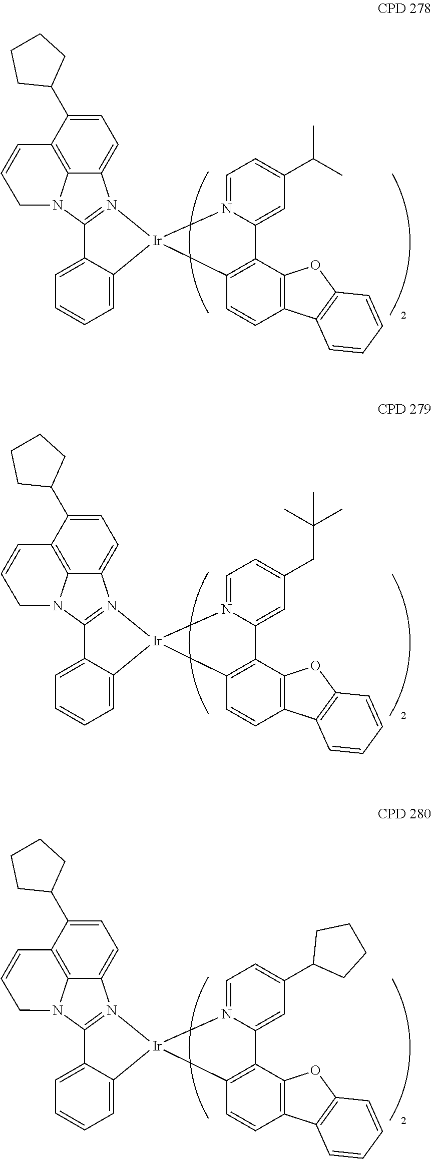

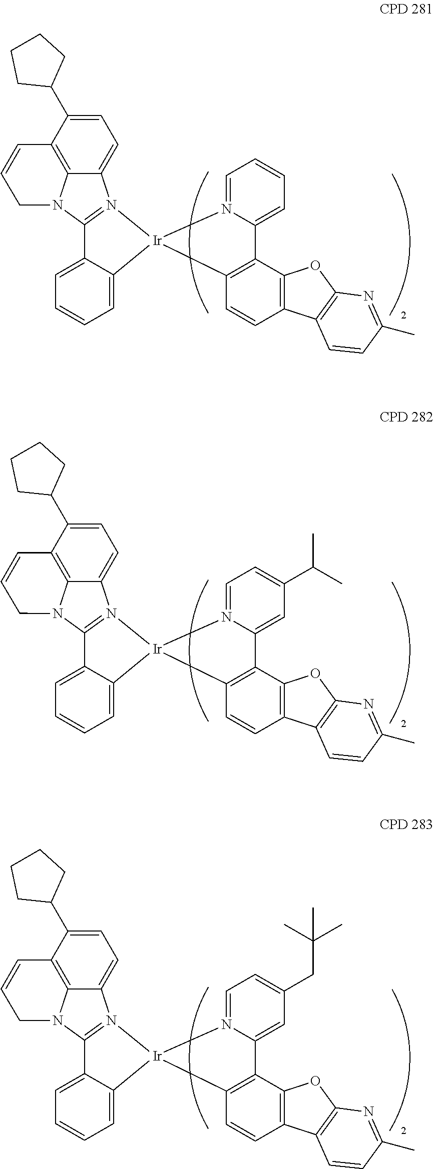

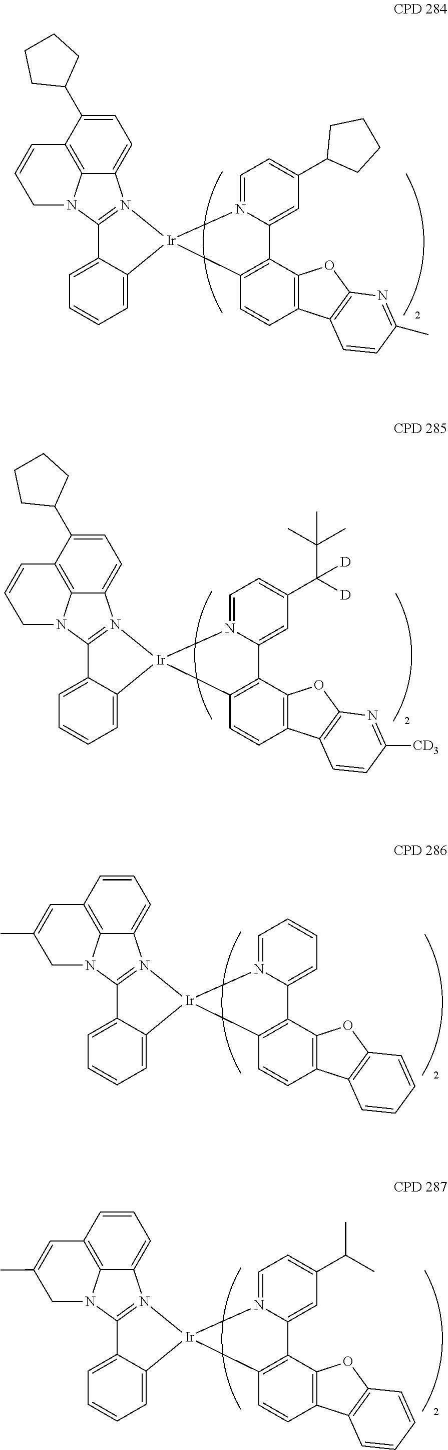

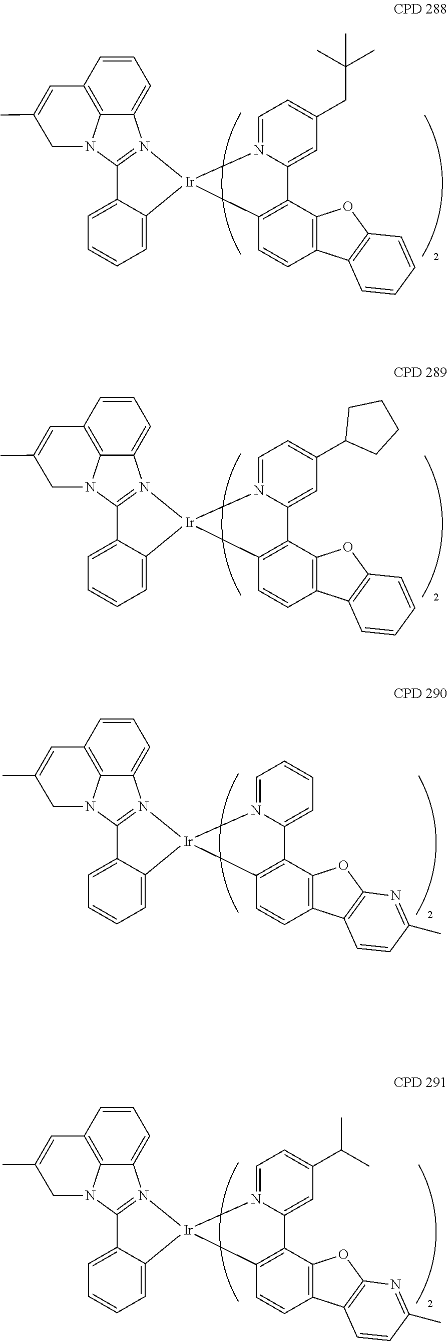

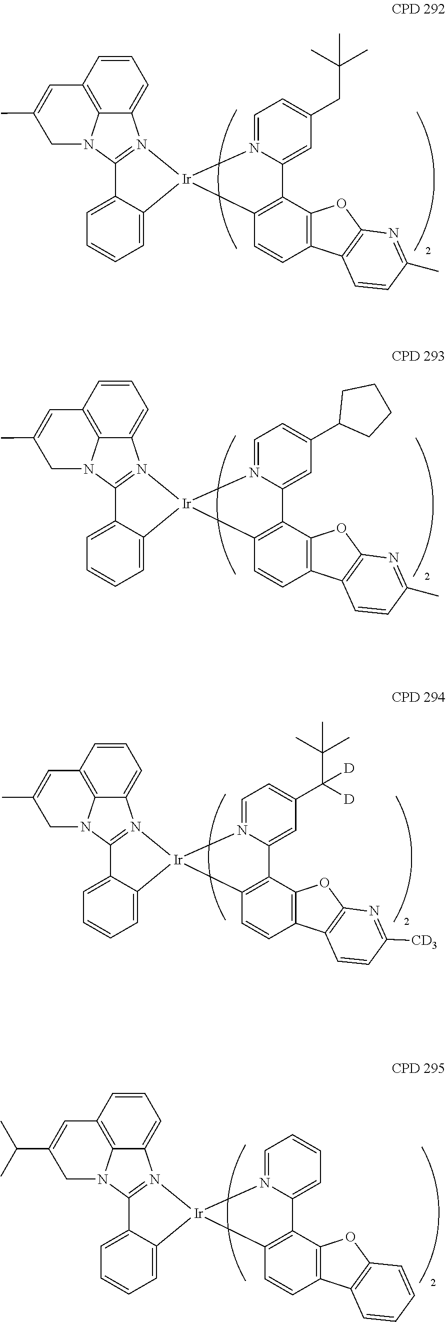

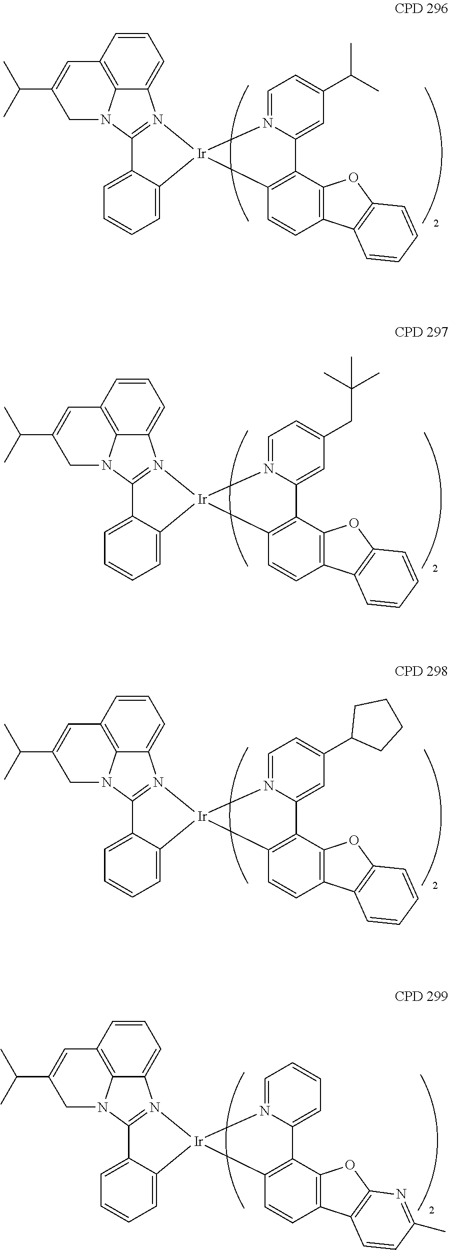

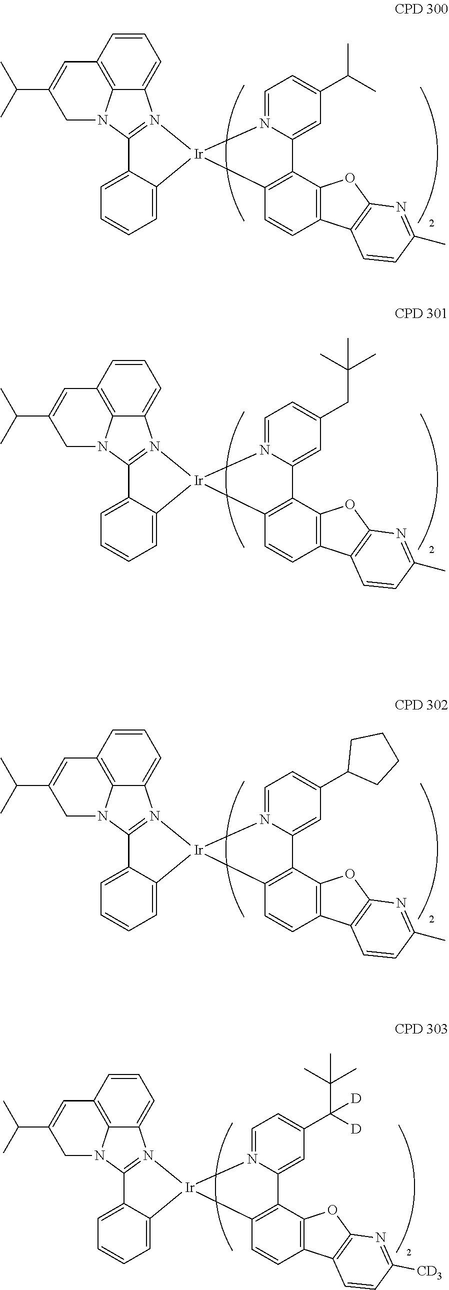

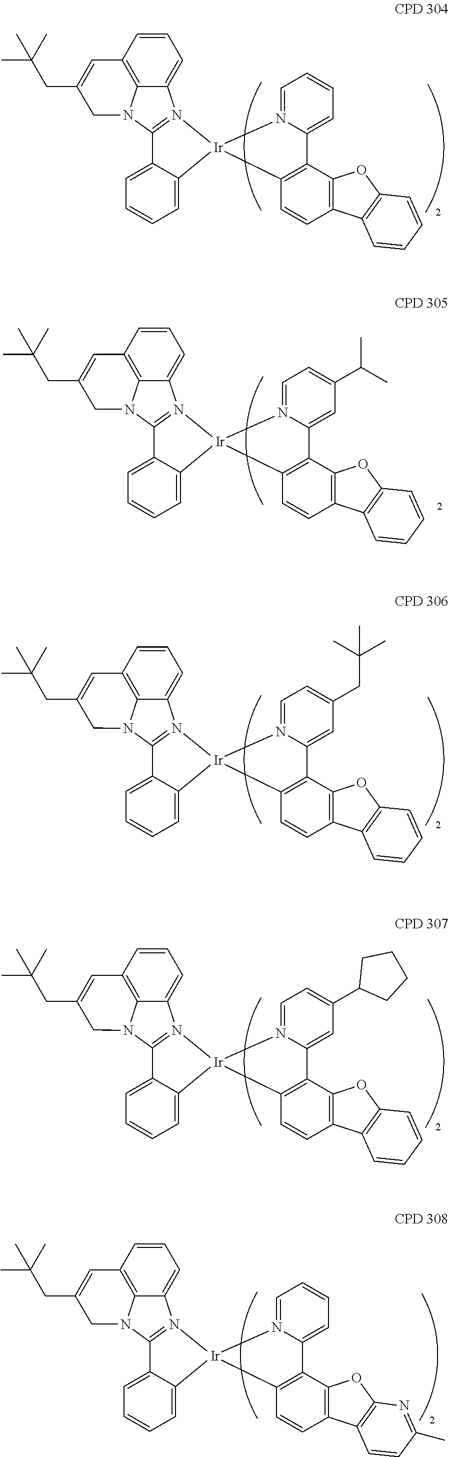

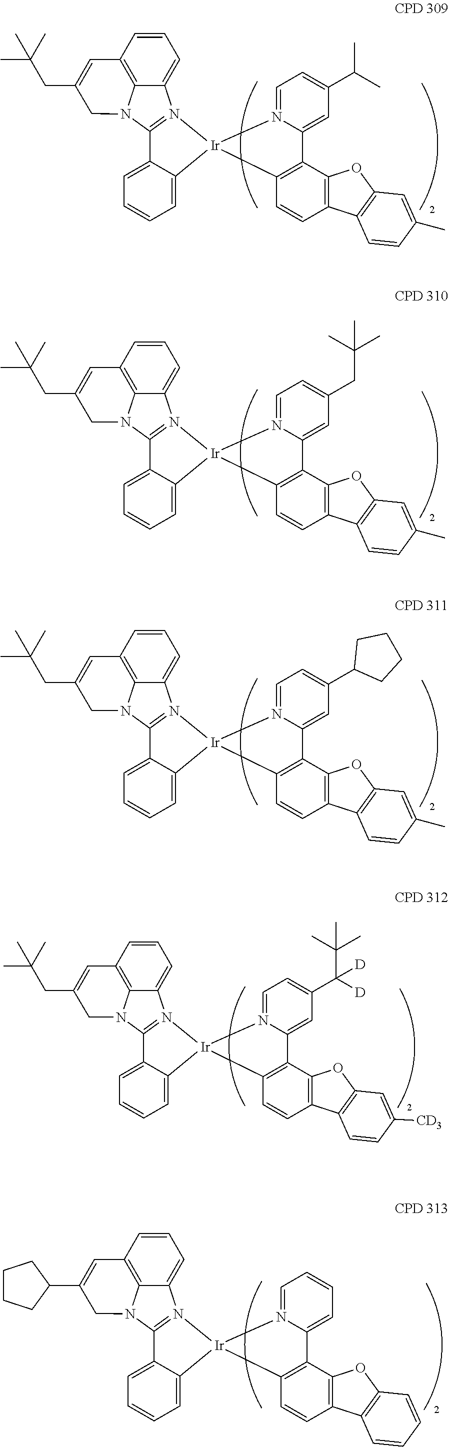

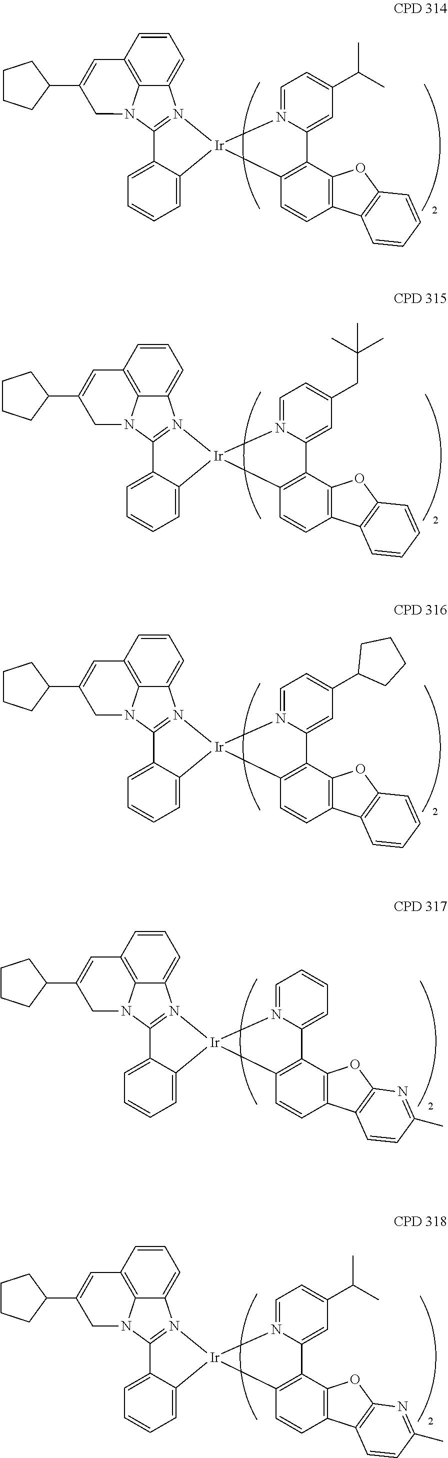

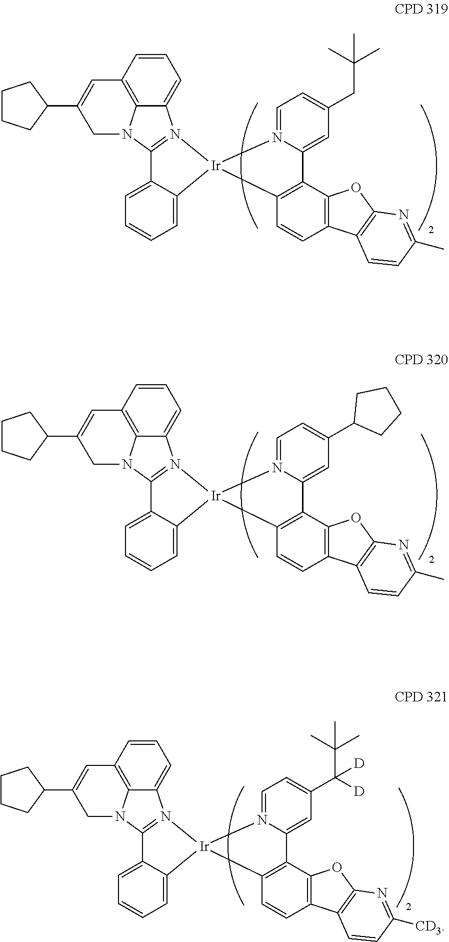

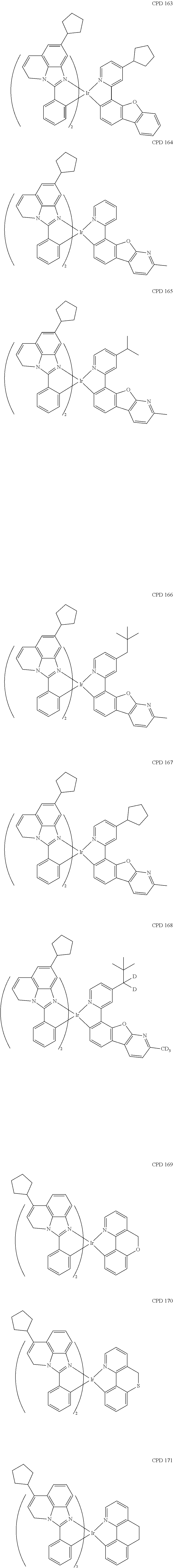

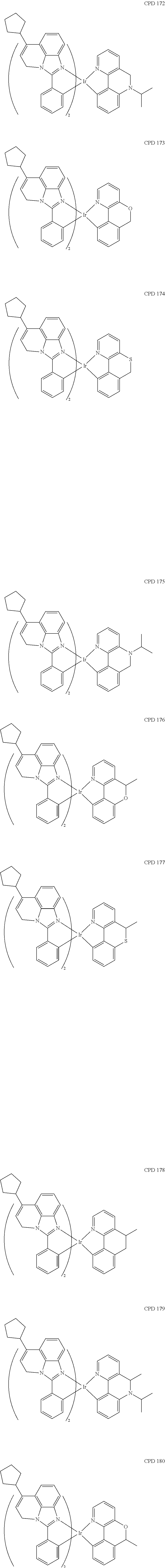

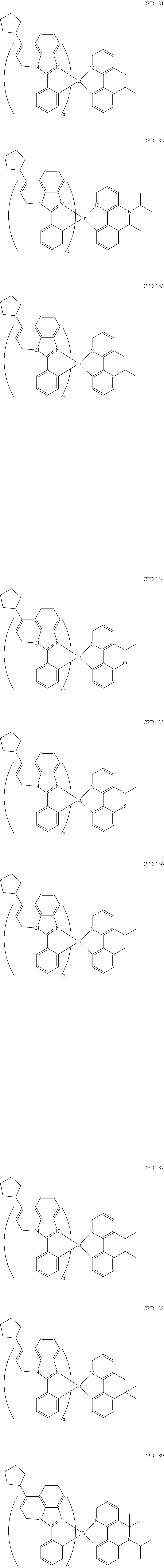

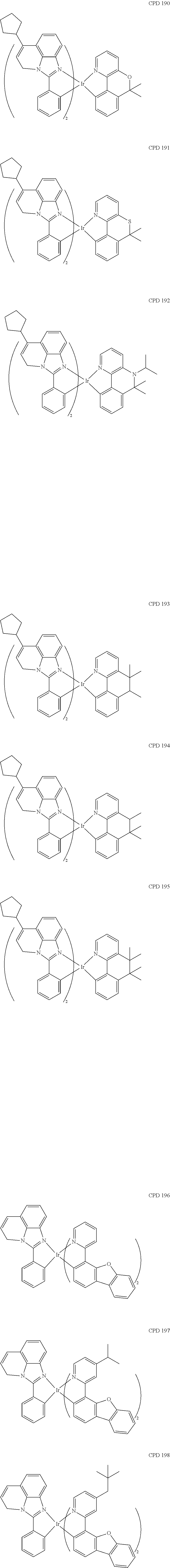

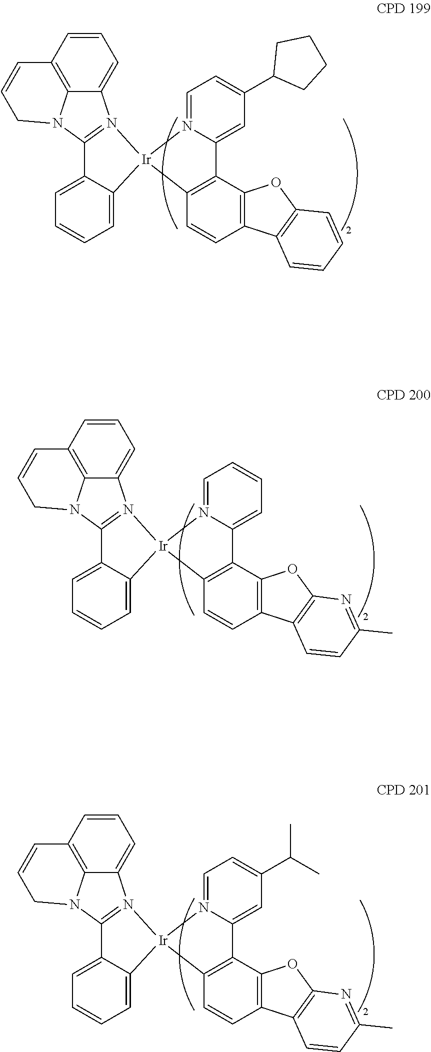

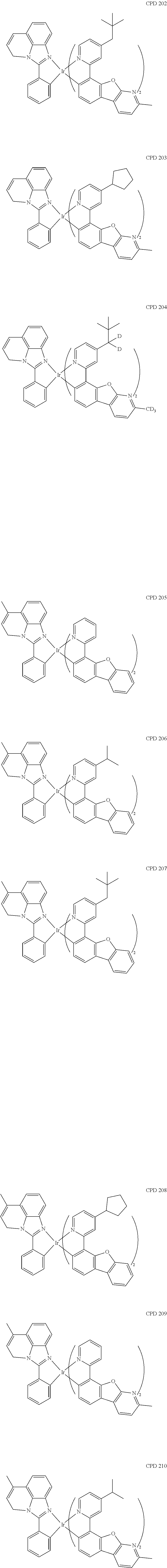

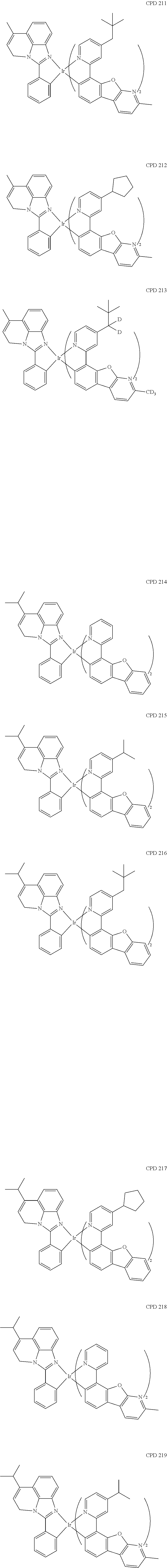

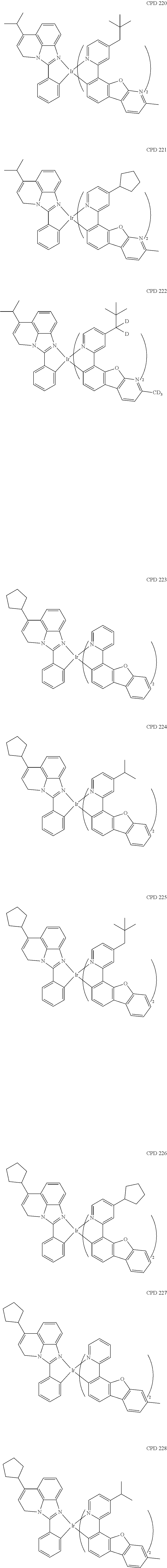

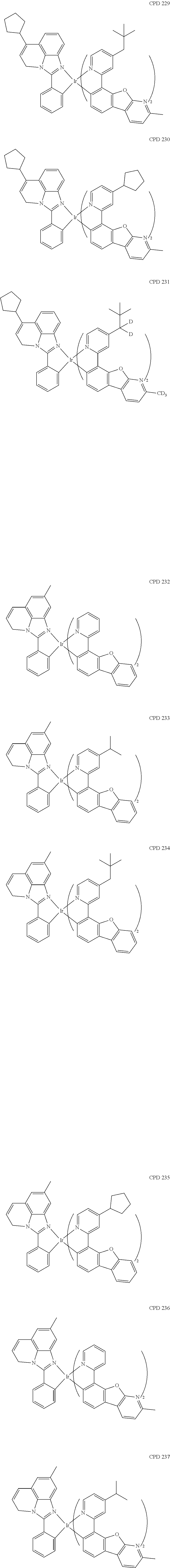

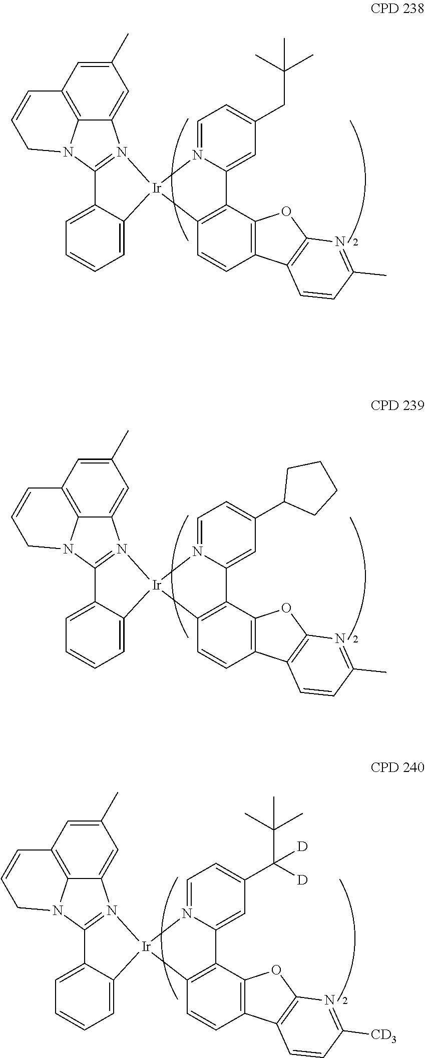

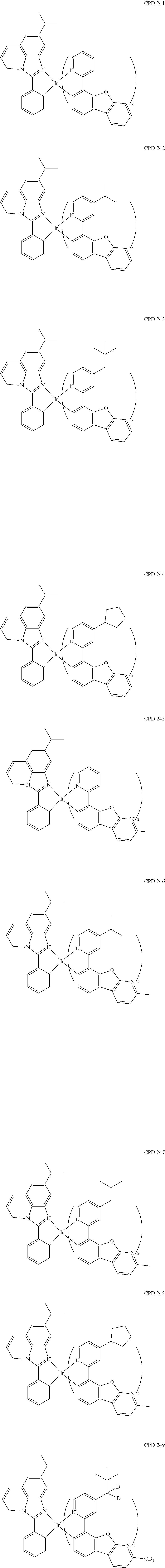

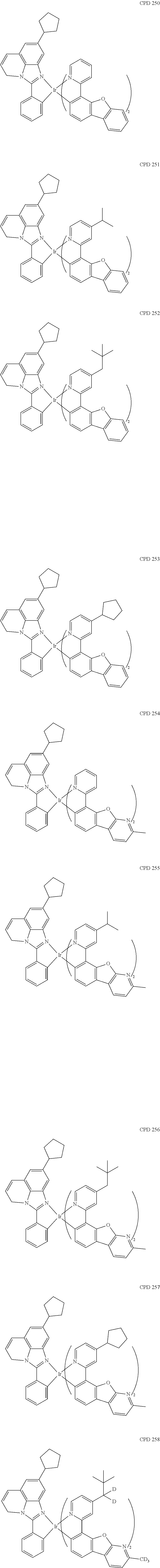

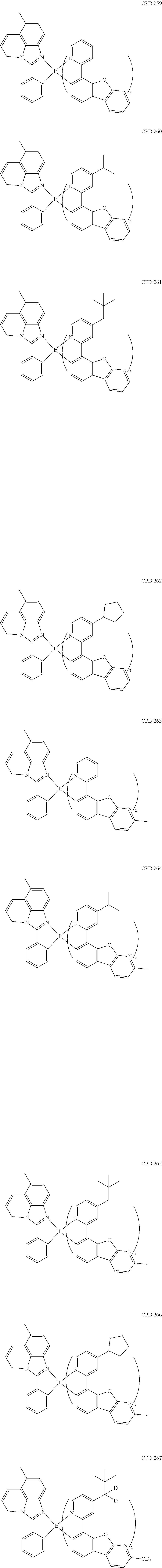

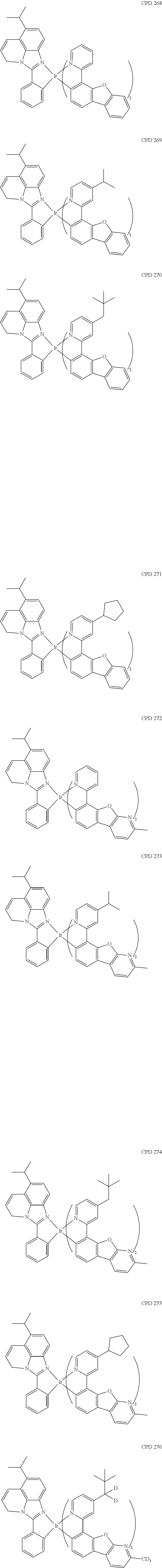

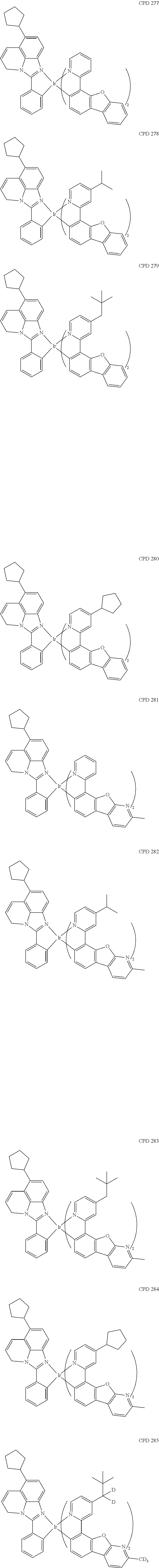

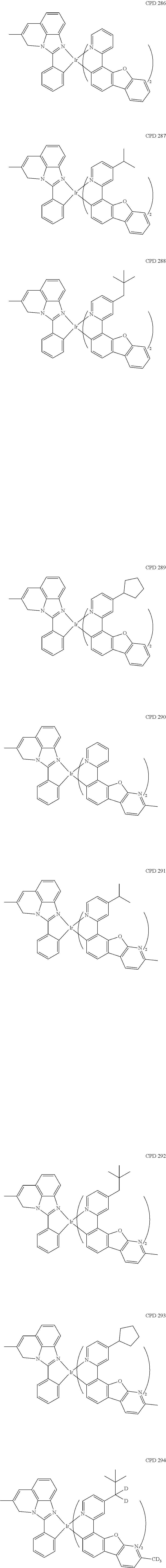

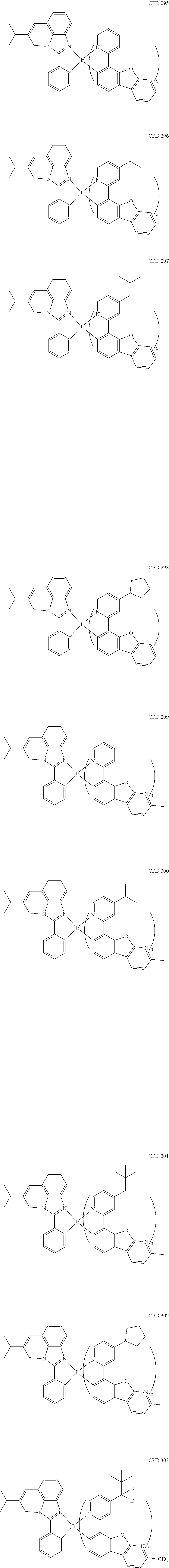

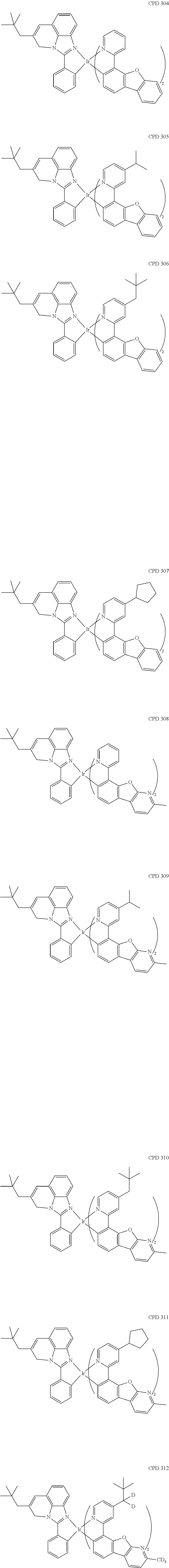

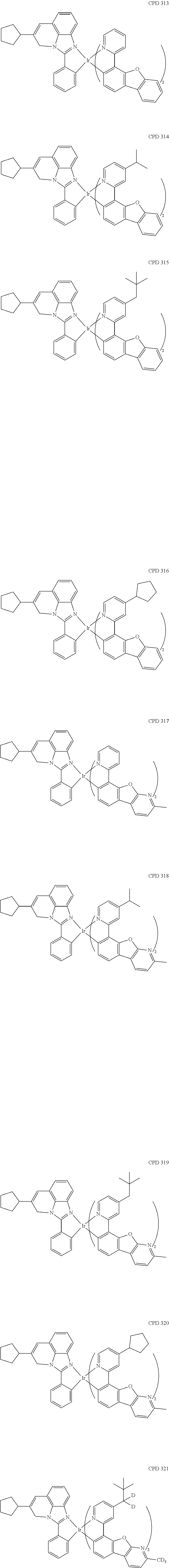

16. Application of the organometallic compound according to claim 1 in an organic electroluminescent device.

17. The application according to claim 16, wherein the organometallic compound is used as a green light-emitting doping material of a light-emitting layer in the organic electroluminescent device.

18. The organometallic compound according to claim 3, wherein at least one of the Rb and the Re is not hydrogen.

19. Application of the organometallic compound according to claim 2 in an organic electroluminescent device.

20. Application of the organometallic compound according to claim 3 in an organic electroluminescent device.
